(19) United States
(12) Patent Application Publication
(10) Pub. No.: US 2020/0176695 A1
(43) Pub. Date: Jun. 4, 2020

(54) Organic light-emitting diode with High efficiency and low voltage

(71) Applicant: SFC CO., LTD., Cheongju-si (KR)

(72) Inventors: Sung Hoon JOO, Goyang-si (KR); Byung-sun YANG, Namwon-si (KR); Ji-Hwan KIM, Anyang-si (KR); Su-Jin KIM, Chuncheon-si (KR); Hyeon Jun JO, Busan (KR); Sungeun CHOI, Seoul (KR)

(21) Appl. No.: 16/563,621

(22) Filed: Sep. 6, 2019

(30) Foreign Application Priority Data
Jul. 12, 2018 (KR) 10-2018-0081138

(51) Int. Cl. H01L 51/00

(52) U.S. Cl. CPC H01L 51/0094; H01L 51/0052; H01L 51/006; H01L 51/0072; H01L 51/5056; H01L 51/0074; H01L 51/0061; H01L 51/008; H01L 51/0073

(57) ABSTRACT

Disclosed herein an organic light-emitting diode of high efficiency, comprising: a first electrode; a second electrode facing the first electrode; a hole injection layer or a hole transport layer interposed between the first electrode and the second electrode; and a light-emitting layer, wherein the hole injection layer or the hole transport layer comprises at least one of the amine compounds represented by the following Chemical Formula A or B and the light-emitting layer comprises at least one of the boron compounds represented by the following Chemical Formula C. Chemical Formulas A to C are as described in the specification.

### TECHNICAL FIELD

The present disclosure pertains to an organic light-emitting diode exhibiting high efficiency and low driving voltage properties and, more particularly, to an organic light-emitting diode exhibiting high efficiency and low driving voltage properties, in which a material having a specific structure is used for a hole injection layer or a hole transport layer and a material having a different specific structure is contained as a dopant in a light-emitting layer.

### BACKGROUND ART

Organic light-emitting diodes (OLEDs), based on self-luminescence, are used to create digital displays with the advantage of having a wide viewing angle and being able to be made thinner and lighter than liquid crystal displays. In addition, an OLED display exhibits a very fast response time. Accordingly, OLEDs find applications in the full color display field or the illumination field.

In general, the term “organic light-emitting phenomenon” refers to a phenomenon in which electrical energy is converted to light energy by means of an organic material. An organic light-emitting diode using the organic light-emitting phenomenon has a structure usually including an anode, a cathode, and an organic material layer interposed therebetween.

In this regard, the organic material layer may have, for the most part, a multilayer structure consisting of different materials, for example, a hole injection layer, a hole transport layer, a light-emitting layer, an electron transport layer, and an electron injection layer in order to enhance the efficiency and stability of the organic light-emitting diode. In the organic light-emitting diode having such a structure, application of a voltage between the two electrodes injects a hole from the anode and an electron from the cathode to the organic layer. In the luminescent zone, the hole and the electron recombine to produce an exciton. When the exciton returns to the ground state from the excited state, the molecule of the organic layer emits light. Such an organic light-emitting diode is known to have characteristics such as self-luminescence, high luminance, high efficiency, low driving voltage, a wide viewing angle, high contrast, and high-speed response.

Materials used as organic layers in OLEDs may be divided into luminescent materials and charge transport materials, for example, a hole injection material, a hole transport material, an electron injection material, and an electron transport material and, as needed, further into an electron-blocking material or a hole-blocking material.

With regard to related arts pertaining to hole transport layers, reference may be made to Korean Patent No. 10-1074193 (issued Oct. 14, 2011), which describes an organic light-emitting diode using a carbazole structure fused with at least one benzene ring in a hole transport layer, and Korean Patent No. 10-1455156 (issued Oct. 27, 2014), which describes an organic light-emitting diode in which the HOMO energy level of an auxiliary light-emitting layer is set between those of a hole transport layer and a light-emitting layer.

In addition, Korean Patent No. 10-2016-0119683 A (issued Oct. 14, 2016), a prior art pertaining to a dopant compound in a light-emitting layer, discloses an organic light-emitting diode employing a novel polycyclic aromatic compound in which multiple aromatic rings are connected via boron and oxygen atoms.

In spite of enormous effort for fabricating organic light-emitting diodes, however, there is still continued need to develop novel organic light-emitting diodes having more effective properties, compared to those developed based on conventional technology.

### PRIOR ART DOCUMENT

Korean Patent No. 10-1074193 (issued Oct. 14, 2011)

Korean Patent No. 10-1455156 (issued Oct. 27, 2014)

Korean Patent No. 10-2016-0119683 A (published Oct. 14, 2016)

### DETAILED DESCRIPTION OF THE INVENTION

### Technical Problem

Therefore, the purpose of the present disclosure is to provide a novel organic light-emitting diode with a low driving voltage and high efficiency, wherein dopant and host materials of specific structures are employed.

### Technical Solution

The present disclosure provides an organic light-emitting diode, comprising: a first electrode; a second electrode facing the first electrode; a hole injection layer or a hole transport layer interposed between the first electrode and the second electrode; and a light-emitting layer,

wherein the hole injection layer or the hole transport layer comprises at least one of the amine compounds represented by the following Chemical Formula A or B and the light-emitting layer comprises at least one of the boron compounds represented by the following Chemical Formula C:

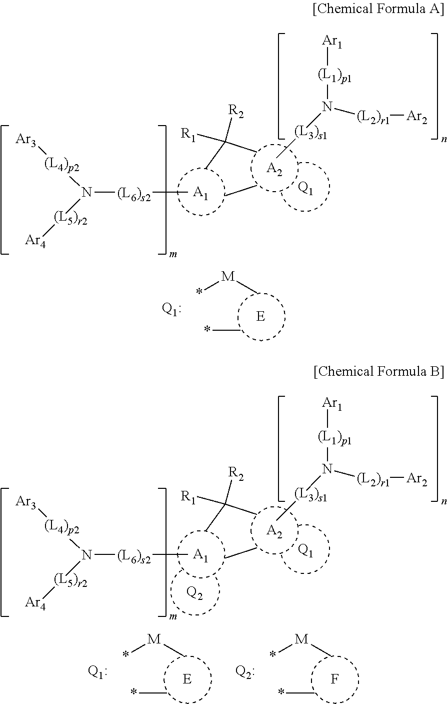

wherein,

A₁, A₂, E, and F, which may be the same or different, are each independently a substituted or unsubstituted aromatic hydrocarbon ring of 6 to 50 carbon atoms, or a substituted or unsubstituted heteroaromatic ring of 2 to 40 carbon atoms;

wherein two adjacent carbon atoms within the aromatic ring of A₁ and two adjacent carbon atoms within the aromatic ring of A₂ form a 5-membered ring with a carbon atom connected to both substituents R₁ and R₂, thus establishing a fused ring structure;

linkers L₁ to L₆, which may be the same or different, are each independently selected from among a single bond, a substituted or unsubstituted alkylene of 1 to 60 carbon atoms, a substituted or unsubstituted alkenylene of 2 to 60 carbon atoms, a substituted or unsubstituted alkynylene of 2 to 60 carbon atoms, a substituted or unsubstituted cycloalkylene of 3 to 60 carbon atoms, a substituted or unsubstituted heterocycloalkylene of 2 to 60 carbon atoms, a substituted or unsubstituted arylene of 6 to 60 carbon atoms, and a substituted or unsubstituted heteroarylene of 2 to 60 carbon atoms;

M is selected from among N—R₃, CR₄R₅, SiR₆R₇, GeR₈R₉, O, S, and Se;

R₁ to R₉ and Ar₁ to Ar₄, which may be the same or different, are each independently selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted alkenyl of 2 to 30 carbon atoms, a substituted or unsubstituted alkynyl of 2 to 20 carbon atoms, a substituted or unsubstituted cycloalkyl of 3 to 30 carbon atoms, a substituted or unsubstituted cycloalkenyl of 5 to 30 carbon atoms, a substituted or unsubstituted heteroaryl of 2 to 50 carbon atoms, a substituted or unsubstituted heterocycloalkyl of 2 to 30 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted alkylamine of 1 to 30 carbon atoms, a substituted or unsubstituted arylamine of 6 to 30 carbon atoms, a substituted or unsubstituted alkylsilyl of 1 to 30 carbon atoms, a substituted or unsubstituted arylsilyl of 6 to 30 carbon atoms, a substituted or unsubstituted alkyl germanium of 1 to 30 carbon atoms, a substituted or unsubstituted aryl germanium of 1 to 30 carbon atoms, a cyano, a nitro, and a halogen,

wherein R₄ and R₂ may be connected to each other to form a mono- or polycyclic aliphatic or aromatic ring which may bear at least one heteroatom selected from among N, O, P, Si, S, Ge, Se, and Te as a ring member;

p1 and p2, r1 and r2, and s1 and s2 are each independently an integer of 1 to 3, under which when any of them is 2 or greater, the corresponding linkers L₁ to L₆ may be the same or different,

m and n, which may be the same or different, are each independently an integer of 0 or 1, with a proviso of m+n=1 or 2,

Ar₁ and Ar₂ may be connected to each other to form a ring and Ara and Ar₄ may be connected to each other to form a ring;

two adjacent carbon atoms of the A₂ ring moiety of Chemical Formula A may occupy respective positions * of Structural Formula Q₁ to form a fused ring,

two adjacent carbon atoms of the A₂ ring moiety of Chemical Formula B may occupy respective positions * of Structural Formula Q₁ to form a fused ring and two adjacent carbon atoms of the A₁ ring moiety of Chemical Formula B may occupy respective positions * of structural Formula Q₂ to form a fused ring

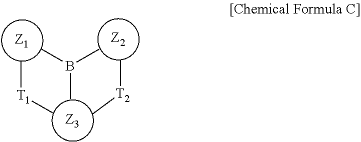

wherein,

Z₁ to Z₃, which may be the same or different, are each independently a substituted or unsubstituted aromatic hydrocarbon ring of 6 to 50 carbon atoms, or a substituted or unsubstituted heteroaromatic ring of 2 to 40 carbon atoms;

T₁ is selected from among N—R₁₁, CR₁₂R₁₃, O, and S;

T₂ is selected from among N—R₁₄, CR₁₅R₁₆, O, and S;

wherein R₁₁ to R₁₆, which may be the same or different, are each independently selected from among a hydrogen atom, a deuterium atom, a substituted or unsubstituted alkyl of 1 to 30 carbon atoms, a substituted Or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen wherein R₁₁ to R₁₆ may each be linked to at least one of Z₁ to Z₃ to further form a mono- or polycyclic aliphatic or aromatic ring.

Here, the term “substituted” in the expression “substituted or unsubstituted” used for [Chemical Formula A] to [Chemical Formula C] means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, an alkenyl of 2 to 24 carbon atoms, an alkynyl of 2 to 24 carbon atoms, a heteroalkyl of 1 to 24 carbon atoms, an aryl of 6 to 24 carbon atoms, an arylalkyl of 7 to 24 carbon atoms, a heteroaryl of 2 to 24 carbon atoms or a heteroarylalkyl of 2 to 24 carbon atoms, an alkoxy of 1 to 24 carbon atoms, an alkylamino of 1 to 24 carbon atoms, an arylamino of 6 to 24 carbon atoms, a heteroarylamino of 1 to 24 carbon atoms, an alkylsilyl of 1 to 24 carbon atoms, an arylsilyl of 6 to 24 carbon atoms, and an aryloxy of 6 to 24 carbon atoms.

### Advantageous Effect

Over conventional organic light-emitting diodes, the organic light-emitting diode according to the present disclosure has the advantage of being driven at a low voltage and exhibiting improved efficiency.

### BRIEF DESCRIPTION OF THE DRAWINGS

FIG. 1 is a schematic view of an organic light-emitting diode according to an embodiment of the present disclosure.

### BEST MODE FOR INVENTION

Hereinafter, exemplary embodiments which can be easily implemented by those skilled in the art will be described with reference to the accompanying drawings. In each drawing of the present disclosure, sizes or scales of components may be enlarged or reduced than their actual sizes or scales for better illustration, and known components are not depicted therein to clearly show features of the present disclosure. Therefore, the present disclosure is not limited to the drawings. When describing the principle of the embodiments of the present disclosure in detail, details of well-known functions and features may be omitted to avoid unnecessarily obscuring the presented embodiments.

In drawings, for convenience of description, sizes of components may be exaggerated for clarity. For example, since sizes and thicknesses of components in drawings are arbitrarily shown for convenience of description, the sizes and thicknesses are not limited thereto. Furthermore, throughout the description, the terms “on” and “over” are used to refer to the relative positioning, and mean not only that one component or layer is directly disposed on another component or layer but also that one component or layer is indirectly disposed on another component or layer with a further component or layer being interposed therebetween. Also, spatially relative terms, such as “below”, “beneath”, “lower”, and “between”, may be used herein for ease of description to refer to the relative positioning.

Throughout the specification, unless explicitly described to the contrary, the word “comprise” and variations such as “comprises” or “comprising” will be understood to imply the inclusion of stated elements but not the exclusion of any other elements.

The present disclosure provides an organic light-emitting diode, comprising: a first electrode; a second electrode facing the first electrode; a hole injection layer or a hole transport layer interposed between the first electrode and the second electrode; and a light-emitting layer, wherein the hole injection layer or the hole transport layer comprises at least one of the amine compounds represented by the following Chemical Formula A or B and the light-emitting layer comprises at least one of the boron compounds represented by the following Chemical Formula C:

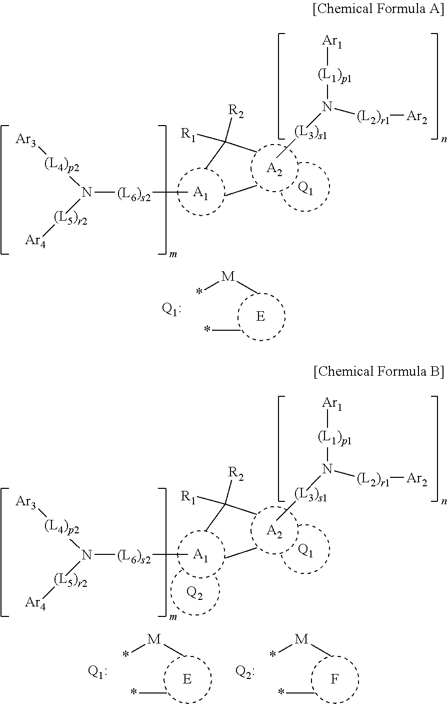

wherein,

A₁, A₂, E, and F, which may be the same or different, are each independently a substituted or unsubstituted aromatic hydrocarbon ring of 6 to 50 carbon atoms, or a substituted or unsubstituted heteroaromatic ring of 2 to 40 carbon atoms;

wherein two adjacent carbon atoms within the aromatic ring of A₁ and two adjacent carbon atoms within the aromatic ring of A₂ form a 5-membered ring with a carbon atom connected to both substituents R₁ and R₂, thus establishing a fused ring structure;

linkers L₁ to L₆, which may be the same or different, are each independently selected from among a single bond, a substituted or unsubstituted alkylene of 1 to 60 carbon atoms, a substituted or unsubstituted alkenylene of 2 to 60 carbon atoms, a substituted or unsubstituted alkynylene of 2 to 60 carbon atoms, a substituted or unsubstituted cycloalkylene of 3 to 60 carbon atoms, a substituted or unsubstituted heterocycloalkylene of 2 to 60 carbon atoms, a substituted or unsubstituted arylene of 6 to 60 carbon atoms, and a substituted or unsubstituted heteroarylene of 2 to 60 carbon atoms;

M is selected from among N—R₃, CR₄R₅, SiR₆R₇, GeR₈R₉, O, S, and Se;

R₁ to R₉ and Ar₁ to Ar₄, which may be the same or different, are each independently selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted alkenyl of 2 to 30 carbon atoms, a substituted or unsubstituted alkynyl of 2 to 20 carbon atoms, a substituted or unsubstituted cycloalkyl of 3 to 30 carbon atoms, a substituted or unsubstituted cycloalkenyl of 5 to 30 carbon atoms, a substituted or unsubstituted heteroaryl of 2 to 50 carbon atoms, a substituted or unsubstituted heterocycloalkyl of 2 to 30 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted alkylamine of 1 to 30 carbon atoms, a substituted or unsubstituted arylamine of 6 to 30 carbon atoms, a substituted or unsubstituted alkylsilyl of 1 to 30 carbon atoms, a substituted or unsubstituted arylsilyl of 6 to 30 carbon atoms, a substituted or unsubstituted alkyl germanium of 1 to 30 carbon atoms, a substituted or unsubstituted aryl germanium of 1 to 30 carbon atoms, a cyano, a nitro, and a halogen,

wherein R₁ and R₂ may be connected to each other to form a mono- or polycyclic aliphatic or aromatic ring which may bear at least one heteroatom selected from among N, O, P, Si, S, Ge, Se, and Te as a ring member;

p1 and p2, r1 and r2, and s1 and s2 are each independently an integer of 1 to 3, under which when any of them is 2 or greater, the corresponding linkers L₁ to L₆ may be the same or different,

m and n, which may be the same or different, are each independently an integer of 0 or 1, with a proviso of m+n=1 or 2,

Ar₁ and Ar₂ may be connected to each other to form a ring and Ara and Ar₄ may be connected to each other to form a ring;

two adjacent carbon atoms of the A₂ ring moiety of Chemical Formula A may occupy respective positions * of Structural Formula Q₁ to form a fused ring,

two adjacent carbon atoms of the A₂ ring moiety of Chemical Formula B may occupy respective positions * of Structural Formula Q₁ to form a fused ring and two adjacent carbon atoms of the A₁ ring moiety of Chemical Formula B may occupy respective positions * of structural Formula Q₂ to form a fused ring

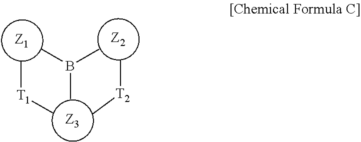

wherein,

Z₁ to Z₃, which may be the same or different, are each independently a substituted or unsubstituted aromatic hydrocarbon ring of 6 to 50 carbon atoms, or a substituted or unsubstituted heteroaromatic ring of 2 to 40 carbon atoms;

T₁ is selected from among N—R₁₁, CR₁₂R₁₃, O, and S;

T₂ is selected from among N—R₁₄, CR₁₅R₁₆, O, and S;
wherein R₁₁ to R₁₆, which may be the same or different, are each independently selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen wherein R₁₁ to R₁₆ may each be linked to at least one of Z₁ to Z₃ to further form a mono- or polycyclic aliphatic or aromatic ring,

wherein the term “substituted” in the expression “substituted or unsubstituted” used for [Chemical Formula A] to [Chemical Formula C] means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, an alkenyl of 2 to 24 carbon atoms, an alkynyl of 2 to 24 carbon atoms, a heteroalkyl of 1 to 24 carbon atoms, an aryl of 6 to 24 carbon atoms, an arylalkyl of 7 to 24 carbon atoms, a heteroaryl of 2 to 24 carbon atoms or a heteroarylalkyl of 2 to 24 carbon atoms, an alkoxy of 1 to 24 carbon atoms, an alkylamino of 1 to 24 carbon atoms, an arylamino of 6 to 24 carbon atoms, a heteroarylamino of 1 to 24 carbon atoms, an alkylsilyl of 1 to 24 carbon atoms, an arylsilyl of 6 to 24 carbon atoms, and an aryloxy of 6 to 24 carbon atoms.

As used herein, the term “aryl” means an organic radical, derived from an aromatic hydrocarbon by removing one hydrogen atom. Further, the aromatic system may include a fused ring that is formed by adjacent substituents on the aryl radical.

Examples of the aryl include phenyl, o-biphenyl, m-biphenyl, p-biphenyl, o-terphenyl, m-terphenyl, p-terphenyl, naphthyl, anthryl, phenanthryl, pyrenyl, indenyl, fluorenyl, tetrahydronaphthyl, perylenyl, chrysenyl, naphthacenyl, and fluoranthenyl at least one hydrogen atom of which may be substituted by a deuterium atom, a halogen atom, a hydroxy, a nitro, a cyano, a silyl, an amino (—NH₂, —NH(R), —N(R′) (R″) wherein R′ and R″ are each independently an alkyl of 1 to 10 alkyl, in this case, called “alkylamino”), an amidino, a hydrazine, a hydrazone, a carboxyl, a sulfonic acid, a phosphoric acid, an alkyl of 1 to 24 carbon atoms, a halogenated alkyl of 1 to 24 carbon atoms, an alkenyl of 1 to 24 carbon atoms, an alkynyl of 1 to 24 carbon atoms, a heteroalkyl of 1 to 24 carbon atoms, an aryl of 6 to 24 carbon atoms, an arylalkyl of 6 to 24 carbon atoms, a heteroaryl of 2 to 24 carbon atoms, or a heteroarylalkyl of 2 to 24 carbon atoms.

The substituent heteroaryl used in the compound of the present disclosure refers to a cyclic aromatic system of 2 to 24 carbon atoms bearing one to three heteroatoms selected from among N, O, P, Si, S, Ge, Se, and Te. In the aromatic system, two or more rings may be fused. One or more hydrogen atoms on the heteroaryl may be substituted by the same substituents as on the aryl.

As used herein, the term “heteroaromatic ring” refers to an aromatic hydrocarbon ring bearing as a ring member at least one and preferably one to four identical or different heteroatoms selected from among N, O, P, Si, S, Ge, Se, and Te.

Examples of the substituent alkyl useful in the present disclosure include methyl, ethyl, propyl, isopropyl, isobutyl, sec-butyl, tert-butyl, pentyl, iso-amyl, and hexyl. At least one hydrogen atom of the alkyl may be substituted by the same substituent as in the aryl.

Examples of the substituent alkoxy useful in the present disclosure include methoxy, ethoxy, propoxy, isobutyloxy, sec-butyloxy, pentyloxy, iso-amyloxy, and hexyloxy. At least one hydrogen atom of the alkoxy may be substituted by the same substituent as in the aryl.

Representative among examples of the silyl useful in the present disclosure are trimethylsilyl, triethylsilyl, triphenylsilyl, trimethoxysilyl, dimethoxyphenylsilyl, diphenylmethylsilyl, silyl, diphenylvinylsilyl, methylcyclobutylsilyl, and dimethylfurylsilyl. One or more hydrogen atoms of the silyl may be substituted by the same substituent as in the aryl.

The amine compound represented by Chemical Formula A or B according to the present disclosure has the structural feature wherein at least one of the A₁ ring and A₂ ring has an amine group attached thereto when the structural formula Q₁ is connected to the A₂ ring in Chemical Formula A or when the structural formulas R₇₃ and Q₁ are connected to the A₁ ring and the A₂ ring, respectively, in Chemical Formula B.

In this regard, the amine compound represented by [Chemical Formula A] or [Chemical Formula B] may be preferably a diamine wherein the A₁ ring and the A₂ ring both have respective amine moieties attached thereto, or a monoamine wherein either the A₁ ring or the A₂ ring has an amine moiety attached thereto. In the case of the monoamine compound, the amine moiety bearing Ar₁ and Ar₂ must be attached to the A₂ ring in [Chemical Formula A] and [Chemical Formula B].

The amine compound represented by [Chemical Formula A] or [Chemical Formula B] may be used as a material for the hole injection layer or hole transport layer.

In [Chemical Formula A] or [Chemical Formula B], A₁, A₂, E, and F, which may be the same or different, are each independently a substituted or unsubstituted aromatic hydrocarbon ring of 6 to 50 carbon atoms.

When A₁, A₂, E, and F in [Chemical Formula A] or [Chemical Formula B] each correspond to a substituted or unsubstituted aromatic hydrocarbon ring of 6 to 50 carbon atoms as mentioned above, the substituted or unsubstituted aromatic hydrocarbon rings of 6 to 50 carbon atoms may be the same or different and are each independently one selected from among [Structural Formula 10] to [Structural Formula 21]:

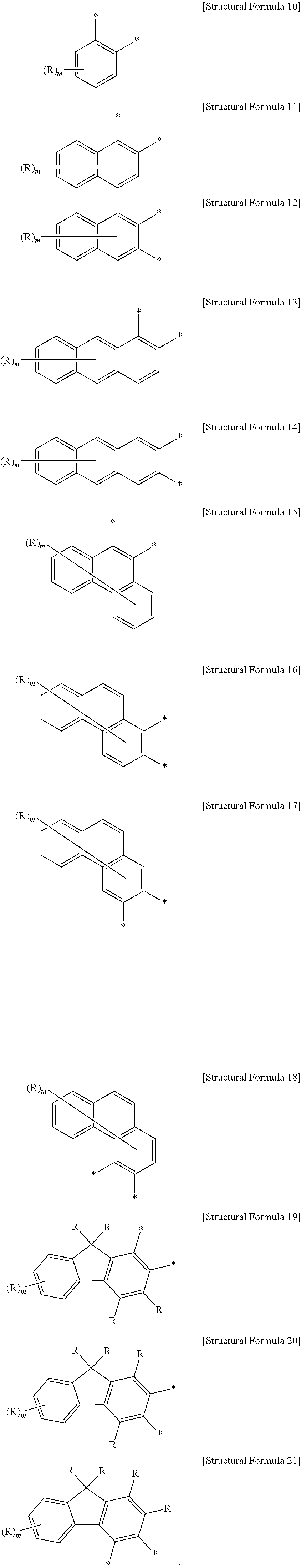

wherein,

“-*” denotes a bonding site participating in forming a 5-membered ring bearing the carbon atom connected to both substituents R₁ and R₂ as a ring member or in forming a 5-membered ring bearing M of structural formula Q₁ or Q₂ as a ring member;

when the aromatic hydrocarbon ring corresponds to the A₁ ring or the A₂ ring and is connected to structure formula Q₁ or Q₂, two adjacent carbon atoms within the ring are linked to * of structural formula Q₁ or Q₂ to form a fused ring;

R is as defined for R₁ and R₂ above; and

m is an integer of 1 to 8 wherein when m is 2 or greater or when R is 2 or greater, the resulting R may be same or different.

In [Chemical Formula A] and [Chemical Formula B], linkers L₁ to L₆ may each be a single bond or one selected from among the following [Structural Formula 22] to [Structural Formula 30]:

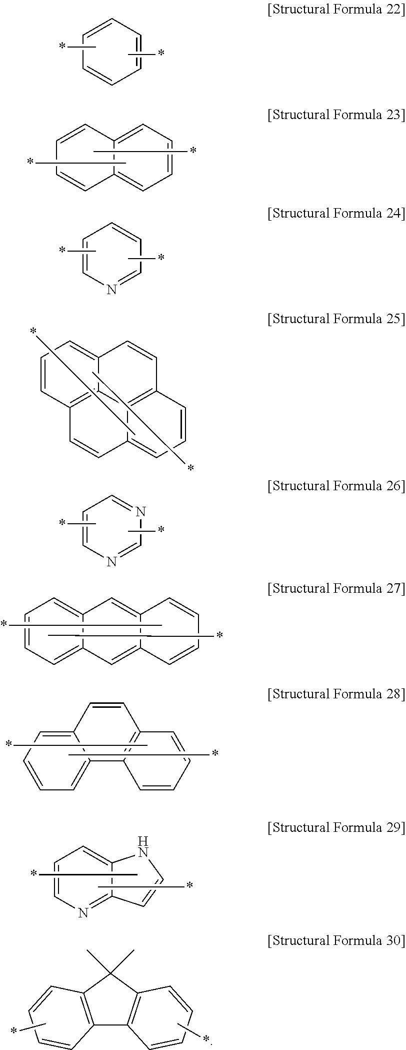

In the linkers, each of unsubstituted carbon atoms of the aromatic ring moiety may be bound with a hydrogen atom or a deuterium atom.

In [Chemical Formula A] or [Chemical Formula B], M may be an oxygen atom (O) or a sulfur atom (S).

In [Chemical Formula A] or [Chemical Formula B], Ar₄ to Ar₄, which may be the same or different, may each be independently one selected from the group among a substituted or unsubstituted alkyl of 1 to 30 carbon atoms, a substituted or unsubstituted aryl of 6 to 50 carbon atoms, a substituted or unsubstituted heteroaryl of 2 to 50 carbon atoms, a substituted or unsubstituted alkylsilyl of 1 to 30 carbon atoms, and a cyano.

According to an embodiment, m and n may satisfy the condition of m+n=1 in [Chemical Formula A] and [Chemical Formula B] and m may be 0 and n may be 1 in [Chemical Formula A].

According another embodiment, m and n may each be 1 in [Chemical Formula A] and [Chemical Formula B].

In addition, the amine compound represented by [Chemical Formula A] or [Chemical Formula B] may be one selected from among the compounds represented by the following <Chemical Formula 1> to <Chemical Formula 300>:

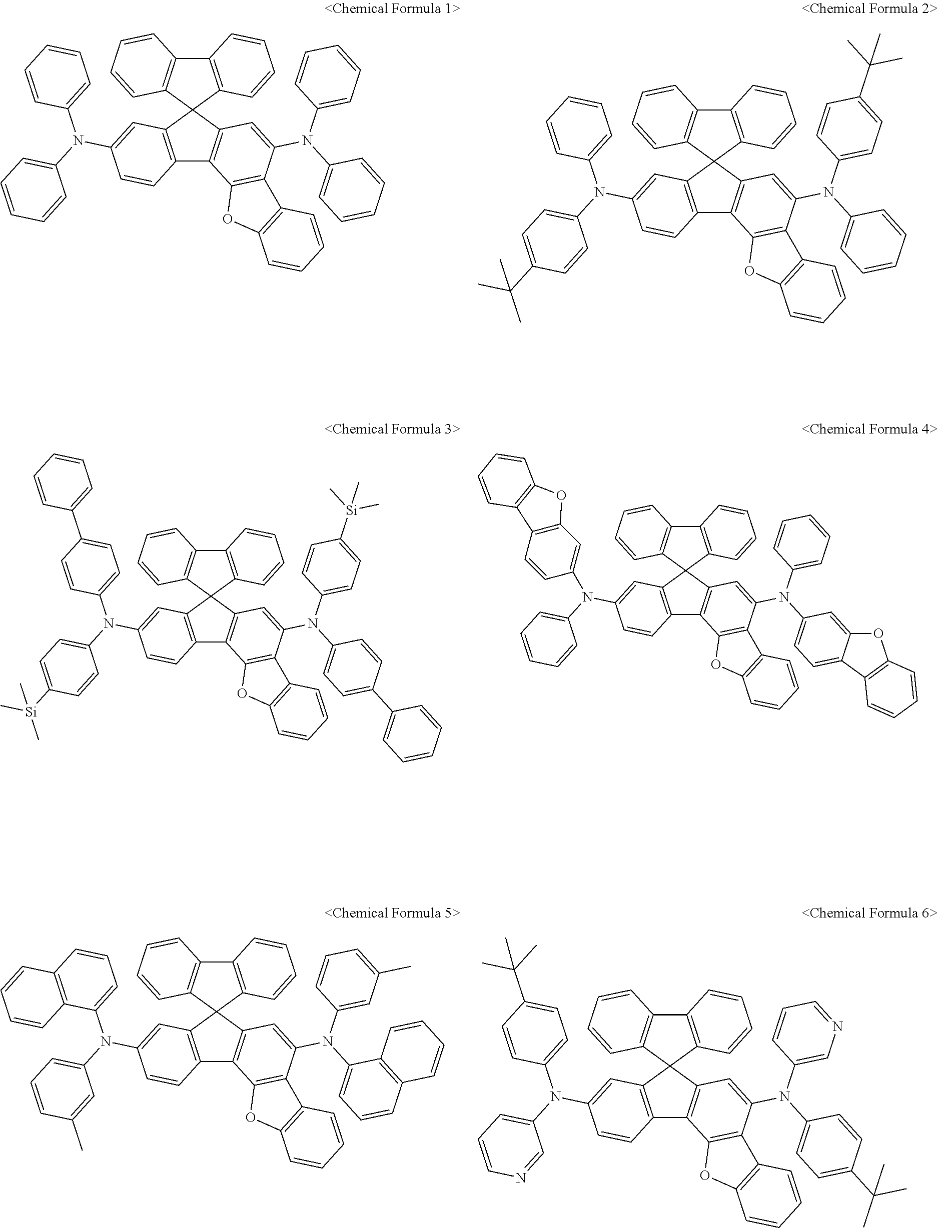

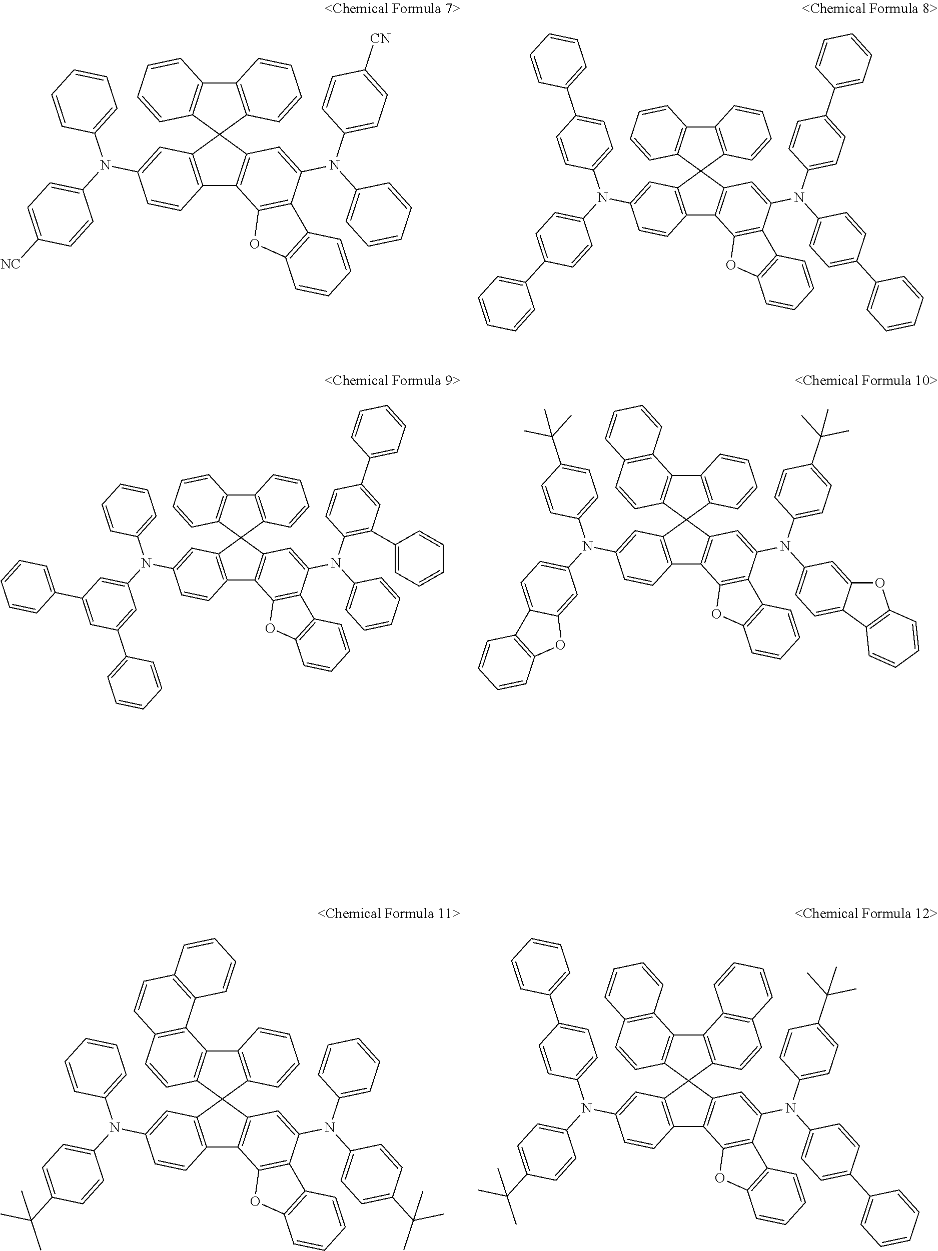

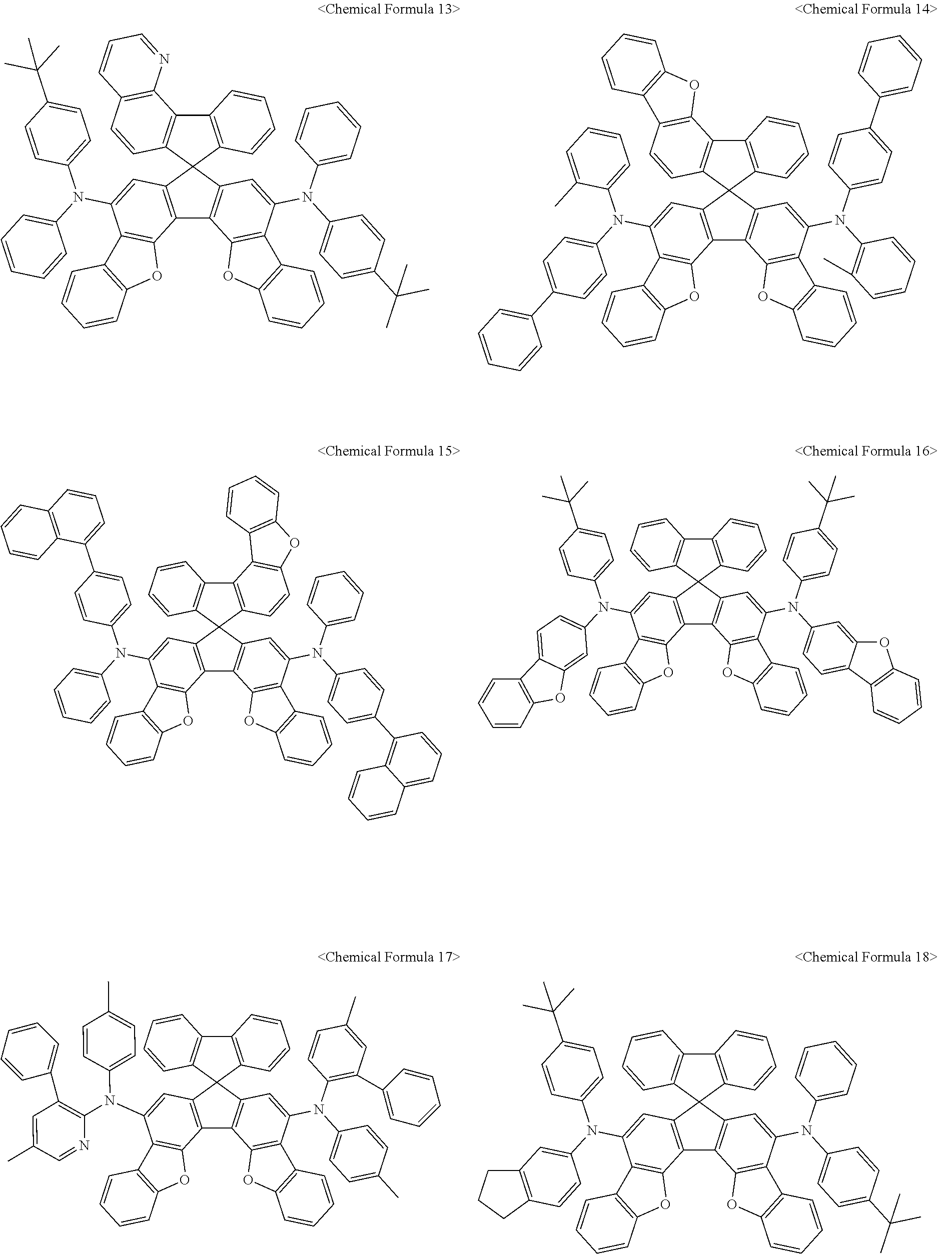

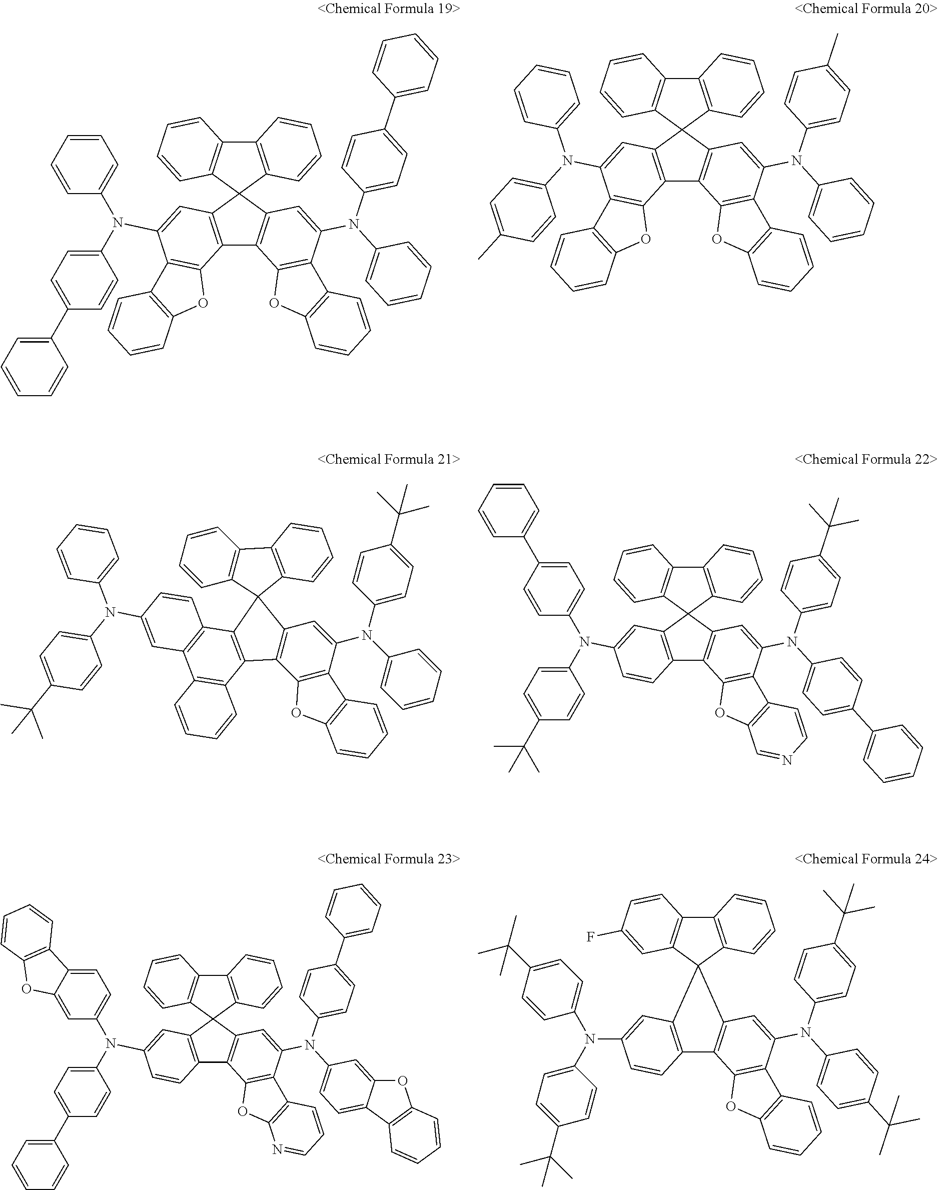

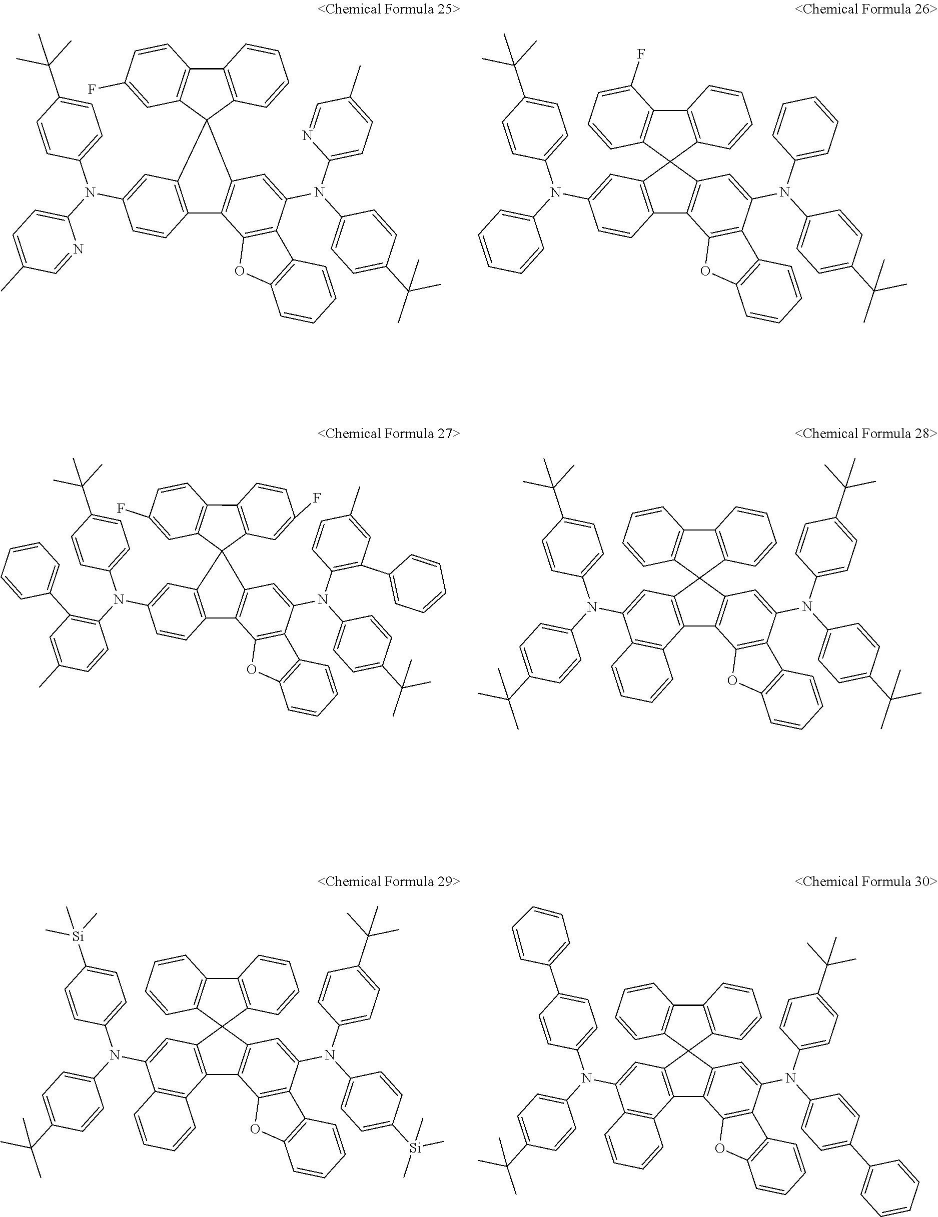

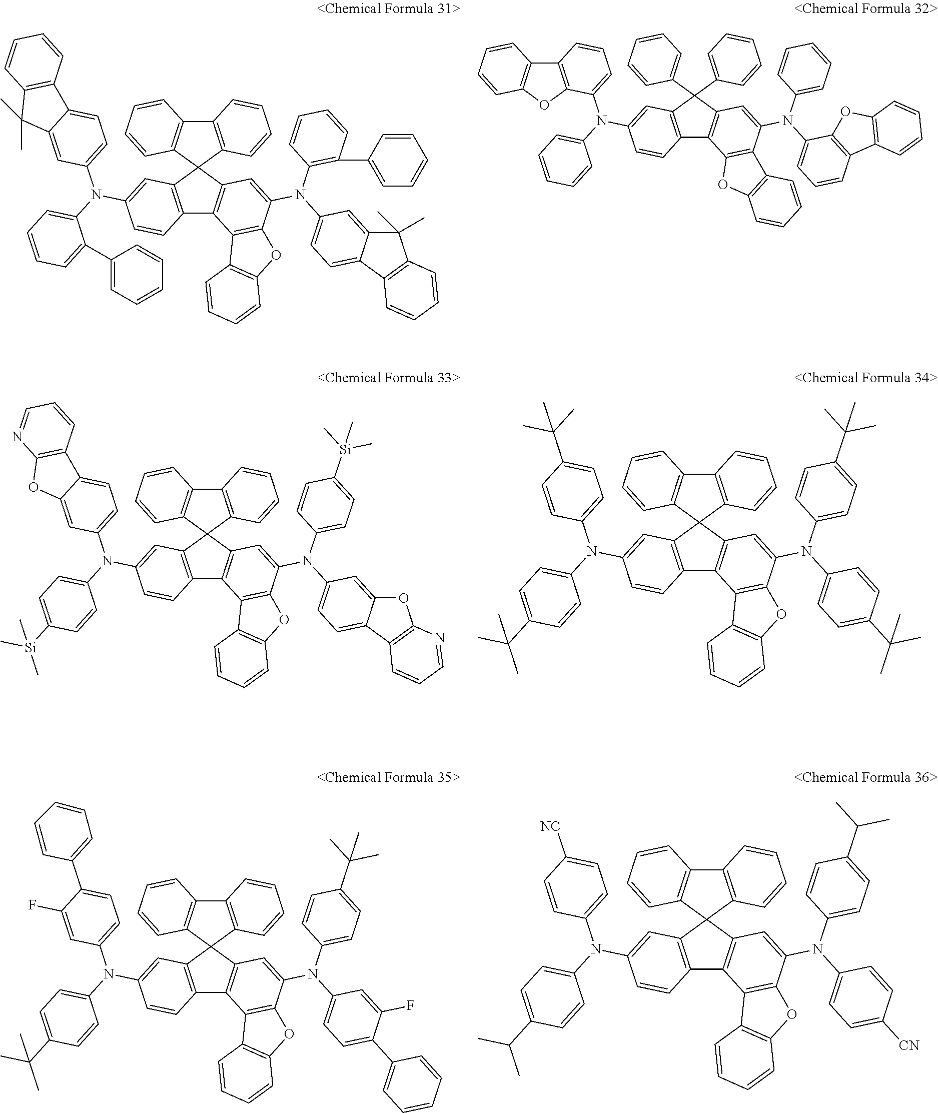

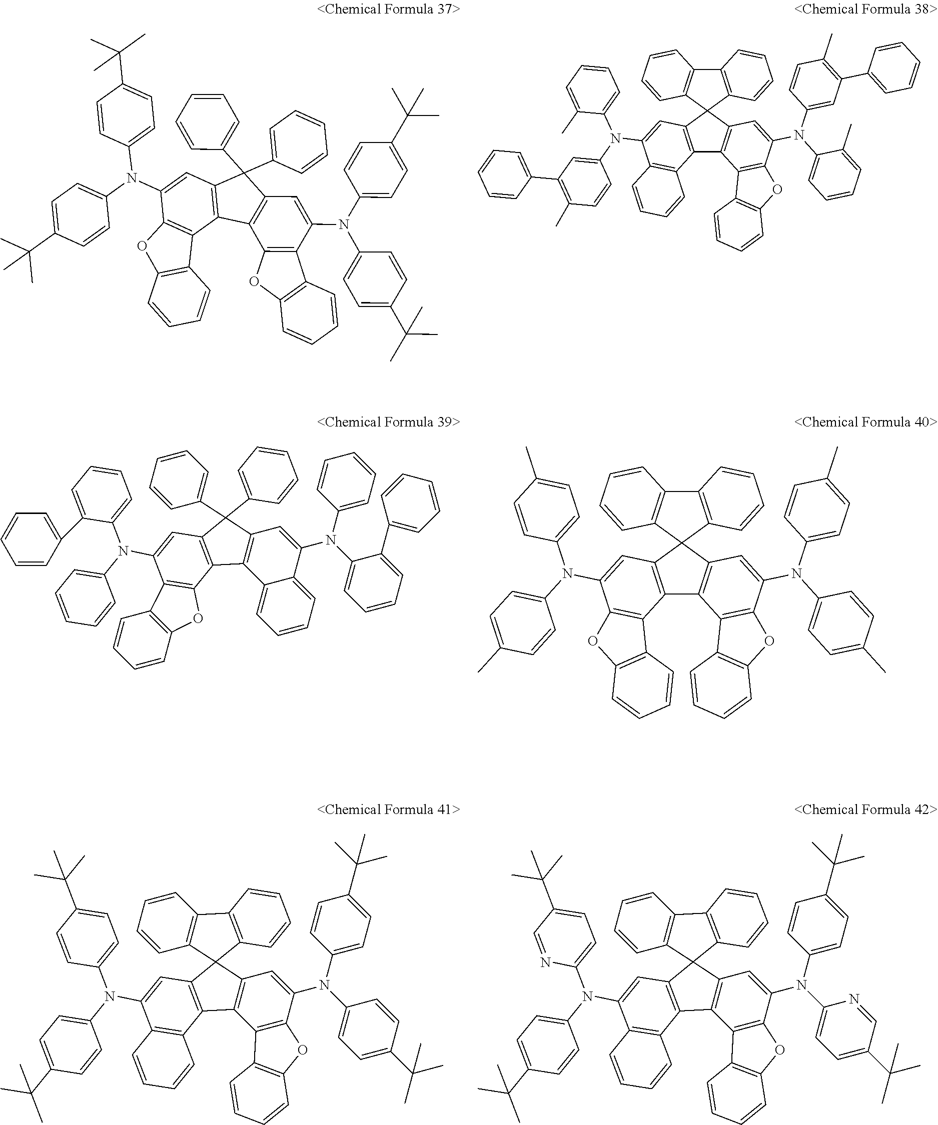

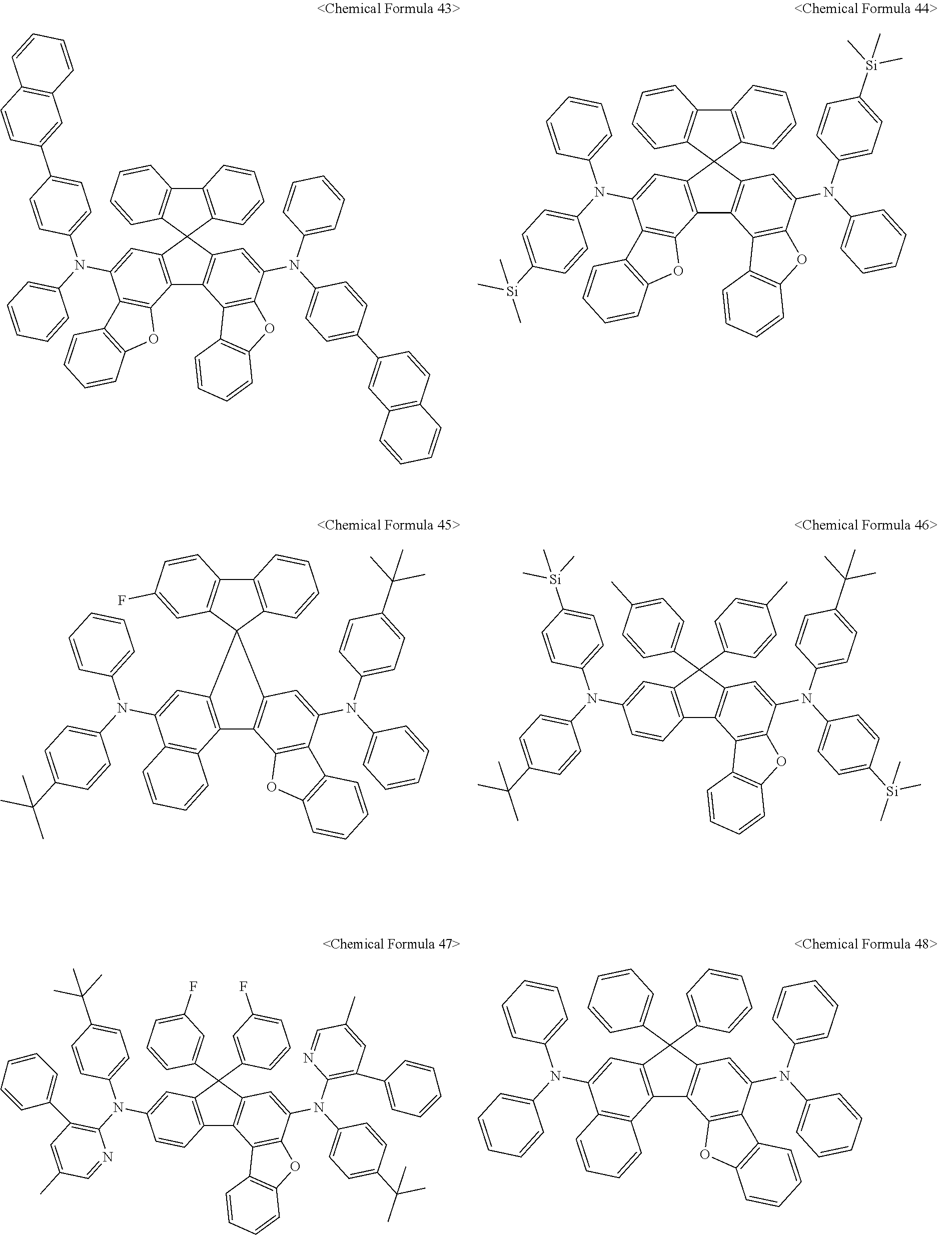

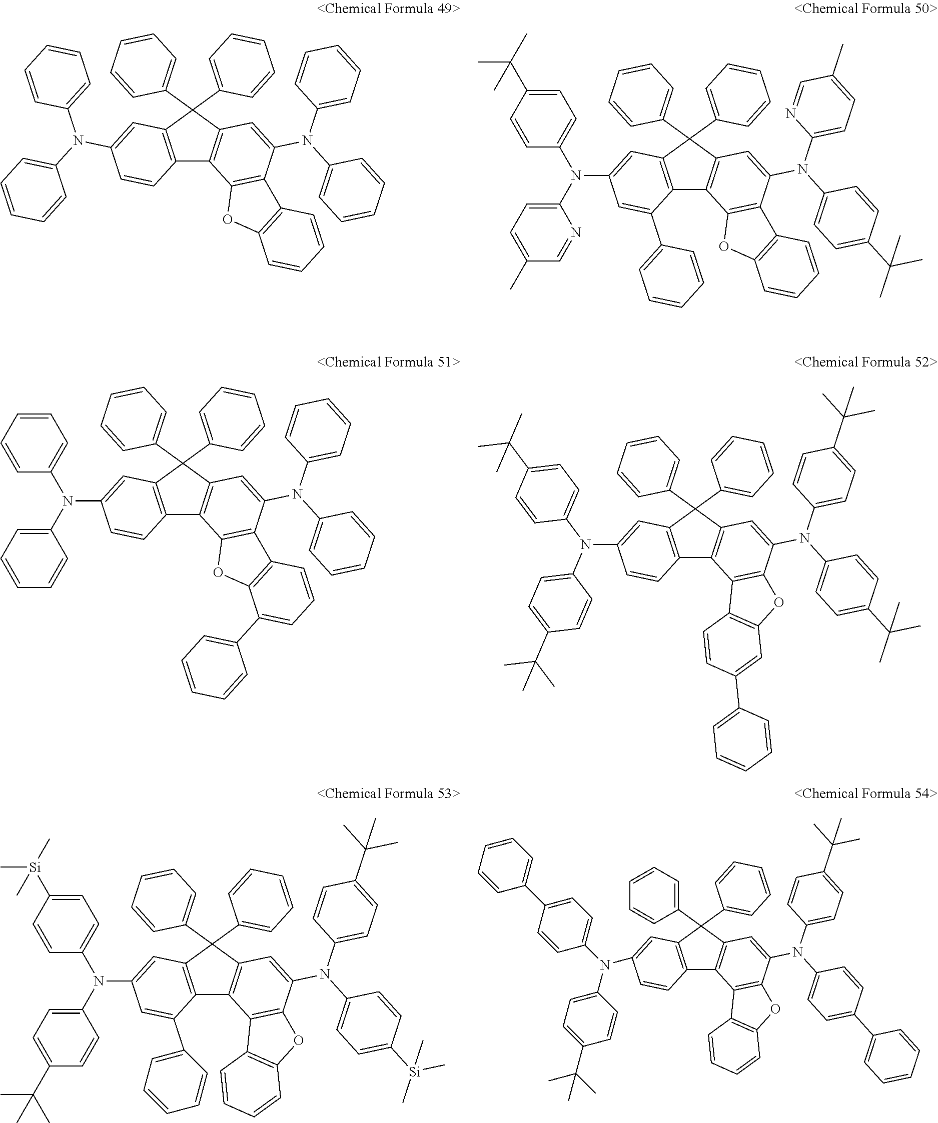

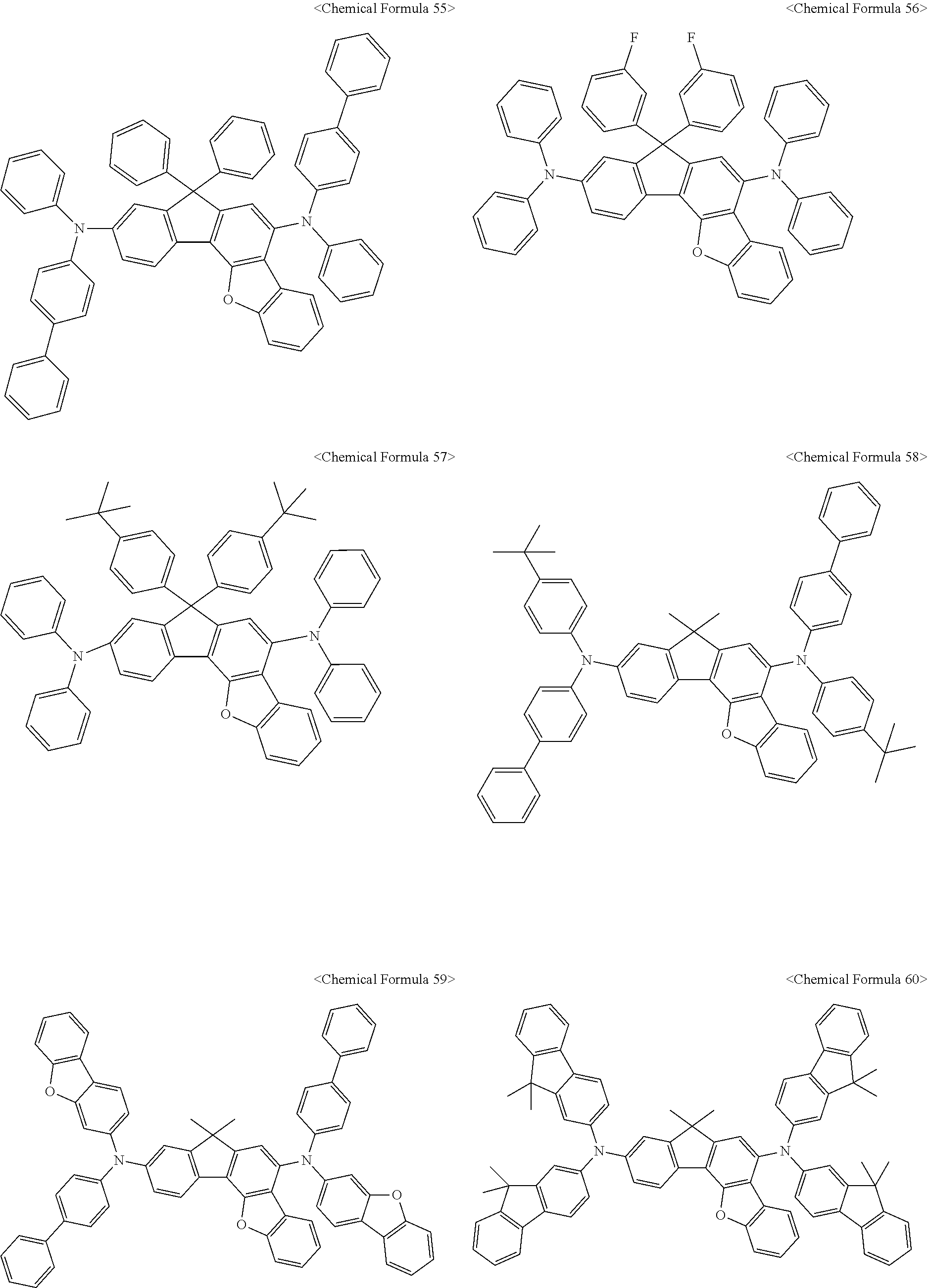

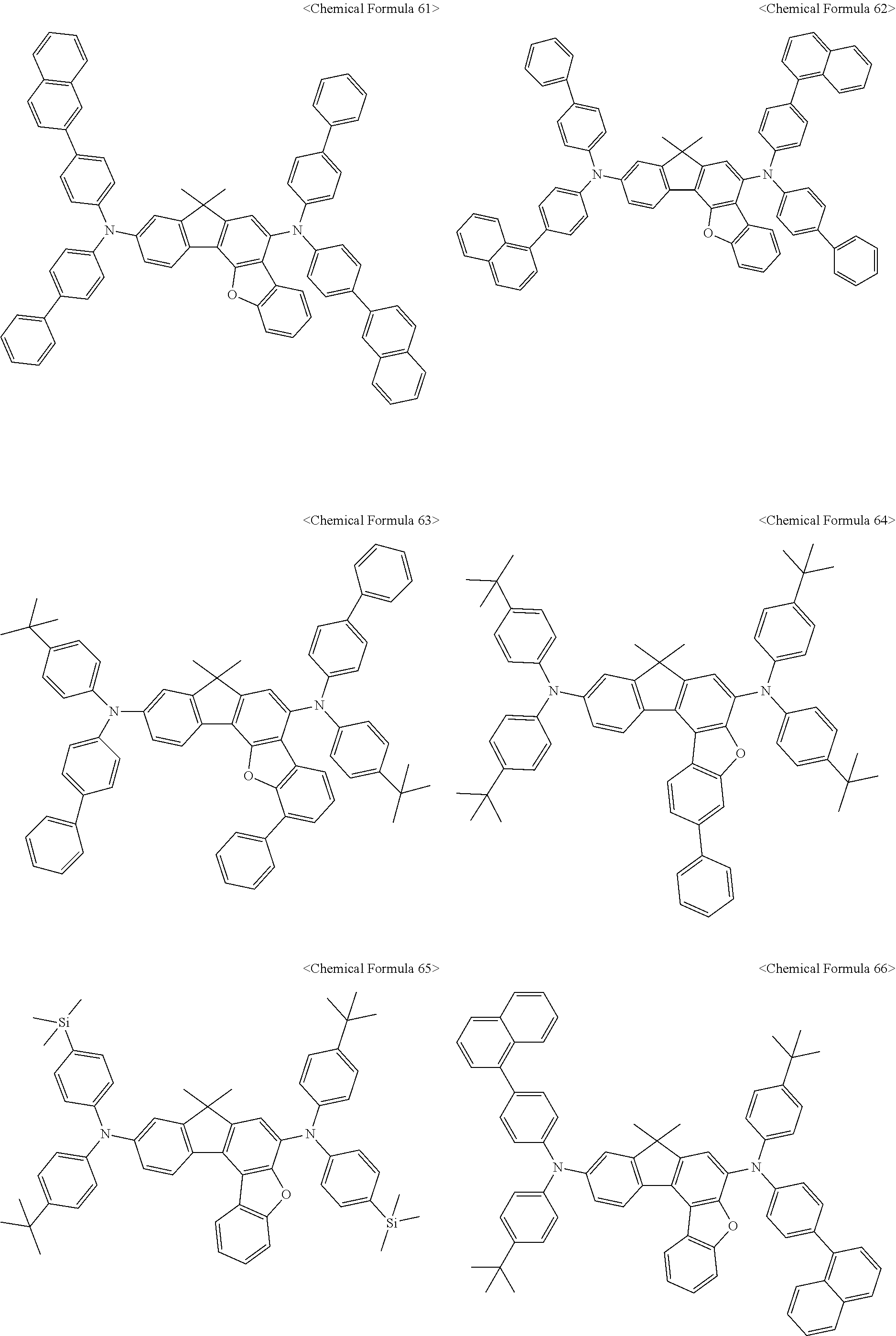

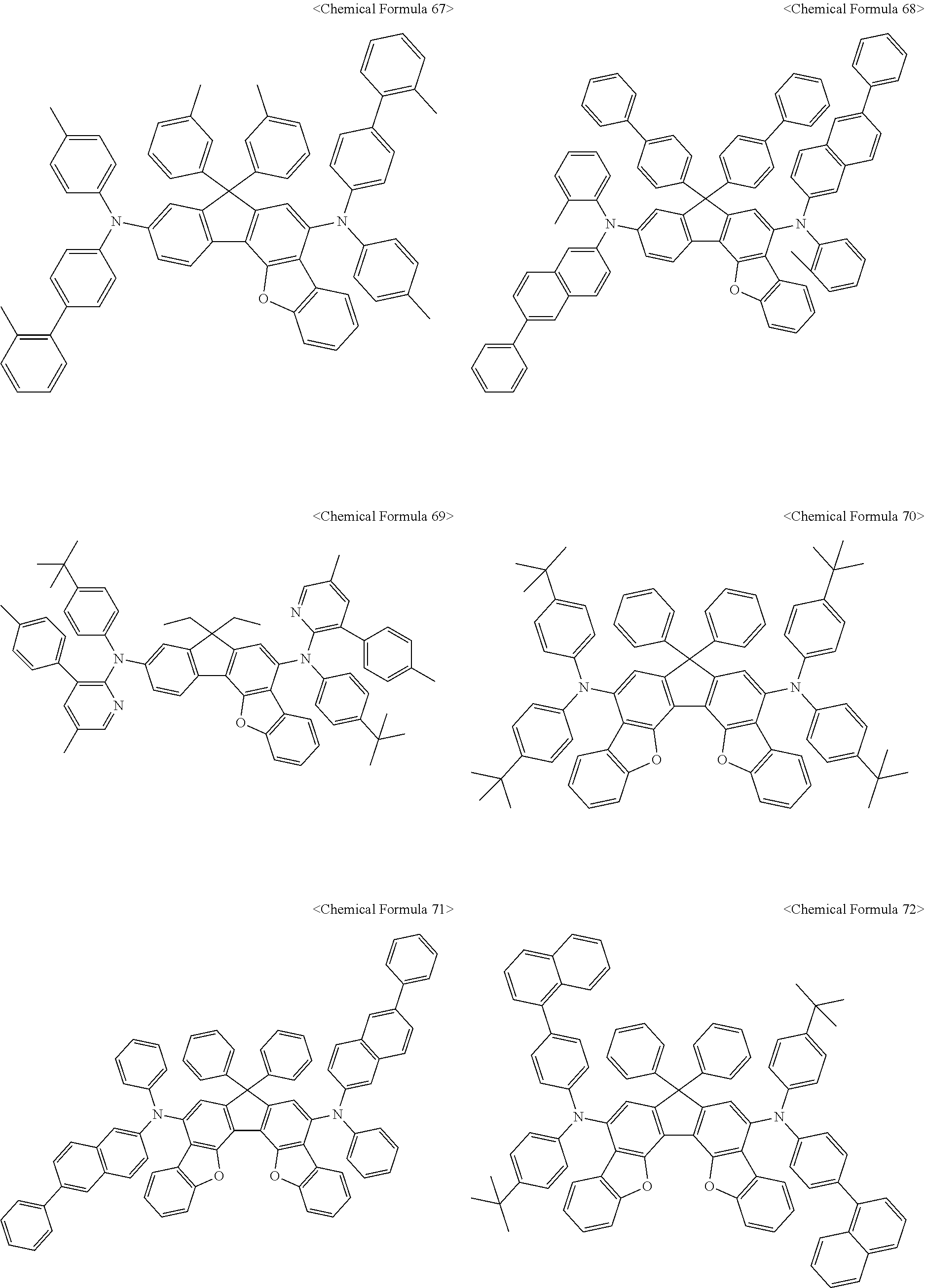

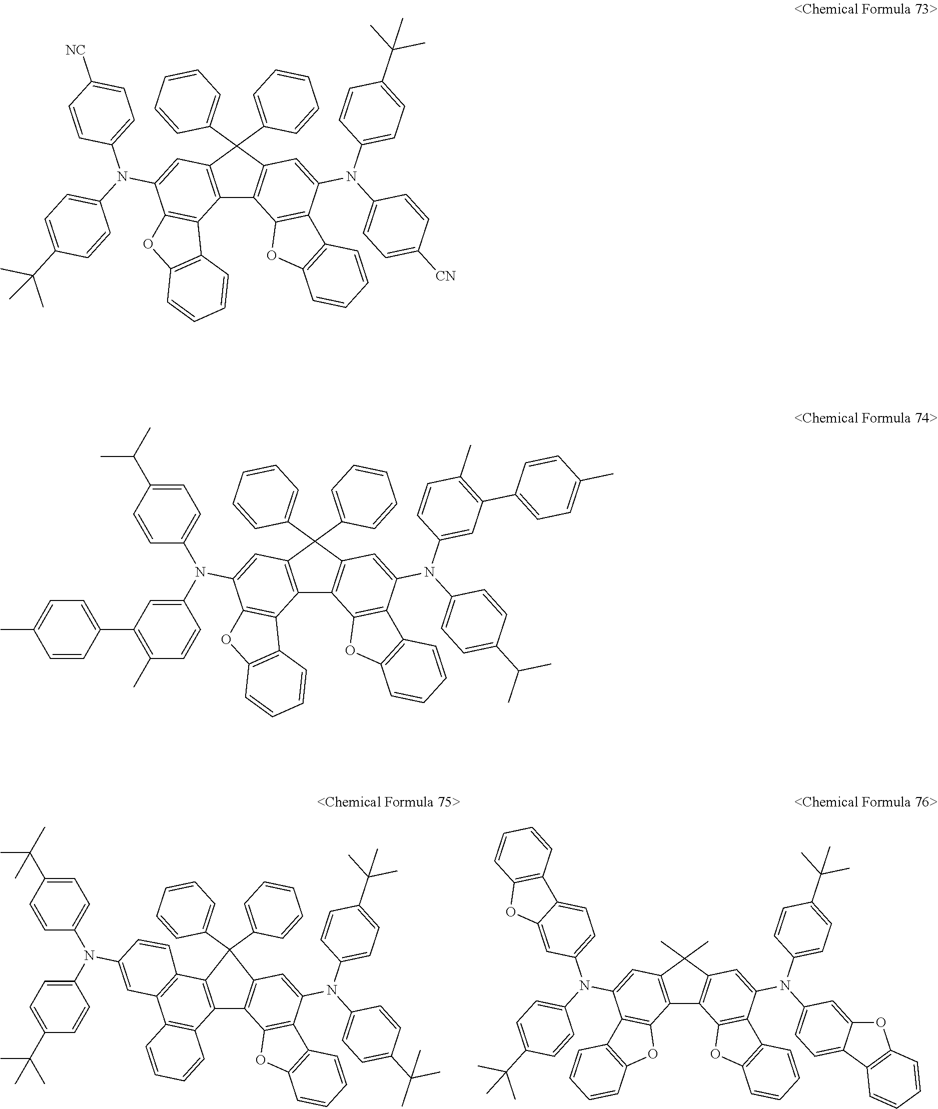

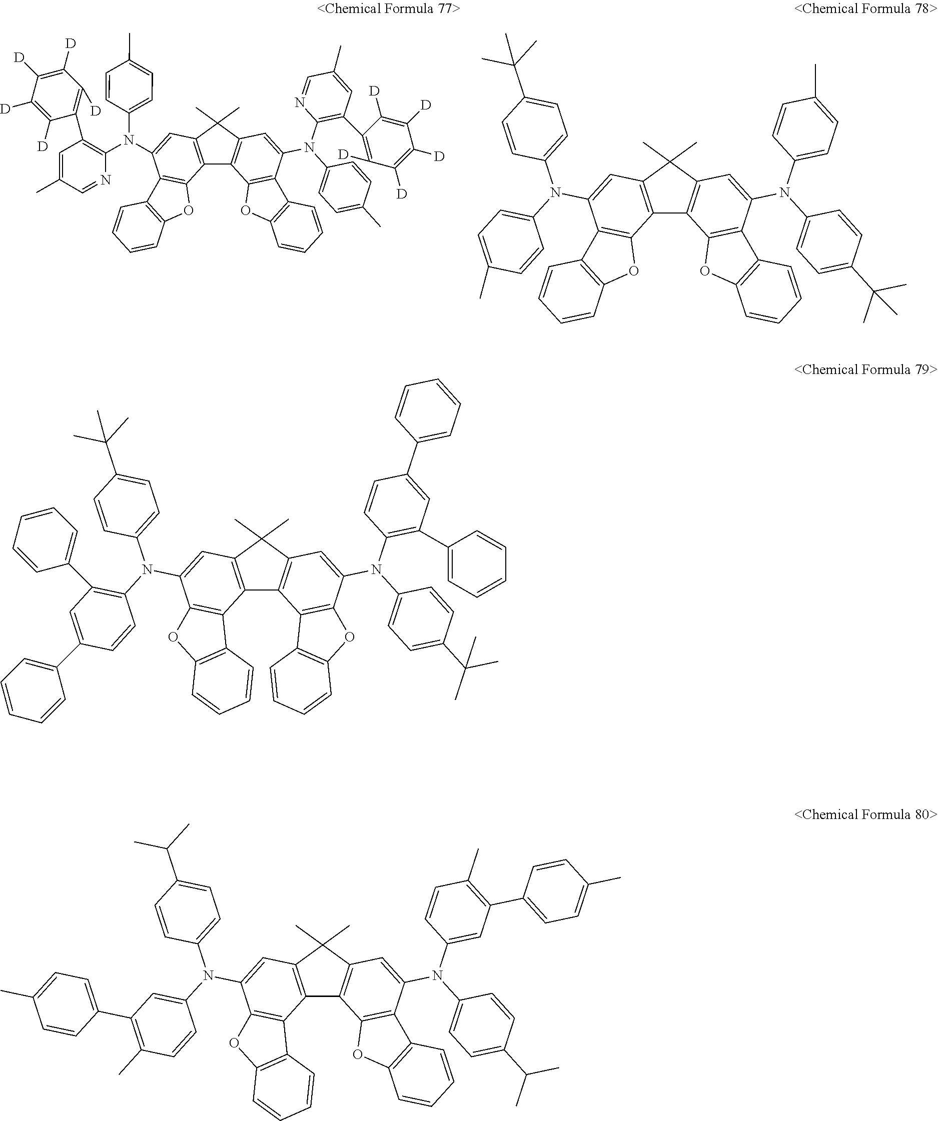

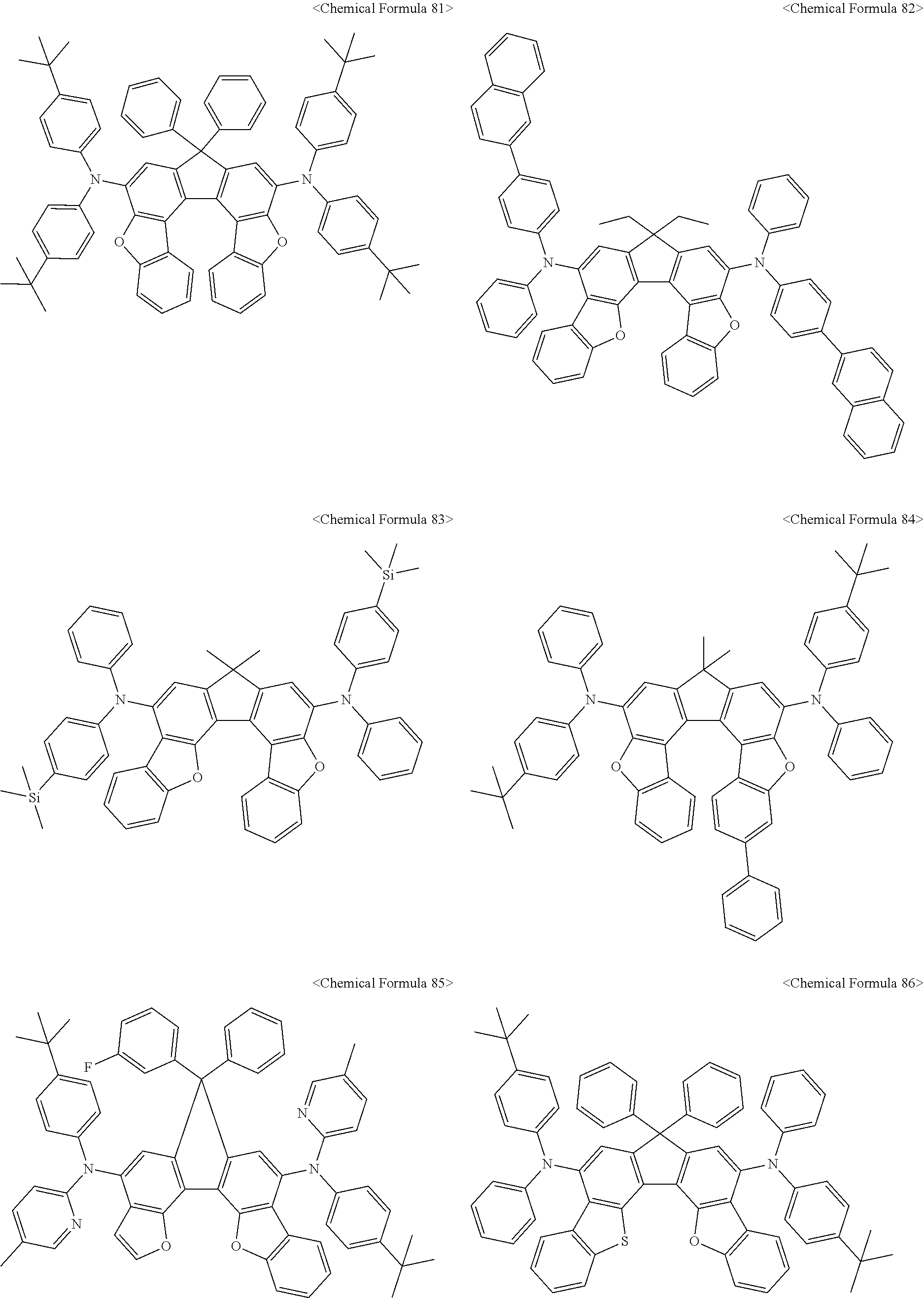

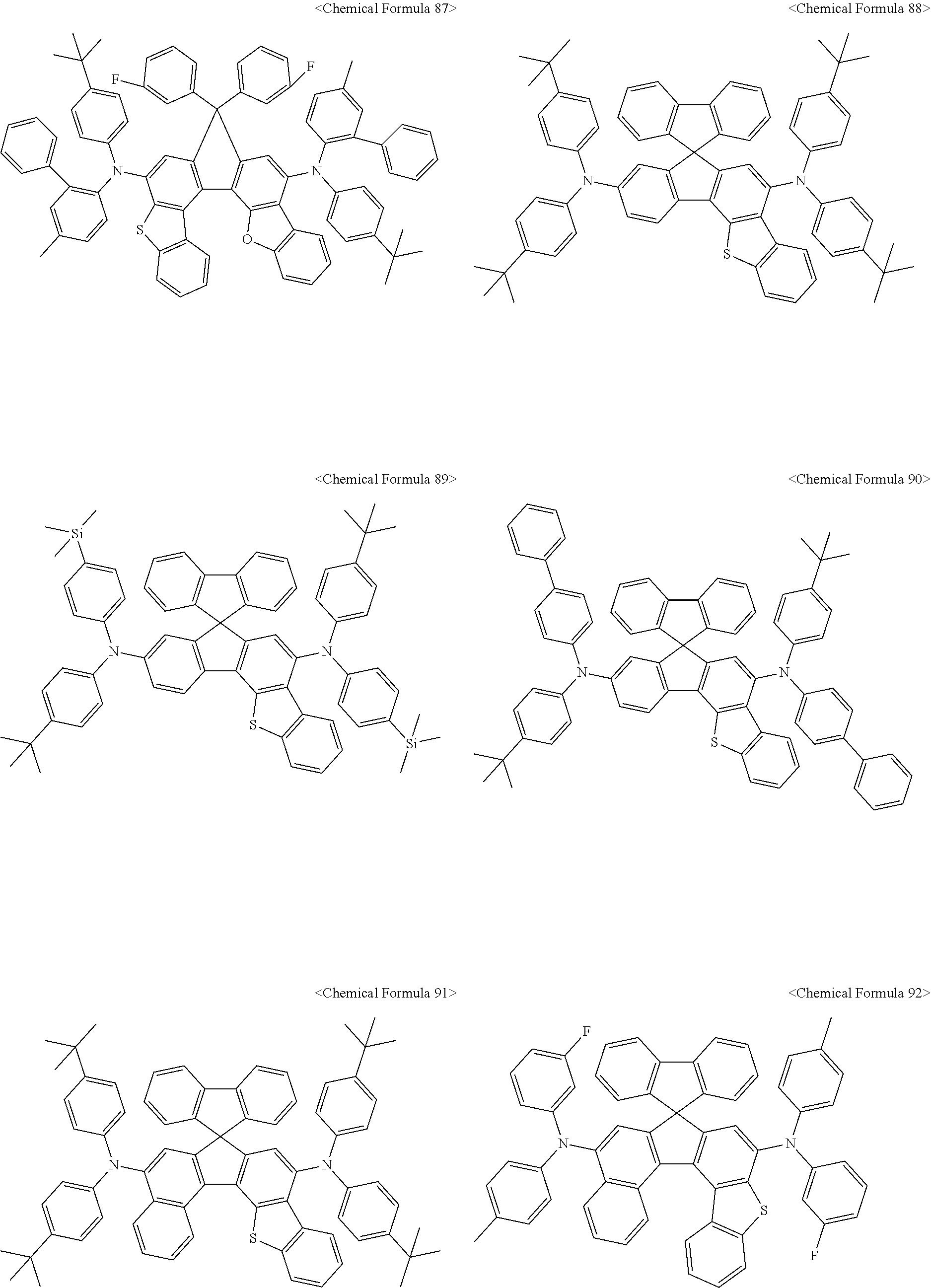

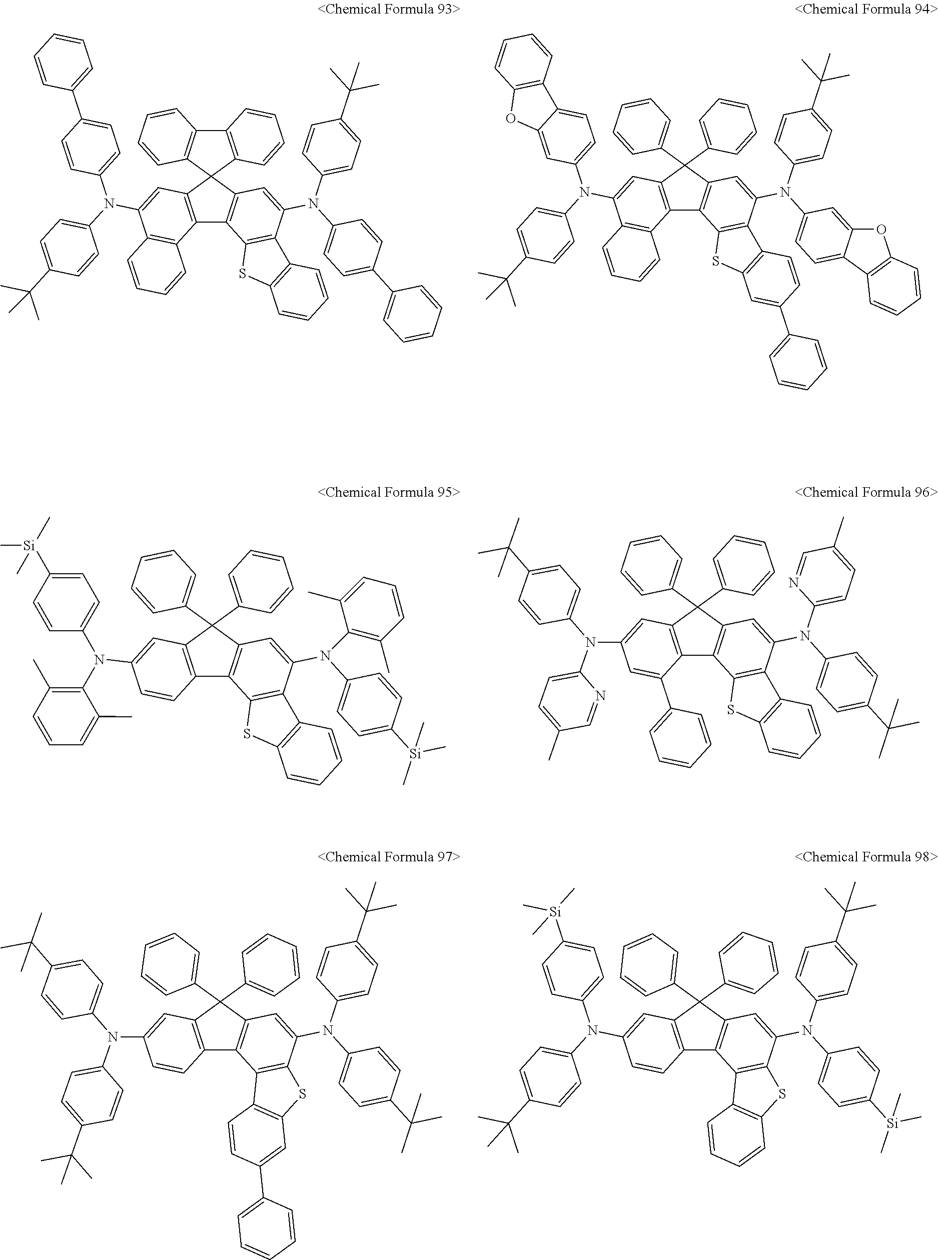

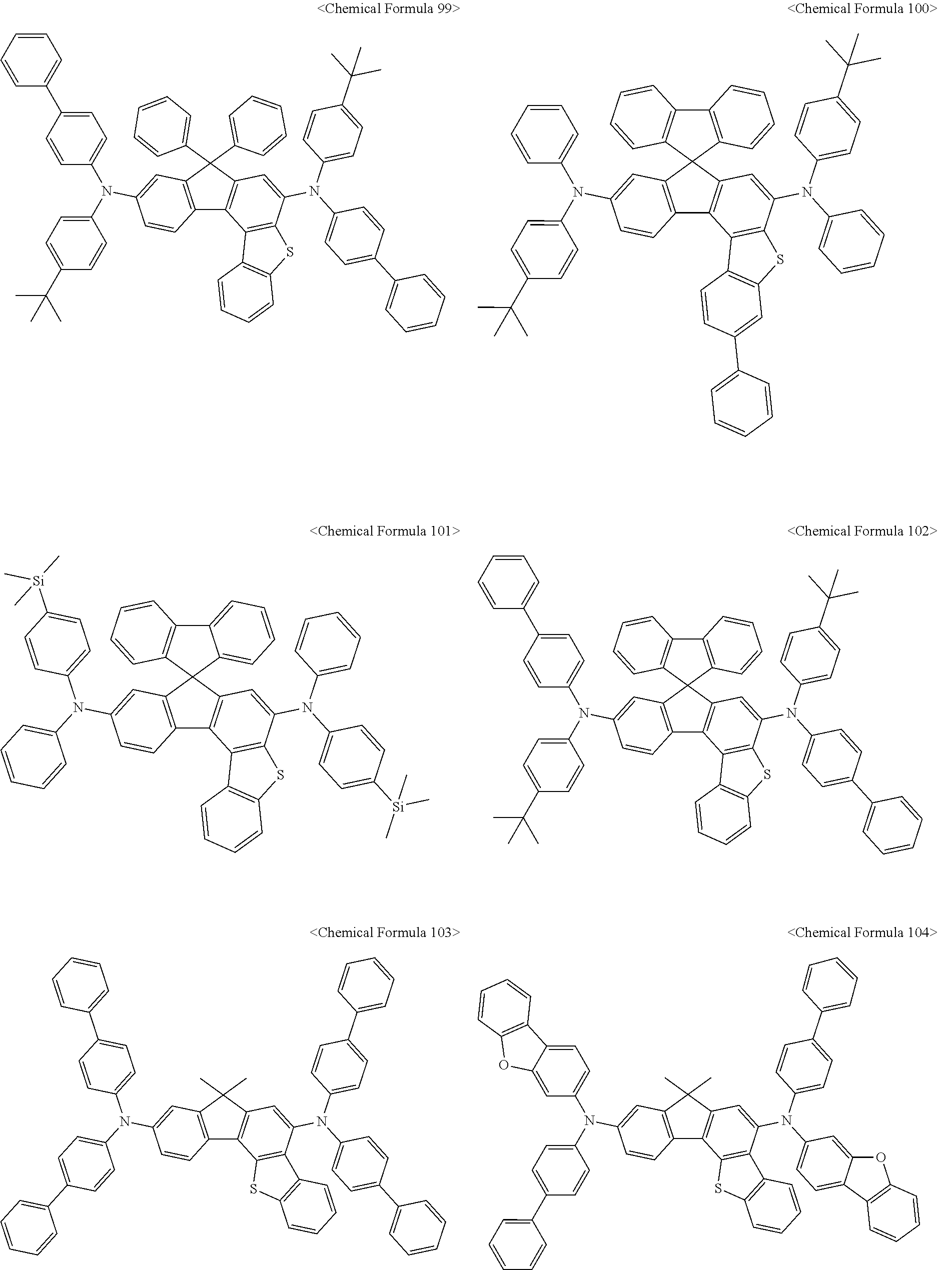

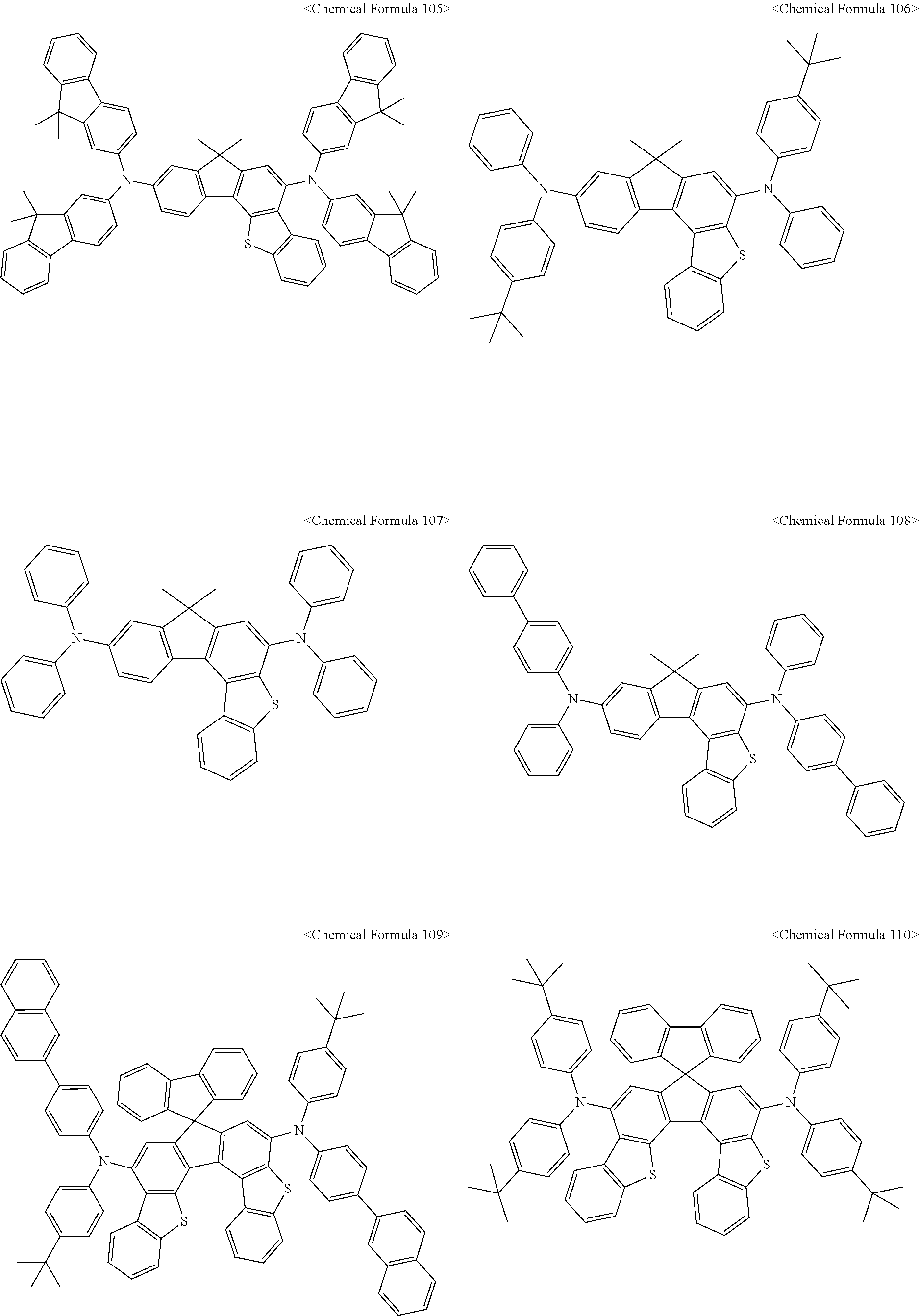

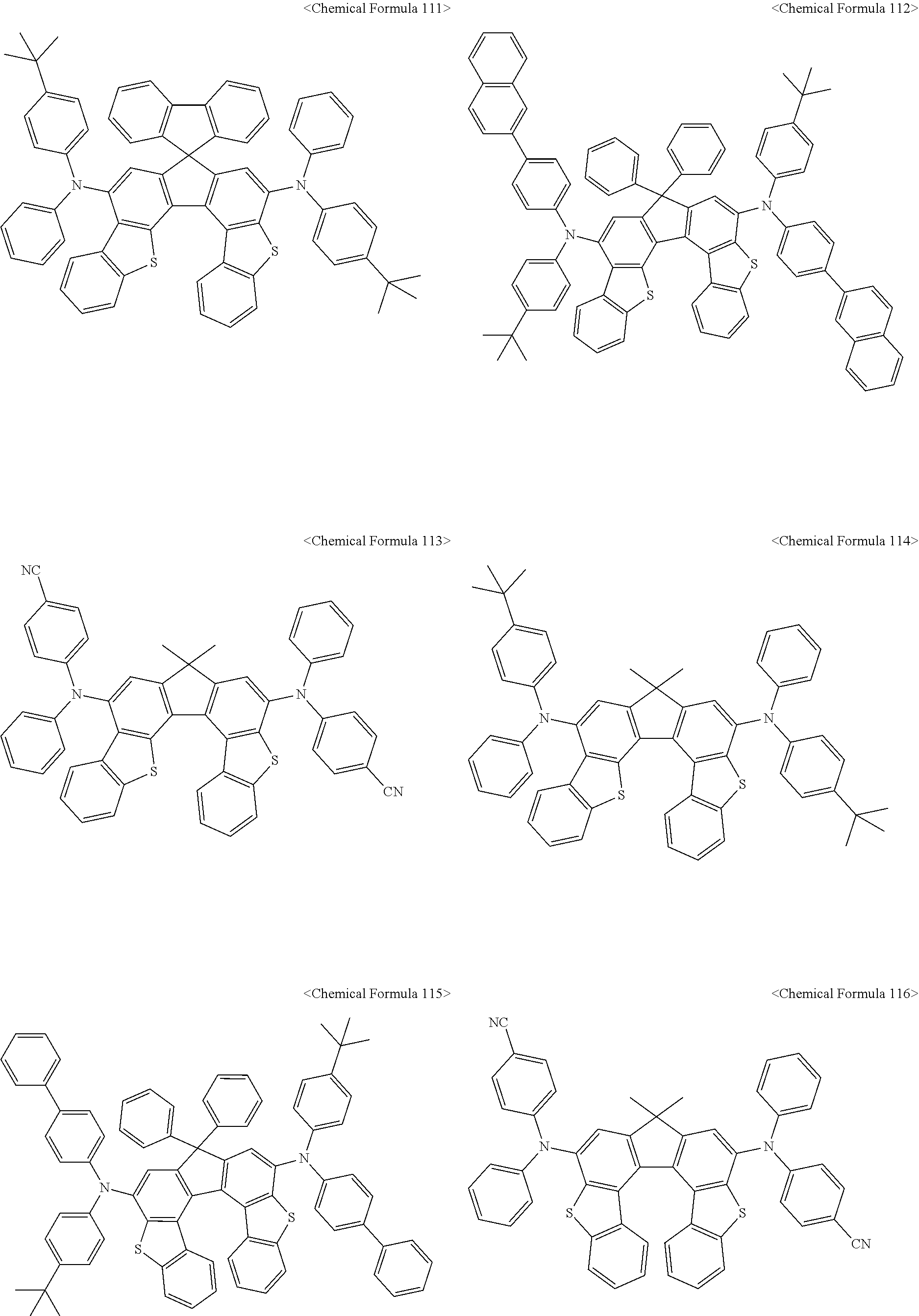

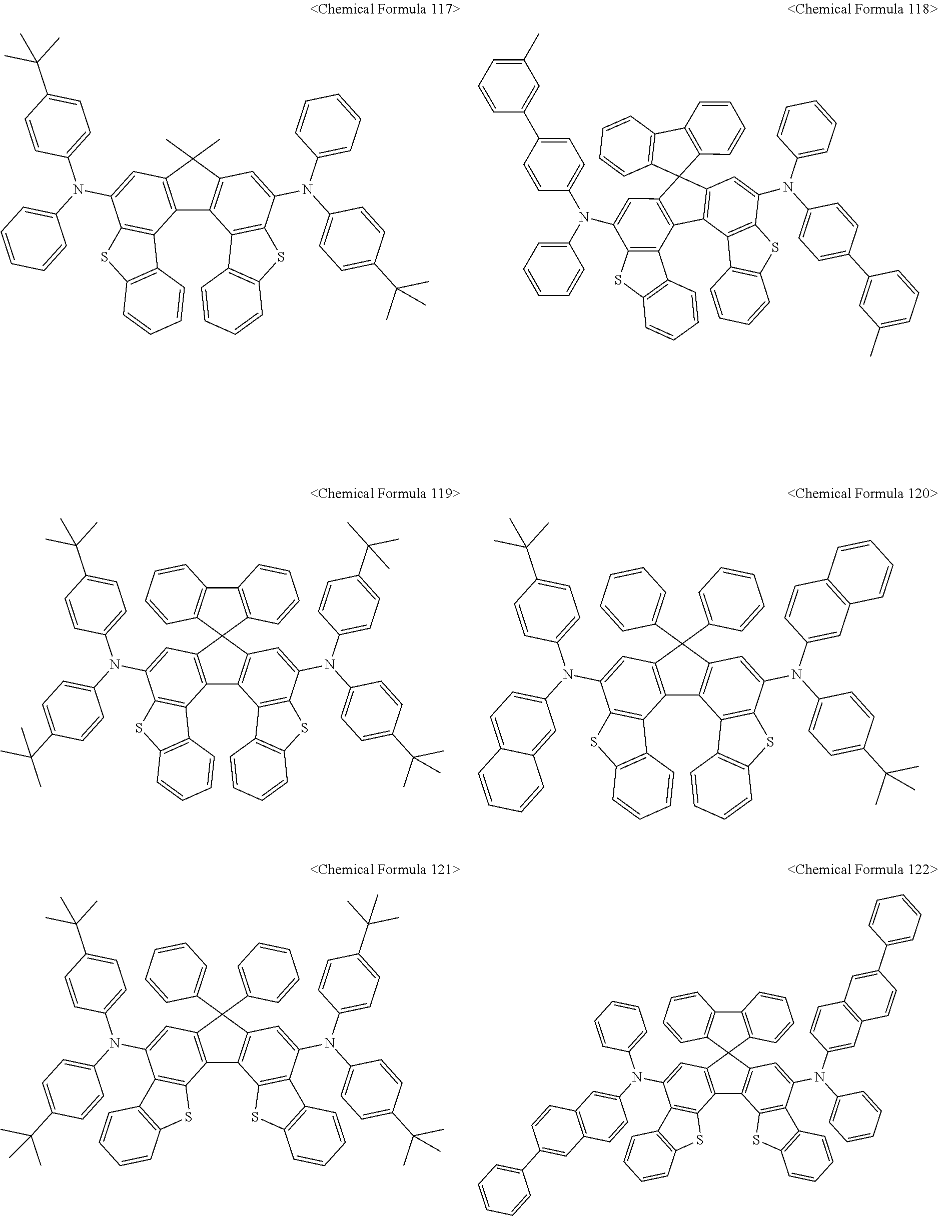

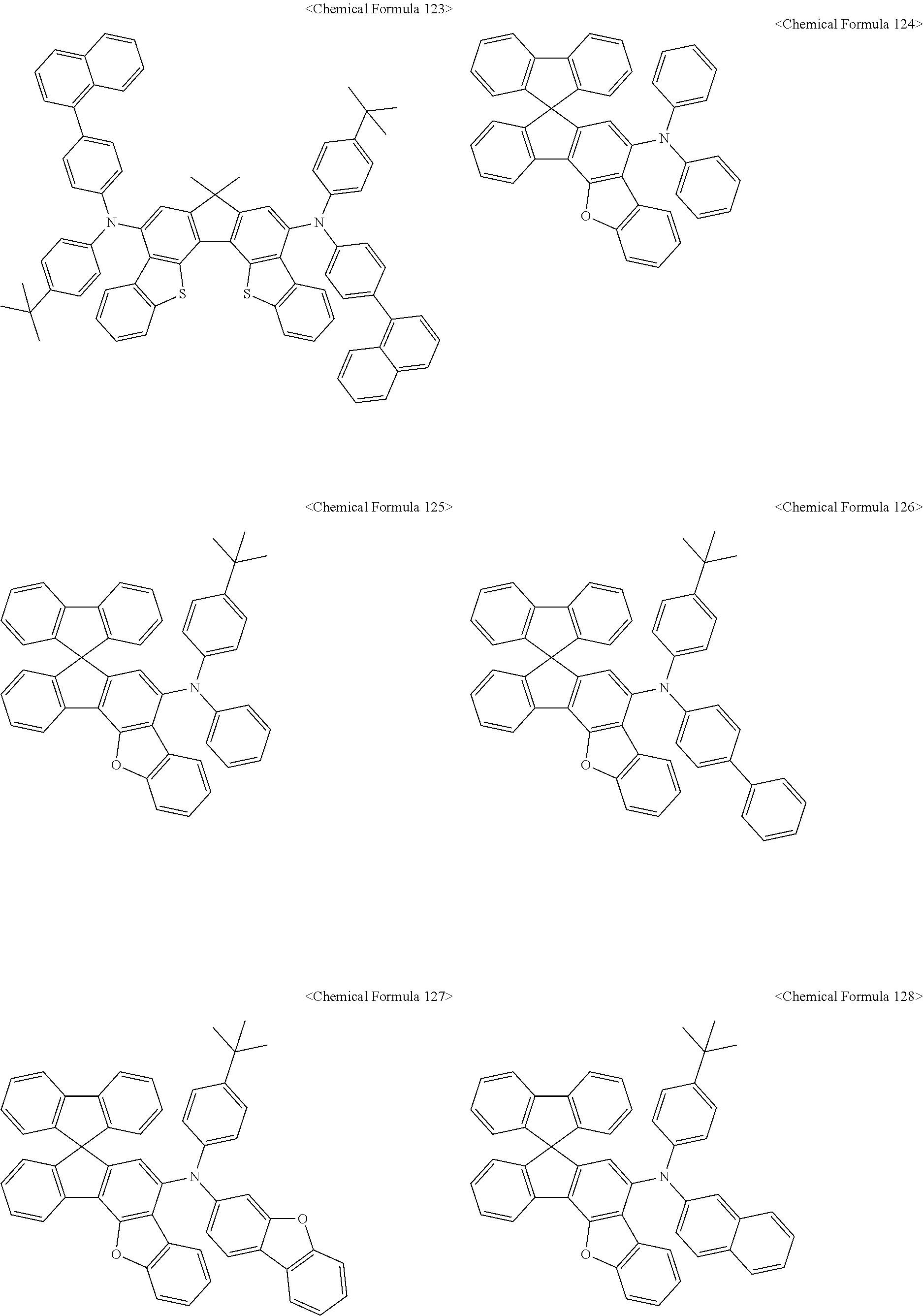

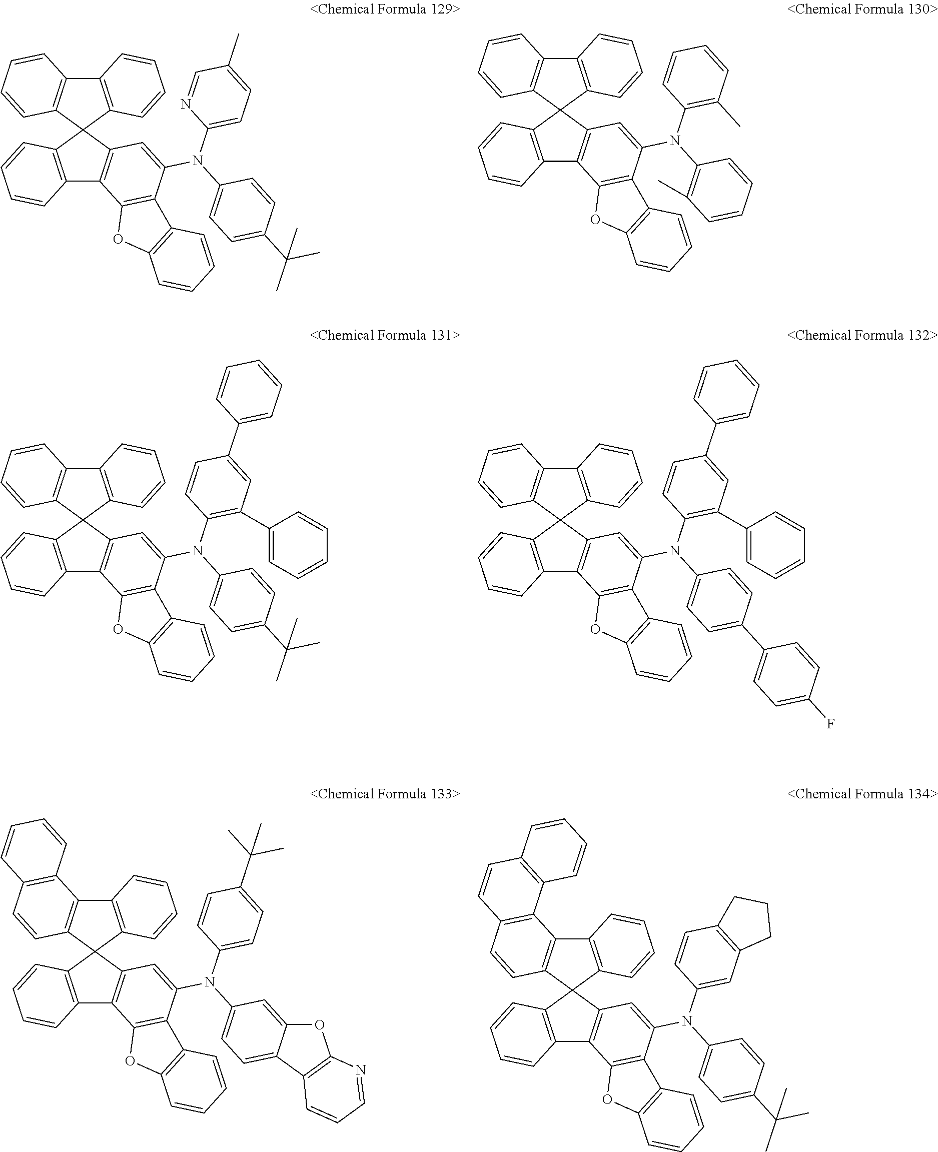

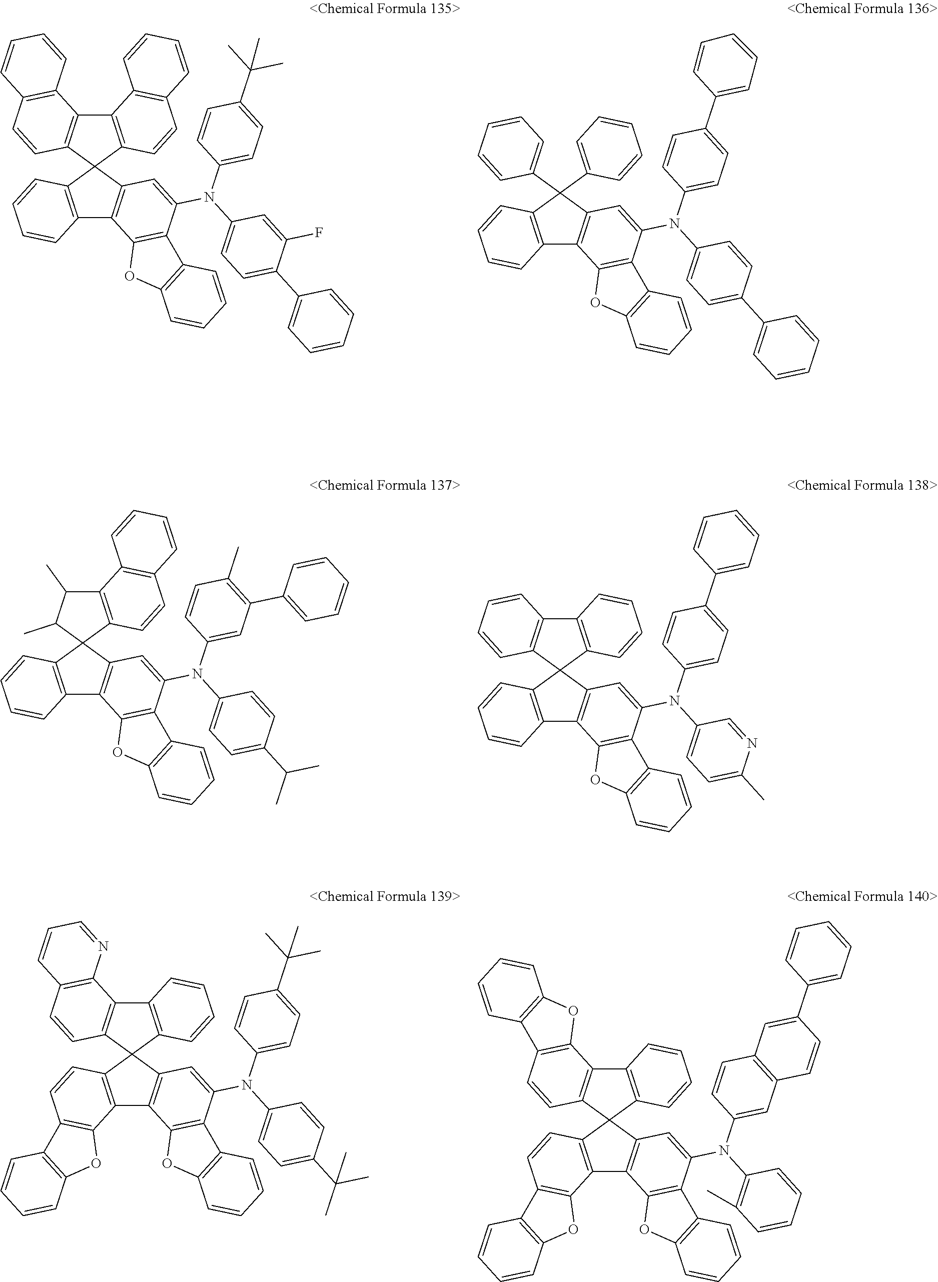

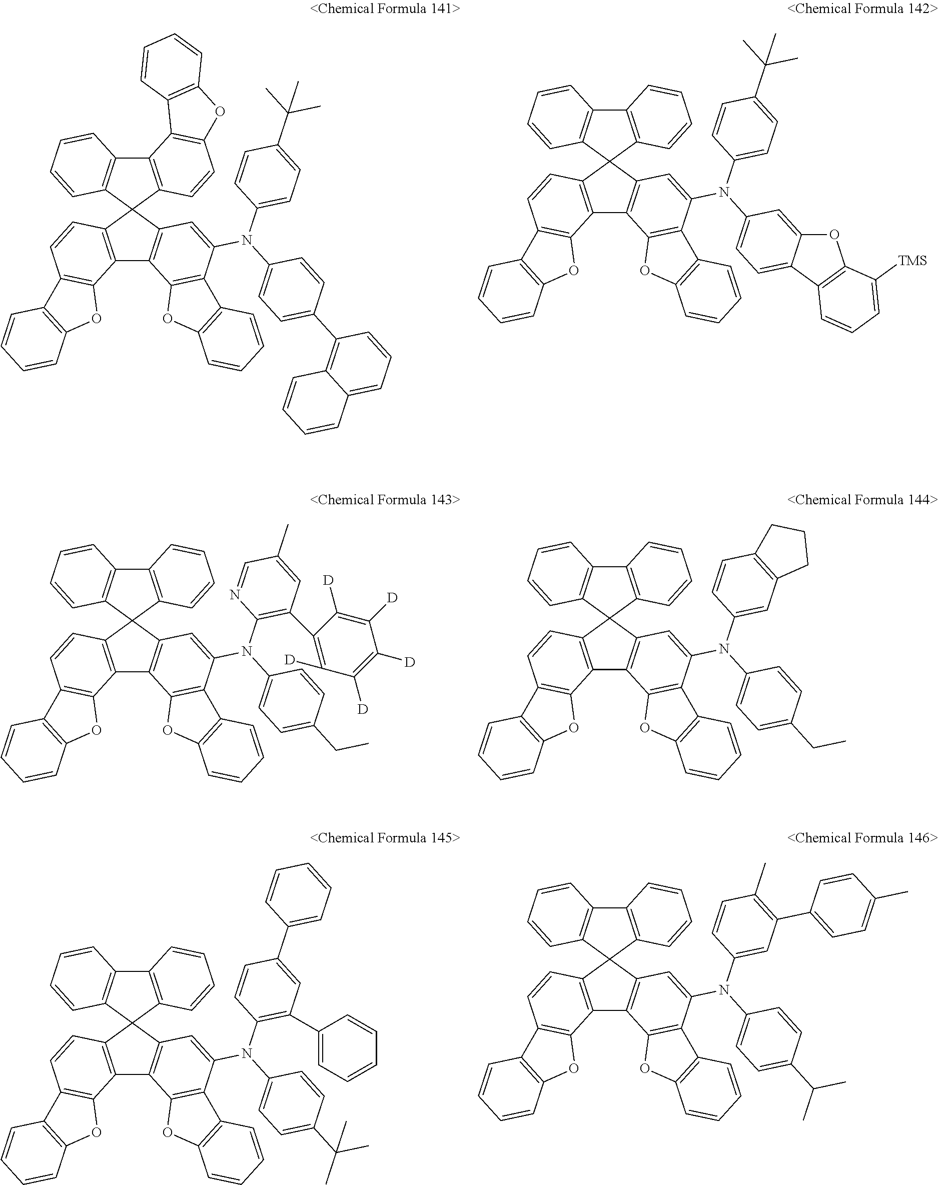

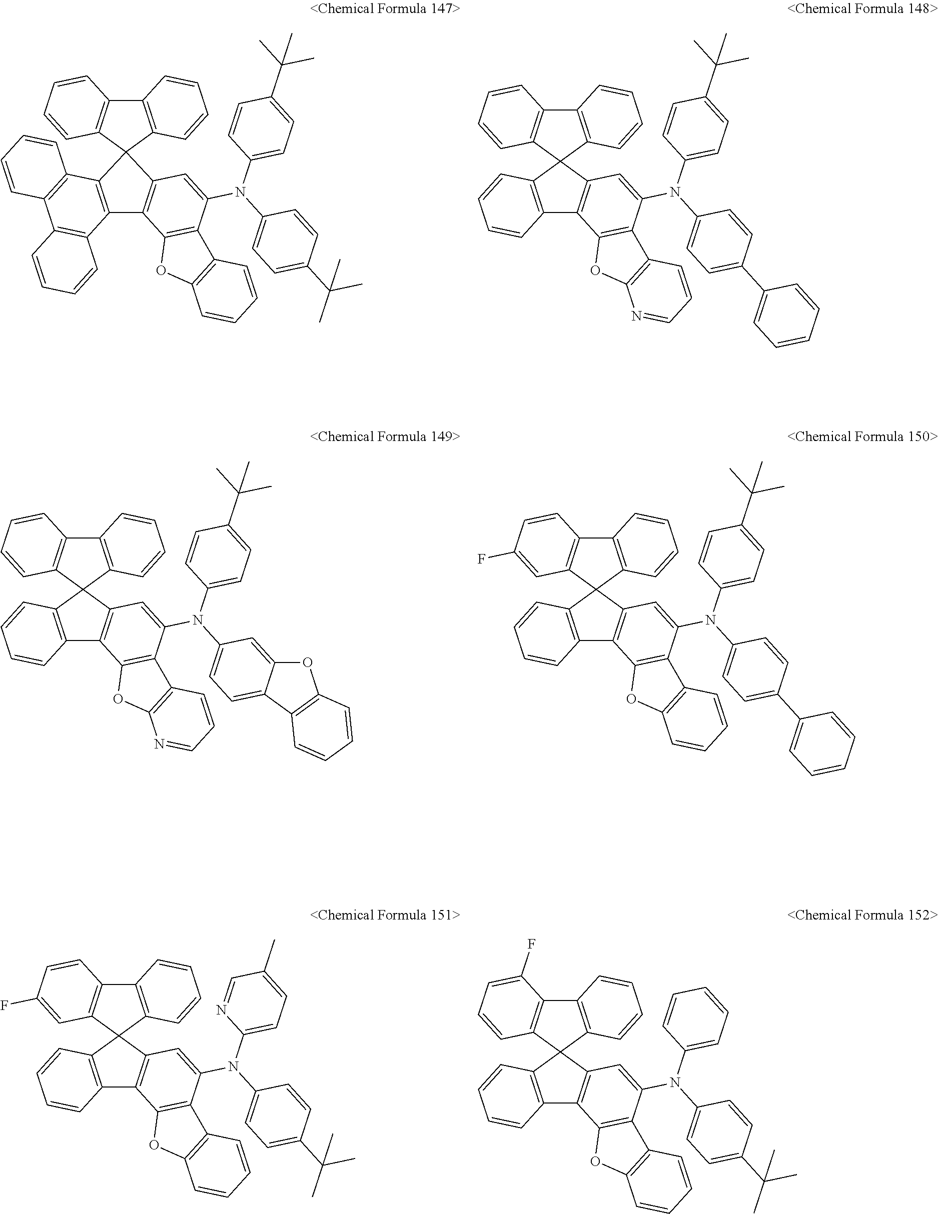

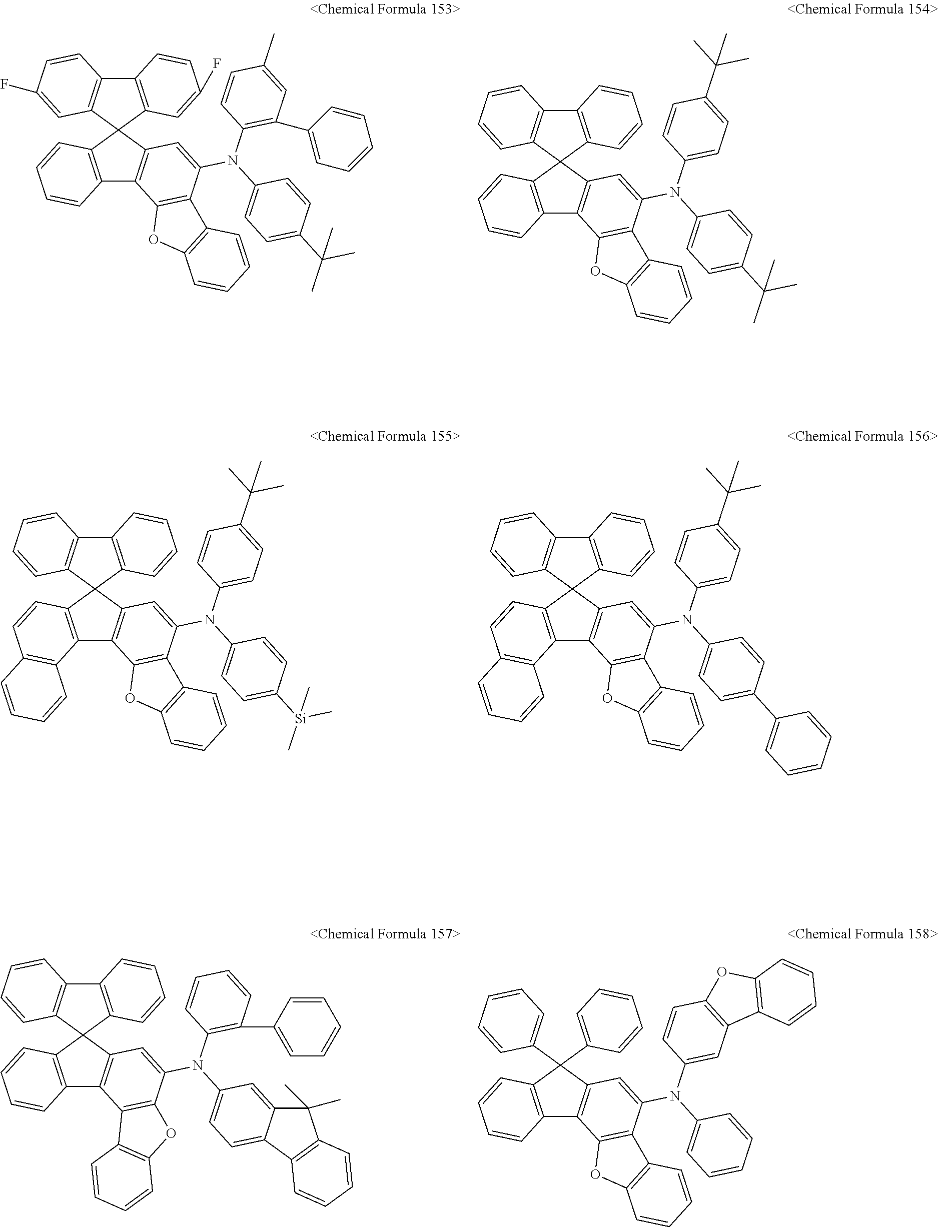

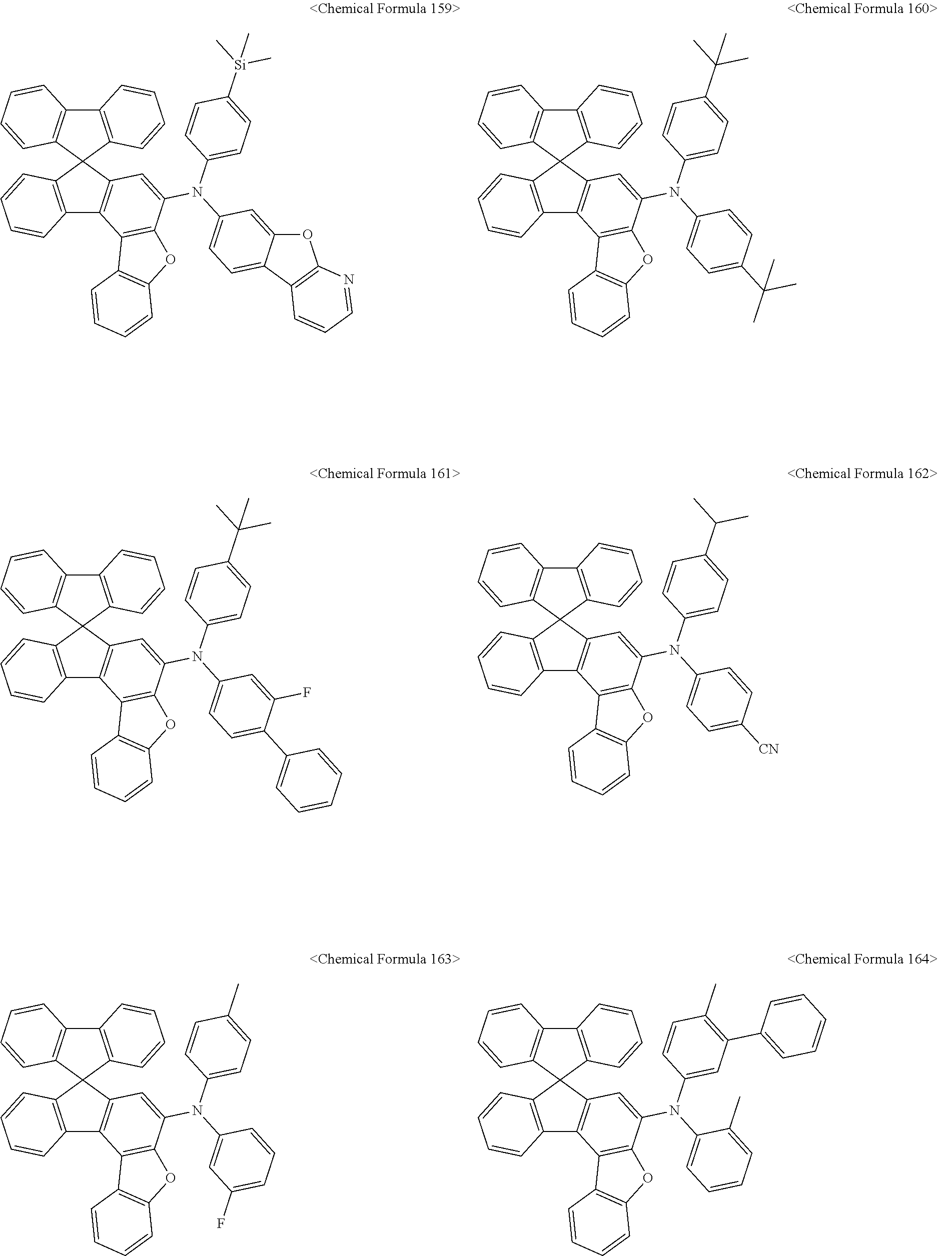

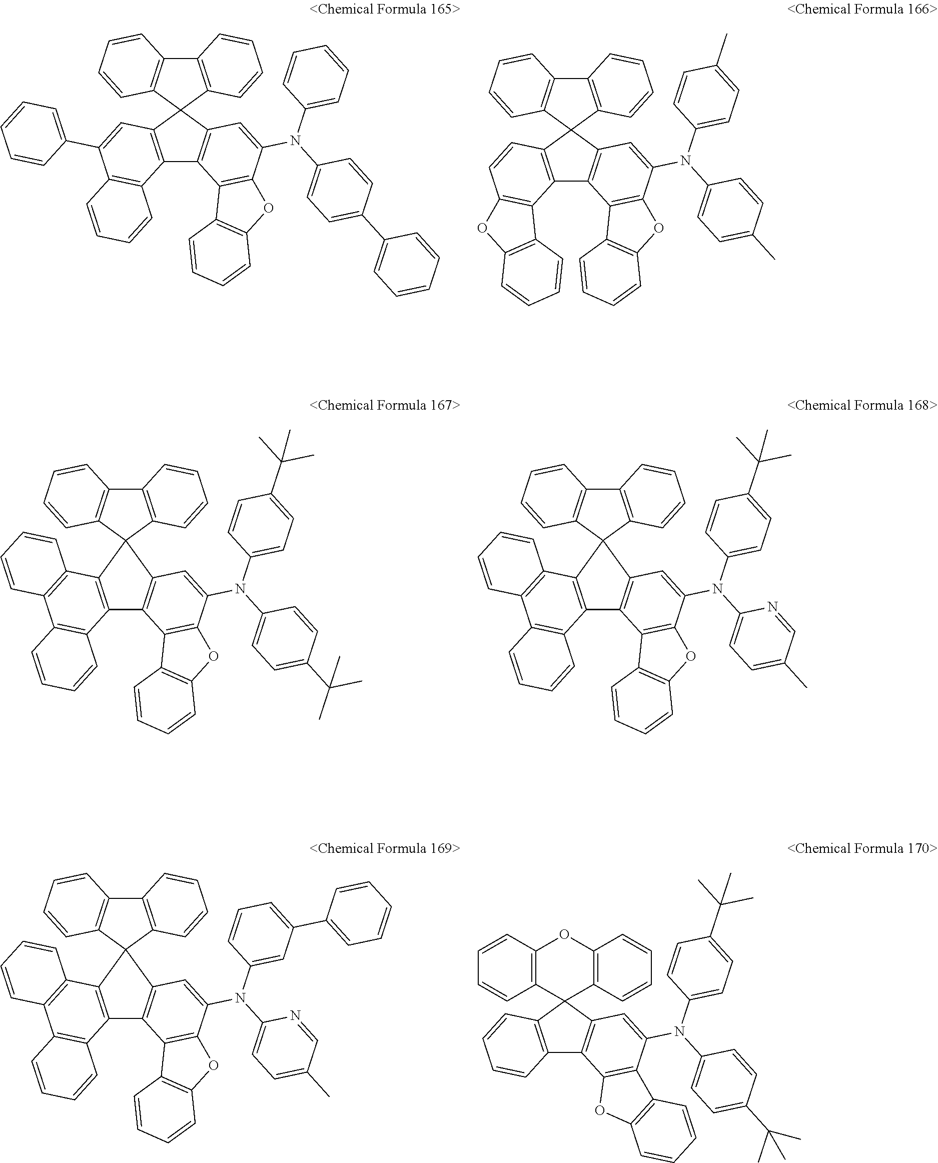

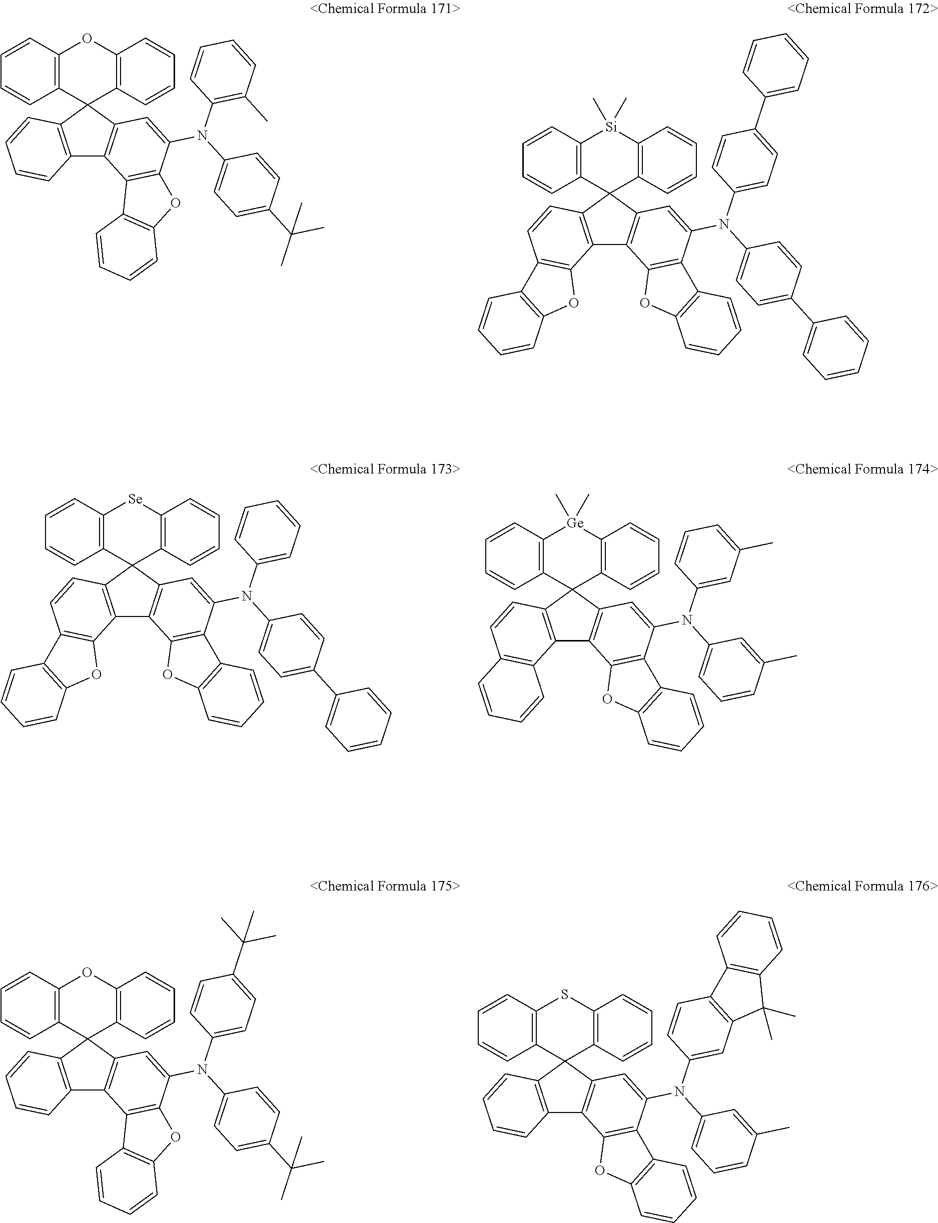

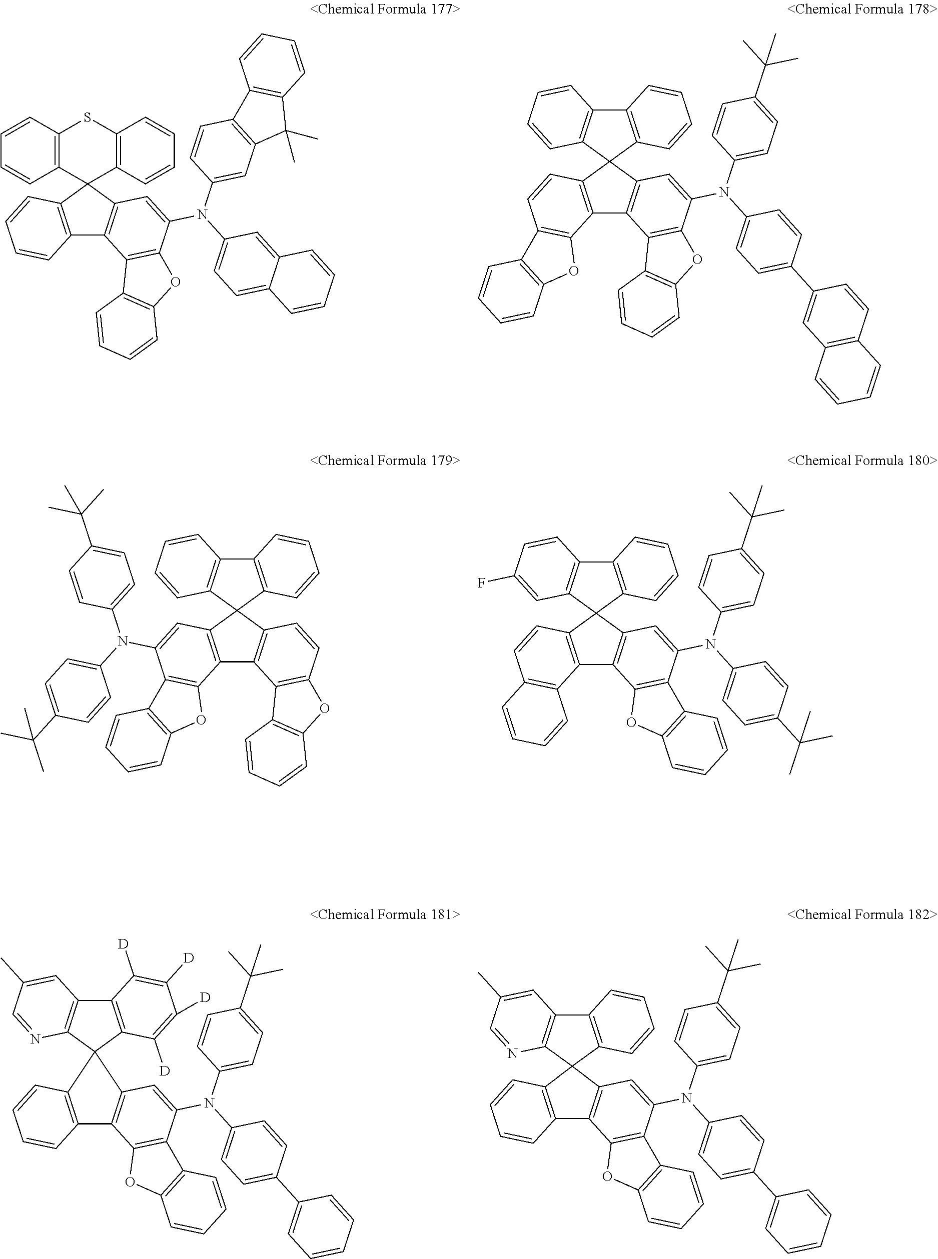

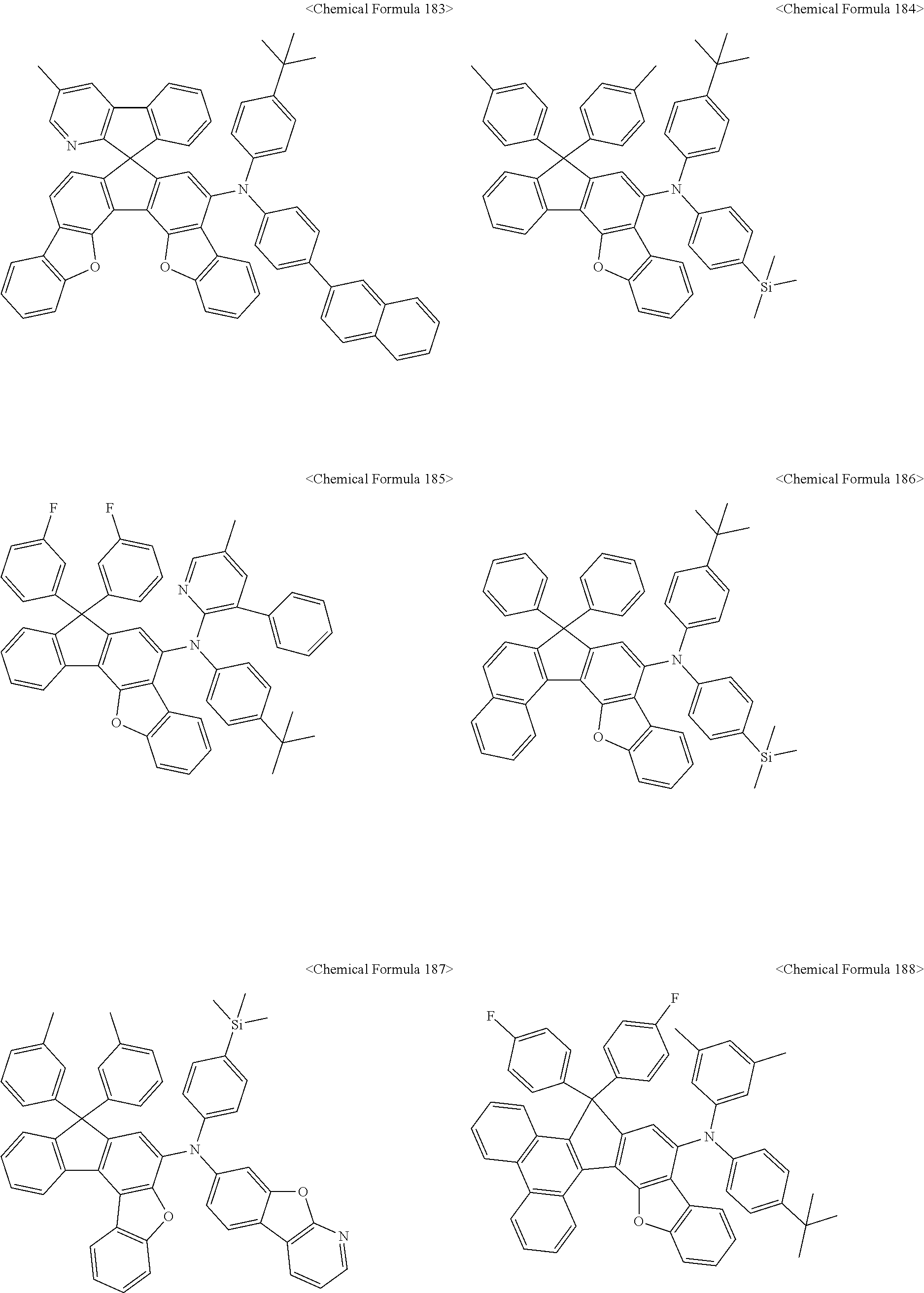

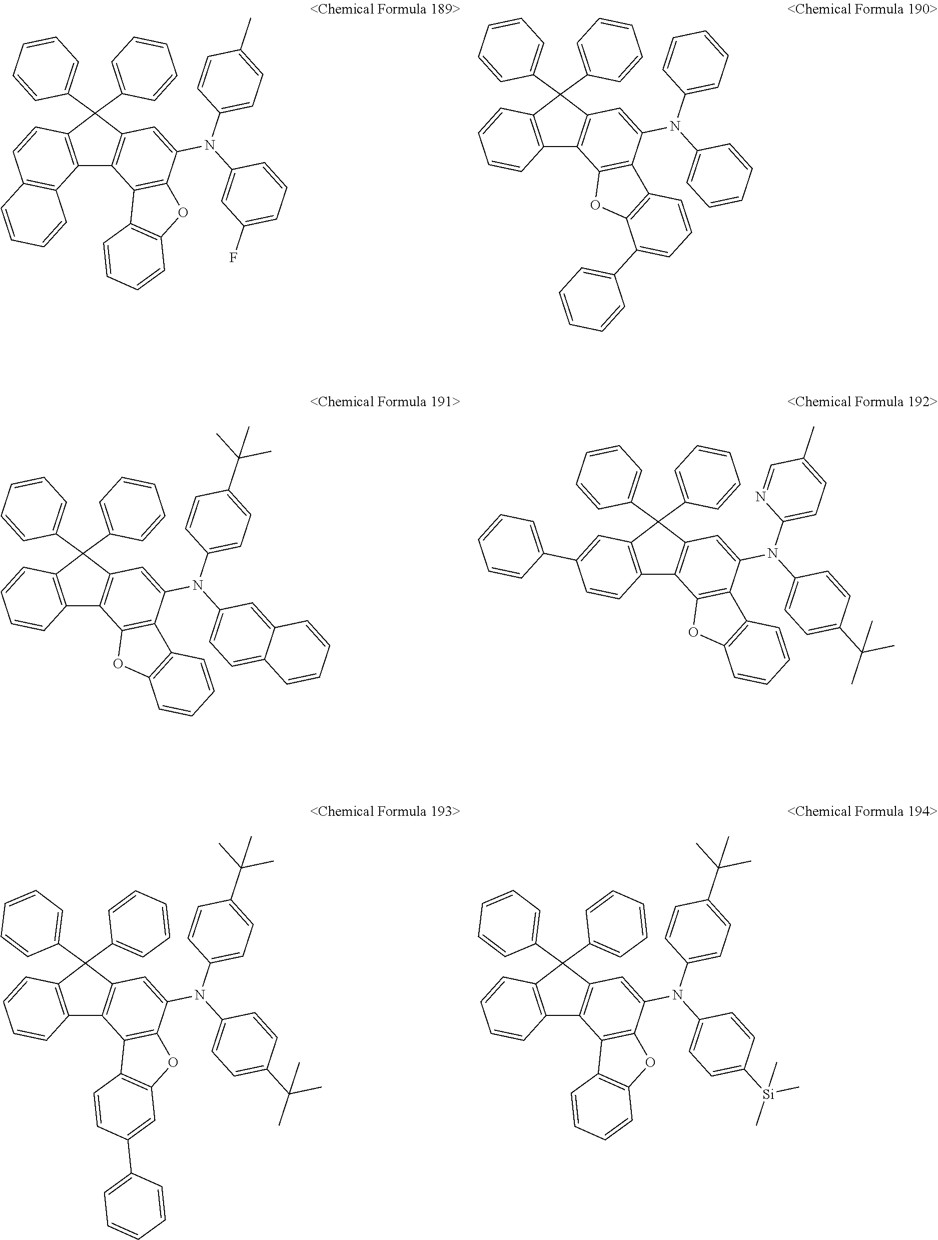

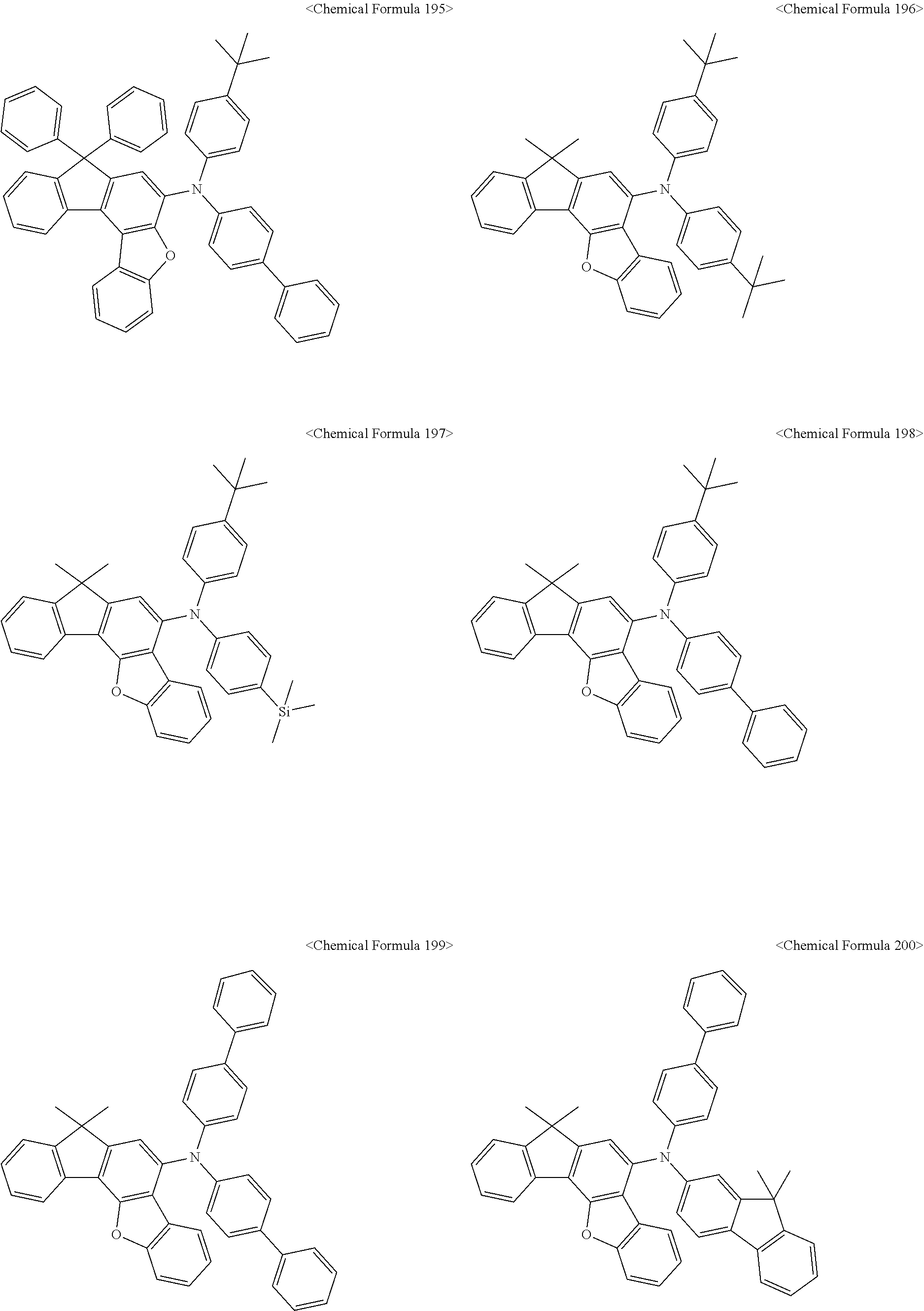

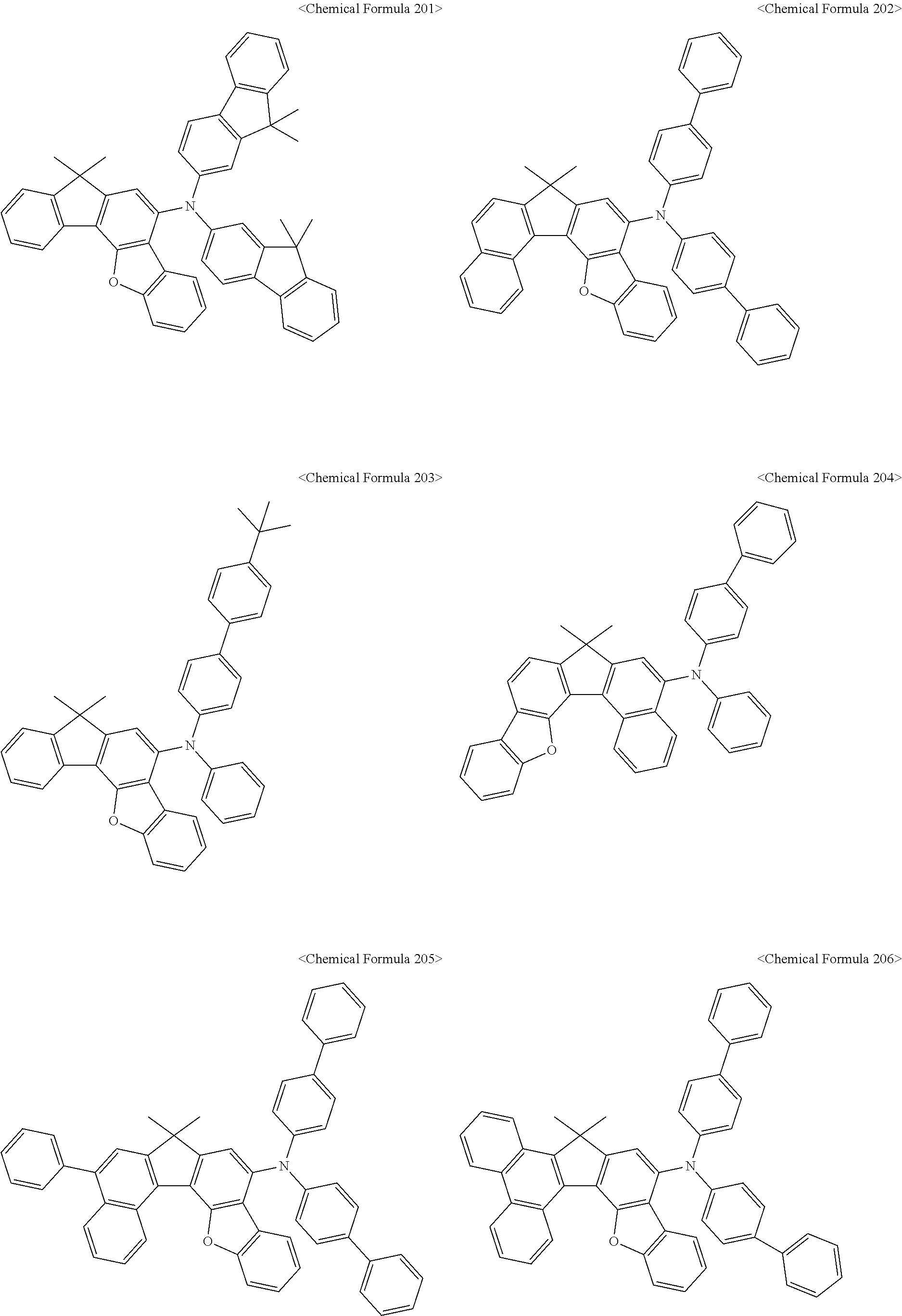

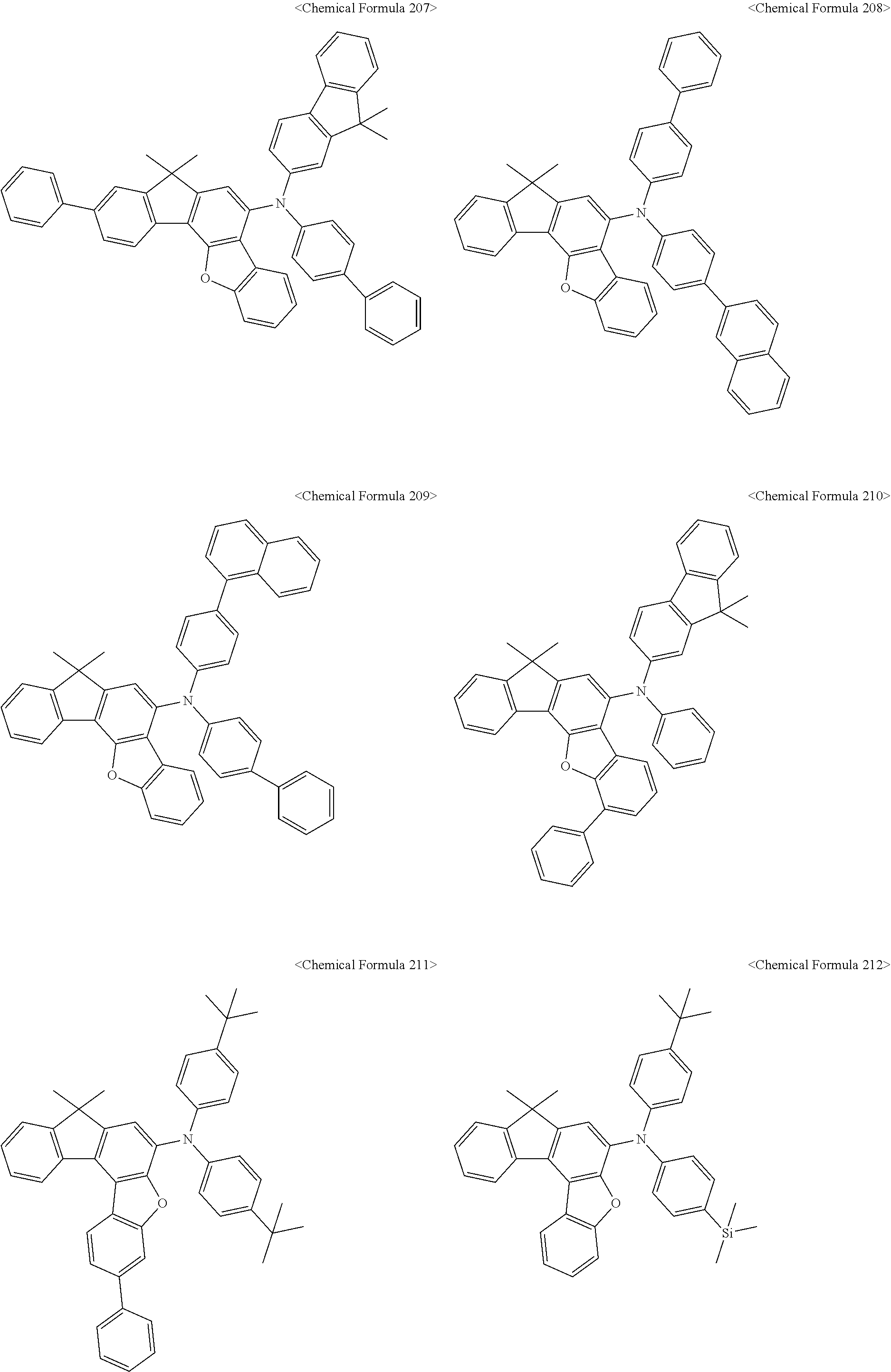

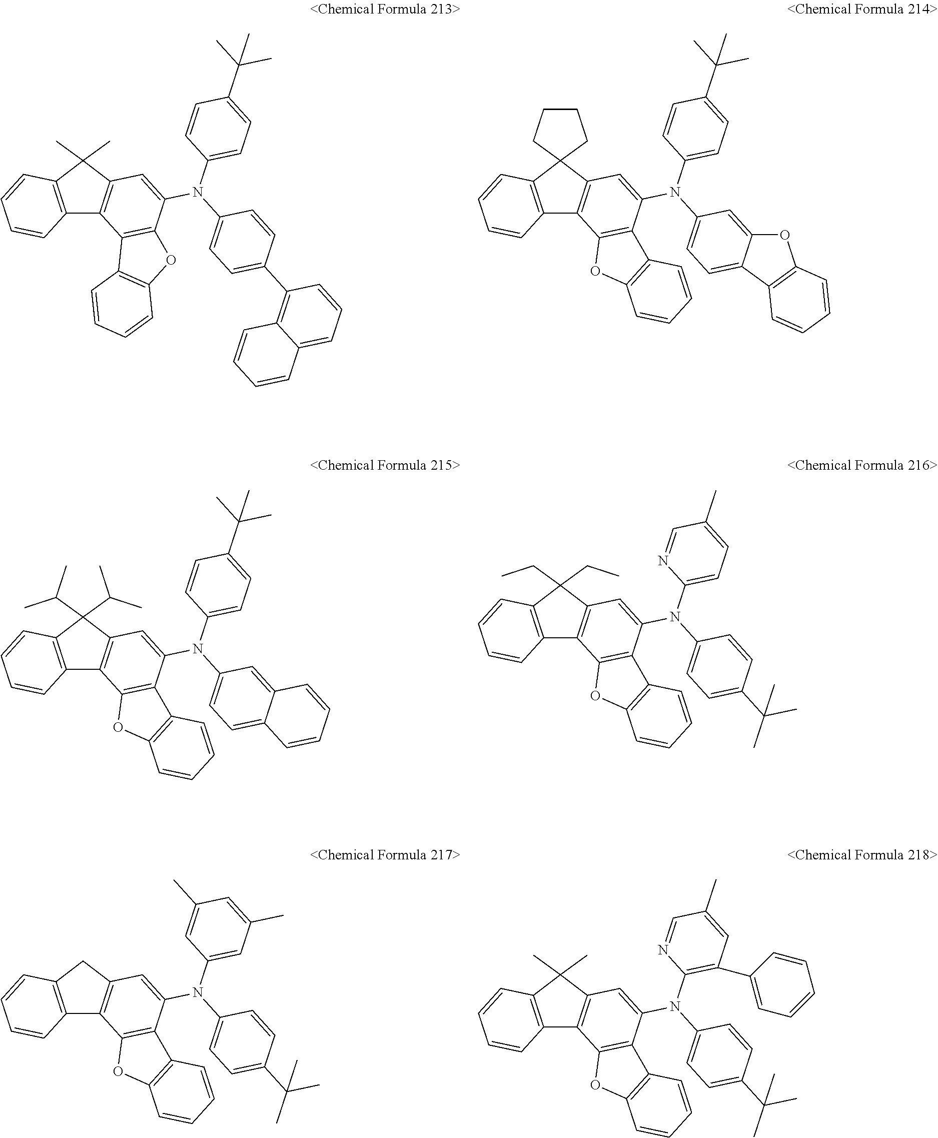 [SMILES: CC(C)(C)c1ccc(N(c2ccc(-c3cccc4ccccc34)cc2)c2cc3c(c4c2oc2ccccc24)-c2ccccc2C3(C)C)cc1 ; CC(C)(C)c1ccc(N(c2ccc3c(c2)oc2ccccc23)c2cc3c(c4oc5ccccc5c24)-c2ccccc2C32CCCC2)cc1 ; CC(C)C1(C(C)C)c2ccccc2-c2c1cc(N(c1ccc(C(C)(C)C)cc1)c1ccc3ccccc3c1)c1c2oc2ccccc21 ; CCC1(CC)c2ccccc2-c2c1cc(N(c1ccc(C(C)(C)C)cc1)c1ccc(C)cn1)c1c2oc2ccccc21 ; Cc1cc(C)cc(N(c2ccc(C(C)(C)C)cc2)c2cc3c(c4oc5ccccc5c24)-c2ccccc2C3)c1 ; Cc1cnc(N(c2ccc(C(C)(C)C)cc2)c2cc3c(c4oc5ccccc5c24)-c2ccccc2C3(C)C)c(-c2ccccc2)c1]

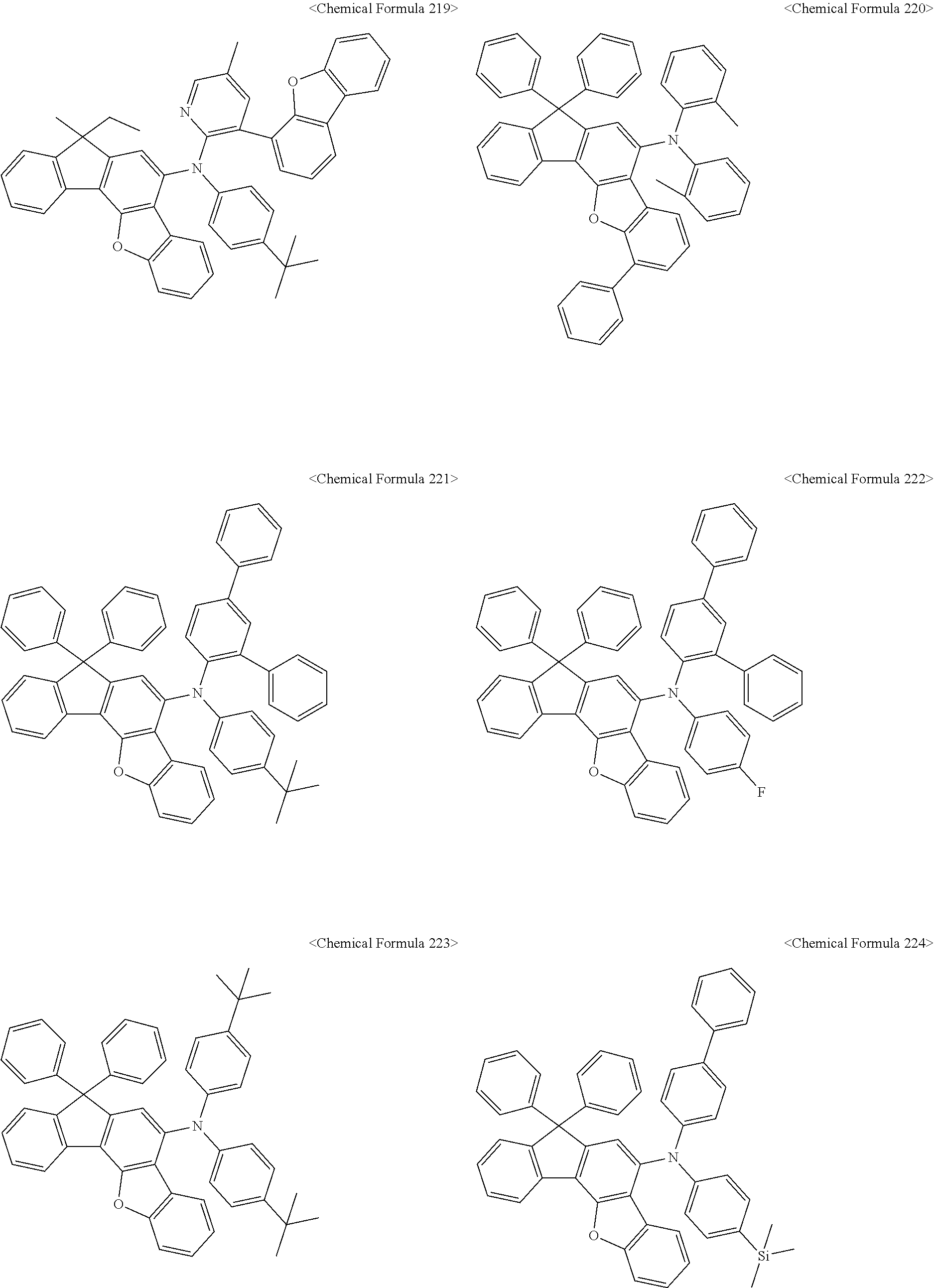

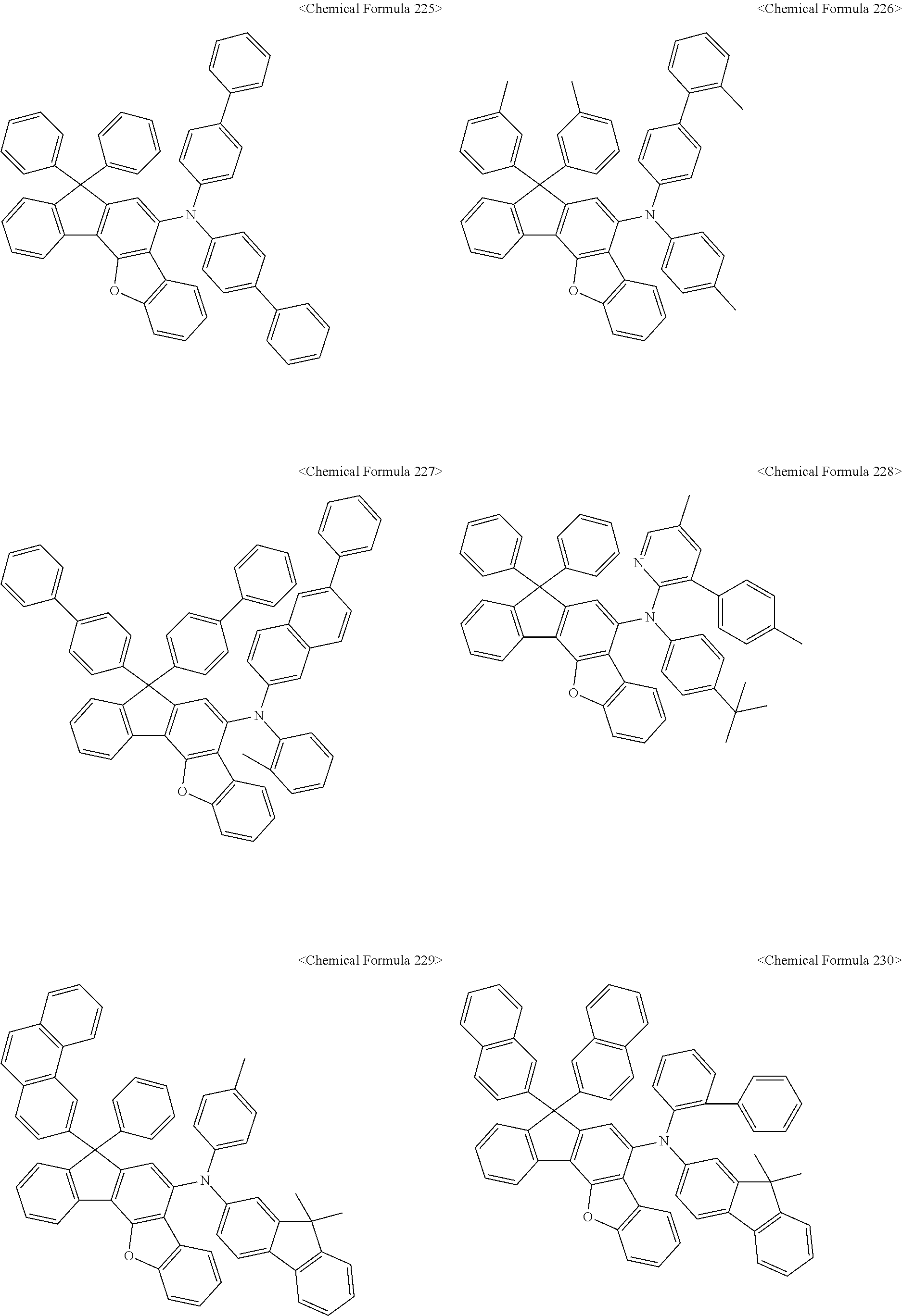

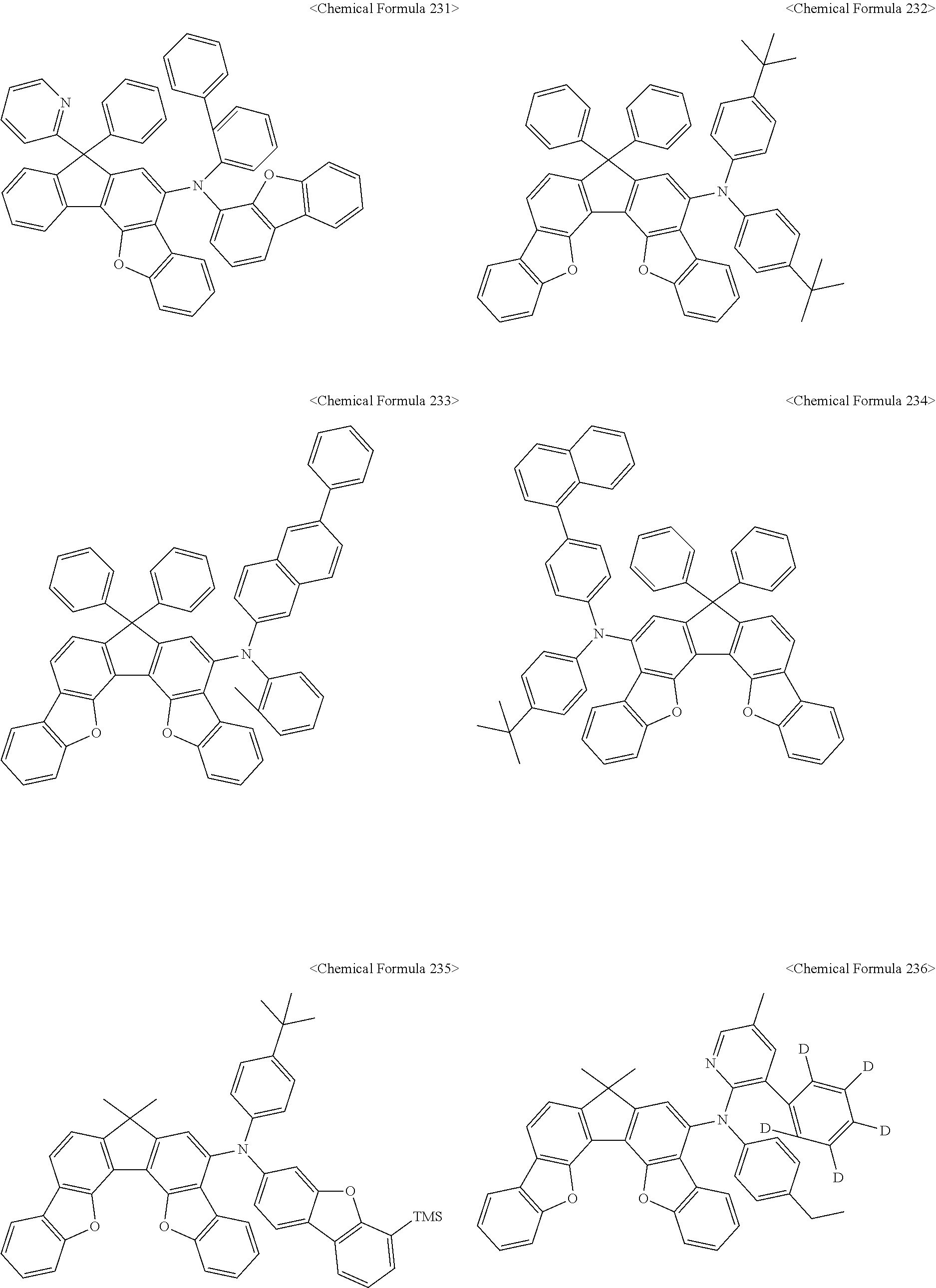

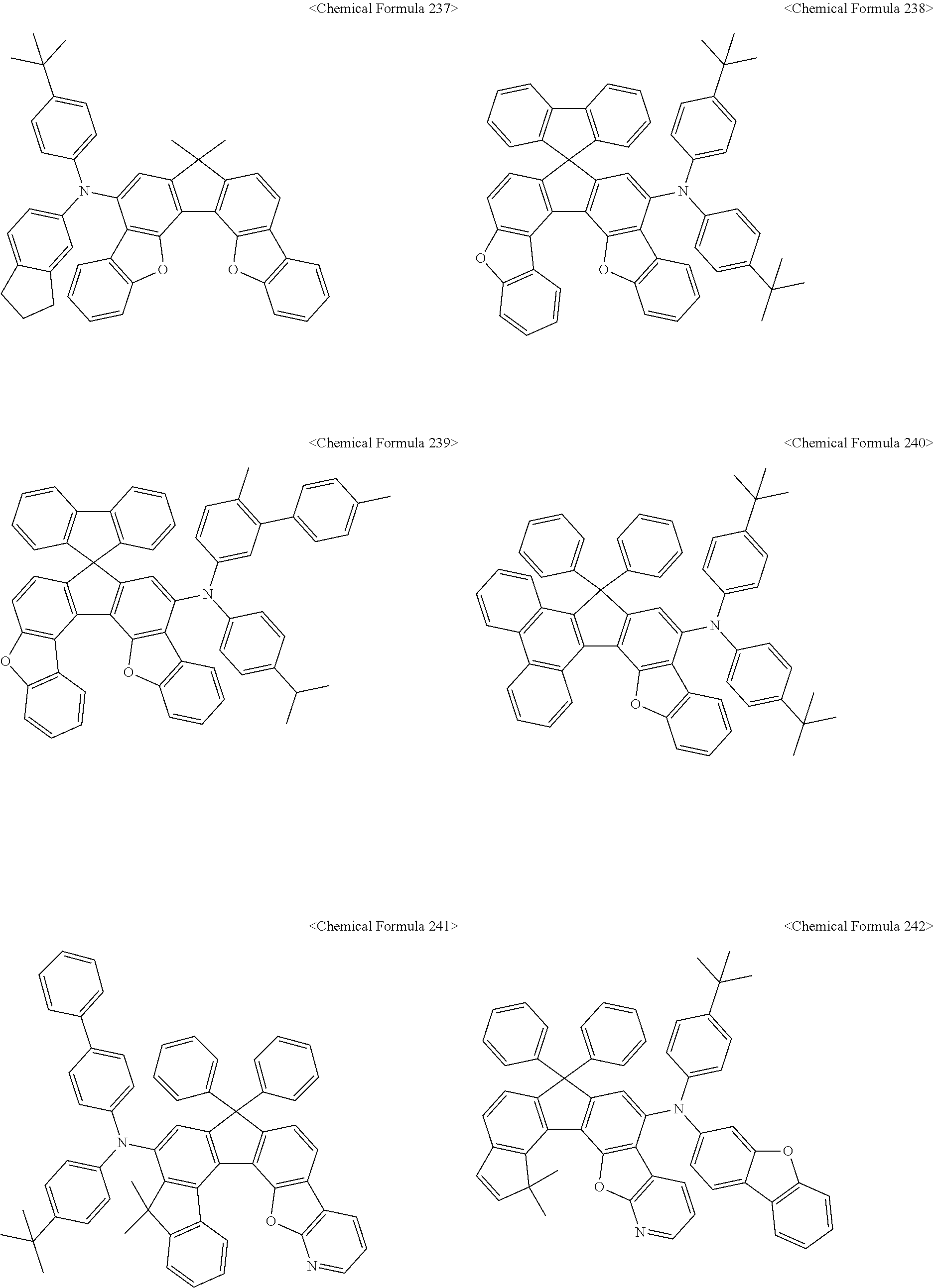

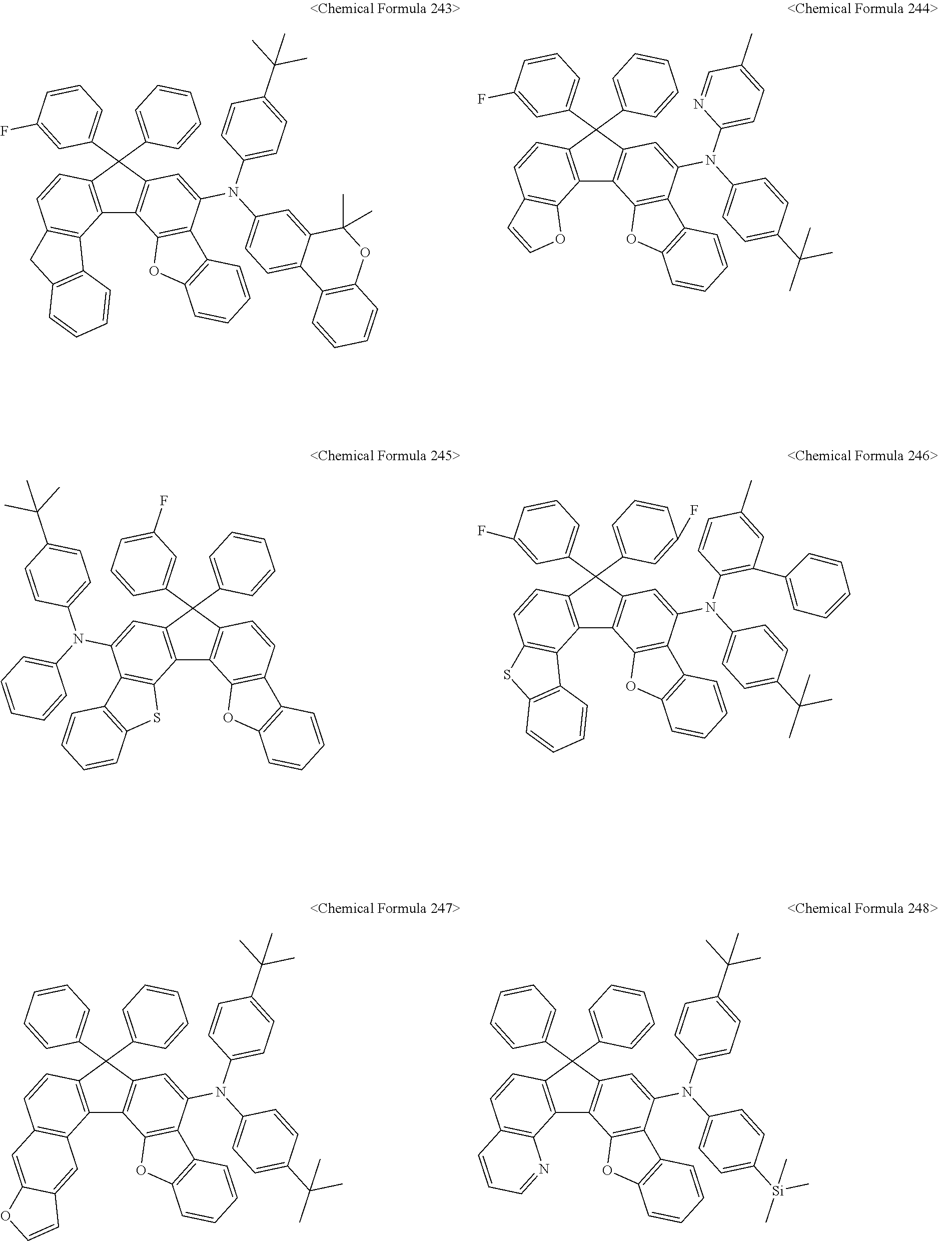

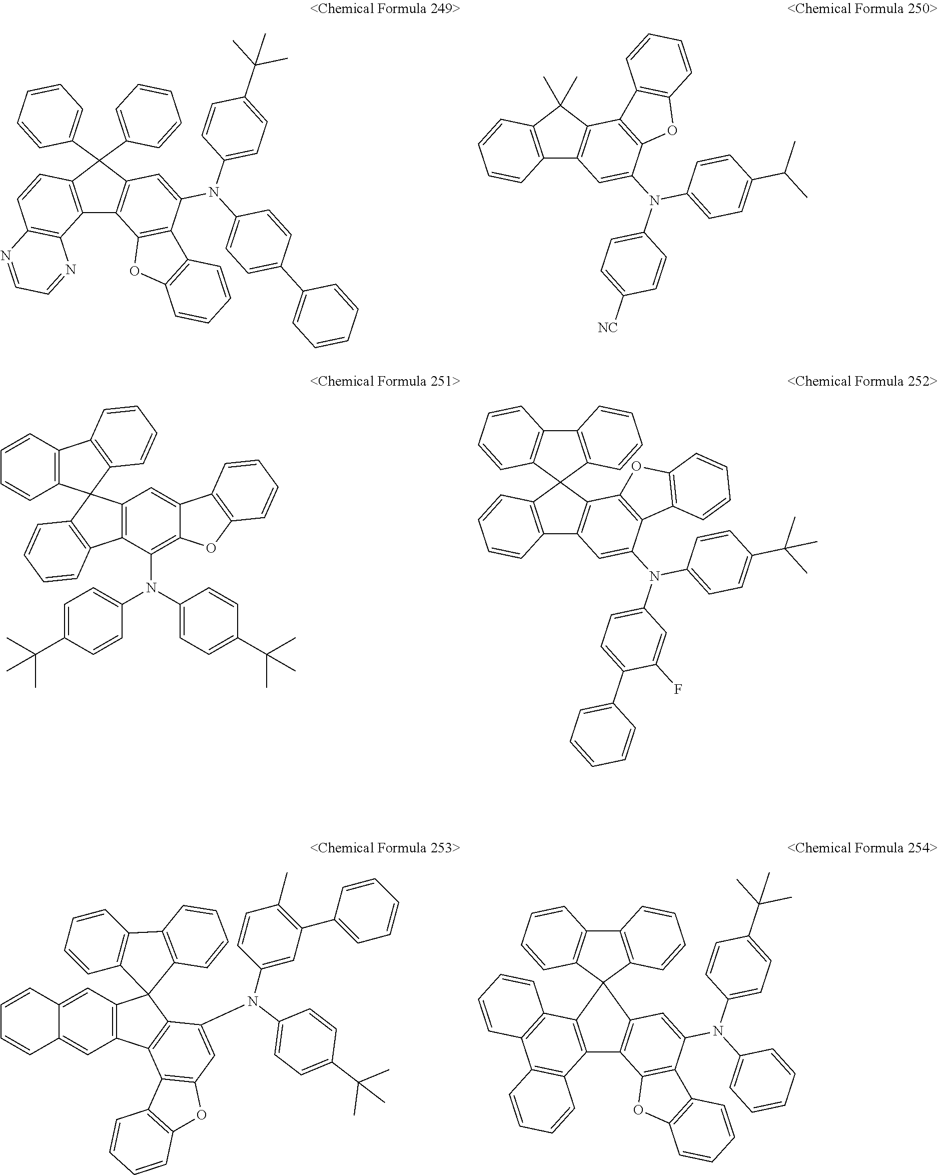

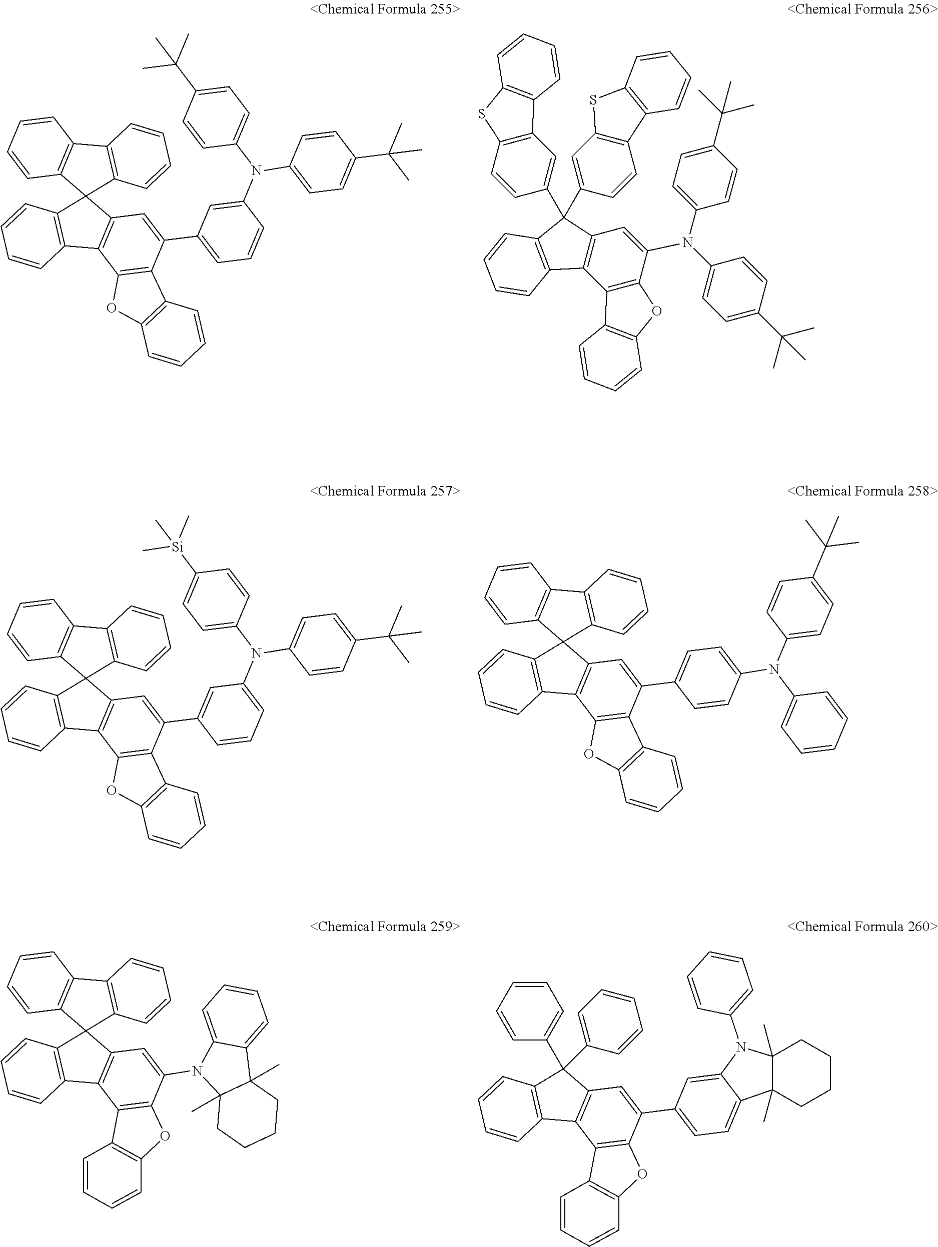

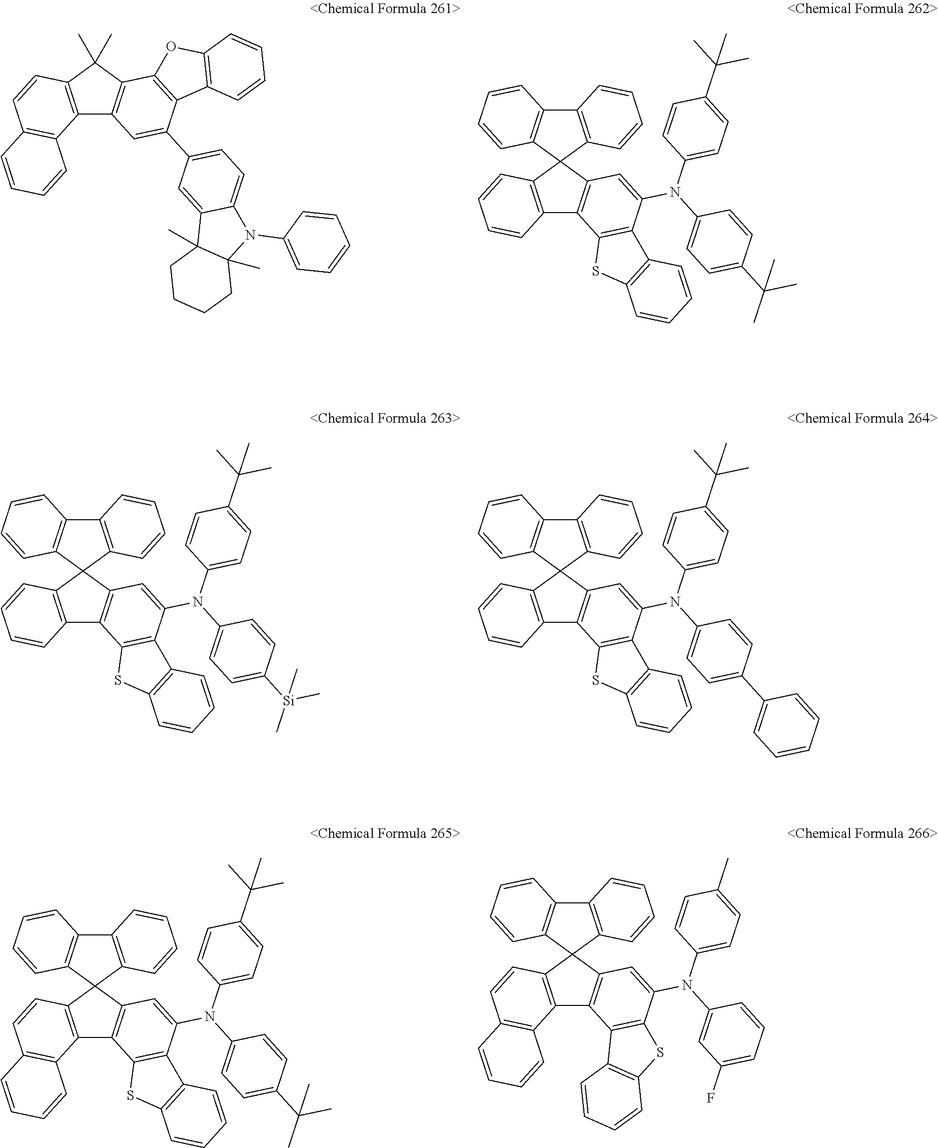

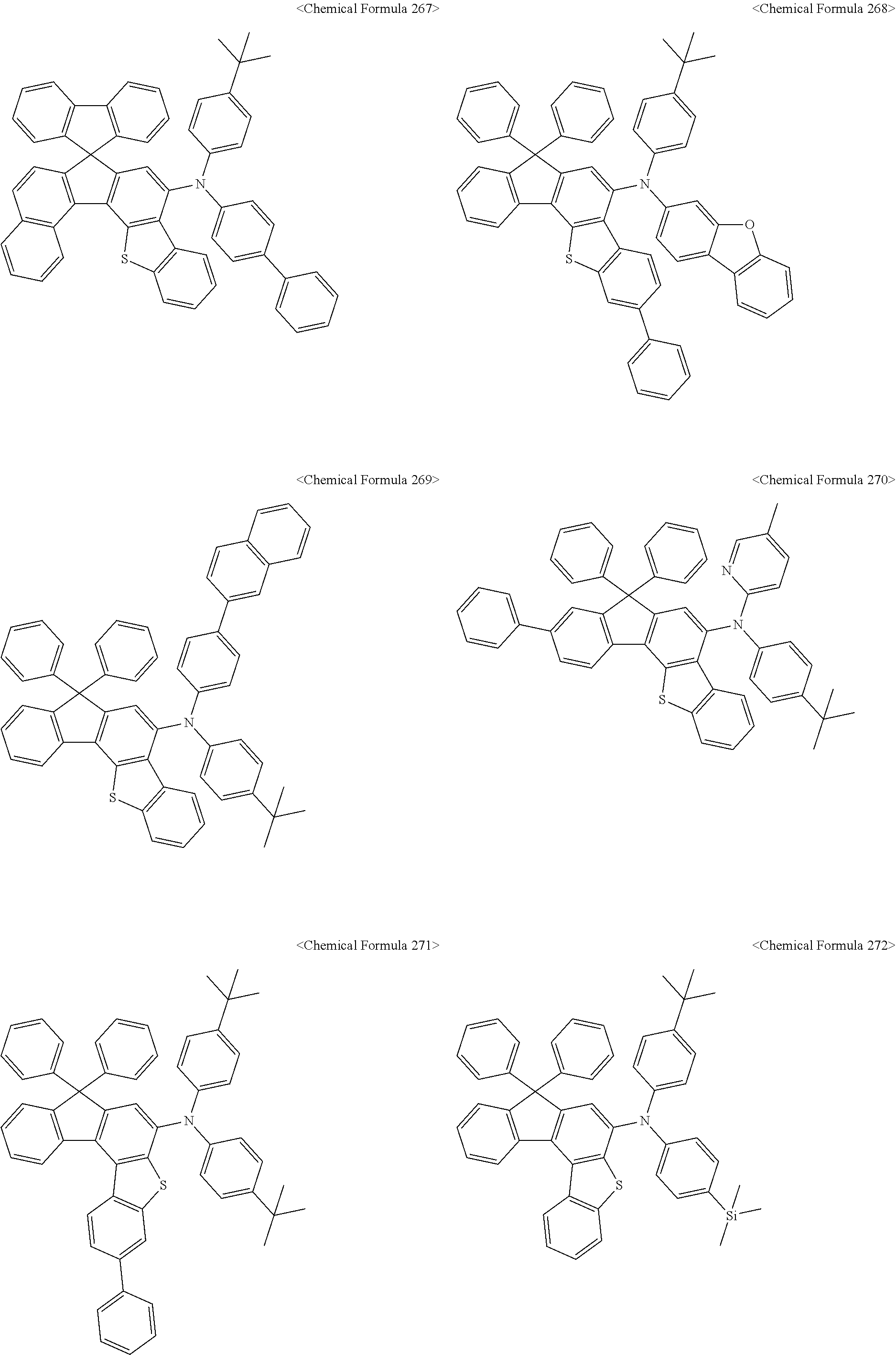

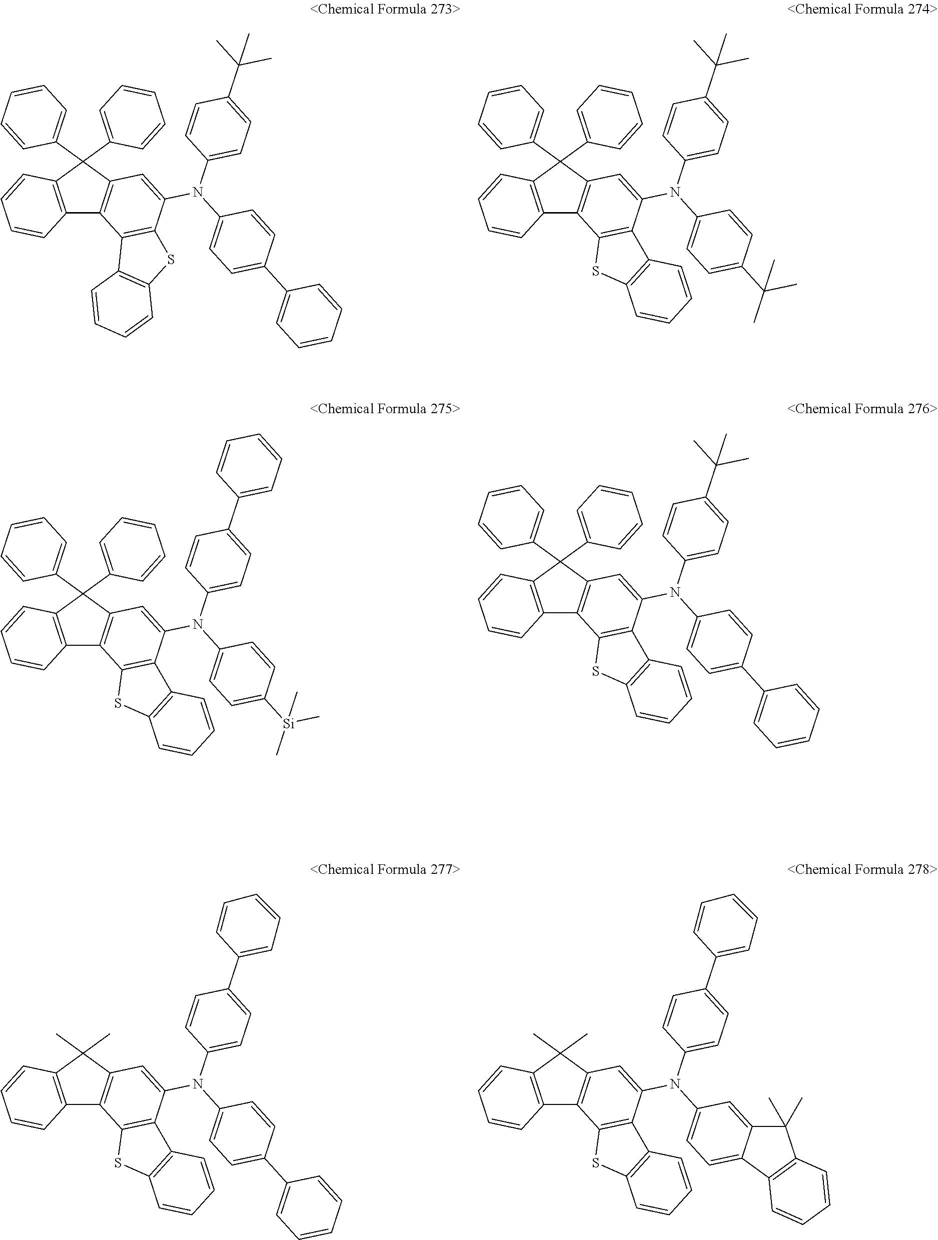

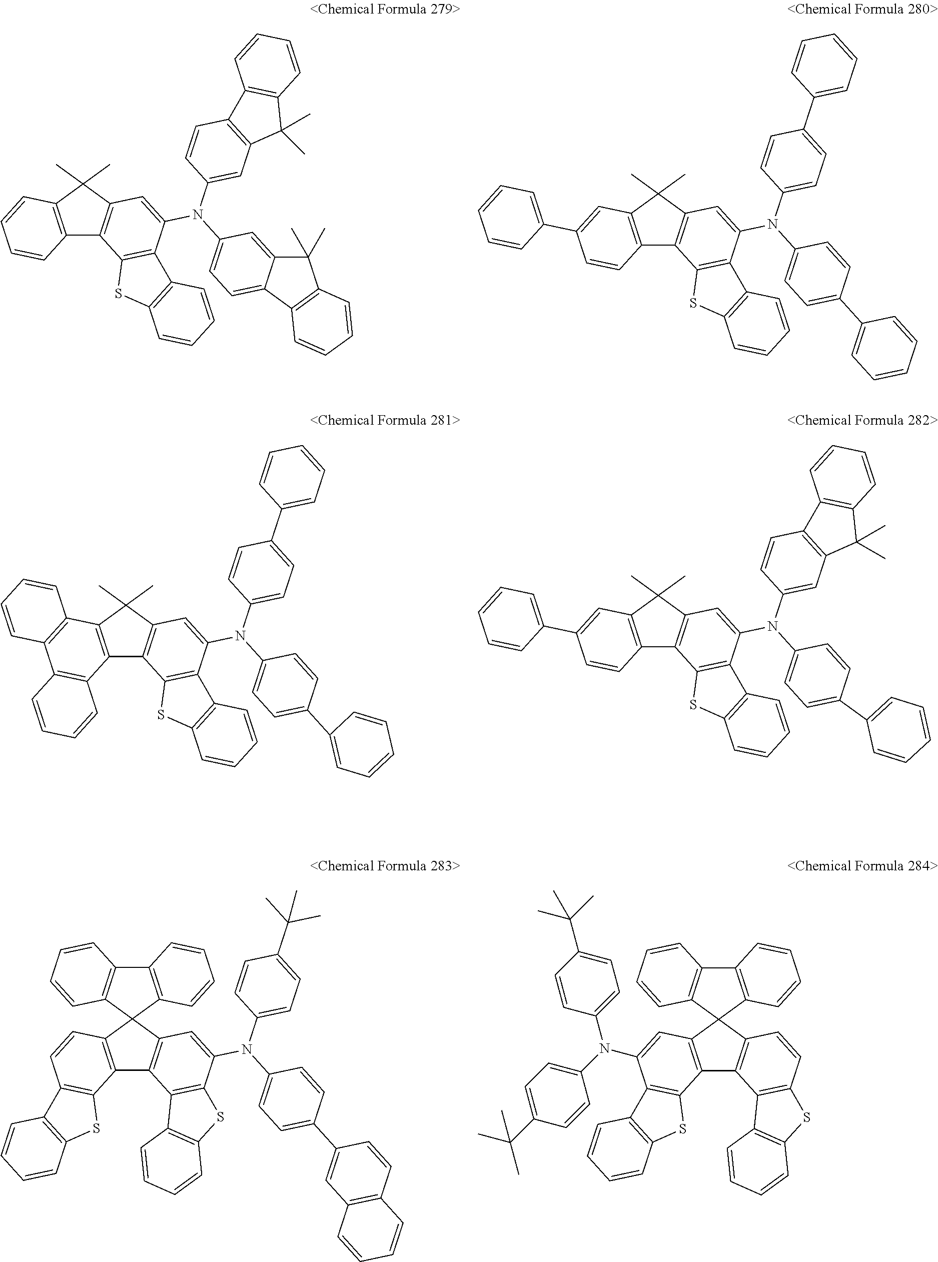

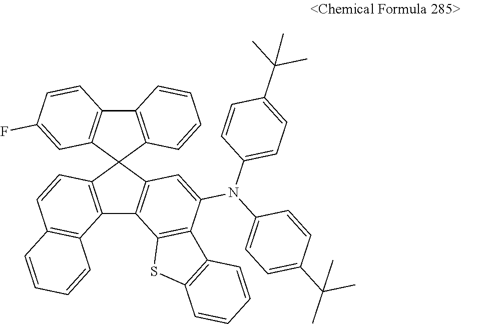 [SMILES: CC(C)(C)c1ccc(N(c2ccc(C(C)(C)C)cc2)c2cc3c(c4sc5ccccc5c24)-c2c(ccc4ccccc24)C32c3ccccc3-c3ccc(F)cc32)cc1]

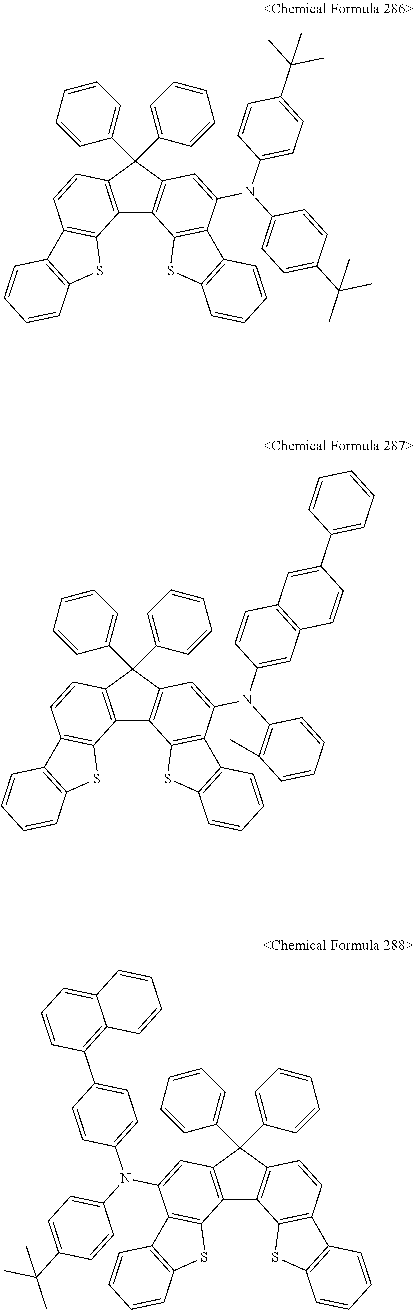

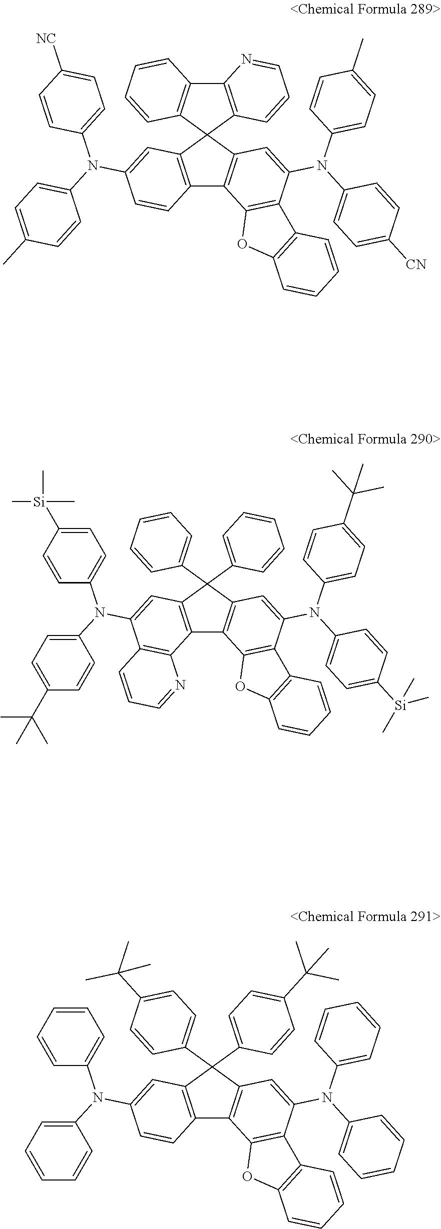 [SMILES: Cc1ccc(N(c2ccc(C#N)cc2)c2ccc3c(c2)C2(c4ccccc4-c4ncccc42)c2cc(N(c4ccc(C)cc4)c4ccc(C#N)cc4)c4c(oc5ccccc54)c2-3)cc1 ; CC(C)(C)c1ccc(N(c2ccc([Si](C)(C)C)cc2)c2cc3c(c4ncccc24)-c2c(cc(N(c4ccc(C(C)(C)C)cc4)c4ccc([Si](C)(C)C)cc4)c4c2oc2ccccc24)C3(c2ccccc2)c2ccccc2)cc1 ; CC(C)(C)c1ccc(C2(c3ccc(C(C)(C)C)cc3)c3cc(N(c4ccccc4)c4ccccc4)ccc3-c3c2cc(N(c2ccccc2)c2ccccc2)c2c3oc3ccccc32)cc1]

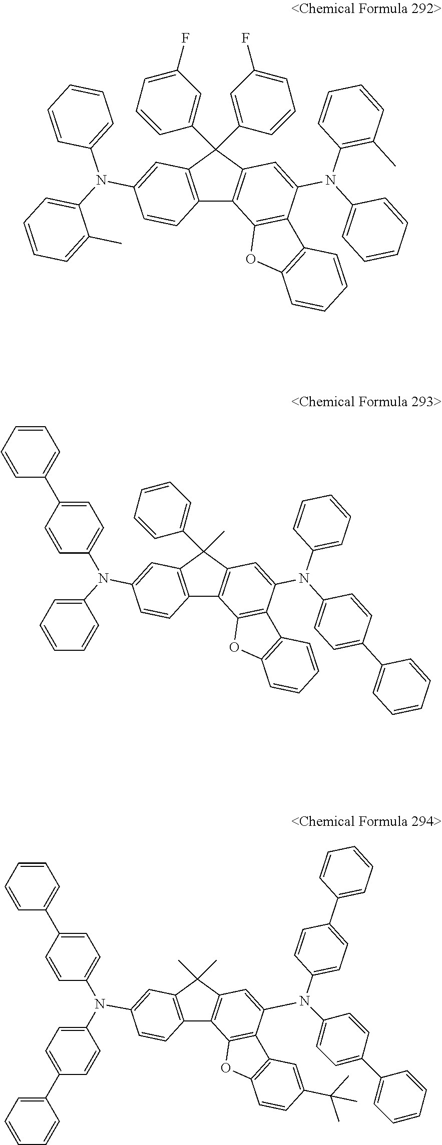 [SMILES: Cc1ccccc1N(c1ccccc1)c1ccc2c(c1)C(c1cccc(F)c1)(c1cccc(F)c1)c1cc(N(c3ccccc3)c3ccccc3C)c3c(oc4ccccc43)c1-2 ; CC1(c2ccccc2)c2cc(N(c3ccccc3)c3ccc(-c4ccccc4)cc3)ccc2-c2c1cc(N(c1ccccc1)c1ccc(-c3ccccc3)cc1)c1c2oc2ccccc21 ; CC(C)(C)c1ccc2oc3c4c(cc(N(c5ccc(-c6ccccc6)cc5)c5ccc(-c6ccccc6)cc5)c3c2c1)C(C)(C)c1cc(N(c2ccc(-c3ccccc3)cc2)c2ccc(-c3ccccc3)cc2)ccc1-4]

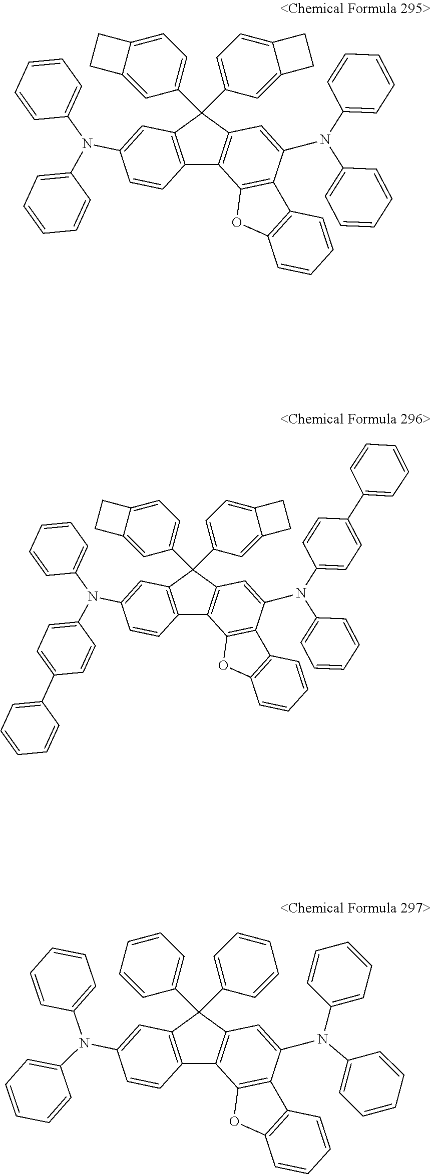 [SMILES: c1ccc(N(c2ccccc2)c2ccc3c(c2)C(c2ccc4c(c2)CC4)(c2ccc4c(c2)CC4)c2cc(N(c4ccccc4)c4ccccc4)c4c(oc5ccccc54)c2-3)cc1 ; c1ccc(-c2ccc(N(c3ccccc3)c3ccc4c(c3)C(c3ccc5c(c3)CC5)(c3ccc5c(c3)CC5)c3cc(N(c5ccccc5)c5ccc(-c6ccccc6)cc5)c5c(oc6ccccc65)c3-4)cc2)cc1 ; c1ccc(N(c2ccccc2)c2ccc3c(c2)C(c2ccccc2)(c2ccccc2)c2cc(N(c4ccccc4)c4ccccc4)c4c(oc5ccccc54)c2-3)cc1]

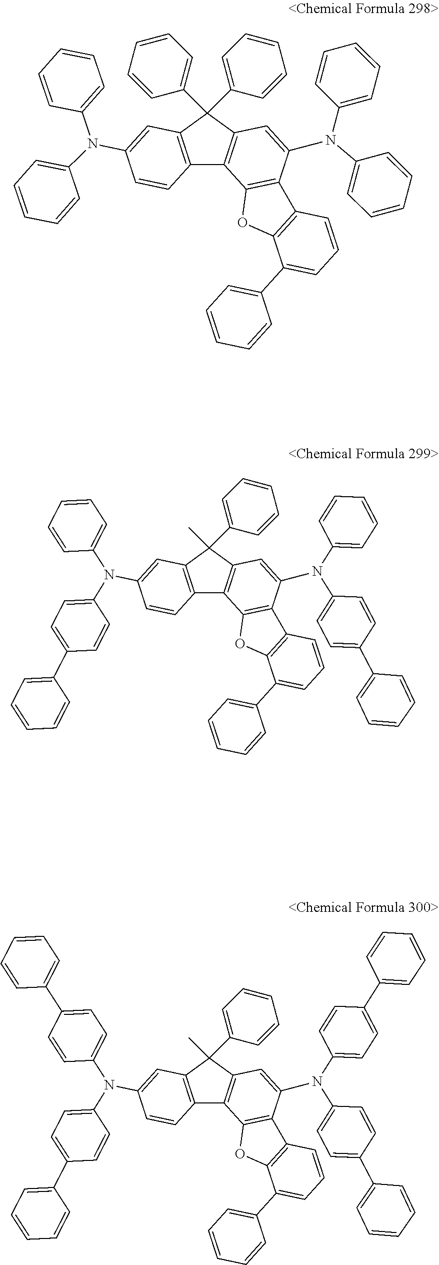 [SMILES: c1ccc(-c2cccc3c2oc2c4c(cc(N(c5ccccc5)c5ccccc5)c23)C(c2ccccc2)(c2ccccc2)c2cc(N(c3ccccc3)c3ccccc3)ccc2-4)cc1 ; CC1(c2ccccc2)c2cc(N(c3ccccc3)c3ccc(-c4ccccc4)cc3)ccc2-c2c1cc(N(c1ccccc1)c1ccc(-c3ccccc3)cc1)c1c2oc2c(-c3ccccc3)cccc21 ; CC1(c2ccccc2)c2cc(N(c3ccc(-c4ccccc4)cc3)c3ccc(-c4ccccc4)cc3)ccc2-c2c1cc(N(c1ccc(-c3ccccc3)cc1)c1ccc(-c3ccccc3)cc1)c1c2oc2c(-c3ccccc3)cccc21]

In the present disclosure, the boron compound represented by [Chemical Formula C] has the structural feature wherein the Z₁ to Z₃ rings, which each correspond to a substituted or unsubstituted aromatic hydrocarbon ring of 6 to 50 carbon atoms or a substituted or unsubstituted heteroaromatic ring of 2 to 50 carbon atoms, are all linked to a boron (B) atom, with Z₁ and Z₃ ring connected to each other via linker T₁, and Z₂ and Z₃ rings connected to each other via linker T₂. The compound represented by [Chemical Formula C] may be used as a material for a dopant in the light-emitting layer.

According to an embodiment, linker T₁ connecting Z₁ and Z₃ rings to each other therethrough may be N—R₁₁ and linker T₂ connecting Z₂ and Z₃ rings to each other therethrough may be N—R₁₄ in [Chemical Formula C]. In this regard, R₁₁ and R₁₄ are each as defined above.

In case where linkers T₁ and T₂ are respectively N—R₁₁ and N—R₁₄ in [Chemical Formula C], R₁₁ and R₁₄, which may be the same or different, may each be independently a substituted or unsubstituted aryl of 6 to 50 carbon atoms, or a substituted or unsubstituted heteroaryl of 2 to 50 carbon atoms.

In [Chemical Formula C], linkers T₁ and T₂, which may be the same or different, may each be independently represented by the following [Structural Formula A]:

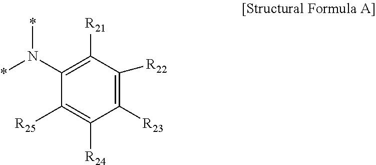

wherein,

“-*” denotes a bonding site at which the linker T₁ is connected to aromatic carbon atoms of Z₁ and Z₃ rings or the linker T₂ is connected to aromatic carbons of Z₂ and Z₃,

R₂₁ to R₂₅, which may be the same or difference, are each independently a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen.

In [Chemical Formula C], either or both of the linkers T₁ and T₂ may be an oxygen atom.

Meanwhile, Z₁ to Z₃ rings, which are each linked to the boron (B) atom in the boron compound represented by [Chemical Formula C], may be the same or different and may each be a substituted or unsubstituted aromatic hydrocarbon ring of 6 to 50 carbon atoms.

When Z₁ to Z₂ rings, which may be the same or different, are each a substituted or unsubstituted aromatic hydrocarbon ring of 6 to 50 carbon atoms, the aromatic hydrocarbon rings of Z₁ to Z₂ may each be independently selected from [Structural Formula 40] to [Structural Formula 51]:

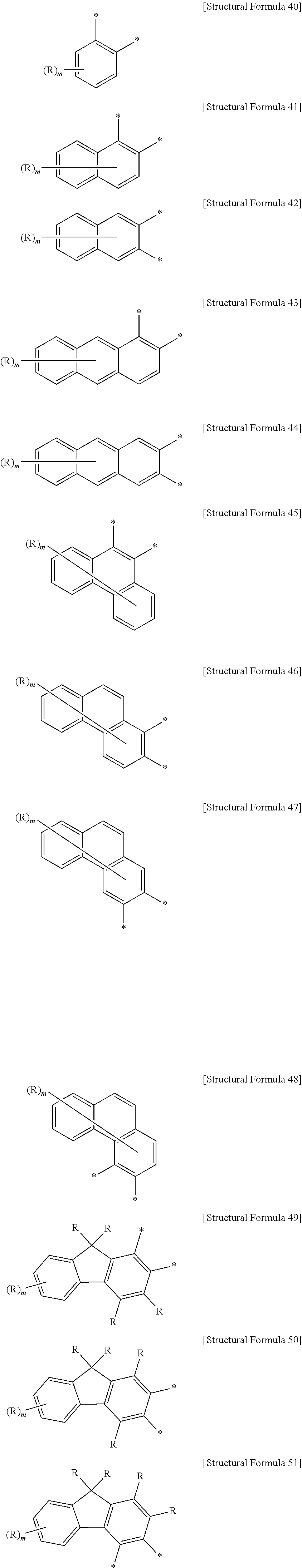

wherein,

“-*” denote a bonding site at which the corresponding carbon atoms within the aromatic ring of Z₁ are bonded to the linker T₁ and the boron atom (B) or the corresponding carbon atoms with the aromatic ring of Z₂ are bonded to the linker T₂ and the boron atom (B),

Rs, which may be the same or different, are selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen, and

m is an integer of 1 to 8 wherein when m is 2 or greater or when R is 2 or greater, the resulting R may be same or different.

In addition, when the aromatic hydrocarbon ring of Z₃ is a substituted or unsubstituted aromatic hydrocarbon ring of 6 to 50 carbon atoms, Z₃ may be the ring represented by the following [Structural Formula B]:

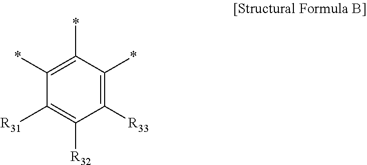

wherein,

“-*” denotes a bonding site at which the corresponding carbon atoms within the aromatic ring of Z₃ are respectively bonded to the linkers T₁ and T₂, and the boron atom (B),

R₃₁ to R₃₃, which may be the same or different, are each independently selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen, and

R₃₁ to R₃₃ may each be linked to an adjacent substituent to form an additional mono- or polycyclic aliphatic or aromatic ring.

Concrete examples of the boron compound represented by [Chemical Formula C] include, but are not limited to, the following <Compound 1> to <Compound 30>:

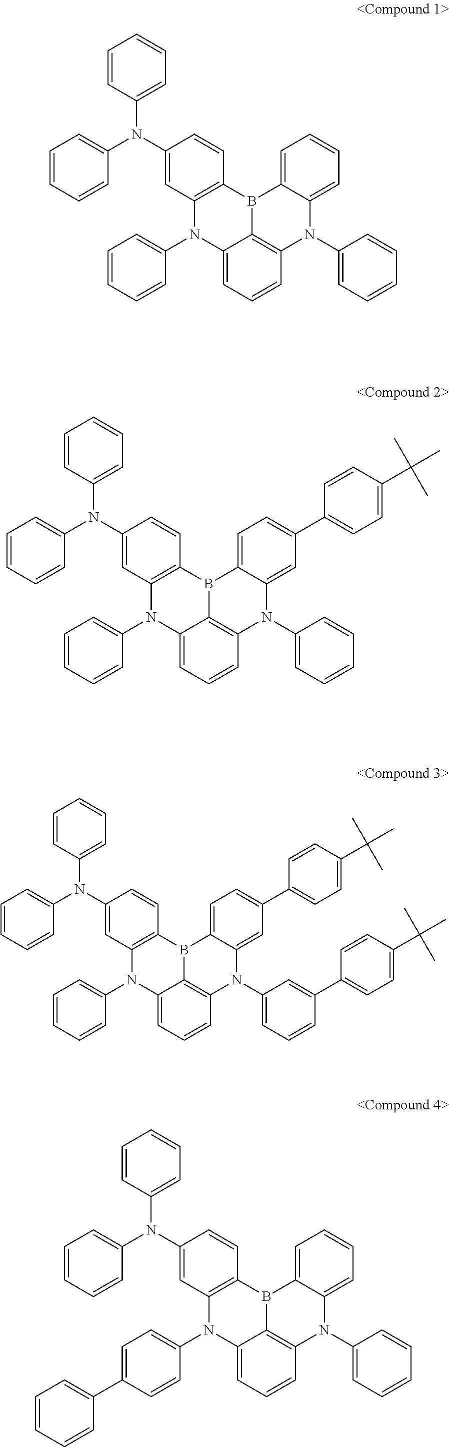 [SMILES: c1ccc(N(c2ccccc2)c2ccc3c(c2)N(c2ccccc2)c2cccc4c2B3c2ccccc2N4c2ccccc2)cc1 ; CC(C)(C)c1ccc(-c2ccc3c(c2)N(c2ccccc2)c2cccc4c2B3c2ccc(N(c3ccccc3)c3ccccc3)cc2N4c2ccccc2)cc1 ; CC(C)(C)c1ccc(-c2cccc(N3c4cc(-c5ccc(C(C)(C)C)cc5)ccc4B4c5ccc(N(c6ccccc6)c6ccccc6)cc5N(c5ccccc5)c5cccc3c54)c2)cc1 ; c1ccc(-c2ccc(N3c4cc(N(c5ccccc5)c5ccccc5)ccc4B4c5ccccc5N(c5ccccc5)c5cccc3c54)cc2)cc1]

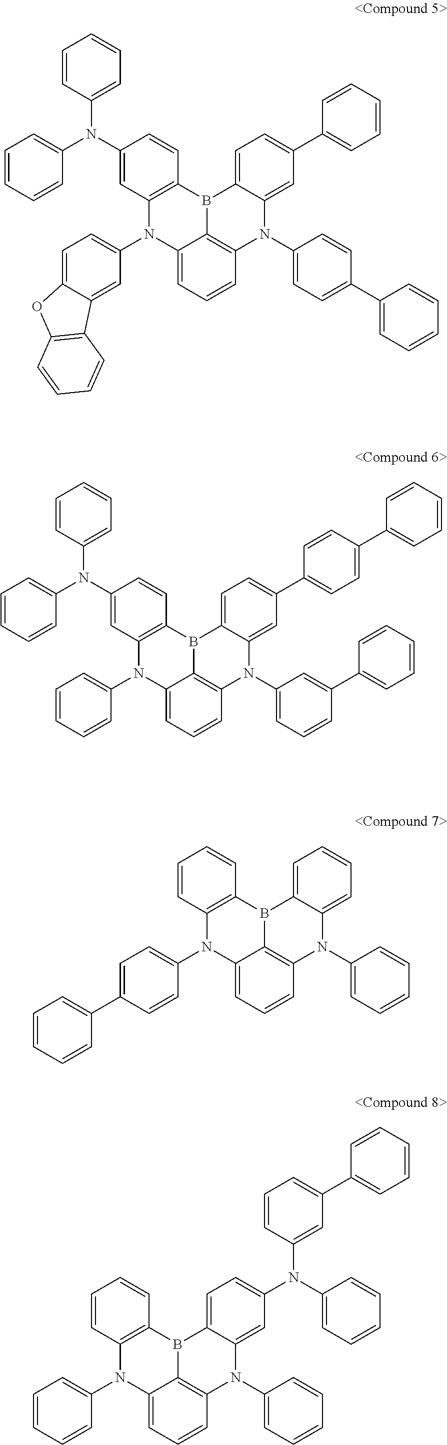 [SMILES: c1ccc(-c2ccc(N3c4cc(-c5ccccc5)ccc4B4c5ccc(N(c6ccccc6)c6ccccc6)cc5N(c5ccc6oc7ccccc7c6c5)c5cccc3c54)cc2)cc1 ; c1ccc(-c2ccc(-c3ccc4c(c3)N(c3cccc(-c5ccccc5)c3)c3cccc5c3B4c3ccc(N(c4ccccc4)c4ccccc4)cc3N5c3ccccc3)cc2)cc1 ; c1ccc(-c2ccc(N3c4ccccc4B4c5ccccc5N(c5ccccc5)c5cccc3c54)cc2)cc1 ; c1ccc(-c2cccc(N(c3ccccc3)c3ccc4c(c3)N(c3ccccc3)c3cccc5c3B4c3ccccc3N5c3ccccc3)c2)cc1]

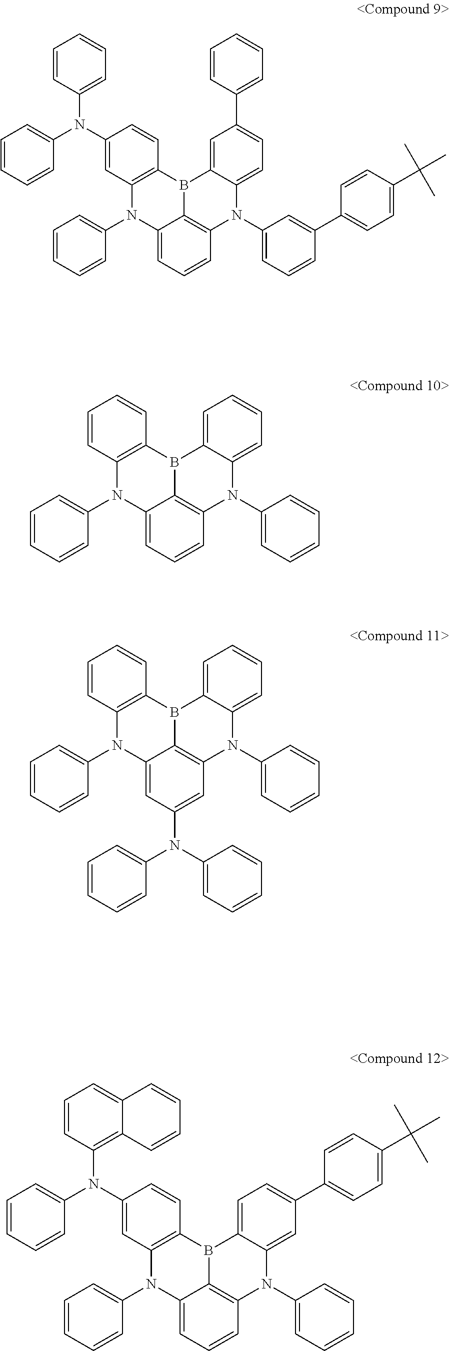 [SMILES: CC(C)(C)c1ccc(-c2cccc(N3c4ccc(-c5ccccc5)cc4B4c5ccc(N(c6ccccc6)c6ccccc6)cc5N(c5ccccc5)c5cccc3c54)c2)cc1 ; c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; CC(C)(C)c1ccc(-c2ccc3c(c2)N(c2ccccc2)c2cccc4c2B3c2ccc(N(c3ccccc3)c3cccc5ccccc35)cc2N4c2ccccc2)cc1]

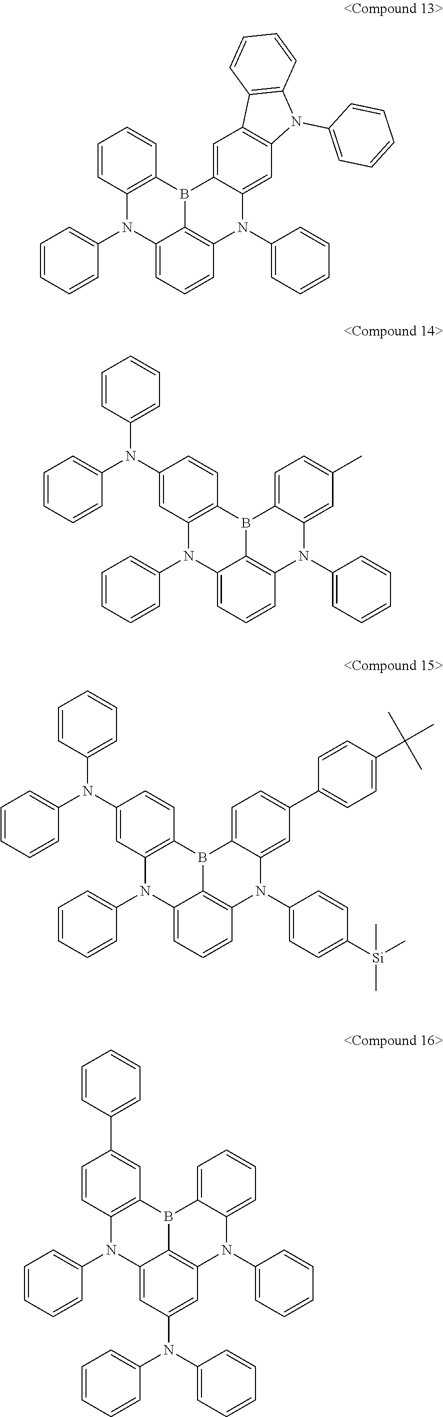 [SMILES: c1ccc(N2c3ccccc3B3c4cc5c6ccccc6n(-c6ccccc6)c5cc4N(c4ccccc4)c4cccc2c43)cc1 ; Cc1ccc2c(c1)N(c1ccccc1)c1cccc3c1B2c1ccc(N(c2ccccc2)c2ccccc2)cc1N3c1ccccc1 ; CC(C)(C)c1ccc(-c2ccc3c(c2)N(c2ccc([Si](C)(C)C)cc2)c2cccc4c2B3c2ccc(N(c3ccccc3)c3ccccc3)cc2N4c2ccccc2)cc1 ; c1ccc(-c2ccc3c(c2)B2c4ccccc4N(c4ccccc4)c4cc(N(c5ccccc5)c5ccccc5)cc(c42)N3c2ccccc2)cc1]

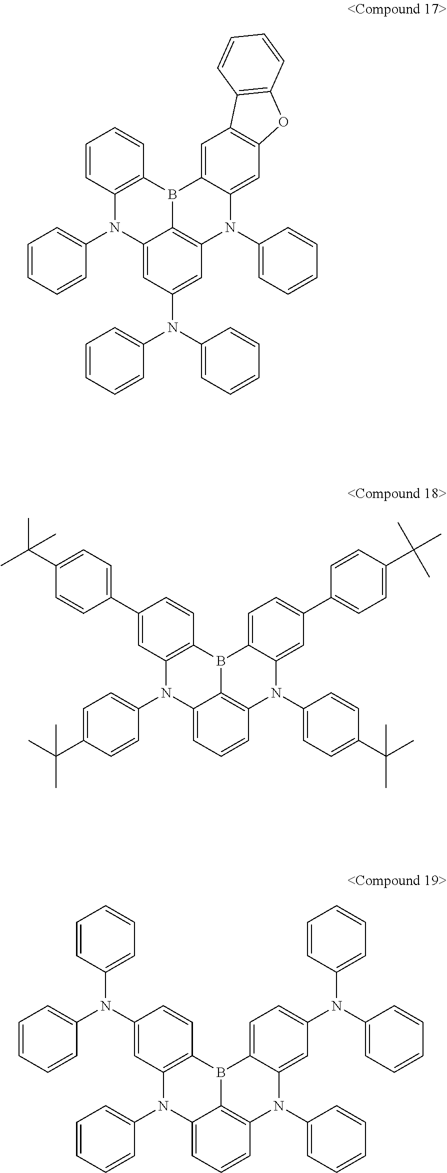 [SMILES: c1ccc(N(c2ccccc2)c2cc3c4c(c2)N(c2ccccc2)c2cc5oc6ccccc6c5cc2B4c2ccccc2N3c2ccccc2)cc1 ; CC(C)(C)c1ccc(-c2ccc3c(c2)N(c2ccc(C(C)(C)C)cc2)c2cccc4c2B3c2ccc(-c3ccc(C(C)(C)C)cc3)cc2N4c2ccc(C(C)(C)C)cc2)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1]

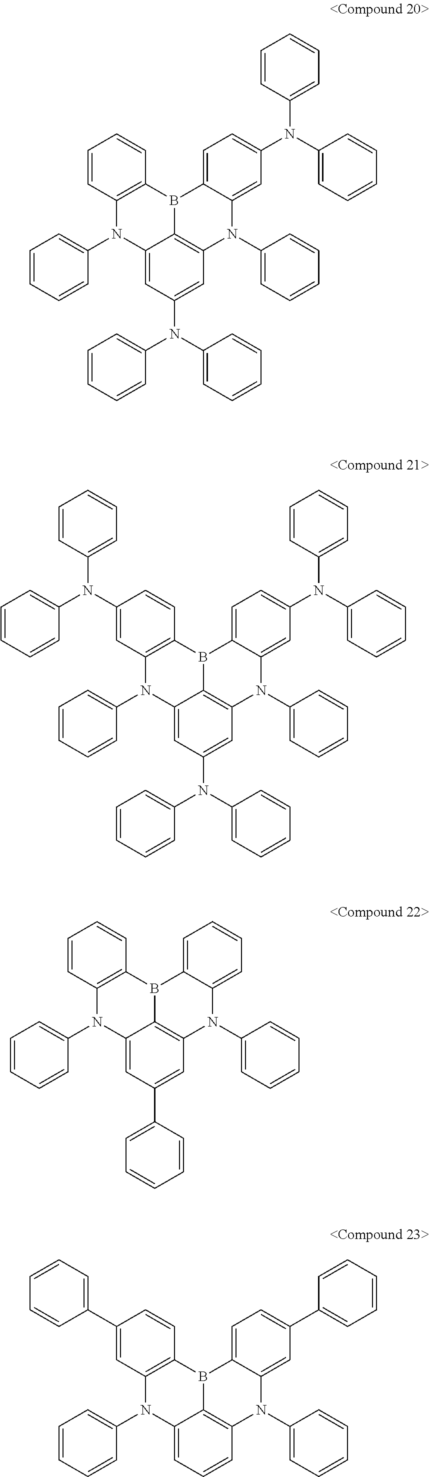 [SMILES: c1ccc(N(c2ccccc2)c2ccc3c(c2)N(c2ccccc2)c2cc(N(c4ccccc4)c4ccccc4)cc4c2B3c2ccccc2N4c2ccccc2)cc1 ; c1ccc(N(c2ccccc2)c2ccc3c(c2)N(c2ccccc2)c2cc(N(c4ccccc4)c4ccccc4)cc4c2B3c2ccc(N(c3ccccc3)c3ccccc3)cc2N4c2ccccc2)cc1 ; c1ccc(-c2cc3c4c(c2)N(c2ccccc2)c2ccccc2B4c2ccccc2N3c2ccccc2)cc1 ; c1ccc(-c2ccc3c(c2)N(c2ccccc2)c2cccc4c2B3c2ccc(-c3ccccc3)cc2N4c2ccccc2)cc1]

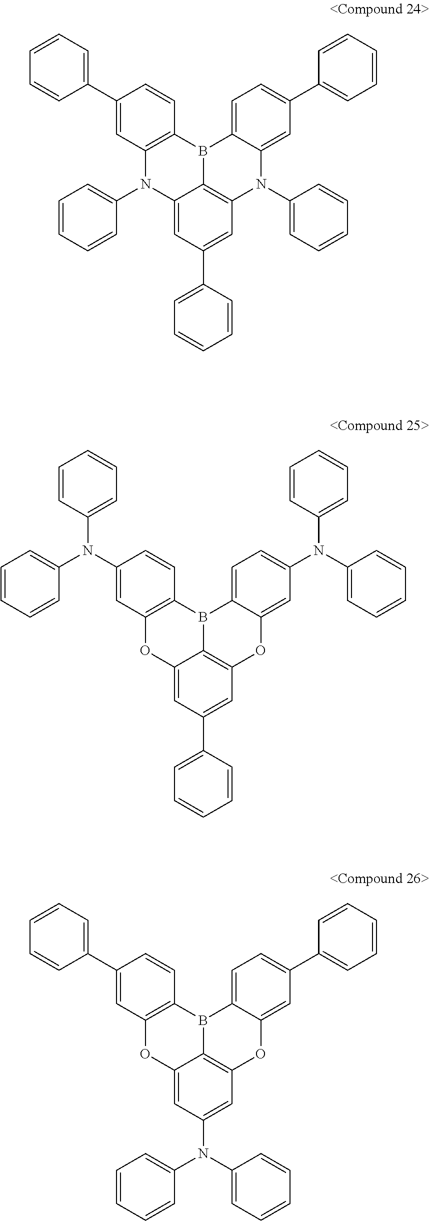 [SMILES: c1ccc(-c2ccc3c(c2)N(c2ccccc2)c2cc(-c4ccccc4)cc4c2B3c2ccc(-c3ccccc3)cc2N4c2ccccc2)cc1 ; c1ccc(-c2cc3c4c(c2)Oc2cc(N(c5ccccc5)c5ccccc5)ccc2B4c2ccc(N(c4ccccc4)c4ccccc4)cc2O3)cc1 ; c1ccc(-c2ccc3c(c2)Oc2cc(N(c4ccccc4)c4ccccc4)cc4c2B3c2ccc(-c3ccccc3)cc2O4)cc1]

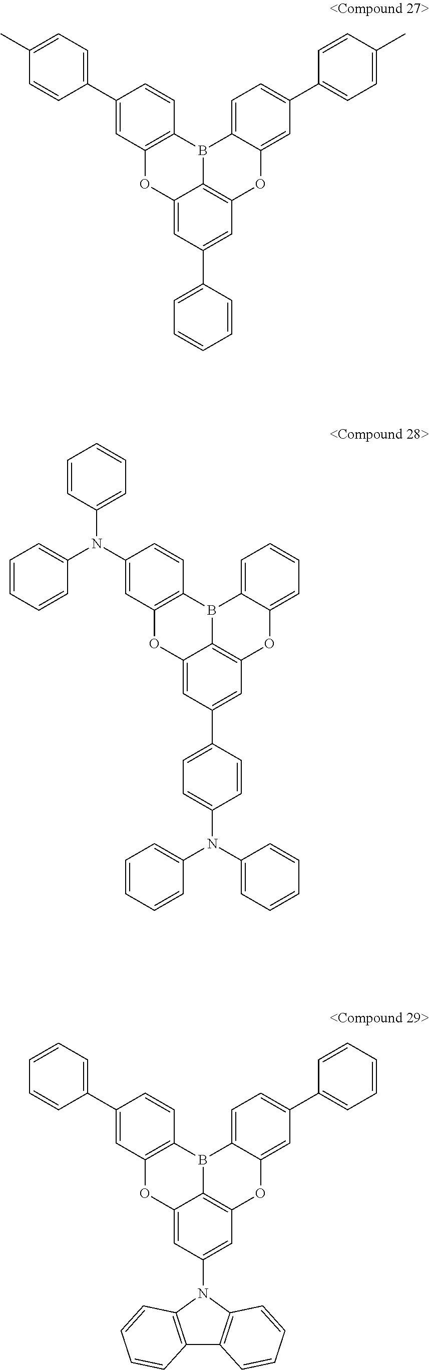

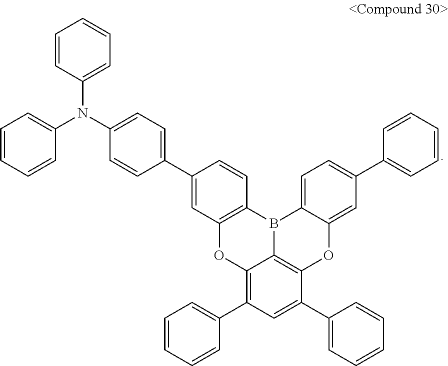 [SMILES: c1ccc(-c2ccc3c(c2)Oc2c(-c4ccccc4)cc(-c4ccccc4)c4c2B3c2ccc(-c3ccc(N(c5ccccc5)c5ccccc5)cc3)cc2O4)cc1]

According to some particular embodiments of the present disclosure, the organic light-emitting diode may further comprise at least one of a hole injection layer, a hole transport layer, a functional layer capable of both hole injection and hole transport, an electron transport layer, and an electron injection layer in addition to the light-emitting layer.

In the present disclosure, the phrase “(an organic layer) includes at least one organic compound” may be construed to mean that “(an organic layer) may include a single organic compound species or two or more different species of organic compounds falling within the scope of the present disclosure”.

In a particular embodiment of the present disclosure, the organic light-emitting diode comprises the first electrode as an anode, the second electrode as a cathode, and the light-emitting layer interposed between the anode and the cathode, wherein the light-emitting layer includes at least one of the boron compounds represented by [Chemical Formula C] as a dopant therein and the compound represented by [Chemical Formula A] or [Chemical Formula B] is used as a hole injection layer or hole transport layer.

In this regard, the content of the dopant may range from about 0.01 to 20 parts by weight, based on 100 parts by weight of the host, but is not limited thereto.

In addition to the above-mentioned dopants and hosts, the light-emitting layer may further include various hosts and dopant materials.

A proper combinational employment of the boron compounds represented by [Chemical Formula C] in the light-emitting layer including the host and the dopant and the compounds represented by [Chemical Formula A] or [Chemical Formula B] as the hole injection layer or the hole transport layer guarantees high efficiency properties.

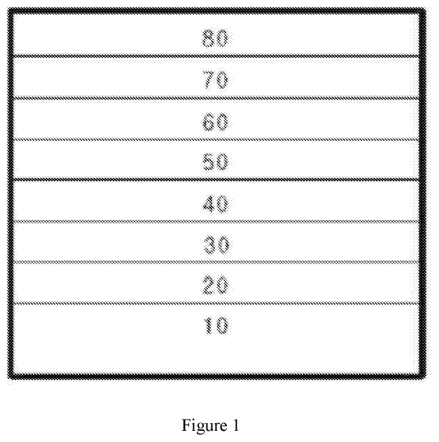

Below, the organic light-emitting diode of the present disclosure is explained with reference to FIG. 1.

FIG. 1 is a schematic cross-sectional view of the structure of an organic light-emitting diode according to an embodiment of the present disclosure.

As shown in FIG. 1, the organic light-emitting diode according to an embodiment of the present disclosure comprises an anode 20, a hole transport layer 40, an organic light-emitting layer 50 containing a host and a dopant, an electron transport layer 60, and a cathode 80, wherein the anode and the cathode serve as a first electrode and a second electrode, respectively, with the interposition of the hole transport layer between the anode and the light-emitting layer and the electron transport layer between the light-emitting layer and the cathode.

Furthermore, the organic light-emitting diode according to an embodiment of the present disclosure may comprise an hole injection layer 30 between the anode 20 and the hole transport layer 40 and an electron injection layer 70 between the electron transport layer 60 and the cathode 80.

Reference is made to FIG. 1 with regard to the fabrication of the organic light-emitting diode of the present disclosure.

First, a substrate 10 is coated with an anode electrode material to form an anode 20. So long as it is used in a typical organic EL device, any substrate may be used as the substrate 10. Preferable is an organic substrate or transparent plastic substrate that exhibits excellent transparency, surface smoothness, ease of handling, and waterproofness. As the anode electrode material, indium tin oxide (ITO), indium zinc oxide (IZO), tin oxide (SnO₂), or zinc oxide (ZnO), which are transparent and superior in terms of conductivity, may be used.

A hole injection layer material is applied on the anode electrode 20 by thermal deposition in a vacuum or by spin coating to form a hole injection layer 30. Subsequently, thermal deposition in a vacuum or spin coating may also be conducted to form a hole transport layer 40 with a hole transport layer material on the hole injection layer 30.

As concerns the materials of the hole injection layer or the hole transport layer, they may be the compounds represented by [Chemical Formula A] or [Chemical Formula B]. Unless the compounds of [Chemical Formula A] or [Chemical Formula B] are used, a compound typically used in the art may be applied.

The hole injection layer or the hole transport layer according to the present disclosure may be formed by depositing a single compound represented by [Chemical Formula A] or [Chemical Formula B] or a mixture of two or more compounds represented by [Chemical Formula A] or [Chemical Formula B] or through a laminated structure of layers deposited with a single compound represented by [Chemical Formula A] or [Chemical Formula B]. In addition, inorganic or organic materials other than the compounds represented by [Chemical Formula A] or [Chemical Formula B] may be deposited in mixture.

No particular limitations are imparted to the hole injection layer material, as long as it is one that is typically used in the art. For example, mention may be made of 2-TNATA [4,4′,4″-tris(2-naphthylphenyl-phenylamino)-triphenylamine], NPD[N,N′-di(1-naphthyl)-N,N′-diphenylbenzidine)], TPD[N,N′-diphenyl-N,N′-bis(3-methylphenyl)-1,1′-biphenyl-4,4′-diamine], Or DNTPD[N,N′-diphenyl-N,N′-bis-[4-(phenyl-m-tolylamino)-phenyl]-biphenyl-4,4′-diamine], but the present disclosure is not limited thereby.

So long as it is typically used in the art, any material may be selected for the hole transport layer without particular limitation. Examples include, but are not limited to, N,N′-bis(3-methylphenyl)-N,N′-diphenyl-[1,1-biphenyl]-4,4′-diamine (TPD) and N,N′-di(naphthalen-1-yl)-N,N′-diphenylbenzidine (a-NPD).

Then, an organic light-emitting layer 50 is deposited on the hole transport layer 40 by deposition in a vacuum or by spin coating.

Here, the light-emitting layer may be composed of a host and a dopant. Materials for the dopant are as described hereinbefore.

The host used in the light-emitting layer may have the structures represented by the following [Chemical Formula D1] to [Chemical Formula D4], which are given illustratively, but not limitedly:

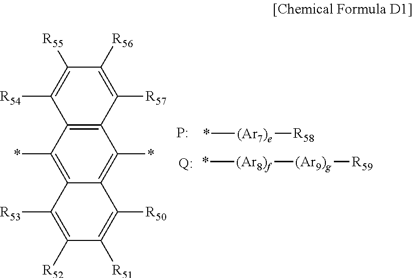

wherein,

Ar₇ to Ar₉, which may be the same or different, are each independently a single bond, a substituted or unsubstituted aromatic hydrocarbon ring of 6 to 50 carbon atoms, or a substituted or unsubstituted heteroaromatic ring of 2 to 50 carbon atoms;

R₅₀ to R₅₉, which may be the same or different, are each independently selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, or a halogen,

linkers Ar₇ to Ar₉, and substituents R₅₀ to R₅₉ may each be linked to an adjacent linker or substituent thereto to further form a mono- or polycyclic aliphatic or aromatic ring;

e, f, and g, which may be the same or different, are each independently an integer of 0 to 4; and

‘-*’ denotes a site at which the structural scaffold bonds to the linker Ar₇ in the P moiety or to the linker Ar₈ in the Q moiety;

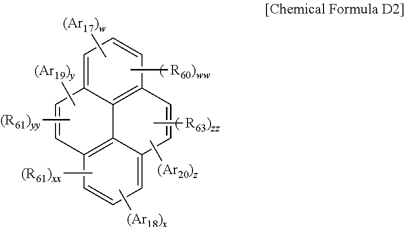

wherein,

Ar₁₇ to Ar₂₀ and R₆₀ to R₆₃, which may be the same or different, are each independently selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen,

w, ww, x, and xx, which may be the same or different, are each independently an integer of 0 to 3, and

y, yy, z, and zz, which may be the same or different, are each independently an integer of 0 to 2;

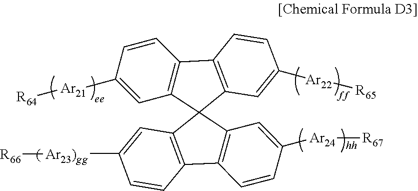

wherein,

Ar₂₁ to Ar₂₄, which may be the same or different, are each independently a single bond, a substituted or unsubstituted aromatic hydrocarbon ring of 6 to 50 carbon atoms, or a substituted or unsubstituted heteroaromatic ring of 2 to 50 carbon atoms;

R₆₄ to R₆₇, which may be the same or different, are each independently selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen; and

ee, ff, gg, and hh, which may be the same or different, are each independently an integer of 1 to 4.

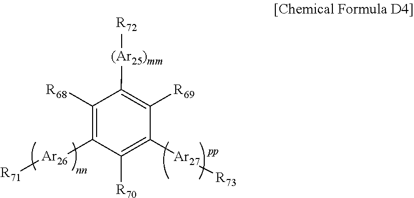

wherein,

Ar₂₅ to Ar₂₇, which may be the same or different, are each independently a single bond, a substituted or unsubstituted aromatic hydrocarbon ring of 6 to 50 carbon atoms, or a substituted or unsubstituted heteroaromatic ring of 2 to 50 carbon atoms;

R₆₈ to R₇₃, which may be the same or different, are each independently selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen,

linkers Ar₂₅ to Ar₂₇ and substituents R₆₈ to R₇₃ may each be linked to an adjacent linker or substituent thereto to further form a mono- or polycyclic aliphatic or aromatic ring;

mm, pp, and nn, which may be the same or different, are each independently an integer of 0 to 4.

Here, the term “substituted” in the expression “substituted or unsubstituted” used for [Chemical Formula D1] to [Chemical Formula D4] is as defined above.

More particularly, concrete examples of the compounds represented by [Chemical Formula D1] to [Chemical Formula D4] include, but are not limited to, the compounds of the following [Host 1] to [Host 56]:

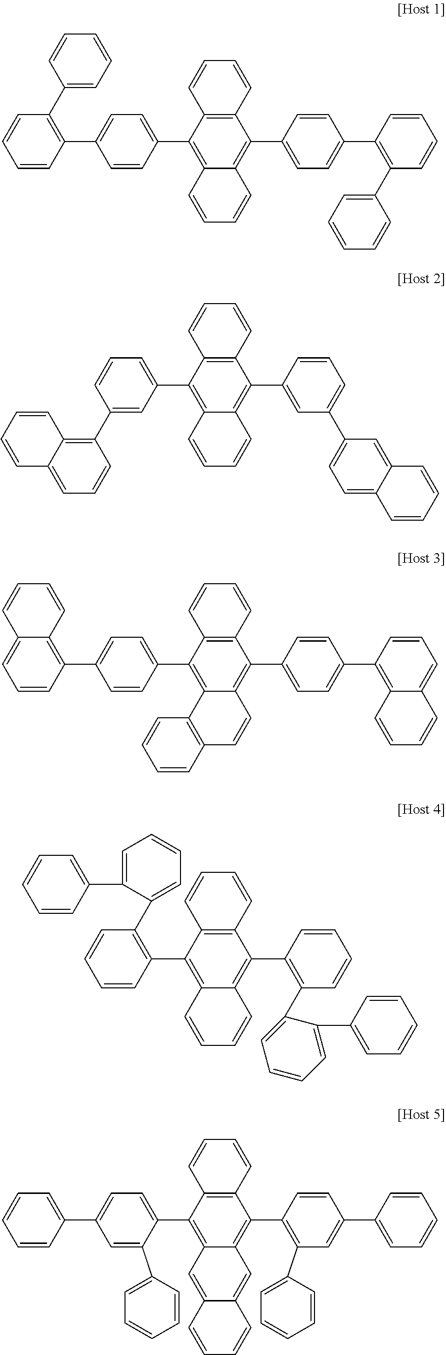

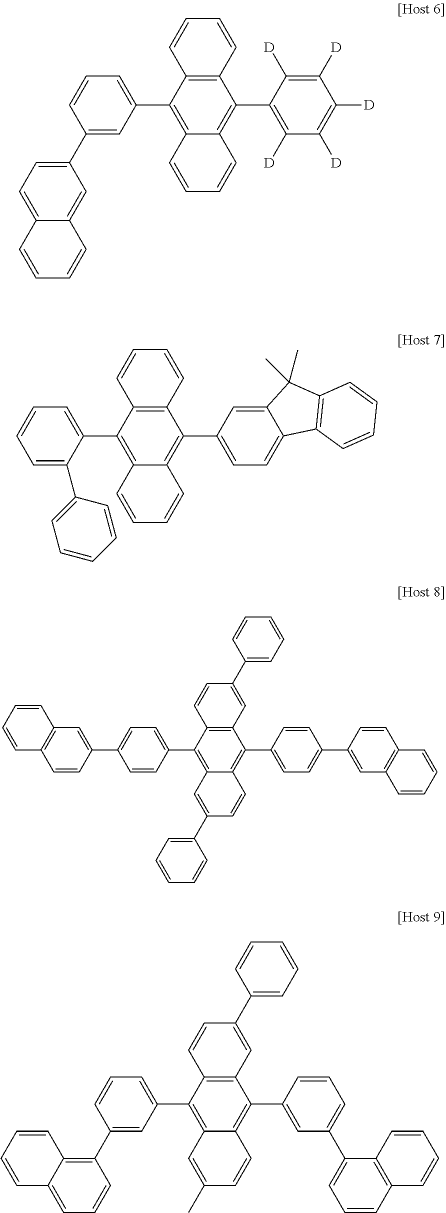

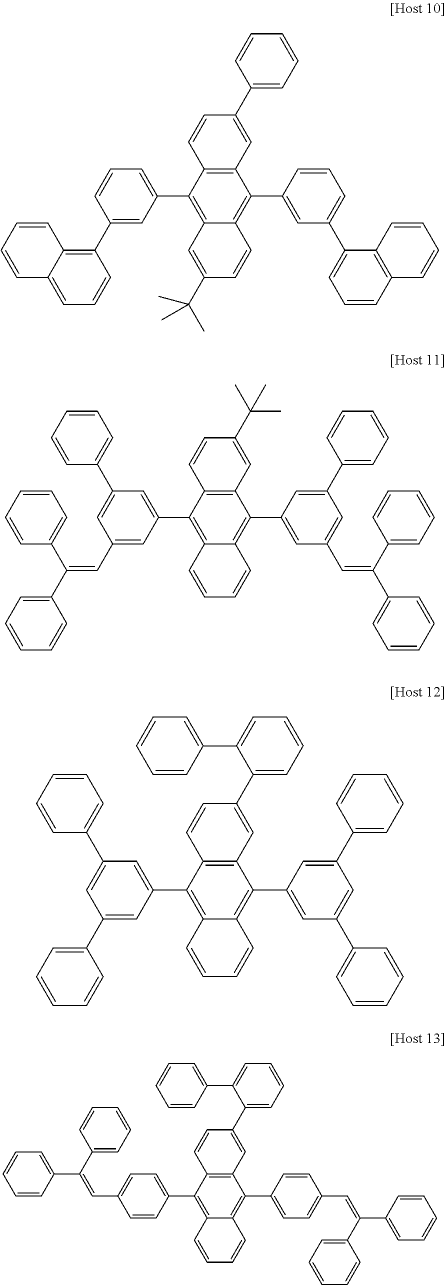

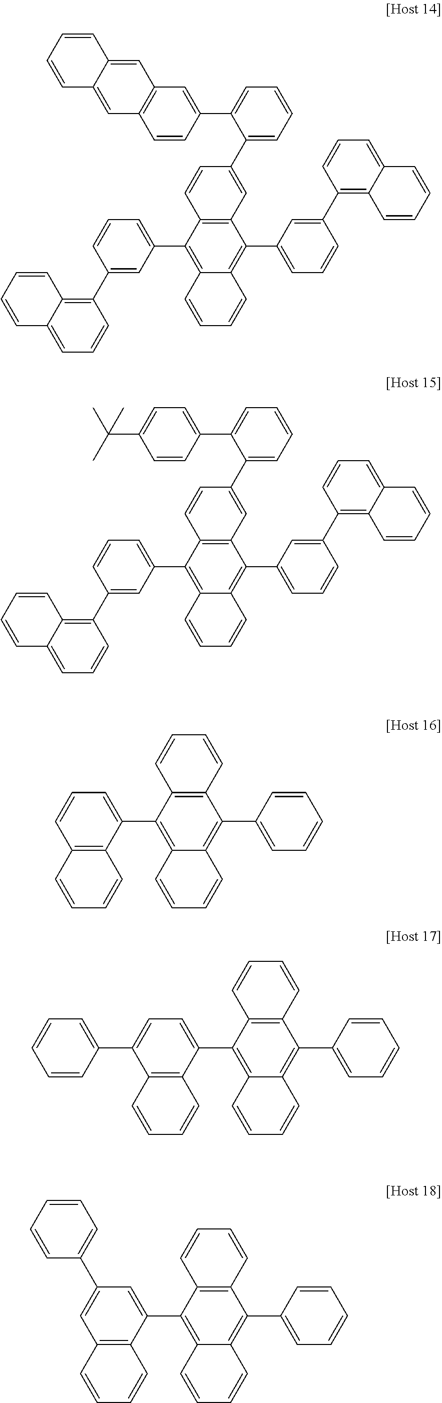

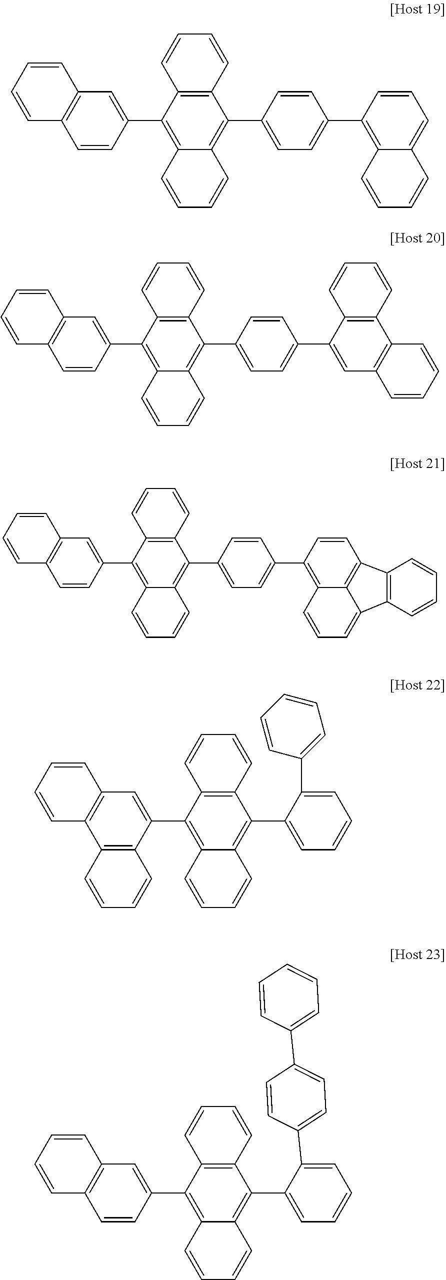

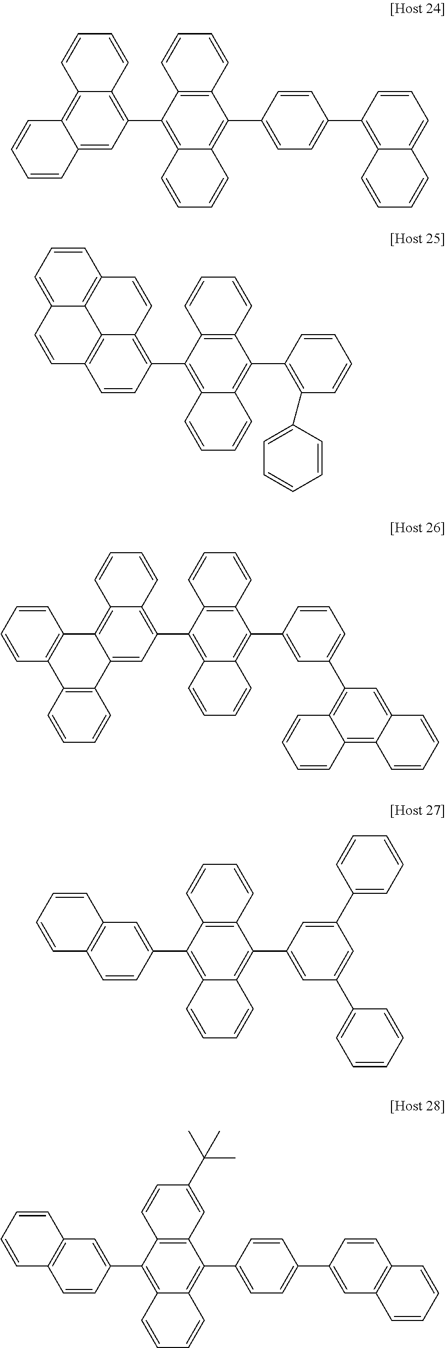

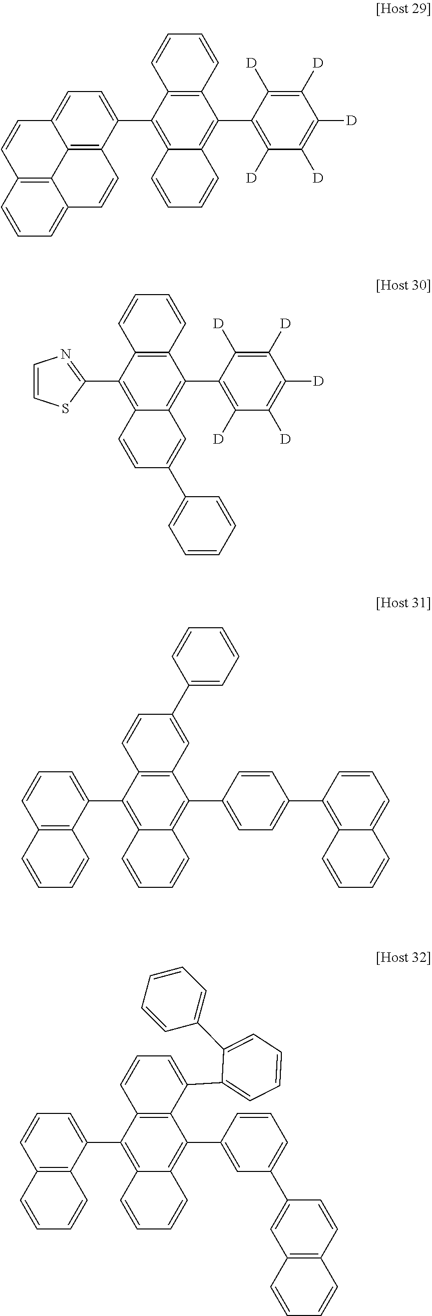

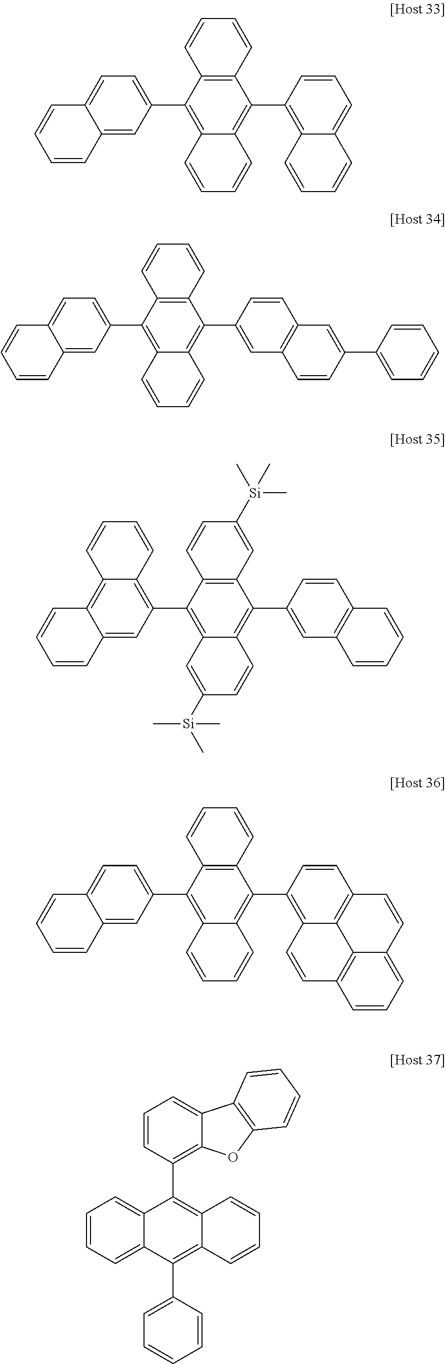

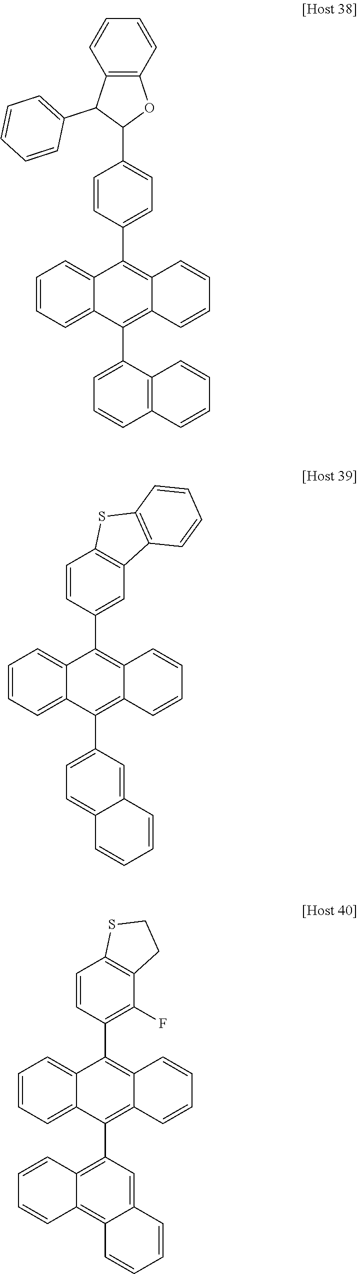 [SMILES: c1ccc(C2c3ccccc3OC2c2ccc(-c3c4ccccc4c(-c4cccc5ccccc45)c4ccccc34)cc2)cc1 ; c1ccc2cc(-c3c4ccccc4c(-c4ccc5sc6ccccc6c5c4)c4ccccc34)ccc2c1 ; Fc1c(-c2c3ccccc3c(-c3cc4ccccc4c4ccccc34)c3ccccc23)ccc2c1CCS2]

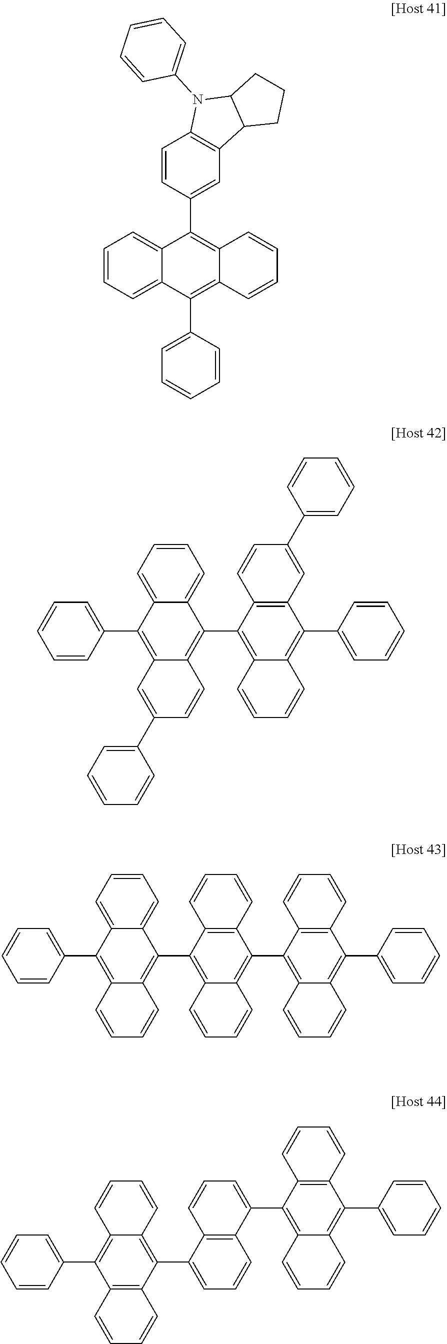

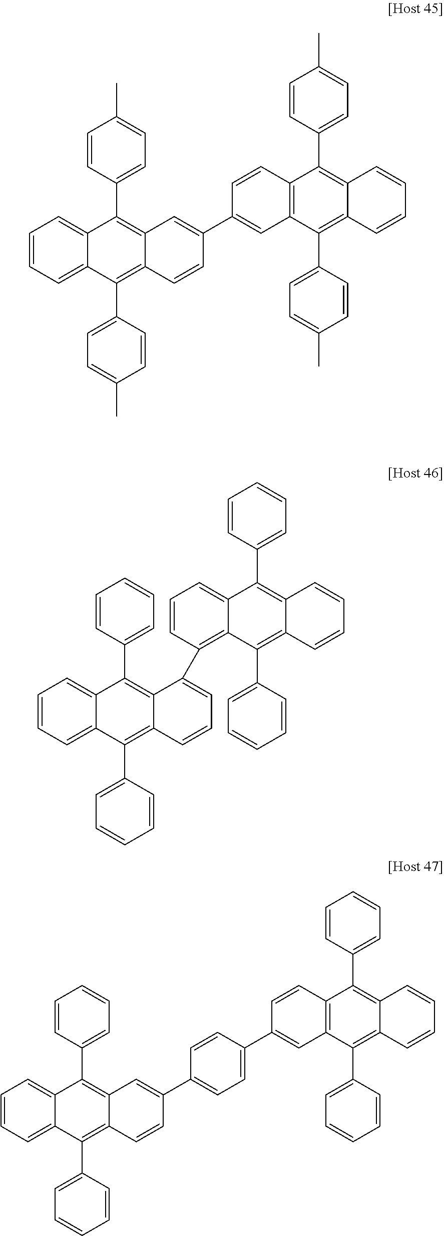

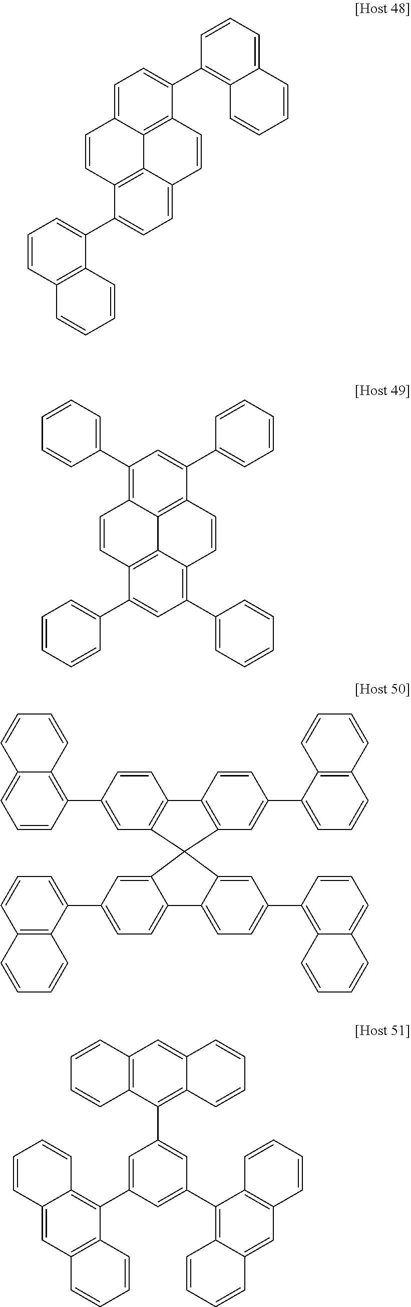

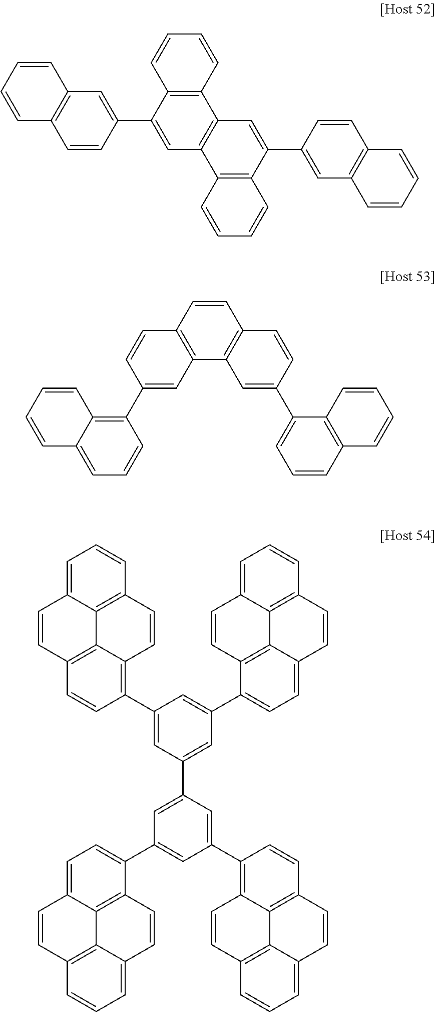

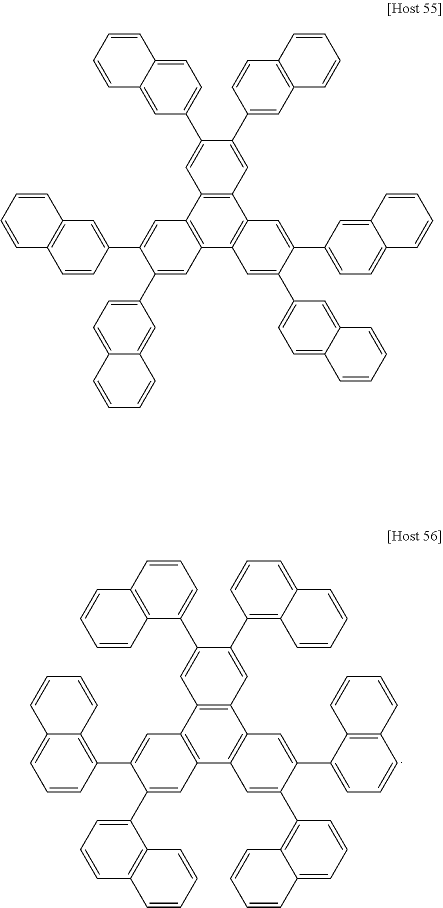

In addition to the above-mentioned dopants and hosts, the light-emitting layer may further include various hosts and dopant materials.

In some embodiments of the present disclosure, the light-emitting layer particularly ranges in thickness from 50 to 2,000 Å.

An electron transport layer 60 is deposited on the organic light-emitting layer by deposition in a vacuum or by spin coating.

A material for use in the electron transport layer functions to stably carry the electrons injected from the electron injection electrode (cathode), and may be an electron transport material known in the art. Examples of the electron transport material known in the art include quinoline derivatives, particularly, tris(8-quinolinorate)aluminum (Alq3), Liq, TAZ, Balq, beryllium bis(benzoquinolin-10-olate) (Bebq2), 2-[4-(9,10-Dinaphthalen-2-yl-anthracen-2-yl)-phenyl]-1-phenyl-1H-benzoimidazole, 3-[5-(9,10-Di-naphthalen-2-yl-anthracen-2-yl)-pyridin-2-yl]-quinoline, BCP, and oxadiazole derivatives such as PBD, BMD, and BND, but are not limited thereto:

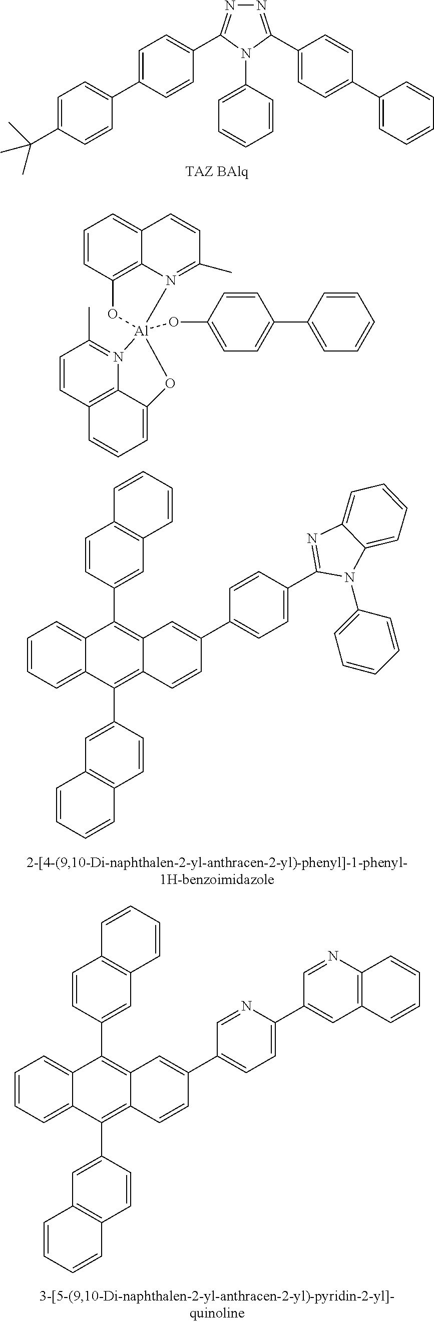

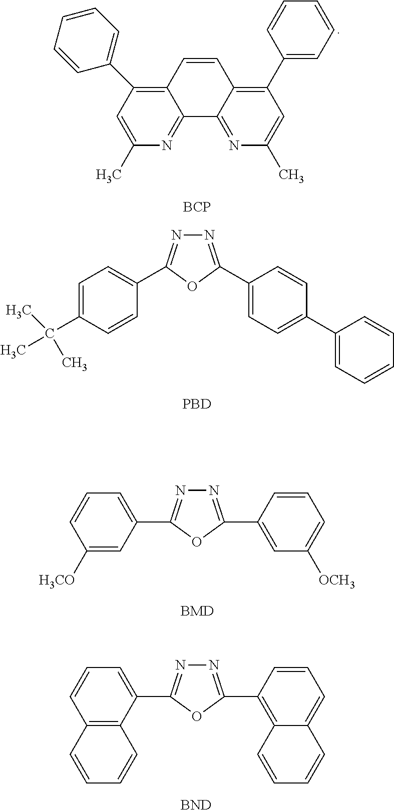

After formation of the electron transport layer, an electron injection layer (EIL) that functions to facilitate electron injection from the cathode, thus improving the power efficiency of the diode, may be further deposited on the electron transport layer. No particular limitations are imparted to the material of EIL.

So long as it is conventionally used in the art, any material can be available for the electron injection layer without particular limitations. Examples include LiF, NaCl, CsF, Li₂O, and BaO. A deposition condition of the EIL may be almost the same as that for the hole injection layer.

The electron injection layer may range in thickness from about 1 Å to about 100 Å and particularly from about 3 Å to about 90 Å. Given the thickness range for the electron injection layer, the diode can exhibit satisfactory electron injection properties without actually elevating a driving voltage.

In order to facilitate electron injection, the cathode may be made of a material having a small work function, such as metal or metal alloy such as lithium (Li), magnesium (Mg), aluminum (Al), aluminum-lithium (Al—Li), calcium (Ca), magnesium-indium (Mg—In), and magnesium-silver (Mg—Ag). Alternatively, ITO or IZO may be employed to form a transparent cathode for a top-emitting organic light-emitting diode.

Moreover, the organic light-emitting diode of the present disclosure may further comprise a light-emitting layer containing a blue, green, or red luminescent material that emits radiations in the wavelength range of 380 nm to 800 nm. That is, the light-emitting layer in the present disclosure has a multi-layer structure wherein the blue, green, or red luminescent material may be a fluorescent material or a phosphorescent material.

Furthermore, at least one selected from among the layers may be deposited using a single-molecule deposition process or a solution process.

Here, the deposition process is a process by which a material is vaporized in a vacuum or at a low pressure and deposited to form a layer, and the solution process is a method in which a material is dissolved in a solvent and applied for the formation of a thin film by means of inkjet printing, roll-to-roll coating, screen printing, spray coating, dip coating, spin coating, etc.

Also, the organic light-emitting diode of the present disclosure may be applied to a device selected from among flat display devices, flexible display devices, monochrome or grayscale flat illumination devices, and monochrome or grayscale flexible illumination devices.

A better understanding of the present disclosure may be obtained through the following examples which are set forth to illustrate, but are not to be construed as limiting the present invention.

### EXAMPLES

### Synthesis of HTL Materials

### Synthesis Example 1: Synthesis of Compound of Chemical Formula 19

### Synthesis Example 1-(1): Synthesis of [Intermediate 1-a]

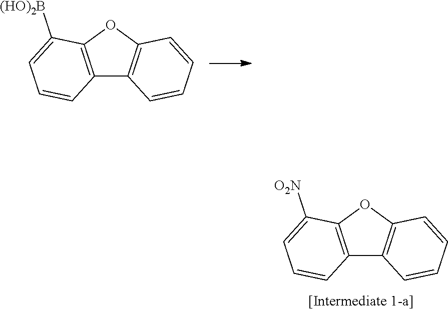 [SMILES: OB(O)c1cccc2c1oc1ccccc12 ; O=[N+]([O-])c1cccc2c1oc1ccccc12]

In a 2-L round-bottom flask reactor, 4-dibenzofuran boronic acid (85.0 g, 0.401 mol), bismuth (III) nitrate pentahydrate (99.2 g, 0.200 mol), and toluene (400 ml) were stirred together at 70° C. for 3 hrs in a nitrogen atmosphere. After completion of the reaction, the reaction mixture was cooled to room temperature and the solid thus formed was filtered and washed with toluene to afford [Intermediate 1-a]. (61.5 g, 72%)

### Synthesis Example 1-(2): Synthesis of [Intermediate 1-b]

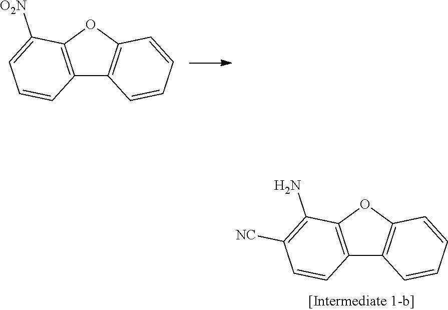 [SMILES: O=[N+]([O-])c1cccc2c1oc1ccccc12 ; N#Cc1ccc2c(oc3ccccc32)c1N]

In a 2-L round-bottom flask reactor, ethyl cyanoacetate (202.9 g, 1.794 mol) and dimethyl formamide (500 ml) were placed. Potassium hydroxide (67.10 g, 1.196 mol) and potassium cyanide (38.95 g, 0.598 mol) were added, followed by dimethyl formamide (200 ml). The resulting mixture was stirred at room temperature, added with [Intermediate 1-a] (127. g, 0.737 mol) little by little, and then stirred at 50° C. for 72 hrs. After completion of the reaction, an aqueous sodium hydroxide solution (25%, 200 ml) was added and stirred for 3 hrs under reflux. After cooling to room temperature, extraction with ethyl acetate and water was conducted. The organic layer thus formed was separated, and concentrated in a vacuum. Purification by column chromatography afforded [Intermediate 1-b] (20.0 g, 16%).

### Synthesis Example 1-(3): Synthesis of [Intermediate 1-c]

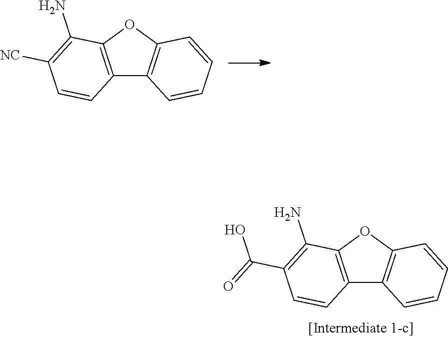 [SMILES: N#Cc1ccc2c(oc3ccccc32)c1N ; Nc1c(C(=O)O)ccc2c1oc1ccccc12]

In a 2-L round-bottom flask reactor, a mixture of [Intermediate 1-b] (20.0 g, 96 mmol), ethanol (600 ml), and an aqueous potassium hydroxide solution (170 ml, 142.26 g, 2.53 mol) was stirred for 12 hrs under reflux. After completion of the reaction mixture was cooled to room temperature, and then acidified with 6 N HCl (400 ml). Stirring for 20 min was followed by filtration. The solid thus obtained was washed with ethanol to afford [Intermediate 1-c] (17.0 g, 88.5%).

### Synthesis Example 1-(4): Synthesis of [Intermediate 1-d]

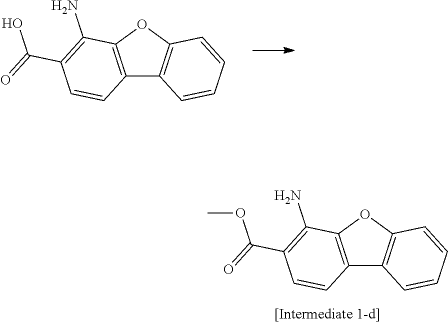 [SMILES: Nc1c(C(=O)O)ccc2c1oc1ccccc12 ; COC(=O)c1ccc2c(oc3ccccc32)c1N]

In a 2-L round-bottom flask reactor, a mixture of [Intermediate 1-c] (17.0 g, 75 mmol) and sulfuric acid (15 ml) was stirred for 72 hrs under reflux. After completion of the reaction, the reaction mixture was extracted with ethyl acetate and water. The organic layer was separated and washed with an aqueous sodium hydrogen carbonate solution. An excess of methanol was added during the vacuum concentration of the organic layer, followed by filtration to afford [Intermediate 1-d] (14.0 g, 77.6%).

### Synthesis Example 1-(5): Synthesis of [Intermediate 1-e]

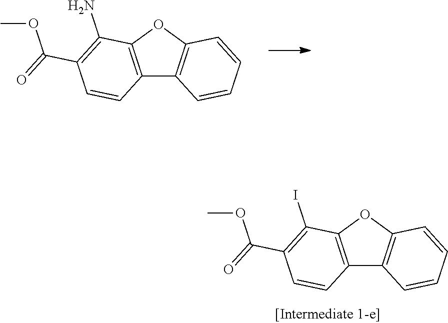 [SMILES: COC(=O)c1ccc2c(oc3ccccc32)c1N ; COC(=O)c1ccc2c(oc3ccccc32)c1I]

In a 1-L round-bottom flask reactor, a mixture of [Intermediate 1-d] (32.6 g, 0.135 mol), HCl (30 ml), and water (150 ml) was cooled to 0° C. and stirred for 1 hr. At the same temperature, an aqueous solution (75 ml) of sodium nitrite (11.2 g, 0.162 mol) was added and then stirred for 1 hr. An aqueous solution (75 ml) of potassium iodide (44.8 g, 0.270 mol) was dropwise added, taking care not to increase the temperature of the reaction solution above 5° C. Stirring was continued for 5 hrs at room temperature, and after completion of the reaction, the reaction mixture was washed with an aqueous sodium thiosulfate solution and extracted with ethyl acetate and water. The organic layer was separated and concentrated in a vacuum. Purification through column chromatography gave [Intermediate 1-e] (22.8 g, 48%).

### Synthesis Example 1-(6): Synthesis of [Intermediate 1-f]

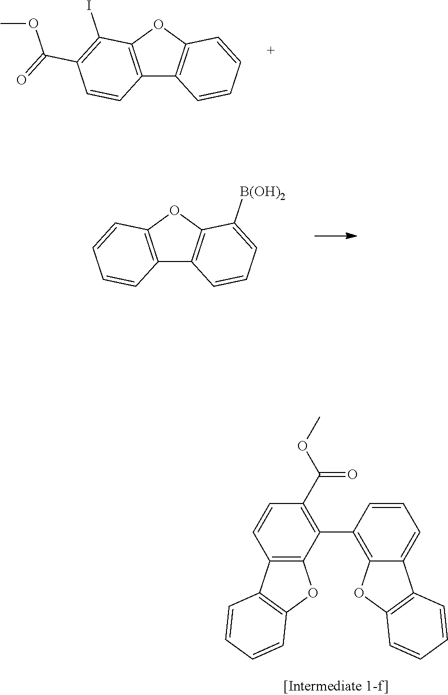 [SMILES: COC(=O)c1ccc2c(oc3ccccc32)c1I ; OB(O)c1cccc2c1oc1ccccc12 ; COC(=O)c1ccc2c(oc3ccccc32)c1-c1cccc2c1oc1ccccc12]

In a 500-mL round-bottom flask reactor, [Intermediate 1-e] (25.7 g, 73 mmol), 4-dibenzofuran boronic acid (18.7 g, 88 mmol), tetrakis(triphenylphosphine)palladium (1.7 g, 0.15 mmol), and potassium carbonate (20.2 g, 146.7 mmol) were stirred together with toluene (125 mL), tetrahydrofuran (125 mL), and water (50 mL) for 10 hrs at 80° C. After completion of the reaction, the reaction mixture was cooled to room temperature and extracted with ethyl acetate. The organic layer thus formed was separated, concentrated in a vacuum, and purified by column chromatography to afford [Intermediate 1-f]. (24.1 g, 84%)

### Synthesis Example 1-(7): Synthesis of [Intermediate 1-g]

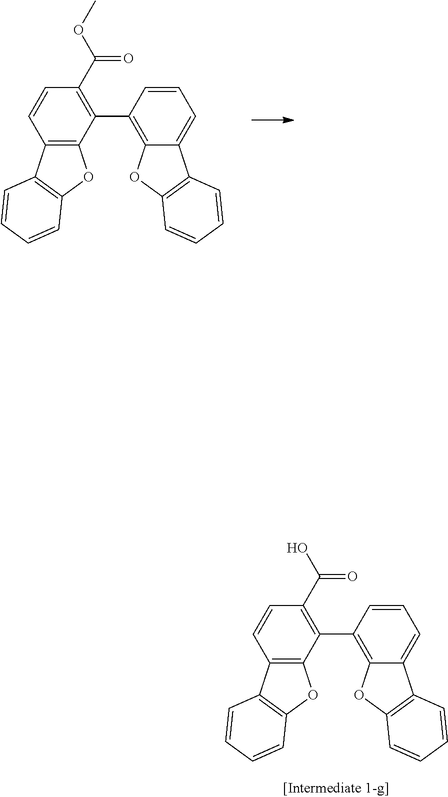 [SMILES: COC(=O)c1ccc2c(oc3ccccc32)c1-c1cccc2c1oc1ccccc12 ; O=C(O)c1ccc2c(oc3ccccc32)c1-c1cccc2c1oc1ccccc12]

In a 500-mL round-bottom flask reactor, [Intermediate 1-f] (17.6 g, 45 mmol), sodium hydroxide (2.14 g, 54 mmol), and ethanol (170 ml) were stirred together for 48 hrs under reflux. After the completion of the reaction was confirmed using thin-layer chromatography, the reaction mixture was cooled to room temperature. The chilled solution was acidified with drops of 2-N HCl, followed by stirring for 30 min. The solid thus formed was filtered and then recrystallized in dichloromethane and n-hexane to afford [Intermediate 1-g]. (14.5 g, 85%)

### Synthesis Example 1-(8): Synthesis of [Intermediate 1-h]

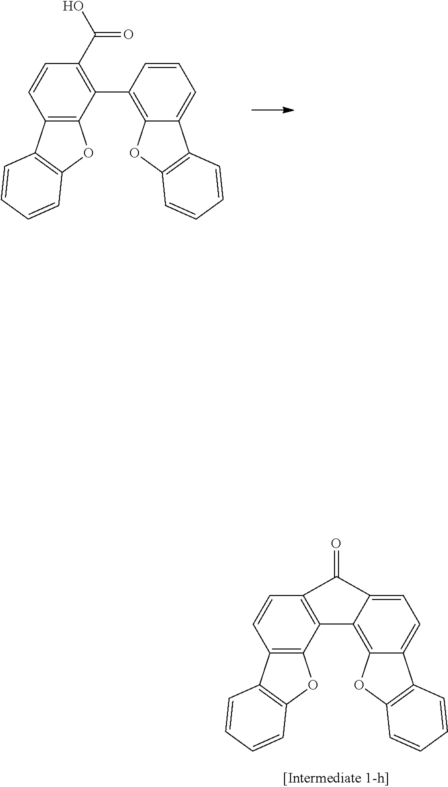 [SMILES: O=C(O)c1ccc2c(oc3ccccc32)c1-c1cccc2c1oc1ccccc12 ; O=C1c2ccc3c(oc4ccccc43)c2-c2c1ccc1c2oc2ccccc21]

In a 250-mL round-bottom flask reactor, [Intermediate 1-g] (14.7 g, 39 mmol) and methanesulfonic acid (145 ml) were stirred together for 3 hrs at 80° C. After the completion of the reaction was confirmed using thin-layer chromatography, the reaction mixture was cooled to room temperature and dropwise added to ice water (150 ml). After stirring for 30 min, the solid thus formed was filtered and washed with water and methanol to afford [Intermediate 1-h]. (11.0 g, 78%)

### Synthesis Example 1-(9): Synthesis of [Intermediate 1-i]

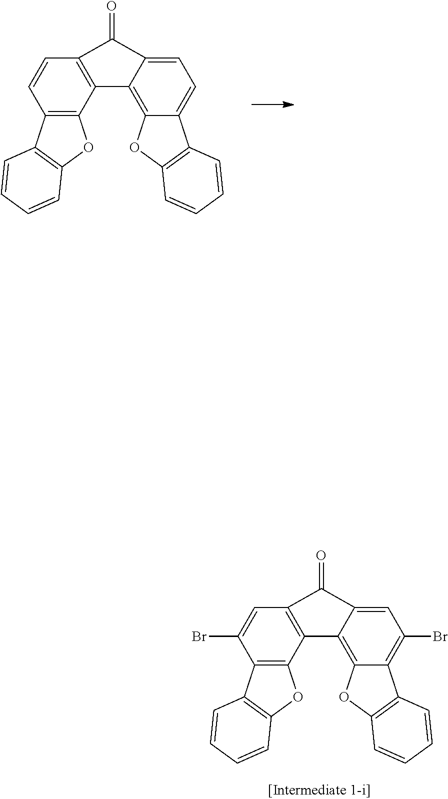 [SMILES: O=C1c2ccc3c(oc4ccccc43)c2-c2c1ccc1c2oc2ccccc21 ; O=C1c2cc(Br)c3c(oc4ccccc43)c2-c2c1cc(Br)c1c2oc2ccccc21]

In a 1-L round-bottom flask reactor, [Intermediate 1-h] (11.9 g, 33 mmol) and dichloromethane (300 ml) were stirred together at room temperature. A dilution of bromine (3.4 ml, 66 mmol) in dichloromethane (50 ml) was dropwise added, followed by stirring at room temperature for 8 hrs. After completion of the reaction, the reaction mixture was stirred together with acetone (100 ml). The solid thus formed was filtered and washed with acetone. Recrystallization in monochlorobenzene afforded [Intermediate 1-i]. (10.6 g, 62%)

### Synthesis Example 1-(10): Synthesis of [Intermediate 1-j]

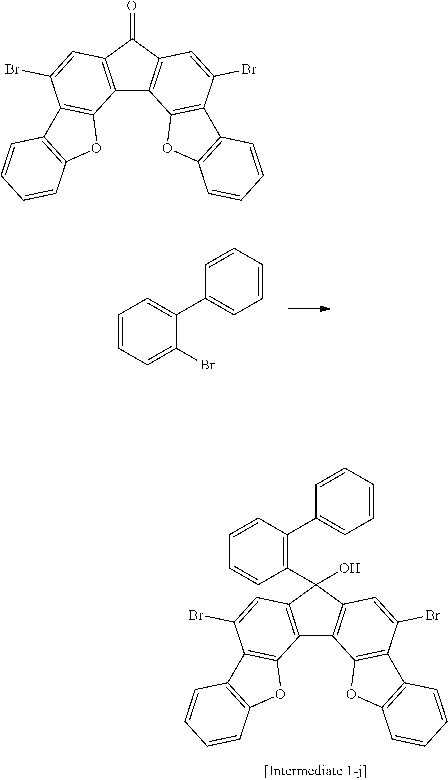 [SMILES: O=C1c2cc(Br)c3c(oc4ccccc43)c2-c2c1cc(Br)c1c2oc2ccccc21 ; Brc1ccccc1-c1ccccc1 ; OC1(c2ccccc2-c2ccccc2)c2cc(Br)c3c(oc4ccccc43)c2-c2c1cc(Br)c1c2oc2ccccc21]

In a 250-ml round-bottom flask reactor, 2-bromobiphenyl (8.4 g, 0.036 mol) and tetrahydrofuran (110 ml) were chilled at −78° C. in a nitrogen atmosphere. At the same temperature, n-butyl lithium (19.3 ml, 0.031 mol) was dropwise added to the chilled reaction solution, which was then stirred for 2 hrs. Thereafter, [Intermediate 1-i] (13.5 g, 0.026 mol) was added little by little to the reaction solution and stirred at room temperature. When the reaction mixture started to change in color, the reaction was monitored via TLC. After the reaction was stopped with H₂O (50 ml), extraction was conducted with ethyl acetate and water. The organic layer was separated, concentrated in a vacuum, and recrystallized in acetonitrile to afford [Intermediate 1-j] as a solid. (12.6 g, 72%)

### Synthesis Example 1-(11): Synthesis of [Intermediate 1-k]

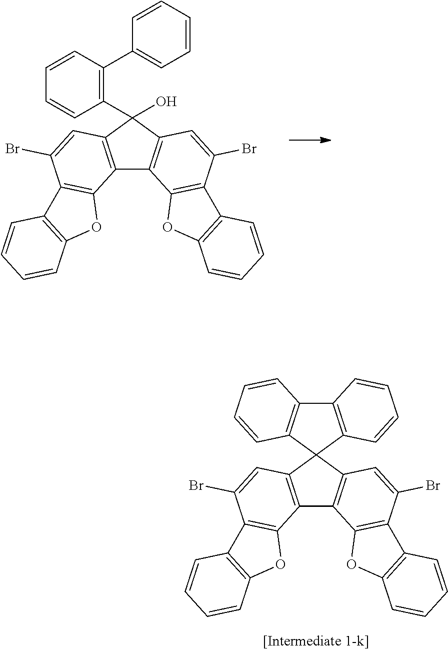 [SMILES: OC1(c2ccccc2-c2ccccc2)c2cc(Br)c3c(oc4ccccc43)c2-c2c1cc(Br)c1c2oc2ccccc21 ; Brc1cc2c(c3oc4ccccc4c13)-c1c(cc(Br)c3c1oc1ccccc13)C21c2ccccc2-c2ccccc21]

In a 250-ml round-bottom flask reactor, a mixture of [Intermediate 1-j] (14.1 g, 0.021 mol), acetic acid (120 ml), and sulfuric acid (2 ml) was stirred for 5 hrs under reflux. When a precipitate was formed, the completion of the reaction was monitored using thin-layer chromatography. The reaction mixture was then cooled to room temperature and filtered. The filtrate was washed with H₂O and methanol and dissolved in monochlorobenzene. Following silica gel chromatography, the fraction was concentrated and cooled to room temperature to give [Intermediate 1-k]. (11.8 g, 86%)

### Synthesis Example 1-(12): Synthesis of [Chemical Formula 19]

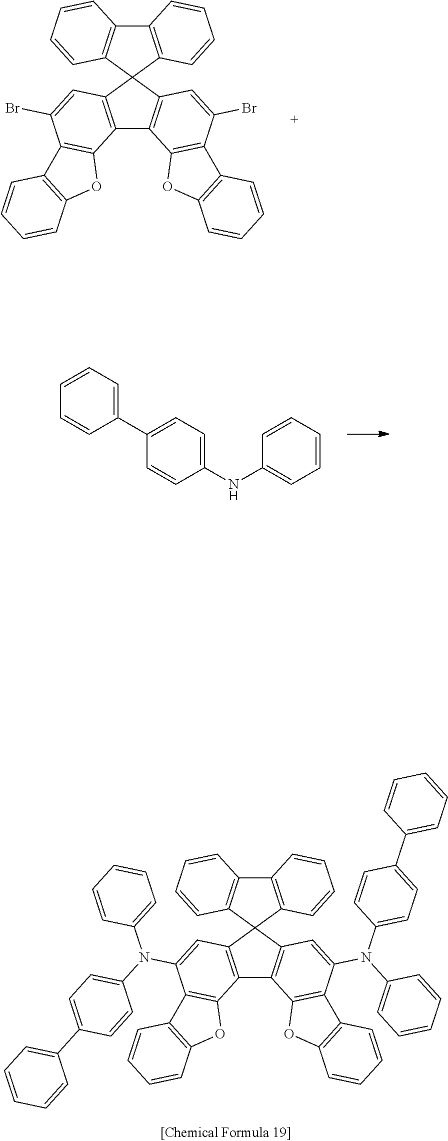 [SMILES: Brc1cc2c(c3oc4ccccc4c13)-c1c(cc(Br)c3c1oc1ccccc13)C21c2ccccc2-c2ccccc21 ; c1ccc(Nc2ccc(-c3ccccc3)cc2)cc1 ; c1ccc(-c2ccc(N(c3ccccc3)c3cc4c(c5oc6ccccc6c35)-c3c(cc(N(c5ccccc5)c5ccc(-c6ccccc6)cc5)c5c3oc3ccccc35)C43c4ccccc4-c4ccccc43)cc2)cc1]

In a 250-ml round-bottom flask reactor, a mixture of [Intermediate 1-k] (5.9 g, 0.009 mol), N-phenyl-4-biphenylamine (5.1 g, 0.021 mol), palladium (II) acetate (0.08 g, 0.4 mmol), sodium tert-butoxide (3.4 g, 0.035 mol), tri-tert-butyl phosphine (0.07 g, 0.4 mmol), and toluene (60 ml) was stirred for 2 hrs under reflux. After completion of the reaction, the reaction mixture was cooled to room temperature and then extracted with dichloromethane and water. The organic layer thus formed was separated, dried over magnesium sulfate, and concentrated in a vacuum. The concentrate was purified by column chromatography and recrystallized in dichloromethane and acetone to yield [Chemical Formula 19] as a solid. (3.1 g, 35%)

MS (MALDI-TOF): m/z 982.36 [M⁺]

### Synthesis Example 2: Synthesis of Compound of Chemical Formula 34

### Synthesis Example 2-(1): Synthesis of [Intermediate 2-a]

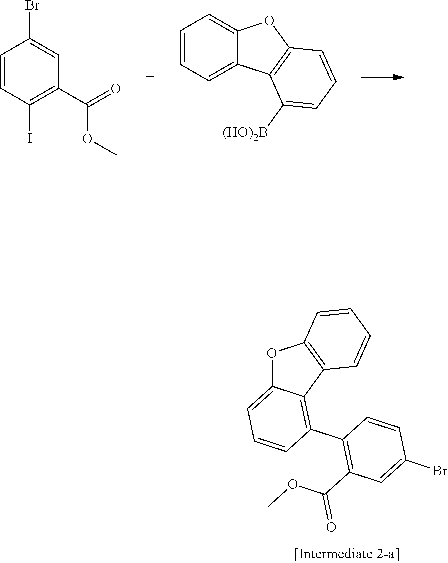 [SMILES: COC(=O)c1cc(Br)ccc1I ; OB(O)c1cccc2oc3ccccc3c12 ; COC(=O)c1cc(Br)ccc1-c1cccc2oc3ccccc3c12]

In a 500-mL round-bottom flask reactor, methyl 5-bromo-2-iodobenzoate (25.0 g, 73 mmol), 1-dibenzofuran boronic acid (18.7 g, 88 mmol), tetrakis(triphenyl phosphine)palladium (1.7 g, 0.15 mmol), and potassium carbonate (20.2 g, 146.7 mmol) were stirred together with toluene (125 mL), tetrahydrofuran (125 mL), and water (50 mL) for 10 hrs at 80° C. After completion of the reaction, the reaction mixture was cooled to room temperature and extracted with ethyl acetate. The organic layer thus formed was separated, concentrated in a vacuum, and purified by column chromatography to afford [Intermediate 2-a]. (75.0 g, 60.1%).

### Synthesis Example 2-(2): Synthesis of [Intermediate 2-b]

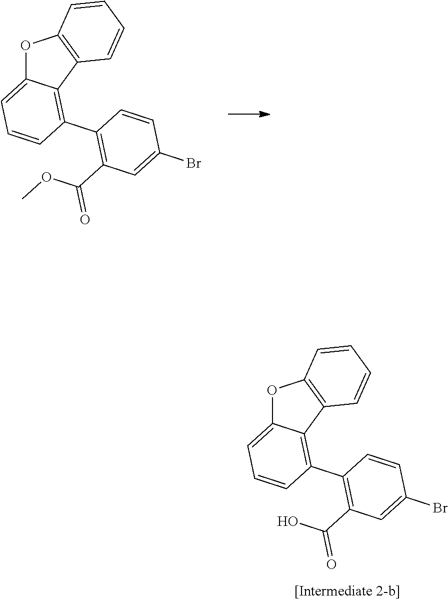 [SMILES: COC(=O)c1cc(Br)ccc1-c1cccc2oc3ccccc3c12 ; O=C(O)c1cc(Br)ccc1-c1cccc2oc3ccccc3c12]

In a 500-mL round-bottom flask reactor, [Intermediate 2-a] (17.0 g, 45 mmol), sodium hydroxide (2.14 g, 54 mmol), and ethanol (170 ml) were stirred together for 48 hrs under reflux. After the completion of the reaction was confirmed using thin-layer chromatography, the reaction mixture was cooled to room temperature. The chilled solution was acidified with drops of 2-N HCl, followed by stirring for 30 min. The solid thus formed was filtered and then recrystallized in dichloromethane and n-hexane to afford [Intermediate 2-b]. (14.5 g, 88.6%)

### Synthesis Example 2-(3): Synthesis of [Intermediate 2-c]

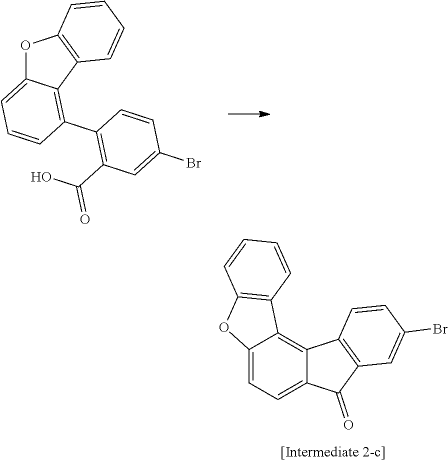 [SMILES: O=C(O)c1cc(Br)ccc1-c1cccc2oc3ccccc3c12 ; O=C1c2cc(Br)ccc2-c2c1ccc1oc3ccccc3c21]

The same procedure as in Synthesis Example 1-(8) was carried out, with the exception of using [Intermediate 2-b] instead of [Intermediate 1-g] to afford [Intermediate 2-c] (yield 82%).

### Synthesis Example 2-(4): Synthesis of [Intermediate 2-d]

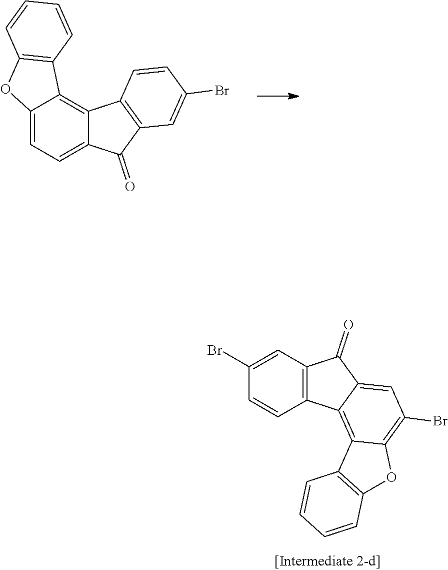 [SMILES: O=C1c2cc(Br)ccc2-c2c1ccc1oc3ccccc3c21 ; O=C1c2cc(Br)ccc2-c2c1cc(Br)c1oc3ccccc3c21]

The same procedure as in Synthesis Example 1-(9) was carried out, with the exception of using [Intermediate 2-c] instead of [Intermediate 1-h] to afford [Intermediate 2-d] (yield 77%).

### Synthesis Example 2-(5): Synthesis of [Intermediate 2-e]

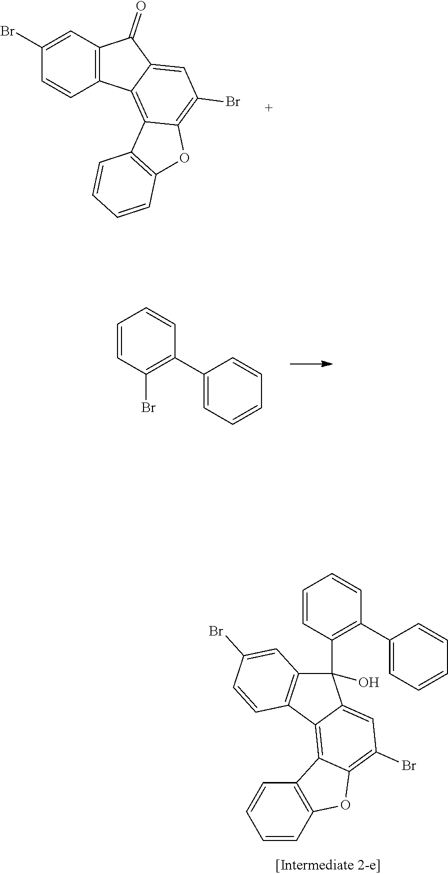 [SMILES: O=C1c2cc(Br)ccc2-c2c1cc(Br)c1oc3ccccc3c21 ; Brc1ccccc1-c1ccccc1 ; OC1(c2ccccc2-c2ccccc2)c2cc(Br)ccc2-c2c1cc(Br)c1oc3ccccc3c21]

The same procedure as in Synthesis Example 1-(10) was carried out, with the exception of using [Intermediate 2-d] instead of [Intermediate 1-i] to afford [Intermediate 2-e] (yield 79%).

### Synthesis Example 2-(6): Synthesis of [Intermediate 2-f]

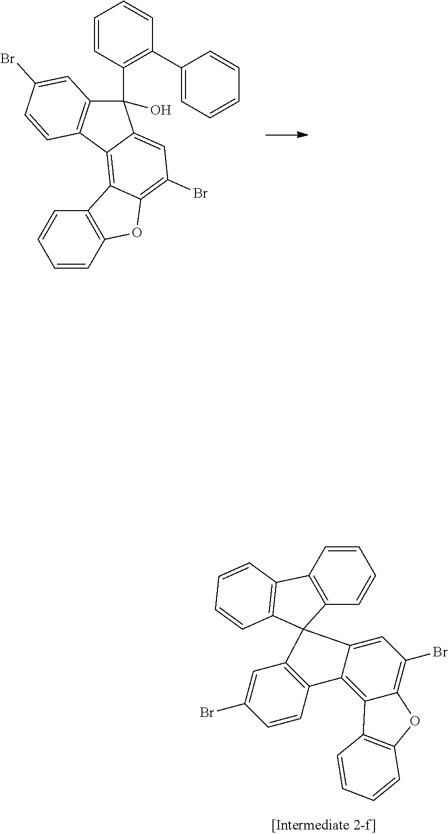 [SMILES: OC1(c2ccccc2-c2ccccc2)c2cc(Br)ccc2-c2c1cc(Br)c1oc3ccccc3c21 ; Brc1ccc2c(c1)C1(c3ccccc3-c3ccccc31)c1cc(Br)c3oc4ccccc4c3c1-2]

The same procedure as in Synthesis Example 1-(11) was carried out, with the exception of using [Intermediate 2-e] instead of [Intermediate 1-j] to afford [Intermediate 2-f] (yield 88%).

### Synthesis Example 2-(7): Synthesis of [Chemical Formula 34]

The same procedure as in Synthesis Example 1-(12) was carried out, with the exception of using [Intermediate 2-f] and bis(4-tert-butylphenyl) amine instead of [Intermediate 1-k] and N-phenyl-4-biphenylamine, respectively, to afford [Chemical Formula 34] (yield 35%).

MS (MALDI-TOF): m/z 964.53 [M⁺]

### Synthesis Example 3: Synthesis of Compound of Chemical Formula 49

### Synthesis Example 3-(1): Synthesis of [Intermediate 3-a]

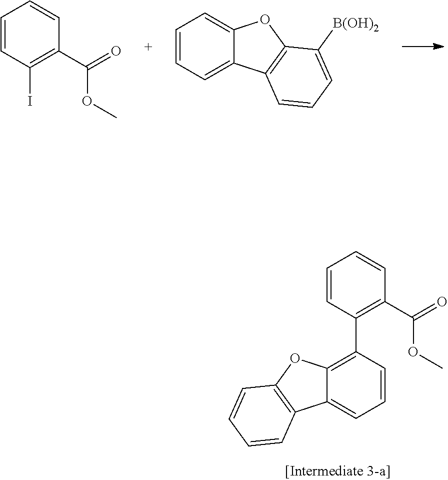 [SMILES: COC(=O)c1ccccc1I ; OB(O)c1cccc2c1oc1ccccc12 ; COC(=O)c1ccccc1-c1cccc2c1oc1ccccc12]

In a 500-mL round-bottom flask reactor, methyl 2-iodobenzoate (19.1 g, mmol), 4-dibenzofuran boronic acid (18.7 g, 88 mmol), tetrakis(triphenylphosphine)palladium (1.7 g, 0.15 mmol), and potassium carbonate (20.2 g, 146.7 mmol) stirred together with toluene (125 mL), tetrahydrofuran (125 mL), and water (50 mL) for 10 hrs at 80° C. After completion of the reaction, the reaction mixture was cooled to room temperature and extracted with ethyl acetate. The organic layer thus formed was separated, concentrated in a vacuum, and purified by column chromatography to afford [Intermediate 3-a]. (9.5 g, 43%)

### Synthesis Example 3-(2): Synthesis of [Intermediate 3-b]

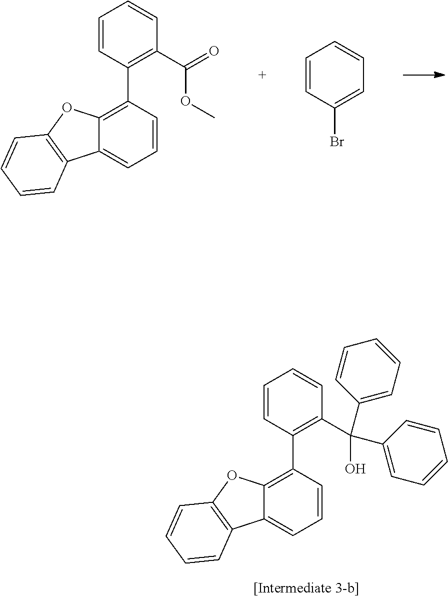 [SMILES: COC(=O)c1ccccc1-c1cccc2c1oc1ccccc12 ; Brc1ccccc1 ; OC(c1ccccc1)(c1ccccc1)c1ccccc1-c1cccc2c1oc1ccccc12]

In a 2-L round-bottom flask reactor, bromobenzene (13.2 g, 83.97 mmol) and tetrahydrofuran (250 ml) were stirred together at a low temperature in a nitrogen atmosphere. At −78° C., n-butyl lithium (ca. 58 ml) was dropwise added over 2 hrs, followed by [Intermediate 3-a] (9.4 g 31.1 mmol). After completion of the reaction, the reaction mixture was stirred, together with water (100 ml), for 30 min, and extraction gave [Intermediate 3-b]. (3.2 g, 24%)

### Synthesis Example 3-(3): Synthesis of [Intermediate 3-c]

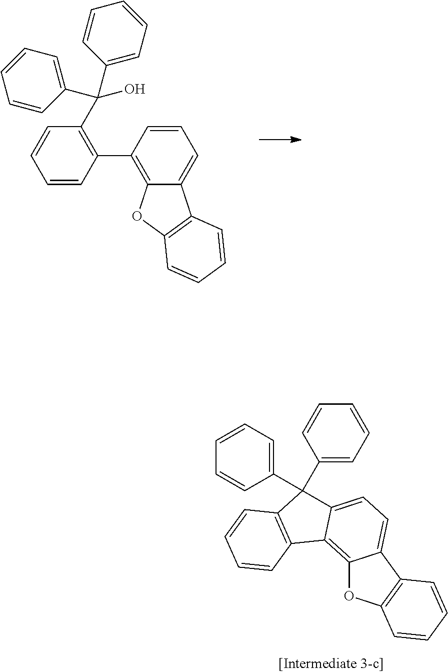 [SMILES: OC(c1ccccc1)(c1ccccc1)c1ccccc1-c1cccc2c1oc1ccccc12 ; c1ccc(C2(c3ccccc3)c3ccccc3-c3c2ccc2c3oc3ccccc32)cc1]

In a 2-L round-bottom flask reactor, [Intermediate 3-b] (55.0 g, 129 mmol), acetic acid (500 ml), and sulfuric acid (10 ml) were stirred together for 5 hrs under reflux. After completion of the reaction, the reaction mixture was cooled to room temperature, and the precipitates were filtered and washed with methanol to afford [Intermediate 3-c]. (50 g, 95%)

### Synthesis Example 3-(4): Synthesis of [Intermediate 3-d]

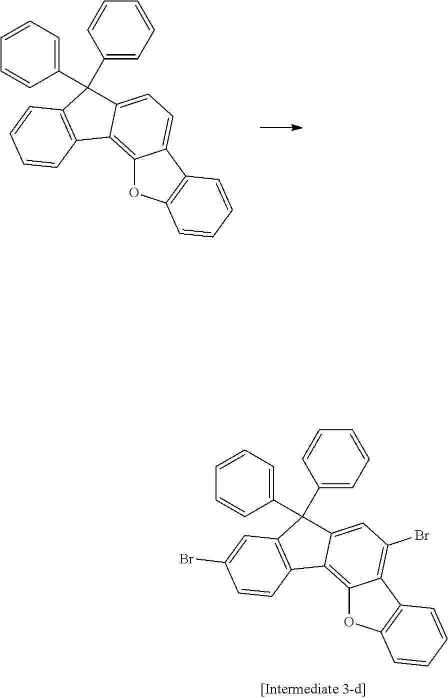 [SMILES: c1ccc(C2(c3ccccc3)c3ccccc3-c3c2ccc2c3oc3ccccc32)cc1 ; Brc1ccc2c(c1)C(c1ccccc1)(c1ccccc1)c1cc(Br)c3c(oc4ccccc43)c1-2]

The same procedure as in Synthesis Example 1-(9) was carried out, with the exception of using [Intermediate 3-c] instead of [Intermediate 1-h] to afford [Intermediate 3-d] (yield 78%).

### Synthesis Example 3-(5): Synthesis of [Chemical Formula 49]

The same procedure as in Synthesis Example 1-(12) was carried out, with the exception of using [Intermediate 3-d] and diphenylamine instead of [Intermediate 1-k] and N-phenyl-4-biphenylamine, respectively, to afford [Chemical Formula 49] (yield 38%).

MS (MALDI-TOF): m/z 742.30 [M⁺]

### Synthesis Example 4: Synthesis of Compound of Chemical Formula 58

### Synthesis Example 4-(1): Synthesis of [Intermediate 4-a]

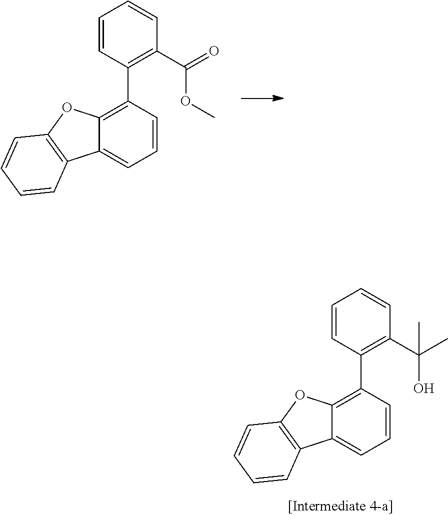 [SMILES: COC(=O)c1ccccc1-c1cccc2c1oc1ccccc12 ; CC(C)(O)c1ccccc1-c1cccc2c1oc1ccccc12]

In a round-bottom flask, tetrahydrofuran (250 ml) was mixed with [Intermediate 3-a] (25.0 g, 80 mmol) and the mixture was cooled to −78° C. under a nitrogen atmosphere. After 30 min, drops of 1.0 M methyl magnesium bromide (210 ml, 240 mmol) was slowly added over 1 hour, followed by elevation to room temperature. At room temperature, stirring for 2 hours was conducted before dropwise addition of an aqueous ammonium chloride solution. Extraction, vacuum distillation, and recrystallization in hexane in sequence afforded [Intermediate 4-a] (19.4 g, 80%).

### Synthesis Example 4-(2): Synthesis of [Intermediate 4-b]

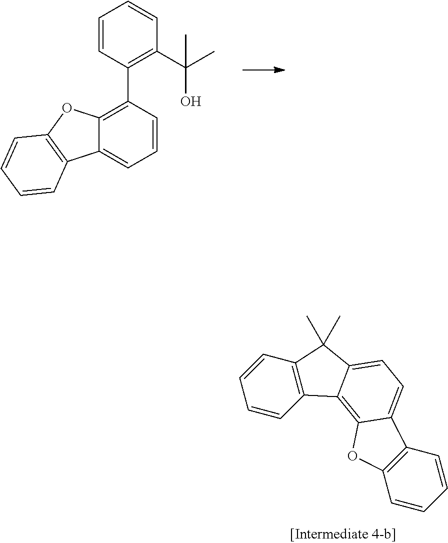 [SMILES: CC(C)(O)c1ccccc1-c1cccc2c1oc1ccccc12 ; CC1(C)c2ccccc2-c2c1ccc1c2oc2ccccc21]

In a round-bottom flask reactor, acetic acid (300 ml) was stirred together with [Intermediate 4-a] (20 g, 66 mmol), at 0° C. for 10 min, and then together with phosphoric acid (350 mL) at room temperature for about 1 hr. Following neutralization with an aqueous sodium hydroxide solution, extraction and vacuum concentration were conducted sequentially. Purification via column chromatography afforded [Intermediate 4-b] (13.7 g, 73%).

### Synthesis Example 4-(3): Synthesis of [Intermediate 4-c]

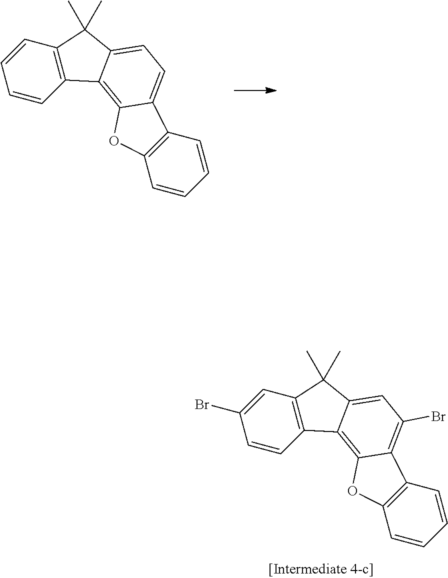 [SMILES: CC1(C)c2ccccc2-c2c1ccc1c2oc2ccccc21 ; CC1(C)c2cc(Br)ccc2-c2c1cc(Br)c1c2oc2ccccc21]

The same procedure as in Synthesis Example 1-(9) was carried out, with the exception of using [Intermediate 4-b] instead of [Intermediate 1-h] to afford [Intermediate 4-c] (yield 65%).

### Synthesis Example 4-(4): Synthesis of [Intermediate 4-d]

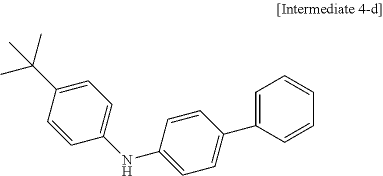 [SMILES: CC(C)(C)c1ccc(Nc2ccc(-c3ccccc3)cc2)cc1]

In a 500-ml round-bottom flask reactor, 4-tert-butylaniline (32.1 g, 215 mmol) 4-bromobiphenyl (50.1 g, 215 mmol), bis-dibenzylidene acetone dipalladium (3.9 g, 4 mmol), 2,2′-bis(diphenylphosphine)-1,1′-binaphthyl (1.2 g, 4 mmol), sodium tert-butoxide (41.3 g, 43 mmol), and toluene (200 ml) were stirred together under reflux. The reaction mixture was cooled to room temperature and washed with methanol. Recrystallization in dichloromethane and methane gave [Intermediate 4-d] (50.5 g, 78%).

### Synthesis Example 4-(5): Synthesis of [Chemical Formula 58]

The same procedure as in Synthesis Example 1-(12) was carried out, with the exception of using [Intermediate 4-c] and [Intermediate 4-d] instead of [Intermediate 1-k] and N-phenyl-4-biphenylamine, respectively, to afford [Chemical Formula 58] (yield 38%).

MS (MALDI-TOF): m/z 882.45 [M⁺]

### Synthesis Example 5: Synthesis of Compound of Chemical Formula 73

### Synthesis Example 5-(1): Synthesis of [Intermediate 5-a]

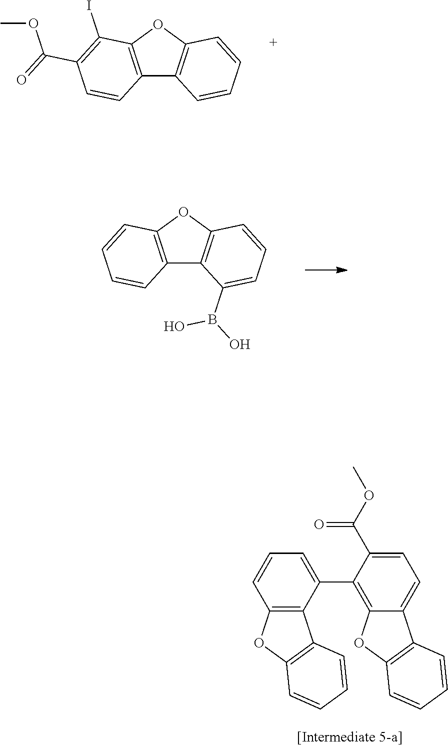 [SMILES: COC(=O)c1ccc2c(oc3ccccc32)c1I ; OB(O)c1cccc2oc3ccccc3c12 ; COC(=O)c1ccc2c(oc3ccccc32)c1-c1cccc2oc3ccccc3c12]

The same procedure as in Synthesis Example 1-(6) was carried out, with the exception of using 1-dibenzofuran boronic acid instead of 4-dibenzofuran boronic acid to afford [Intermediate 5-a] (yield 52.3%).

### Synthesis Example 5-(2): Synthesis of [Intermediate 5-b]

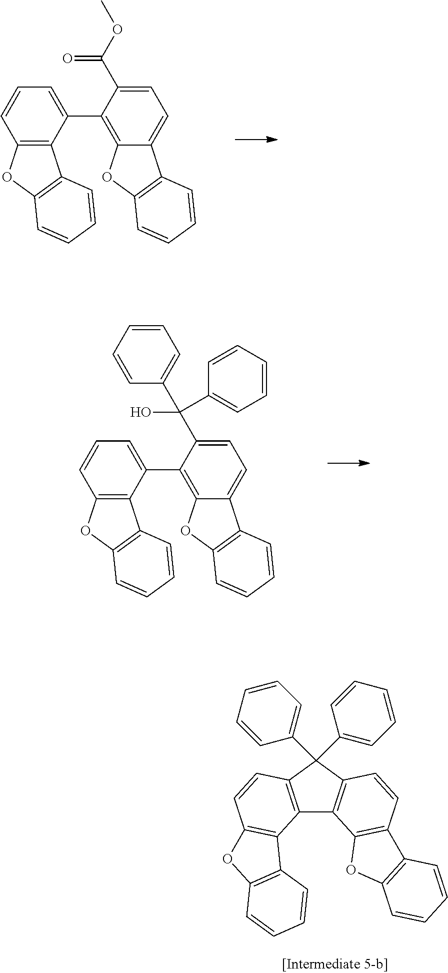 [SMILES: COC(=O)c1ccc2c(oc3ccccc32)c1-c1cccc2oc3ccccc3c12 ; OC(c1ccccc1)(c1ccccc1)c1ccc2c(oc3ccccc32)c1-c1cccc2oc3ccccc3c12 ; c1ccc(C2(c3ccccc3)c3ccc4c(oc5ccccc54)c3-c3c2ccc2oc4ccccc4c32)cc1]

In a 500-ml round-bottom flask reactor, a mixture of bromobenzene (25.5 g, 0.163 mol) and tetrahydrofuran (170 ml) was cooled to −78° C. under a nitrogen atmosphere. At the same temperature, n-butyl lithium (1.6 M) (95.6 ml, 0.153 mol) was dropwise added to the mixture, and stirred for 1 hrs. Then, [Intermediate 5-a] (20.0 g, 0.051 mol) was added and stirred at room temperature for 3 hrs. After completion of the reaction, water (50 ml) was added to the reaction mixture that was then stirred for 30 min. The reaction mixture was extracted with ethylacetate and water, and the organic layer was separated and concentrated in a vacuum. The concentrate was mixed with acetic acid (200 ml) and HCl (1 ml) and stirred at 80° C. When the reaction was completed, the reaction mixture was cooled to room temperature, and filtered. The filtrate was washed with methanol to afford [Intermediate 5-b] (20.0 g, 78%).

### Synthesis Example 5-(3): Synthesis of [Intermediate 5-c]

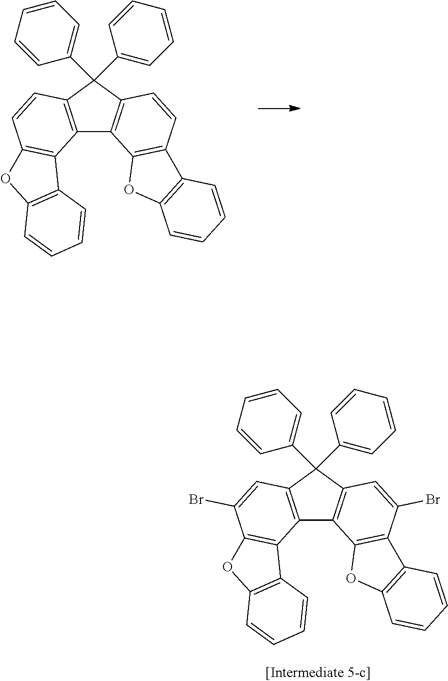 [SMILES: c1ccc(C2(c3ccccc3)c3ccc4c(oc5ccccc54)c3-c3c2ccc2oc4ccccc4c32)cc1 ; Brc1cc2c(c3c1oc1ccccc13)-c1c(cc(Br)c3c1oc1ccccc13)C2(c1ccccc1)c1ccccc1]

The same procedure as in Synthesis Example 1-(9) was carried out, with the exception of using [Intermediate 5-b] instead of [Intermediate 1-h] to afford [Intermediate 5-c] (yield 55%).

### Synthesis Example 5-(4): Synthesis of [Chemical Formula 73]

The same procedure as in Synthesis Example 1-(12) was carried out, with the exception of using [Intermediate 5-c] and 4-(4-tert-butylphenylamino)benzonitrile instead of [Intermediate 1-k] and N-phenyl-4-biphenylamine, respectively, to afford [Chemical Formula 73] (yield 40%).

MS (MALDI-TOF): m/z 994.42 [M⁺]

### Synthesis Example 6: Synthesis of Compound of Chemical Formula 86

### Synthesis Example 6-(1): Synthesis of [Intermediate 6-a]

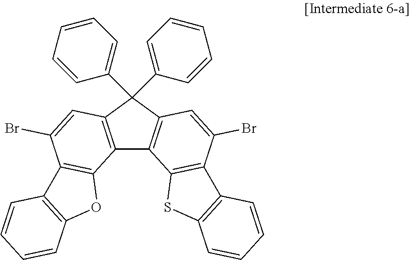 [SMILES: Brc1cc2c(c3oc4ccccc4c13)-c1c(cc(Br)c3c1sc1ccccc13)C2(c1ccccc1)c1ccccc1]

The same procedure as in Synthesis Examples 5-(1) to 5-(3) was carried out, with the exception of using 4-dibenzothiophene boronic acid instead of 1-dibenzofuran boronic acid of Example 5-(1) to afford [Intermediate 6-a] (yield 52%).

### Synthesis Example 6-(2): Synthesis of [Chemical Formula 86]

The same procedure as in Synthesis Example 1-(12) was carried out, with the exception of using [Intermediate 6-a] and (4-tert-butylphenyl)-phenylamine instead of [Intermediate 1-k] and N-phenyl-4-biphenylamine to afford [Chemical Formula 86] (yield 35%).

MS (MALDI-TOF): m/z 960.41 [M⁺]

### Synthesis Example 7: Synthesis of Compound of Chemical Formula 95

### Synthesis Example 7-(1): Synthesis of [Intermediate 7-a]

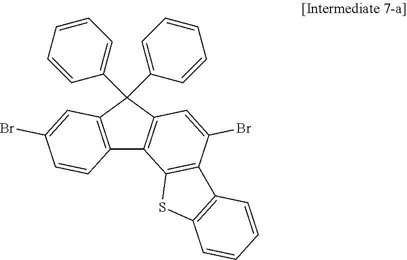 [SMILES: Brc1ccc2c(c1)C(c1ccccc1)(c1ccccc1)c1cc(Br)c3c(sc4ccccc43)c1-2]

The same procedure as in Examples 3-(1) to 3-(4) Synthesis was carried out, with the exception of using 4-dibenzothiophene boronic acid instead of 4-dibenzofuran boronic acid in Example 3-(1) to afford [Intermediate 7-a]. (yield 68%)

### Synthesis Example 7-(2): Synthesis of [Intermediate 7-b]

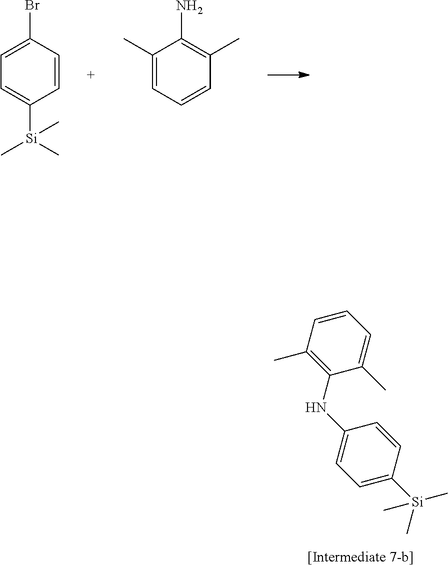

In a 250-ml round bottom flask, a mixture of 1-bromo-4-(trimethylsilyl)benzene (11.4 g, 0.050 mol), 2,6-dimethylaniline (6.2 g, 0.050 mol), palladium acetate (0.22 g, 1 mmol), 2,2′-bis(diphenylphosphino)-1-1′-binaphthyl (1.3 g, 2 mmol), sodium tert-butoxide (12.2 g, 0.120 mol), and toluene (100 mL) was fluxed for 12 hrs. After being cooled to room temperature, the reaction mixture was extracted with ethyl acetate. Column chromatography separated [Intermediate 7-b] (10.5 g, 78%).

### Synthesis Example 7-(3): Synthesis of [Chemical Formula 95]

The same procedure as in Synthesis Example 1-(12) was carried out, with the exception of using [Intermediate 7-a] and [Intermediate 7-b] instead of [Intermediate 1-k] and N-phenyl-4-biphenylamine, respectively, to afford [Chemical Formula 95] (yield 37%).

MS (MALDI-TOF): m/z 958.42 [M⁺]

### Synthesis Example 8: Synthesis of Compound of Chemical Formula 125

### Synthesis Example 8-(1): Synthesis of [Intermediate 8-a]

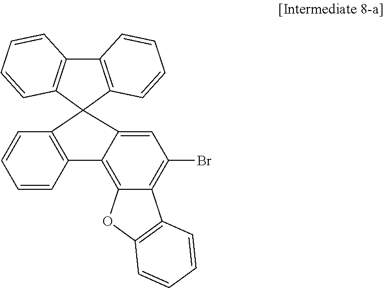 [SMILES: Brc1cc2c(c3oc4ccccc4c13)-c1ccccc1C21c2ccccc2-c2ccccc21]

The same procedure as in Synthesis Examples 2-(1) to 2-(6) was carried out, with the exception of using methyl 2-iodobenzoate and 4-dibenzofuran boronic acid instead of methyl 5-bromo-2-iodobenzoate and 1-dibenzofuran boronic acid in Synthesis Example 2-(1) to afford [Intermediate 8-a]. (yield 54%)

### Synthesis Example 8-(2): Synthesis of [Chemical Formula 125]

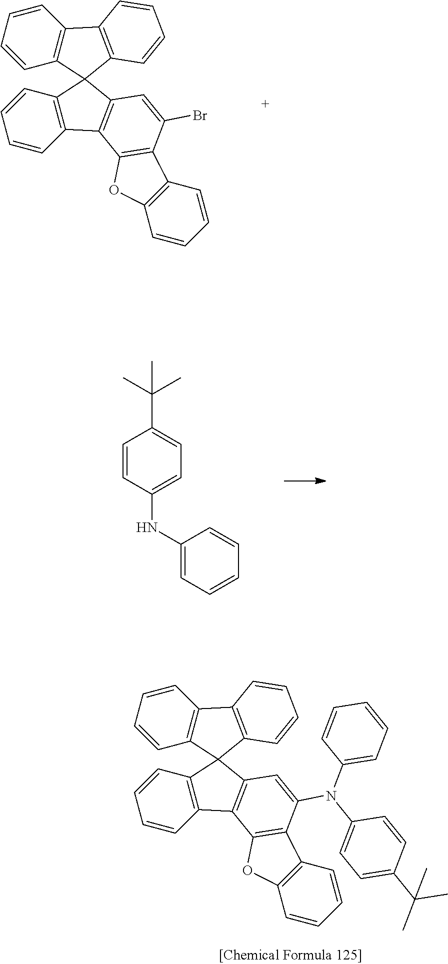 [SMILES: Brc1cc2c(c3oc4ccccc4c13)-c1ccccc1C21c2ccccc2-c2ccccc21 ; CC(C)(C)c1ccc(Nc2ccccc2)cc1 ; CC(C)(C)c1ccc(N(c2ccccc2)c2cc3c(c4oc5ccccc5c24)-c2ccccc2C32c3ccccc3-c3ccccc32)cc1]

In a 250-ml round-bottom flask, a mixture of [Intermediate 8-a] (4.4 g, 0.009 mol), (4-tert-butylphenyl)-phenylamine (4.7 g, 0.021 mol), palladium (II) acetate (0.08 g, 0.4 mmol), sodium tert-butoxide (3.4 g, 0.035 mol), tri-tert-butyl phosphine (0.07 g, 0.4 mmol), and toluene (60 ml) was stirred for 2 hrs under reflux. After completion of the reaction, the reaction mixture was cooled to room temperature and then extracted with dichloromethane and water. The organic layer thus formed was separated, dried over magnesium sulfate, and concentrated in a vacuum. The concentrate was purified by column chromatography and recrystallized in dichloromethane and acetone to yield [Chemical Formula 125]. (3.3 g, 58%).

MS (MALDI-TOF): m/z 629.27 [M⁺]

### Synthesis Example 9: Synthesis of Compound of Chemical Formula 154

### Synthesis Example 9-(1): Synthesis of [Intermediate 9-a]

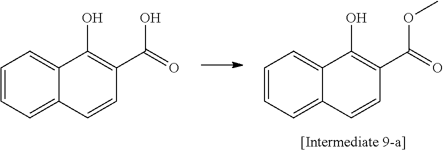

In a 2-L round-bottom flask reactor, 1-hydroxy 2-naphthalic acid (50 g, 266 mmol), methanol (1000 ml), and sulfuric acid (100 ml) were stirred together for 100 hrs under reflux. The completion of the reaction was confirmed by TLC before the reaction mixture was cooled to room temperature. The mixture was concentrated in a vacuum and extracted with dichloromethane and water. The organic layer was isolated, dried over magnesium sulfate, and filtered. The filtrate was concentrated at a reduced pressure and crystallized in an excess of heptane to afford [Intermediate 9-a] (39 g, 72.6%).

### Synthesis Example 9-(2): Synthesis of [Intermediate 9-b]

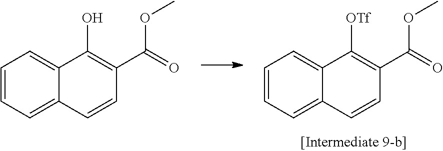 [SMILES: COC(=O)c1ccc2ccccc2c1O ; COC(=O)c1ccc2ccccc2c1OS(=O)(=O)C(F)(F)F]

In a 2-L round-bottom flask reactor, [Intermediate 9-a] (36 g, 178 mmol) was stirred together with dichloromethane. Under a nitrogen atmosphere, pyridine (28.1 g, 356 mmol) was added and stirred at room temperature for 20 min. The resulting solution was cooled to 0° C. and then added with drops of trifluoromethanesulfonic anhydride (65.24 g, 231 mmol) under a nitrogen atmosphere. After 3 hrs of stirring, the completion of the reaction was confirmed by TLC. Water (20 ml) was added, and the mixture was stirred for 10 min. The reaction mixture was concentrated in a vacuum, followed by purification through column chromatography to afford [Intermediate 9-b] (36.3 g, 61%).

### Synthesis Example 9-(3): Synthesis of [Intermediate 9-c]

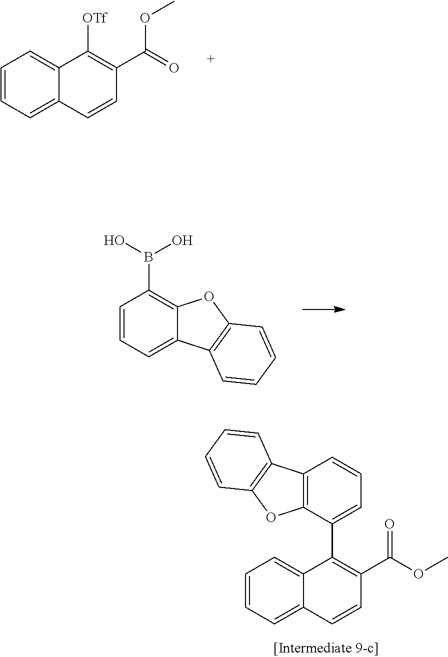 [SMILES: COC(=O)c1ccc2ccccc2c1OS(=O)(=O)C(F)(F)F ; OB(O)c1cccc2c1oc1ccccc12 ; COC(=O)c1ccc2ccccc2c1-c1cccc2c1oc1ccccc12]

In a 1-L round-bottom flask reactor, a mixture of [Intermediate 9-b] (36.4 g, 0.109 mol), 4-dibenzoboronic acid (25.4 g, 0.120 mol), tetrakis(triphenylphosphine)palladium (2.5 g, 0.22 mmol), and potassium carbonate (30.1 g, 0.218 mol) was stirred together with toluene (300 mL), ethanol (130 mL) and water (90 mL) at 80° C. for 5 hrs. After completion of the reaction, the reaction mixture was cooled to room temperature and extracted with ethyl acetate. The organic layer was isolated and concentrated in a vacuum. Purification through column chromatography afforded [Intermediate 9-c]. (17.7 g, 46.1%)

### Synthesis Example 9-(4): Synthesis of [Intermediate 9-d]

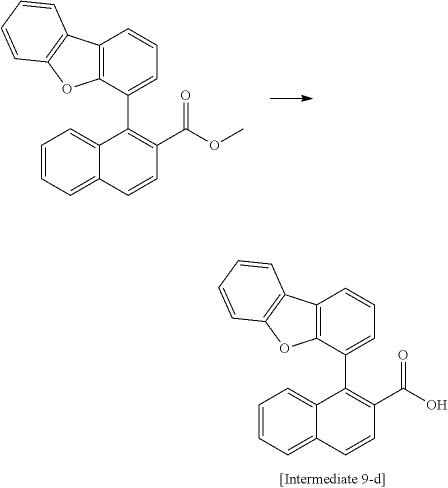 [SMILES: COC(=O)c1ccc2ccccc2c1-c1cccc2c1oc1ccccc12 ; O=C(O)c1ccc2ccccc2c1-c1cccc2c1oc1ccccc12]

In a 1-L round-bottom flask reactor, [Intermediate 9-c] (18.0 g, 0.051 mol) was stirred together with sodium hydroxide (2.65 g, 0.066 mol) for 48 hrs under reflux. After completion of the reaction, the reaction mixture was cooled to room temperature. The chilled solution was acidified with drops of 2-N HCl, followed by stirring for 30 min. The solid thus formed was filtered and recrystallized in dichloromethane and n-hexane to afford [Intermediate 9-d]. (14.3 g, 82.7%)

### Synthesis Example 9-(5): Synthesis of [Intermediate 9-e]

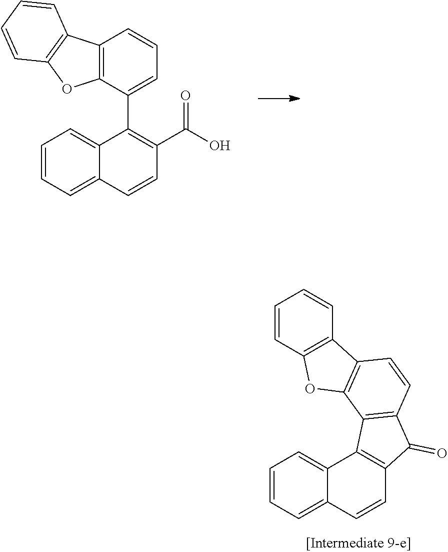 [SMILES: O=C(O)c1ccc2ccccc2c1-c1cccc2c1oc1ccccc12 ; O=C1c2ccc3ccccc3c2-c2c1ccc1c2oc2ccccc21]

In a 500-mL round-bottom flask reactor, [Intermediate 9-d] (14.2 g, 0.042 mol) and methanesulfonic acid (170 ml) were stirred together for 3 hrs at 80° C. After the completion of the reaction was confirmed using thin-layer chromatography, the reaction mixture was cooled to room temperature and dropwise added to ice water (150 ml). After stirring for 30 min, the precipitates thus formed were filtered and washed with water and methanol. They were dissolved in monochlorobenzene and filtered through a silica gel pad. The filtrate was concentrated by heating and recrystallized in acetone to afford [Intermediate 9-e]. (9.5 g, 71%)

### Synthesis Example 9-(6): Synthesis of [Intermediate 9-f]

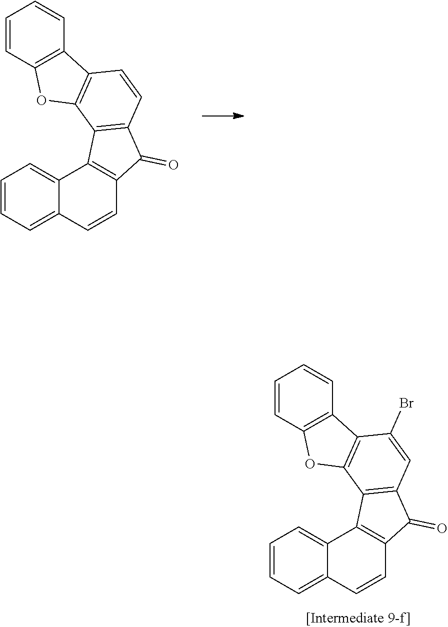 [SMILES: O=C1c2ccc3ccccc3c2-c2c1ccc1c2oc2ccccc21 ; O=C1c2ccc3ccccc3c2-c2c1cc(Br)c1c2oc2ccccc21]

In a 1-L round-bottom flask reactor, [Intermediate 9-e] (9.6 g, 0.030 mol) and dichloromethane (360 ml) were stirred together at room temperature. A dilution of bromine (3.1 ml, 0.06 mol) in dichloromethane (40 ml) was dropwise added, followed by stirring at room temperature for 12 hrs. After completion of the reaction, methanol (100 ml) was added to induce the formation of precipitates. They were then filtered and washed with methanol. Recrystallization in 1,2-dichlorobenzene and acetone afforded [Intermediate 9-f] (8.6 g, 71.7%).

### Synthesis Example 9-(7): Synthesis of [Intermediate 9-g]

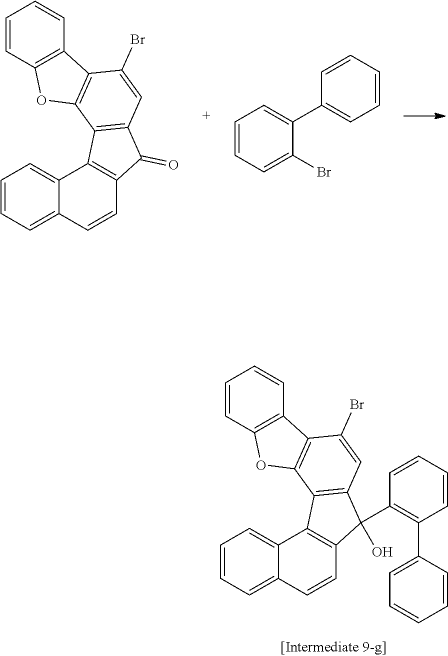 [SMILES: O=C1c2ccc3ccccc3c2-c2c1cc(Br)c1c2oc2ccccc21 ; Brc1ccccc1-c1ccccc1 ; OC1(c2ccccc2-c2ccccc2)c2ccc3ccccc3c2-c2c1cc(Br)c1c2oc2ccccc21]

The same procedure as in Synthesis Example 1-(10) was carried out, with the exception of using [Intermediate 9-f] instead of [Intermediate 1-i] to afford [Intermediate 9-g] (yield 73.4%).

### Synthesis Example 9-(8): Synthesis of [Intermediate 9-h]

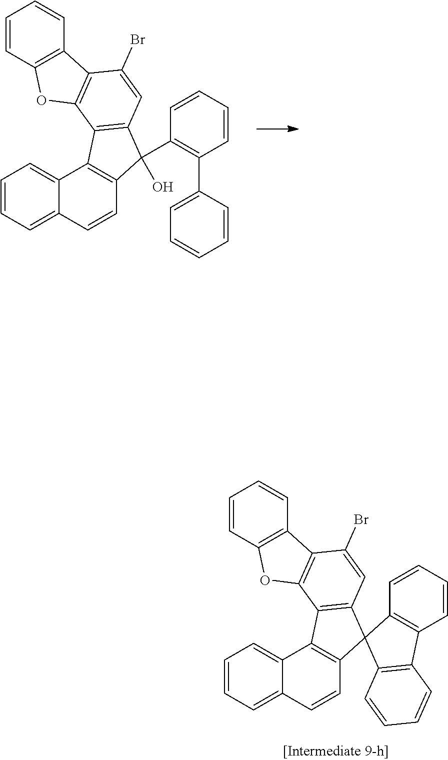 [SMILES: OC1(c2ccccc2-c2ccccc2)c2ccc3ccccc3c2-c2c1cc(Br)c1c2oc2ccccc21 ; Brc1cc2c(c3oc4ccccc4c13)-c1c(ccc3ccccc13)C21c2ccccc2-c2ccccc21]

The same procedure as in Synthesis Example 1-(11) was carried out, with the exception of using [Intermediate 9-g] instead of [Intermediate 1-j] to afford [Intermediate 9-h] (yield 64.8%).

### Synthesis Example 9-(9): Synthesis of [Chemical Formula 154]

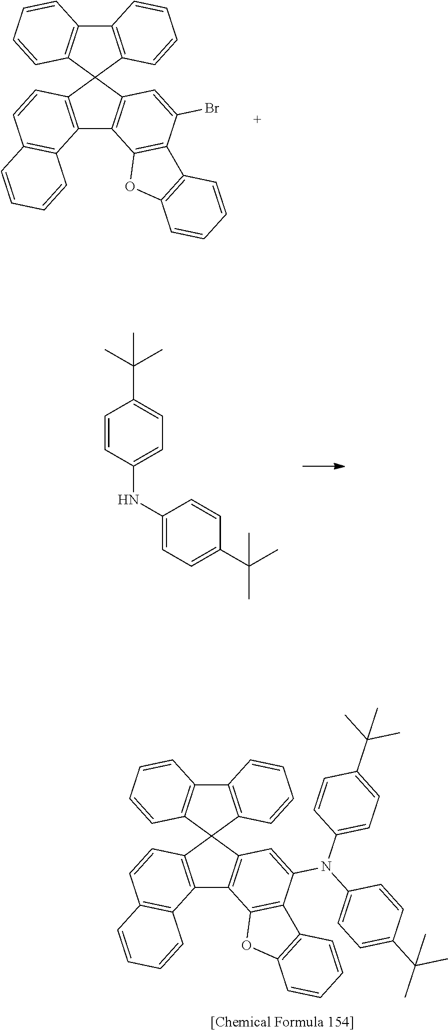 [SMILES: Brc1cc2c(c3oc4ccccc4c13)-c1c(ccc3ccccc13)C21c2ccccc2-c2ccccc21 ; CC(C)(C)c1ccc(Nc2ccc(C(C)(C)C)cc2)cc1 ; CC(C)(C)c1ccc(N(c2ccc(C(C)(C)C)cc2)c2cc3c(c4oc5ccccc5c24)-c2c(ccc4ccccc24)C32c3ccccc3-c3ccccc32)cc1]

The same procedure as in Synthesis Example 8-(2) was carried out, with the exception of using [Intermediate 9-h] and bis(4-tert-butylphenyl)amine instead of [Intermediate 8-a] and (4-tert-butylphenyl)-phenylamine, respectively, to afford [Chemical Formula 154] (yield 75%).

MS (MALDI-TOF): m/z 735.35 [M⁺]

### Synthesis Example 10: Synthesis of Compound of Chemical Formula 158

### Synthesis Example 10-(1): Synthesis of [Intermediate 10-a]

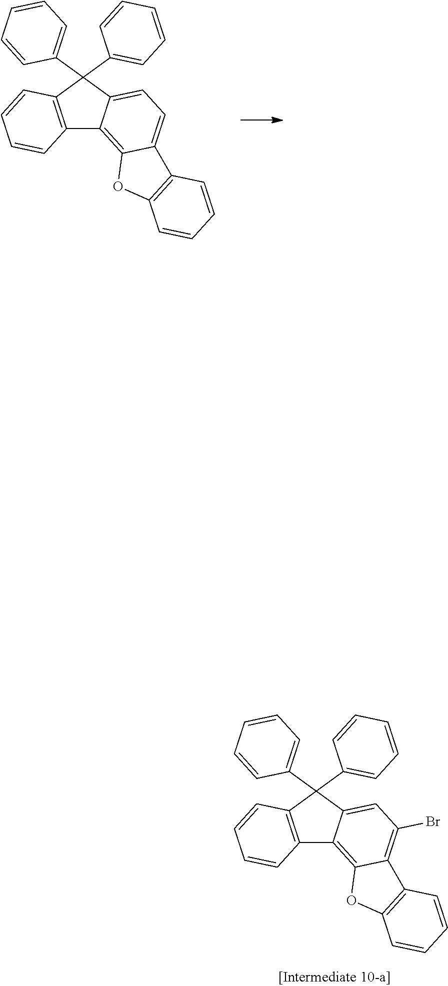 [SMILES: c1ccc(C2(c3ccccc3)c3ccccc3-c3c2ccc2c3oc3ccccc32)cc1 ; Brc1cc2c(c3oc4ccccc4c13)-c1ccccc1C2(c1ccccc1)c1ccccc1]

In a 2-L round-bottom flask reactor, [Intermediate 3-c] (50 g, 122 mmol) was stirred together with dichloromethane (600 ml), at room temperature. A dilution of bromine (13.7 ml, 85 mmol) in dichloromethane (50 ml) was dropwise added, followed by stirring for about 3 hrs. Recrystallization in methanol afforded [Intermediate 10-a]. (45 g, 76%)

### Synthesis Example 10-(2): Synthesis of [Intermediate 10-b]

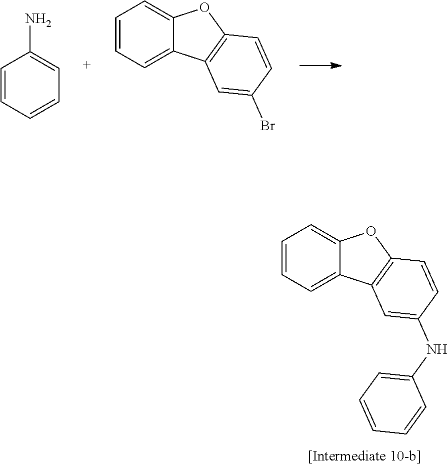 [SMILES: Nc1ccccc1 ; Brc1ccc2oc3ccccc3c2c1 ; c1ccc(Nc2ccc3oc4ccccc4c3c2)cc1]

In a 500-ml round-bottom flask reactor, aniline (20 g, 215 mmol) 2-bromodibenzofuran (53.1 g, 215 mmol), bis-dibenzylidene acetone dipalladium (3.9 g, 4 mmol), 2,2′-bis(diphenylphosphine)-1,1′-binaphthyl (1.2 g, 4 mmol), sodium tert-butoxide (41.3 g, 43 mmol), and toluene (200 ml) were stirred together under reflux. The reaction mixture was cooled to room temperature and washed with methanol. Recrystallization in dichloromethane and methane gave [Intermediate 10-b]. (40 g, 72%)

### Synthesis Example 10-(3): Synthesis of [Chemical Formula 158]

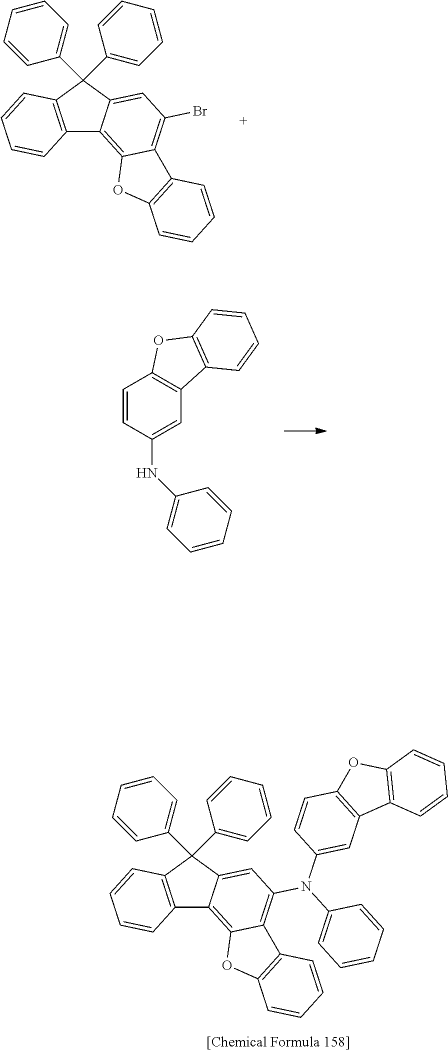 [SMILES: Brc1cc2c(c3oc4ccccc4c13)-c1ccccc1C2(c1ccccc1)c1ccccc1 ; c1ccc(Nc2ccc3oc4ccccc4c3c2)cc1 ; c1ccc(N(c2ccc3oc4ccccc4c3c2)c2cc3c(c4oc5ccccc5c24)-c2ccccc2C3(c2ccccc2)c2ccccc2)cc1]

The same procedure as in Synthesis Example 8-(2) was carried out, with the exception of using [Intermediate 10-a] and [Intermediate 10-b] instead of [Intermediate 8-a] and (4-tert-butylphenyl)-phenylamine, respectively, to afford [Chemical Formula 158] (yield 66%).

MS (MALDI-TOF): m/z 665.24 [M⁺]

### Synthesis Example 11: Synthesis of Compound of Chemical Formula 190

### Synthesis Example 11-(1): Synthesis of [Intermediate 11-a]

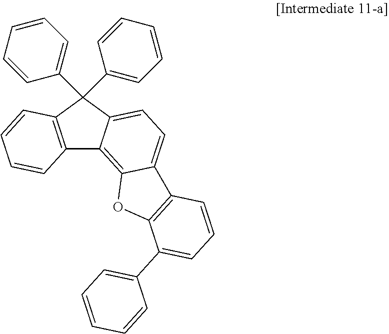 [SMILES: c1ccc(-c2cccc3c2oc2c4c(ccc23)C(c2ccccc2)(c2ccccc2)c2ccccc2-4)cc1]

The same procedure as in Synthesis Example 3-(1) to 3-(3) was carried out, with the exception of using (6-phenyldibenzo[b,d]furan-4-yl)boronic acid instead of 4-dibenzofuran boronic acid in Synthesis Example 3-(1) to afford [Intermediate 11-a]. (53%)

### Synthesis Example 11-(2): Synthesis of [Intermediate 11-b]

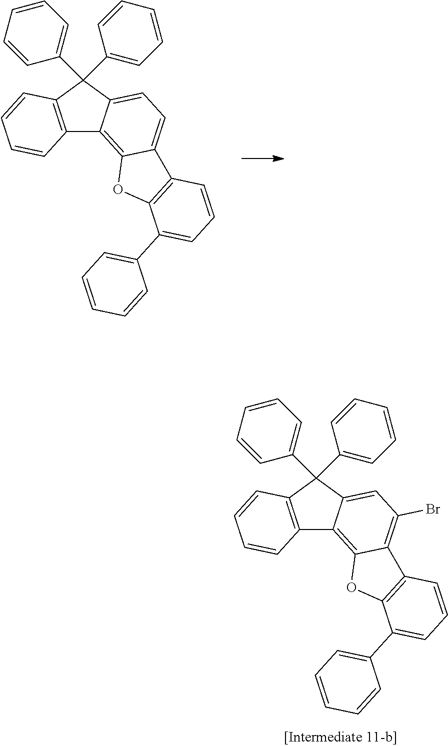 [SMILES: c1ccc(-c2cccc3c2oc2c4c(ccc23)C(c2ccccc2)(c2ccccc2)c2ccccc2-4)cc1 ; Brc1cc2c(c3oc4c(-c5ccccc5)cccc4c13)-c1ccccc1C2(c1ccccc1)c1ccccc1]

The same procedure as in Synthesis Example 10-(1) was carried out, with the exception of using [Intermediate 11-a] instead of [Intermediate 3-c] to afford [Intermediate 11-b] (yield 78%).

### Synthesis Example 11-(3): Synthesis of [Chemical Formula 190]

The same procedure as in Synthesis Example 8-(2) was carried out, with the exception of using [Intermediate 11-a] and diphenylamine instead of [Intermediate 8-a] and (4-tert-butylphenyl)-phenylamine, respectively, to afford [Chemical Formula 190] (yield 72%).

MS (MALDI-TOF): m/z 651.26 [M⁺]

### Synthesis Example 12: Synthesis of Compound of Chemical Formula 289

### Synthesis Example 12-(1): Synthesis of [Intermediate 12-a]

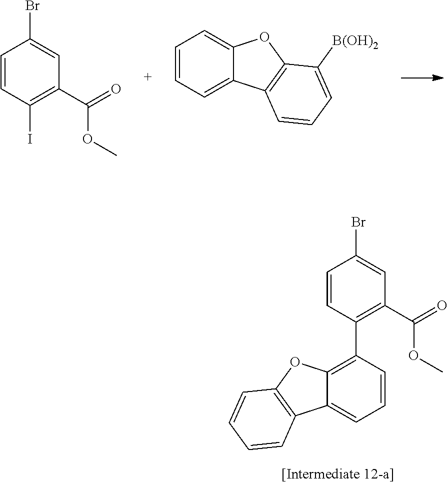 [SMILES: COC(=O)c1cc(Br)ccc1I ; OB(O)c1cccc2c1oc1ccccc12 ; COC(=O)c1cc(Br)ccc1-c1cccc2c1oc1ccccc12]

In a 500-mL round-bottom flask reactor, methyl 5-bromo-2-iodobenzoate (25.0 g, 73 mmol), 4-dibenzofuran boronic acid (18.7 g, 88 mmol), tetrakis (triphenylphosphine)palladium (1.7 g, 0.15 mmol), and potassium carbonate (20.2 g, 146.7 mmol) stirred together with toluene (125 mL), tetrahydrofuran (125 mL), and water (50 mL) for 10 hrs at 80° C. After completion of the reaction, the reaction mixture was cooled to room temperature and extracted with ethyl acetate. The organic layer thus formed was separated, concentrated in a vacuum, and purified by column chromatography to afford [Intermediate 12-a] (75.0 g, 60.1%).

### Synthesis Example 12-(2): Synthesis of [Intermediate 12-b]

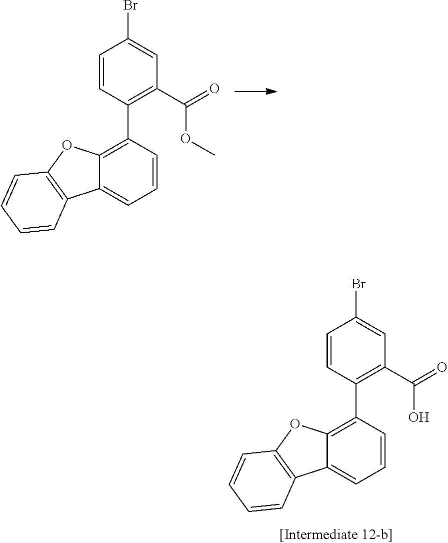 [SMILES: COC(=O)c1cc(Br)ccc1-c1cccc2c1oc1ccccc12 ; O=C(O)c1cc(Br)ccc1-c1cccc2c1oc1ccccc12]

In a 500-mL round-bottom flask reactor, [Intermediate 12-a] (17.0 g, 45 mmol), sodium hydroxide (2.14 g, 54 mmol) and ethanol (170 ml) were stirred together for 48 hrs under reflux. After the completion of the reaction was confirmed by thin layer chromatography, the reaction mixture was cooled to room temperature. The chilled solution was acidified with drops of 2-N HCl, followed by stirring for 30 min. The solid thus formed was filtered, and recrystallized in dichloromethane and n-hexane to afford [Intermediate 12-b] (14.5 g, 88.6%).

### Synthesis Example 12-(3): Synthesis of [Intermediate 12-c]

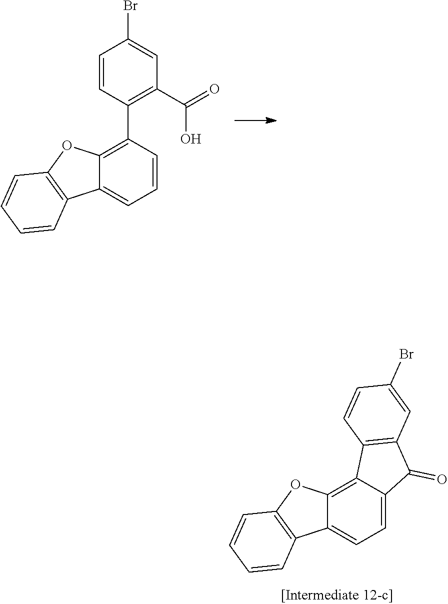 [SMILES: O=C(O)c1cc(Br)ccc1-c1cccc2c1oc1ccccc12 ; O=C1c2cc(Br)ccc2-c2c1ccc1c2oc2ccccc21]

In a 250-mL round-bottom flask reactor, [Intermediate 12-b] (14.5 g, 39 mmol) and methanesulfonic acid (145 ml) were stirred together for 3 hrs at 80° C. After the completion of the reaction was confirmed by thin layer chromatography, the reaction mixture was cooled to room temperature and dropwise added to ice water (150 ml). After stirring for 30 min, the solid thus formed was filtered and washed with water and methanol to afford [Intermediate 12-c] (11.50 g, 83.4%).

### Synthesis Example 12-(4): Synthesis of [Intermediate 12-d]

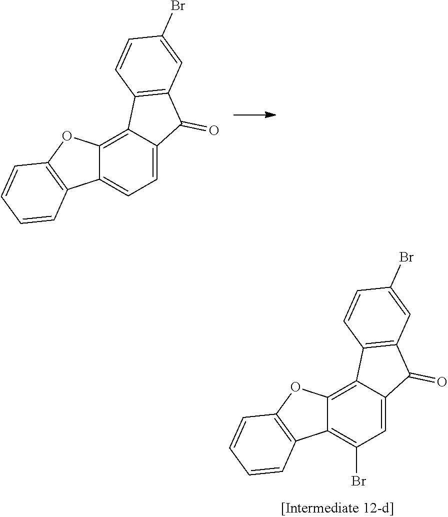 [SMILES: O=C1c2cc(Br)ccc2-c2c1ccc1c2oc2ccccc21 ; O=C1c2cc(Br)ccc2-c2c1cc(Br)c1c2oc2ccccc21]

In a 1-L round-bottom flask reactor, [Intermediate 12-c] (11.5 g, 33 mmol) and dichloromethane (300 ml) were stirred together at room temperature. A dilution of bromine (3.4 ml, 66 mmol) in dichloromethane (50 ml) was dropwise added, followed by stirring at room temperature for 8 hrs. After completion of the reaction, the reaction mixture was stirred together with acetone (100 ml). The solid thus formed was filtered, and washed with acetone. Recrystallization in monochlorobenzene afforded [Intermediate 12-d] (11.0 g, 78%).

### Synthesis Example 12-(5): Synthesis of [Intermediate 12-e]

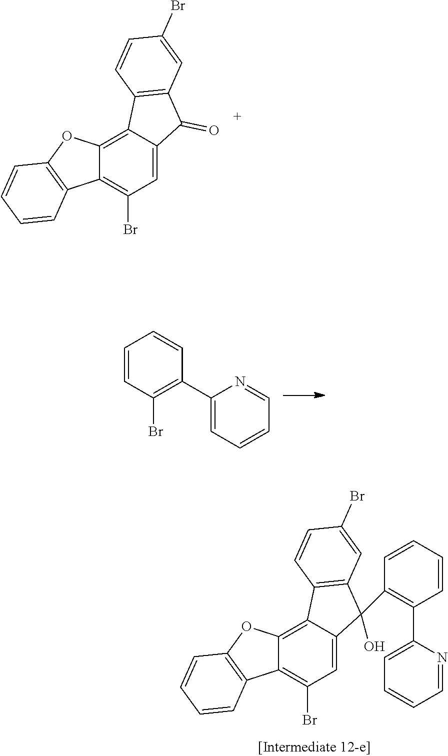 [SMILES: O=C1c2cc(Br)ccc2-c2c1cc(Br)c1c2oc2ccccc21 ; Brc1ccccc1-c1ccccn1 ; OC1(c2ccccc2-c2ccccn2)c2cc(Br)ccc2-c2c1cc(Br)c1c2oc2ccccc21]

In a 250-ml round-bottom flask reactor, 2-(2-bromophenyl)pyridine (8.4 g, 0.036 mol) and tetrahydrofuran (110 ml) were chilled at −78° C. under a nitrogen atmosphere. At the same temperature, n-butyl lithium (19.3 ml, 0.031 mol) was dropwise added to the reaction solution which was then stirred for 2 hrs. Thereafter, [Intermediate 12-d] (11.0 g, 0.026 mol) was added little by little to the reaction solution, and stirred at room temperature. When the reaction mixture started to change color, the reaction was monitored via thin layer chromatography. After the reaction was stopped with water (50 ml), extraction was conducted with ethyl acetate and water. The organic layer was separated, concentrated in a vacuum, and recrystallized in acetonitrile to afford [Intermediate 12-e] (11.4 g, 75%).

### Synthesis Example 12-(6): Synthesis of [Intermediate 12-f]

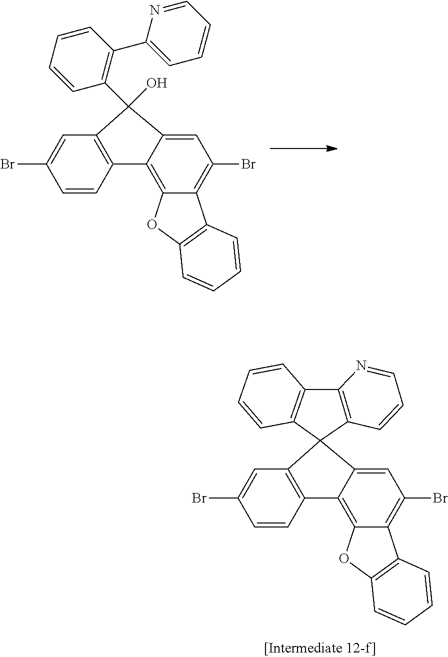 [SMILES: OC1(c2ccccc2-c2ccccn2)c2cc(Br)ccc2-c2c1cc(Br)c1c2oc2ccccc21 ; Brc1ccc2c(c1)C1(c3ccccc3-c3ncccc31)c1cc(Br)c3c(oc4ccccc43)c1-2]

In a 250-ml round-bottom flask reactor, a mixture of [Intermediate 12-e] (12.2 g, 0.021 mol), acetic acid (120 ml), and sulfuric acid (2 ml) was stirred for 5 hrs under reflux. When a precipitate was formed, the completion of the reaction was monitored using thin layer chromatography. The reaction mixture was then cooled to room temperature and filtered. The filtrate was washed with H₂O and methanol and dissolved in monochlorobenzene. Following silica gel chromatography, the fraction was concentrated and cooled to room temperature to give [Intermediate 12-f] (10.3 g, 87%).

### Synthesis Example 12-(7): Synthesis of [Chemical Formula 289]

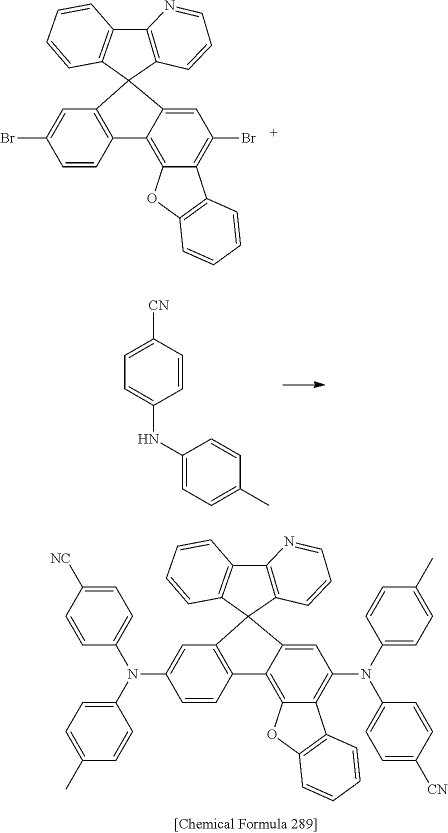

The same procedure as in Synthesis Example 1-(12) was carried out, with the exception of using [Intermediate 12-f] and 4-[(4-methylphenyl)aminobenzonitrile] instead of [Intermediate 1-k] and N-phenyl-4-biphenylamine, respectively, to afford [Chemical Formula 289] (yield 35%).

MS (MALDI-TOF): m/z 819.30 [M⁺]

### Synthesis Example 13: Synthesis of Compound of Chemical Formula 292

### Synthesis Example 13-(1): Synthesis of [Intermediate 13-a]

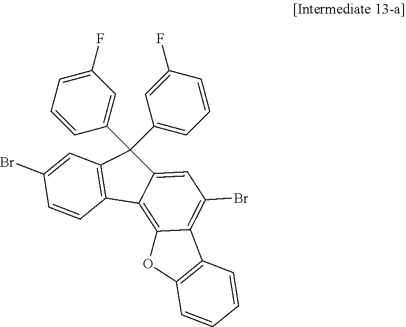 [SMILES: Fc1cccc(C2(c3cccc(F)c3)c3cc(Br)ccc3-c3c2cc(Br)c2c3oc3ccccc32)c1]

The same procedure as in Synthesis Example 3-(1) to Synthesis Example 3-(4) was carried out, with the exception of using 3-bromofluorobenzene instead of bromobenzene in Synthesis Example 3-(2) to afford [Intermediate 13-a]. (yield 57%)

### Synthesis Example 13-(2): Synthesis of [Chemical Formula 292]

The same procedure as in Synthesis Example 1-(12) was carried out, with the exception of using [Intermediate 13-a] and 2-methyl-N-(2-methylphenyl)aniline instead of [Intermediate 1-k] and N-phenyl-4-biphenylamine to afford [Chemical Formula 292] (yield 34%).

MS (MALDI-TOF): m/z 806.31 [M⁺]

### Synthesis Example 14: Synthesis of Compound of Chemical Formula 293

### Synthesis Example 14-(1): Synthesis of [Intermediate 14-a]

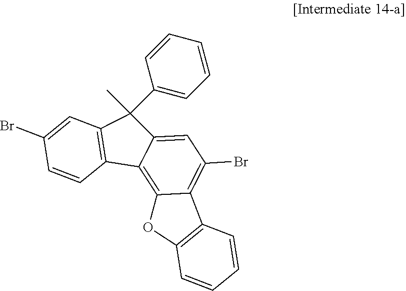 [SMILES: CC1(c2ccccc2)c2cc(Br)ccc2-c2c1cc(Br)c1c2oc2ccccc21]

The same procedure as in Synthesis Example 3-(1) to Synthesis Example 3-(4) was carried out, with the exception of using 1-bromo-2-iodobenzene and acetophenone instead of 2-iodobenzoate in Synthesis Example 3-(1) and [Intermediate 3-a] in Synthesis Example 3-(2), respectively, to afford [Intermediate 14-a]. (yield 65%)

### Synthesis Example 14-(2): Synthesis of [Chemical Formula 293]

The same procedure as in Synthesis Example 1-(12) was carried out, with the exception of using [Intermediate 14-a] and N-phenyl-4-biphenylamine instead of [Intermediate 1-k] and N-phenyl-4-biphenylamine, respectively, to afford [Chemical Formula 293] (yield 44%).

MS (MALDI-TOF): m/z 832.35 [M⁺]

### Synthesis Example 15: Synthesis of Compound of Chemical Formula 294

### Synthesis Example 15-(1): Synthesis of [Intermediate 15-a]

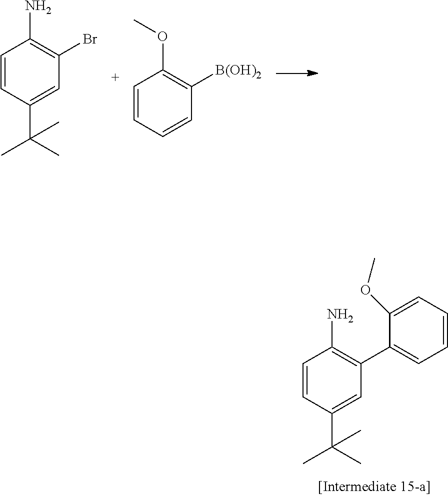 [SMILES: CC(C)(C)c1ccc(N)c(Br)c1 ; COc1ccccc1B(O)O ; COc1ccccc1-c1cc(C(C)(C)C)ccc1N]

In a 500-mL round-bottom flask reactor, 2-bromo-4-tert-butylaniline (16.7 g, 73 mmol), 2-methoxyphenyl boronic acid (13.4 g, 88 mmol), tetrakis(triphenylphosphine)palladium (1.7 g, 0.15 mmol), and potassium carbonate (20.2 g, 146.7 mmol) stirred together with toluene (125 mL), tetrahydrofuran (125 mL), and water (50 mL) for 10 hrs at 80° C. After completion of the reaction, the reaction mixture was cooled to room temperature and extracted with ethyl acetate. The organic layer thus formed was separated, concentrated in a vacuum, and purified by column chromatography to afford [Intermediate 15-a]. (12.1 g, 65%)

### Synthesis Example 15-(2): Synthesis of [Intermediate 15-b]

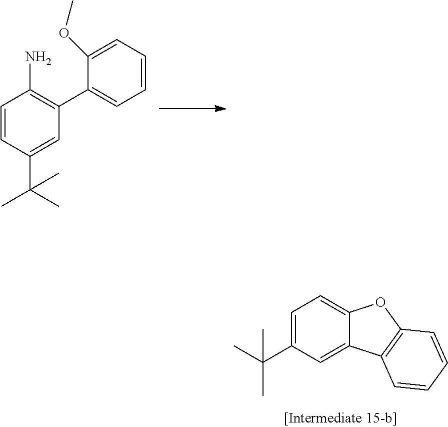 [SMILES: COc1ccccc1-c1cc(C(C)(C)C)ccc1N ; CC(C)(C)c1ccc2oc3ccccc3c2c1]

In a 1-L round-bottom flask reactor, a mixture of [Intermediate 15-a] (40.0 g, 157 mmol) and water (160 ml) was stirred. Drops of sulfuric acid (38 mL) were added little by little to the mixture which was then cooled to 0° C. An aqueous sodium nitrite solution (480 mL) was dropwise added and stirred for 3 hours before heating to room temperature. After completion of the reaction, water was evaporated to isolate the organic layer which was then purified by column chromatography to afford [Intermediate 15-b]. (29.9 g, 85%)

### Synthesis Example 15-(3): Synthesis of [Intermediate 15-c]

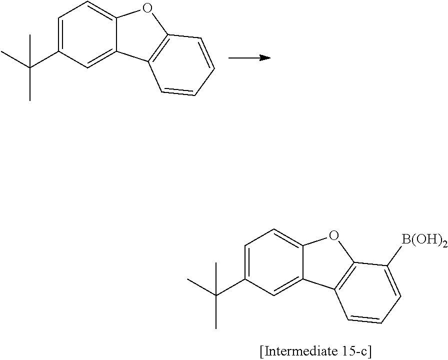 [SMILES: CC(C)(C)c1ccc2oc3ccccc3c2c1 ; CC(C)(C)c1ccc2oc3c(B(O)O)cccc3c2c1]

In a 1-L round-bottom flask, [Intermediate 15-b] (40.0 g, 178 mmol) was dissolved in tetrahydrofuran (240 ml) under a nitrogen atmosphere. The solution was added with drops of 1.6 M N-butyl lithium (144.5 mL, 232 mmol) while being stirred at −78° C. Thereafter, the solution was stirred for 12 hours at room temperature. Subsequently, drops of trimethyl borate (24.1 g, 232 mmol) were slowly added at −78° C. to the solution which was then stirred at room temperature for 1 hr. After completion of the reaction, drops of 2 N HCl was slowly added at room temperature while stirring for 30 min to acidify the solution to a pH of 2. Extraction was made with water and ethyl acetate, and the organic layer thus formed was isolated and concentrated in a vacuum, followed by recrystallization in heptane and dichloromethane to afford [Intermediate 15-c]. (34.4 g, 72%)

### Synthesis Example 15-(4): Synthesis of [Intermediate 15-d]

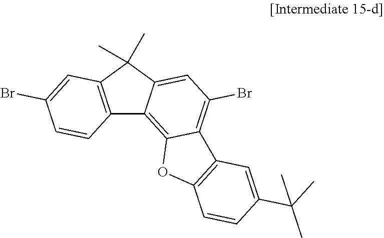 [SMILES: CC(C)(C)c1ccc2oc3c4c(cc(Br)c3c2c1)C(C)(C)c1cc(Br)ccc1-4]

The same procedure as in Synthesis Example 4-(1) to Synthesis Example 4-(3) was carried out, with the exception that the compound obtained using [Intermediate 15-c] instead of 4-dibenzofuran boronic acid in Synthesis Example 3-(1) was used instead of [Intermediate 3-a] in Synthesis Example 4-(1), to afford [Intermediate 15-d]. (yield 67%)

### Synthesis Example 15-(5): Synthesis of [Chemical Formula 294]

The same procedure as in Synthesis Example 1-(12) was carried out, with the exception of using [Intermediate 15-d] and bis(4-biphenylyl)amine instead of [Intermediate 1-k] and N-phenyl-4-biphenylamine, respectively, to afford [Chemical Formula 294] (yield 48%).

MS (MALDI-TOF): m/z 978.45 [M⁺]

### Synthesis of Dopant Materials

### Synthesis Example 16: Synthesis of Compound 3

### Synthesis Example 16-(1): Synthesis of [Intermediate 16-a]

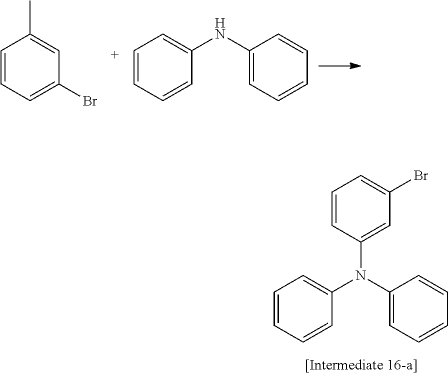

In a 1-L reactor, diphenylamine (30 g, 177 mmol), 1-bromo-3-iodobenzene (55.1 g, 195 mmol), tris(dibenzylideneacetone)palladium (6.5 g, 7 mmol), sodium tert-butoxide (51.2 g, 532 mmol), 2,2′-bis(diphenylphosphino)-1,1′-binaphthyl (2.5 g, 7 mmol), and toluene (300 ml) were fluxed for 24 hrs. After completion of the reaction, the reaction mixture was filtered and concentrated. Purification by column chromatography afforded [Intermediate 16-a] (29 g, 75%).

### Synthesis Example 16-(2): Synthesis of [Intermediate 16-b]

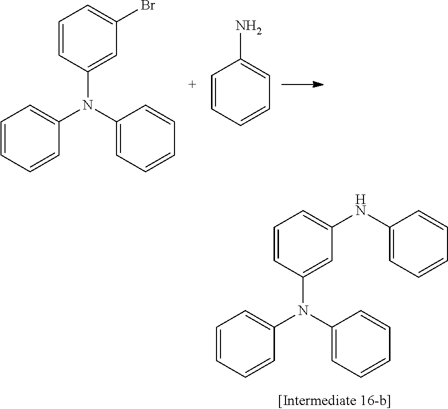

In a 1-L reactor, [Intermediate 16-a] (32.9 g, 101 mmol), aniline (10.4 g, 112 mmol), palladiumacetate (0.5 g, 2 mmol), sodium tert-butoxide (19.5 g, 203 mmol), bis(diphenylphosphino)-1,1′-binaphthyl (1.3 g, 2 mmol), and toluene (320 mL) were fluxed for 24 hrs. After completion of the reaction, the reaction mixture was filtered and concentrated. Purification by column chromatography afforded [Intermediate 16-b] (28 g, 72%).

### Synthesis Example 16-(3): Synthesis of [Intermediate 16-c]

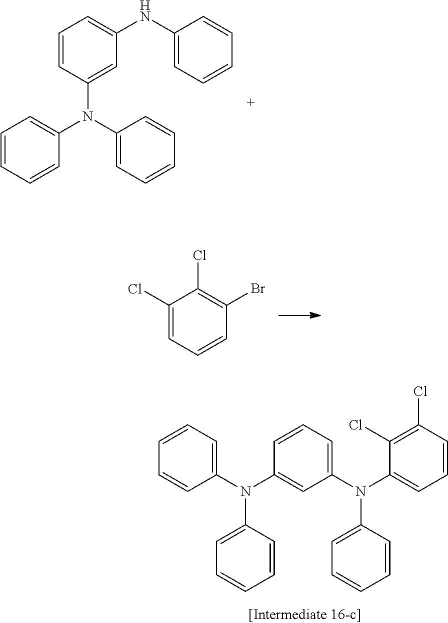 [SMILES: c1ccc(Nc2cccc(N(c3ccccc3)c3ccccc3)c2)cc1 ; Clc1cccc(Br)c1Cl ; Clc1cccc(N(c2ccccc2)c2cccc(N(c3ccccc3)c3ccccc3)c2)c1Cl]

In a 1-L reactor, [Intermediate 16-b] (28 g, 83 mmol), 1-bromo-2,3-dichlorobenzene (20.7 g, 92 mmol), tris(dibenzelideneacetone)palladium (1.6 g, 2 mmol), sodium tert-butoxide (16 g, 166 mmol), tri-tert-butylphosphine (0.7 g, 3 mmol), and toluene (300 ml) were fluxed for 24 hrs. After completion of the reaction, the reaction mixture was filtered and concentrated. Purification by column chromatography afforded [Intermediate 16-c] (29.2 g, 75%).

### Synthesis Example 16-(4): Synthesis of [Intermediate 16-d]

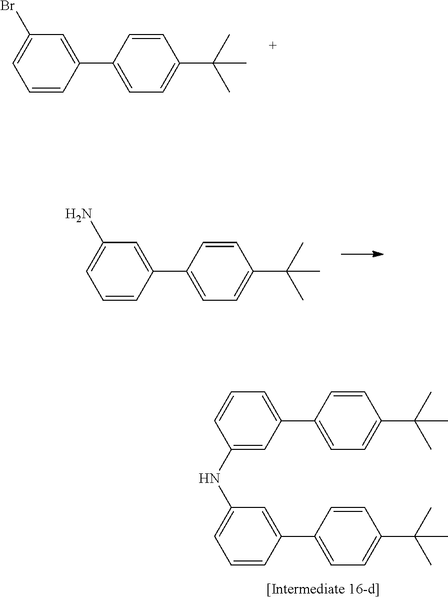 [SMILES: CC(C)(C)c1ccc(-c2cccc(Br)c2)cc1 ; CC(C)(C)c1ccc(-c2cccc(N)c2)cc1 ; CC(C)(C)c1ccc(-c2cccc(Nc3cccc(-c4ccc(C(C)(C)C)cc4)c3)c2)cc1]

In a 1-L reactor, 3-bromo-4′-(tert-butyl)-1,1′-biphenyl (39.9 g, 138 mmol), 3-(4-tert-butylphenyl)aniline (31.1 g, 138 mmol), palladiumacetate (0.6 g, 3 mmol), sodium tert-butoxide (26.5 g, 276 mmol), bis(diphenylphosphino)-1,1′-binaphthyl (1.7 g, 3 mmol), and toluene (400 mL) were fluxed for 24 hrs. After completion of the reaction, the reaction mixture was filtered and concentrated. Purification by column chromatography afforded [Intermediate 16-d] (26.3 g, 62%).

### Synthesis Example 16-(5): Synthesis of [Intermediate 16-e]

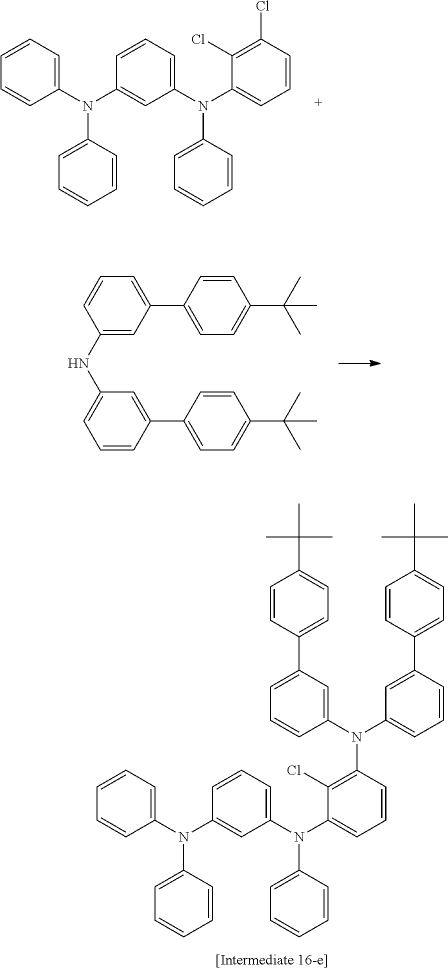 [SMILES: Clc1cccc(N(c2ccccc2)c2cccc(N(c3ccccc3)c3ccccc3)c2)c1Cl ; CC(C)(C)c1ccc(-c2cccc(Nc3cccc(-c4ccc(C(C)(C)C)cc4)c3)c2)cc1 ; CC(C)(C)c1ccc(-c2cccc(N(c3cccc(-c4ccc(C(C)(C)C)cc4)c3)c3cccc(N(c4ccccc4)c4cccc(N(c5ccccc5)c5ccccc5)c4)c3Cl)c2)cc1]

In a 1-L reactor, [Intermediate 16-c] (29.2 g, 61 mmol), [Intermediate 16-d] (26.3 g, 61 mmol), tris(dibenzelideneacetone)palladium (1.1 g, 1 mmol), sodium tert-butoxide (11.7 g, 121 mmol), tri-tert-butylphosphine (0.5 g, 2 mmol), and toluene (300 ml) were fluxed for 24 hrs. After completion of the reaction, the reaction mixture was filtered and concentrated. Purification by column chromatography afforded [Intermediate 16-e] (32.4 g, 61%).

### Synthesis Example 16-(6): Synthesis of [Compound 3]

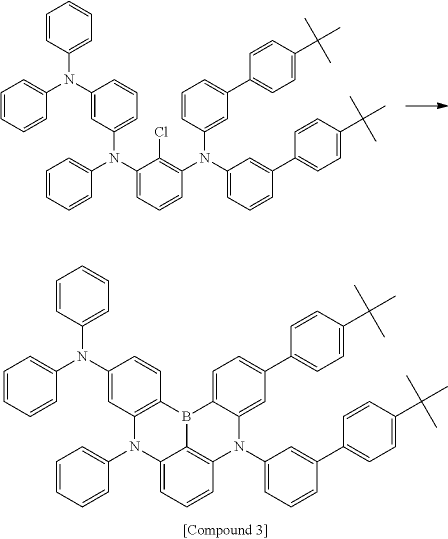 [SMILES: CC(C)(C)c1ccc(-c2cccc(N(c3cccc(-c4ccc(C(C)(C)C)cc4)c3)c3cccc(N(c4ccccc4)c4cccc(N(c5ccccc5)c5ccccc5)c4)c3Cl)c2)cc1 ; CC(C)(C)c1ccc(-c2cccc(N3c4cc(-c5ccc(C(C)(C)C)cc5)ccc4B4c5ccc(N(c6ccccc6)c6ccccc6)cc5N(c5ccccc5)c5cccc3c54)c2)cc1]

In a 1-L reactor, [Intermediate 16-e] (32.4 g, 37 mmol) was dissolved in tert-butylbenzene to which tert-butyl lithium (42.4 mL, 74 mmol) was then dropwise added at −78° C., followed by stirring for 3 hrs at 60° C. At the same temperature, the reactor was purged with nitrogen to remove pentane. Drops of boron tribromide (7.1 mL, 74 mmol) were added at −78° C. and stirred for 1 hr at room temperature. Addition of drops of N,N-diisoprophylethylamine (6 g, 74 mmol) at 0° C. was followed by stirring for 2 hrs at 120° C. After completion of the reaction, an aqueous sodium acetate solution was added and stirred. Following extraction with ethyl acetate, the organic layer was concentrated and isolated by column chromatography to afford [Compound 3] (3.0 g, 25%).

MS (MALDI-TOF): m/z 851.44 [M⁺]

### Synthesis Example 17: Synthesis of Compound 5

### Synthesis Example 17-(1): Synthesis of [Intermediate 17-a]

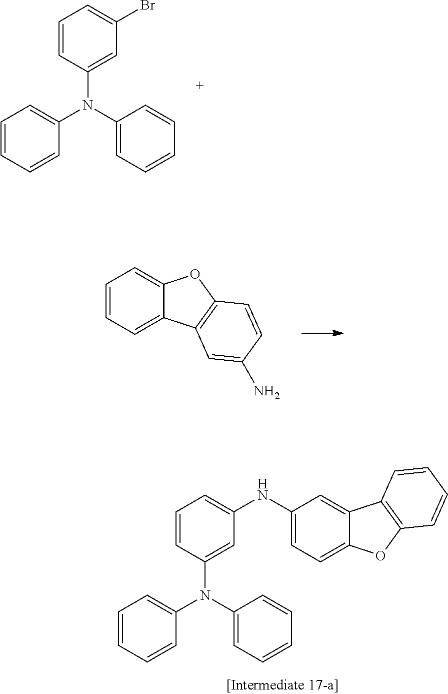 [SMILES: Brc1cccc(N(c2ccccc2)c2ccccc2)c1 ; Nc1ccc2oc3ccccc3c2c1 ; c1ccc(N(c2ccccc2)c2cccc(Nc3ccc4oc5ccccc5c4c3)c2)cc1]

The same procedure as in Synthesis Example 16-(2) was carried out, with the exception of using 2-dibenzofuran amine instead of aniline, to afford [Intermediate 17-a] (yield 74%).

### Synthesis Example 17-(2): Synthesis of [Intermediate 17-b]

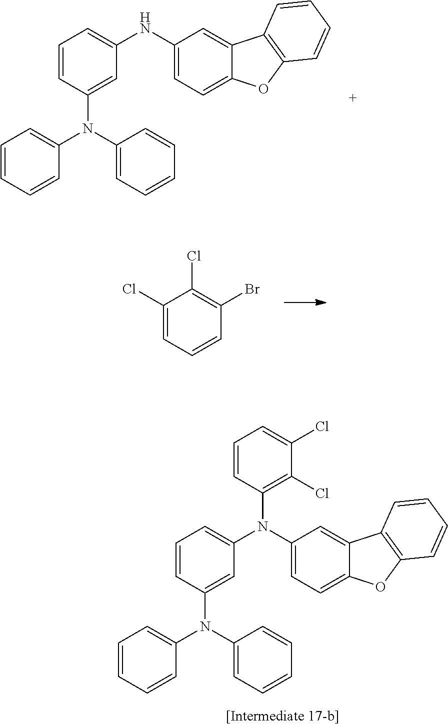 [SMILES: c1ccc(N(c2ccccc2)c2cccc(Nc3ccc4oc5ccccc5c4c3)c2)cc1 ; Clc1cccc(Br)c1Cl ; Clc1cccc(N(c2cccc(N(c3ccccc3)c3ccccc3)c2)c2ccc3oc4ccccc4c3c2)c1Cl]

The same procedure as in Synthesis Example 16-(3) was carried out, with the exception of using [Intermediate 17-a] instead of [Intermediate 16-b], to afford [Intermediate 17-b] (yield 72%).

### Synthesis Example 17-(3): Synthesis of [Intermediate 17-c]

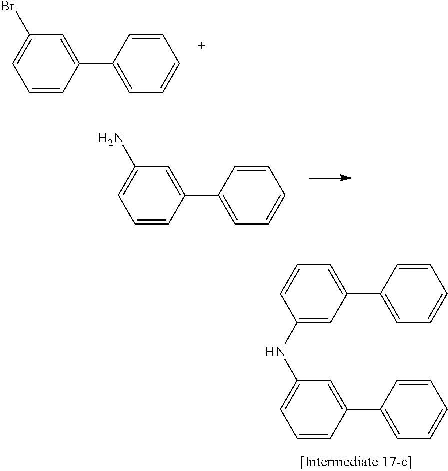

The same procedure as in Synthesis Example 16-(4) was carried out, with the exception of using 3-bromo-1,1′-biphenyl and 3-aminobiphenyl instead of 3-bromo-4′-(tert-butyl)-1,1′-biphenyl and 3-(4-tert-butylphenyl)aniline, respectively, to afford [Intermediate 17-c] (yield 65%).

### Synthesis Example 17-(4): Synthesis of [Intermediate 17-d]

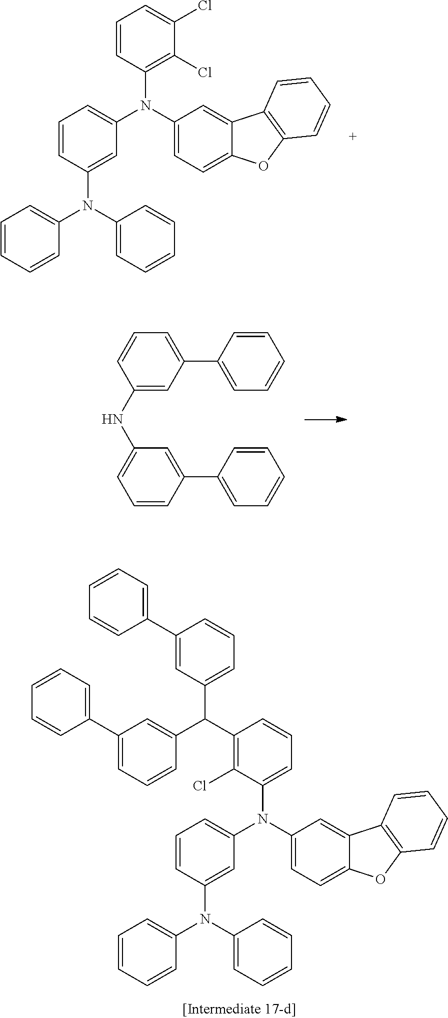 [SMILES: Clc1cccc(N(c2cccc(N(c3ccccc3)c3ccccc3)c2)c2ccc3oc4ccccc4c3c2)c1Cl ; c1ccc(-c2cccc(Nc3cccc(-c4ccccc4)c3)c2)cc1 ; Clc1c(C(c2cccc(-c3ccccc3)c2)c2cccc(-c3ccccc3)c2)cccc1N(c1cccc(N(c2ccccc2)c2ccccc2)c1)c1ccc2oc3ccccc3c2c1]

The same procedure as in Synthesis Example 16-(5) was carried out, with the exception of using [Intermediate 17-b] and [Intermediate 17-c] instead of [Intermediate 16-c] and [Intermediate 16-d], respectively, to afford [Intermediate 17-d] (yield 62%).

### Synthesis Example 17-(5): Synthesis of [Compound 5]

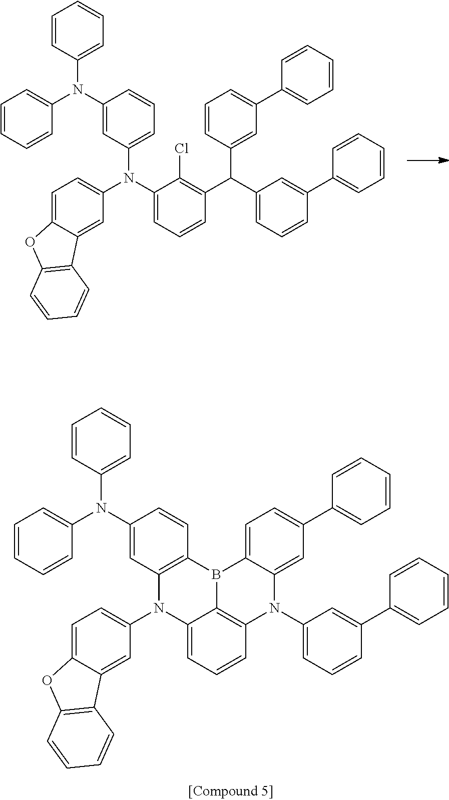 [SMILES: Clc1c(C(c2cccc(-c3ccccc3)c2)c2cccc(-c3ccccc3)c2)cccc1N(c1cccc(N(c2ccccc2)c2ccccc2)c1)c1ccc2oc3ccccc3c2c1 ; c1ccc(-c2cccc(N3c4cc(-c5ccccc5)ccc4B4c5ccc(N(c6ccccc6)c6ccccc6)cc5N(c5ccc6oc7ccccc7c6c5)c5cccc3c54)c2)cc1]

The same procedure as in Synthesis Example 16-(6) was carried out, with the exception of using [Intermediate 17-d] instead of [Intermediate 16-e], to afford [Compound 5] (yield 24%).

MS (MALDI-TOF): m/z 829.33 [M⁺]

### Examples 1 to 30: Fabrication of Organic Light-Emitting Diode

An ITO glass substrate was patterned to have a translucent area of 2 mm×2 mm and cleansed. The ITO glass was mounted in a vacuum chamber that was then set to have a base pressure of 1×10⁻⁷ torr. On the ITO glass substrate, films were sequentially formed of DNTPD (700 Å) and each of the compounds listed in Table 1 below. A light-emitting layer (250 Å) was formed of [BH] as a host and 3% of each of the compounds list in Table 1 as a dopant. Then, [Chemical Formula E-1] was deposited to form an electron transport layer (300 Å), on which an electron injection layer of Liq (5 Å) was formed and then covered with an Al layer (1000 Å) to fabricate an organic light-emitting diode. The organic light-emitting diodes thus obtained were measured at 0.4 mA for luminescence properties:

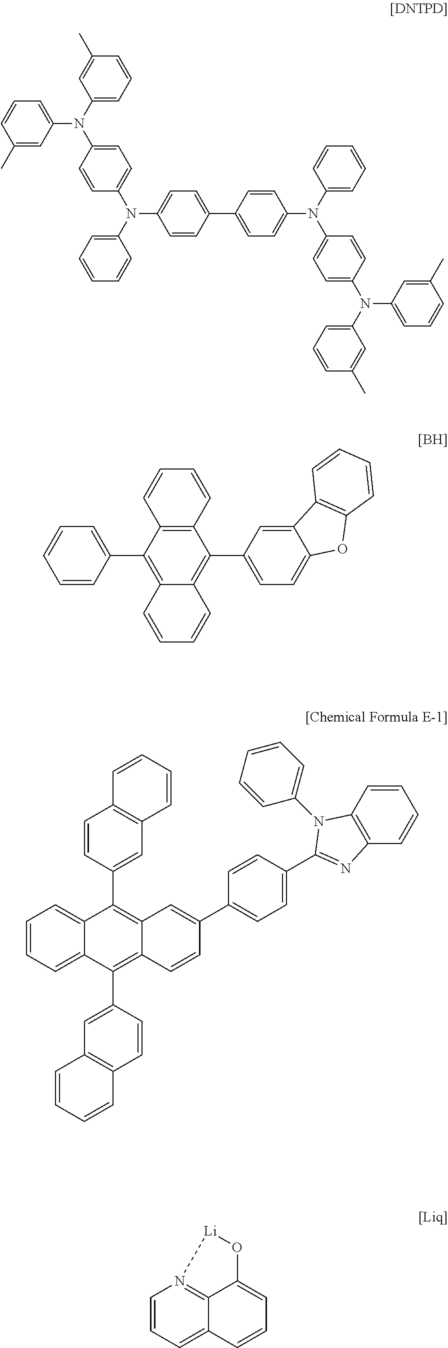

### Comparative Examples 1 to 2

An organic light-emitting diode was fabricated in the same manner as in Example 1, with the exception that [HT] was used, instead of the compounds used for the hole transport layer in Examples 1 to 30. The luminescence of the organic light-emitting diode was measured at 0.4 mA and the measurements are summarized in Table 1. The structure of [HT] is as follows:

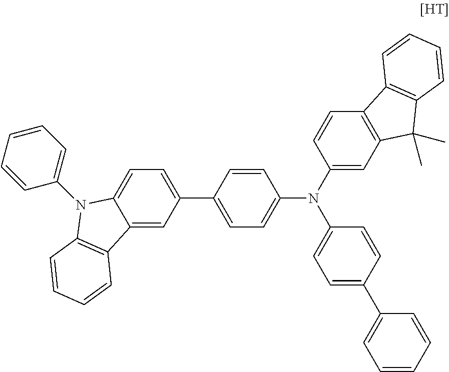 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

### Comparative Examples 3 to 17

An organic light-emitting diode was fabricated in the same manner as in Examples 1 to 15, with the exception that [BD] was used, instead of the dopant compound used in Examples 1 to 15. The luminescence of the organic light-emitting diodes thus obtained was measured at 0.4 mA and the measurements are summarized in Table 1. The structure of [BD] is as follows:

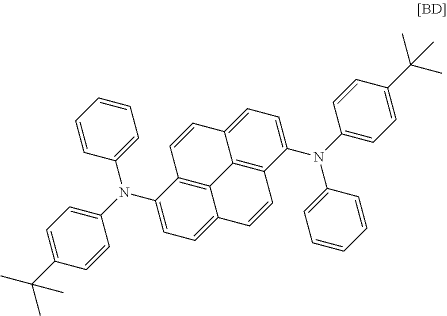 [SMILES: CC(C)(C)c1ccc(N(c2ccccc2)c2ccc3ccc4c(N(c5ccccc5)c5ccc(C(C)(C)C)cc5)ccc5ccc2c3c54)cc1]

### Comparative Example 18

An organic light-emitting diode was fabricated in the same manner as in Examples 1 to 30, with the exception that [HT] and [BD] were used instead of the hole transport layer compound and the dopant compound used in Examples 1 to 30, respectively. The luminescence of the organic light-emitting diode was measured at 0.4 mA and the measurements are summarized in Table 1.

TABLE 1

| | | | Current | | |
|---|---|---|---|---|---|
| | | | Density | | EQE |
| | HTL | Dopant | (mA/cm²) | Volt. | (%) |
| Example 1 | Chemical Formula 19 | Compound 3 | 10 | 3.5 | 10.4 |
| Example 2 | Chemical Formula 34 | Compound 3 | 10 | 3.4 | 10.9 |
| Example 3 | Chemical Formula 49 | Compound 3 | 10 | 3.4 | 12.3 |
| Example 4 | Chemical Formula 58 | Compound 3 | 10 | 3.4 | 11.8 |
| Example 5 | Chemical Formula 73 | Compound 3 | 10 | 3.5 | 11.2 |
| Example 6 | Chemical Formula 86 | Compound 3 | 10 | 3.5 | 11.4 |
| Example 7 | Chemical Formula 95 | Compound 3 | 10 | 3.4 | 10.9 |
| Example 8 | Chemical Formula 125 | Compound 3 | 10 | 3.6 | 10.3 |
| Example 9 | Chemical Formula 154 | Compound 3 | 10 | 3.5 | 10.7 |
| Example 10 | Chemical Formula 158 | Compound 3 | 10 | 3.5 | 11.2 |
| Example 11 | Chemical Formula 190 | Compound 3 | 10 | 3.6 | 10 |
| Example 12 | Chemical Formula 289 | Compound 3 | 10 | 3.4 | 10.5 |
| Example 13 | Chemical Formula 292 | Compound 3 | 10 | 3.4 | 10.8 |
| Example 14 | Chemical Formula 293 | Compound 3 | 10 | 3.5 | 12.1 |
| Example 15 | Chemical Formula 294 | Compound 3 | 10 | 3.5 | 11.6 |
| Example 16 | Chemical Formula 19 | Compound 5 | 10 | 3.5 | 10.7 |
| Example 17 | Chemical Formula 34 | Compound 5 | 10 | 3.5 | 11 |
| Example 18 | Chemical Formula 49 | Compound 5 | 10 | 3.4 | 11.4 |
| Example 19 | Chemical Formula 58 | Compound 5 | 10 | 3.5 | 10.5 |
| Example 20 | Chemical Formula 73 | Compound 5 | 10 | 3.5 | 10.4 |
| Example 21 | Chemical Formula 86 | Compound 5 | 10 | 3.5 | 10.8 |
| Example 22 | Chemical Formula 95 | Compound 5 | 10 | 3.6 | 11.2 |
| Example 23 | Chemical Formula 125 | Compound 5 | 10 | 3.6 | 10.9 |
| Example 24 | Chemical Formula 154 | Compound 5 | 10 | 3.6 | 11.7 |
| Example 25 | Chemical Formula 158 | Compound 5 | 10 | 3.5 | 10.4 |
| Example 26 | Chemical Formula 190 | Compound 5 | 10 | 3.5 | 10.5 |
| Example 27 | Chemical Formula 289 | Compound 5 | 10 | 3.4 | 10.7 |
| Example 28 | Chemical Formula 292 | Compound 5 | 10 | 3.5 | 11.2 |
| Example 29 | Chemical Formula 293 | Compound 5 | 10 | 3.5 | 10.9 |
| Example 30 | Chemical Formula 294 | Compound 5 | 10 | 3.5 | 11.4 |
| Comparative | HT | Compound 3 | 10 | 3.8 | 7.5 |
| Example 1 | | | | | |
| Comparative | HT | Compound 5 | 10 | 3.8 | 7.7 |
| Example 2 | | | | | |
| Comparative | Chemical Formula 19 | BD | 10 | 3.9 | 8.1 |
| Example 3 | | | | | |
| Comparative | Chemical Formula 34 | BD | 10 | 3.8 | 8.5 |
| Example 4 | | | | | |
| Comparative | Chemical Formula 49 | BD | 10 | 3.9 | 8.7 |
| Example 5 | | | | | |
| Comparative | Chemical Formula 58 | BD | 10 | 3.9 | 8 |
| Example 6 | | | | | |
| Comparative | Chemical Formula 73 | BD | 10 | 3.8 | 8.5 |
| Example 7 | | | | | |
| Comparative | Chemical Formula 86 | BD | 10 | 3.9 | 8.3 |
| Example 8 | | | | | |
| Comparative | Chemical Formula 95 | BD | 10 | 3.8 | 8.3 |
| Example 9 | | | | | |
| Comparative | Chemical Formula 125 | BD | 10 | 3.8 | 8.6 |
| Example 10 | | | | | |
| Comparative | Chemical Formula 154 | BD | 10 | 3.9 | 8.4 |
| Example 11 | | | | | |
| Comparative | Chemical Formula 158 | BD | 10 | 3.9 | 8.3 |
| Example 12 | | | | | |
| Comparative | Chemical Formula 190 | BD | 10 | 3.8 | 8.1 |
| Example 13 | | | | | |
| Comparative | Chemical Formula 289 | BD | 10 | 3.9 | 8.1 |
| Example 14 | | | | | |
| Comparative | Chemical Formula 292 | BD | 10 | 3.8 | 8.3 |
| Example 15 | | | | | |
| Comparative | Chemical Formula 293 | BD | 10 | 3.9 | 8.2 |
| Example 16 | | | | | |
| Comparative | Chemical Formula 294 | BD | 10 | 3.8 | 8.4 |
| Example 17 | | | | | |
| Comparative | HT | BD | 10 | 4.3 | 7.3 |
| Example 18 | | | | | |

As is understood from data of Table 1, the organic light-emitting diodes according to the present disclosure exhibit greater emission efficiencies compared to conventional organic light-emitting diodes of Comparative Examples 1 to 18 and thus have high industrial applicability.

1. An organic light-emitting diode, comprising: a first electrode; a second electrode facing the first electrode; a hole injection layer or a hole transport layer interposed between the first electrode and the second electrode; and a light-emitting layer,
wherein the hole injection layer or the hole transport layer comprises at least one of the amine compounds represented by the following Chemical Formula A or B and the light-emitting layer comprises at least one of the boron compounds represented by the following Chemical Formula C: 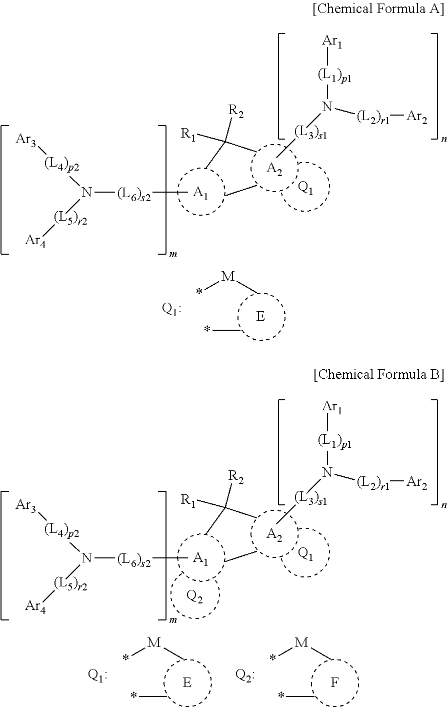
wherein,
A₁, A₂, E, and F, which are same or different, are each independently a substituted or unsubstituted aromatic hydrocarbon ring of 6 to 50 carbon atoms, or a substituted or unsubstituted heteroaromatic ring of 2 to 40 carbon atoms;
wherein two adjacent carbon atoms within the aromatic ring of A₁ and two adjacent carbon atoms within the aromatic ring of A₂ form a 5-membered ring with a carbon atom connected to both substituents R₁ and R₂, thus establishing a fused ring structure;
linkers L₁ to L₆, which are same or different, are each independently selected from among a single bond, a substituted or unsubstituted alkylene of 1 to 60 carbon atoms, a substituted or unsubstituted alkenylene of 2 to 60 carbon atoms, a substituted or unsubstituted alkynylene of 2 to 60 carbon atoms, a substituted or unsubstituted cycloalkylene of 3 to 60 carbon atoms, a substituted or unsubstituted heterocycloalkylene of 2 to 60 carbon atoms, a substituted or unsubstituted arylene of 6 to 60 carbon atoms, and a substituted or unsubstituted heteroarylene of 2 to 60 carbon atoms;
M is selected from among N—R₃, CR₄R₅, SiR₆R₇, GeR₈R₉, O, S, and Se;
R₁ to R₉ and Ar₁ to Ar₄, which are same or different, are each independently selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted alkenyl of 2 to 30 carbon atoms, a substituted or unsubstituted alkynyl of 2 to 20 carbon atoms, a substituted or unsubstituted cycloalkyl of 3 to 30 carbon atoms, a substituted or unsubstituted cycloalkenyl of 5 to 30 carbon atoms, a substituted or unsubstituted heteroaryl of 2 to 50 carbon atoms, a substituted or unsubstituted heterocycloalkyl of 2 to 30 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted alkylamine of 1 to 30 carbon atoms, a substituted or unsubstituted arylamine of 6 to 30 carbon atoms, a substituted or unsubstituted alkylsilyl of 1 to 30 carbon atoms, a substituted or unsubstituted arylsilyl of 6 to 30 carbon atoms, a substituted or unsubstituted alkyl germanium of 1 to 30 carbon atoms, a substituted or unsubstituted aryl germanium of 1 to 30 carbon atoms, a cyano, a nitro, and a halogen,
wherein R₁ and R₂ may be connected to each other to form a mono- or polycyclic aliphatic or aromatic ring which bears at least one heteroatom selected from among N, O, P, Si, S, Ge, Se, and Te as a ring member;
p1 and p2, r1 and r2, and s1 and s2 are each independently an integer of 1 to 3, under which when any of them is 2 or greater, the corresponding linkers L₁ to L₆ are same or different,
m and n, which are same or different, are each independently an integer of 0 or 1, with a proviso of m+n=1 or 2,
Ar₁ and Ar₂ may be connected to each other to form a ring and Ara and Ar₄ can be connected to each other to form a ring;
two adjacent carbon atoms of the A₂ ring moiety of Chemical Formula A occupy respective positions * of Structural Formula Q₁ to form a fused ring,
two adjacent carbon atoms of the A₂ ring moiety of Chemical Formula B occupy respective positions * of Structural Formula Q₁ to form a fused ring and two adjacent carbon atoms of the A₁ ring moiety of Chemical Formula B occupy respective positions * of structural Formula Q₂ to form a fused ring 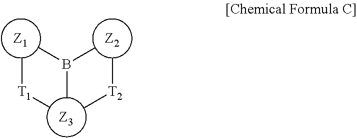
wherein,
Z₁ to Z₃, which are same or different, are each independently a substituted or unsubstituted aromatic hydrocarbon ring of 6 to 50 carbon atoms, or a substituted or unsubstituted heteroaromatic ring of 2 to 40 carbon atoms;
T₁ is selected from among N—R₁₁, CR₁₂R₁₃, O, and S;
T₂ is selected from among N—R₁₄, CR₁₅R₁₆, O, and S;
wherein R₁₁ to R₁₆, which are same or different, are each independently selected from among a hydrogen atom, a deuterium atom, a substituted or unsubstituted alkyl of 1 to 30 carbon atoms, a substituted Or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen wherein R₁₁ to R₁₆ can each be linked to at least one of Z₁ to Z₃ to further form a mono- or polycyclic aliphatic or aromatic ring,
wherein the term “substituted” in the expression “substituted or unsubstituted” used for [Chemical Formula A] to [Chemical Formula C] means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, an alkenyl of 2 to 24 carbon atoms, an alkynyl of 2 to 24 carbon atoms, a heteroalkyl of 1 to 24 carbon atoms, an aryl of 6 to 24 carbon atoms, an arylalkyl of 7 to 24 carbon atoms, a heteroaryl of 2 to 24 carbon atoms or a heteroarylalkyl of 2 to 24 carbon atoms, an alkoxy of 1 to 24 carbon atoms, an alkylamino of 1 to 24 carbon atoms, an arylamino of 6 to 24 carbon atoms, a heteroarylamino of 1 to 24 carbon atoms, an alkylsilyl of 1 to 24 carbon atoms, an arylsilyl of 6 to 24 carbon atoms, and an aryloxy of 6 to 24 carbon atoms.

2. The organic light-emitting diode of claim 1, wherein the light emitting-layer comprises a host and a dopant
wherein the boron compound represented by Chemical Formula C is used as the dopant.

3. The organic light-emitting diode of claim 1, wherein A₁, A₂, E, and F in Chemical Formula A or B are same or different and are each be independently a substituted or unsubstituted aromatic hydrocarbon ring of 6 to 50 carbon atoms.

4. The organic light-emitting diode of claim 3, wherein the substituted or unsubstituted aromatic hydrocarbon rings of 6 to 50 carbon atoms are same or different and are each independently selected from among [Structural Formula 10] to [Structural Formula 21]: 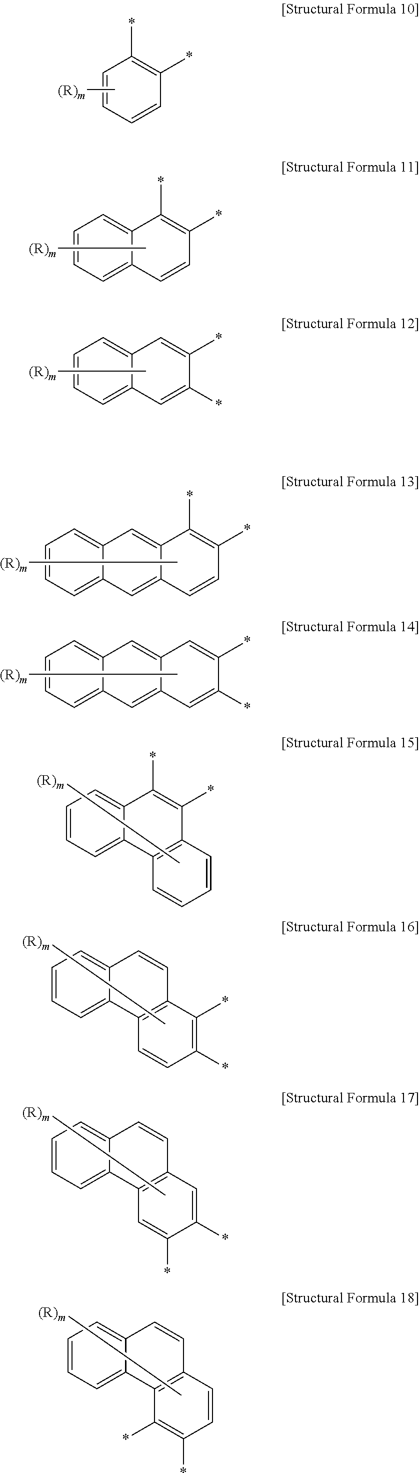 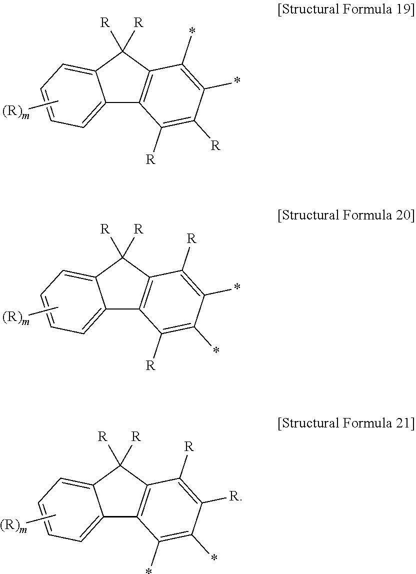
wherein,
“-*” denotes a bonding site participating in forming a 5-membered ring bearing the carbon atom connected to both substituents R₁ and R₂ as a ring member or in forming a 5-membered ring bearing M of structural formula Q₁ or Q₂ as a ring member;
when the aromatic hydrocarbon ring corresponds to the A₁ ring or the A₂ ring and is connected to structure formula Q₁ or Q₂, two adjacent carbon atoms within the ring are linked to * of structural formula Q₁ or Q₂ to form a fused ring;
R is as defined for R₁ and R₂ above; and
m is an integer of 1 to 8 wherein when m is 2 or greater or when R is 2 or greater, the resulting R is same or different.

5. The organic light-emitting diode of claim 1, wherein the linkers L₁ to L₆ are each a single bond or one selected from among the following [Structural Formula 22] to [Structural Formula 30]: 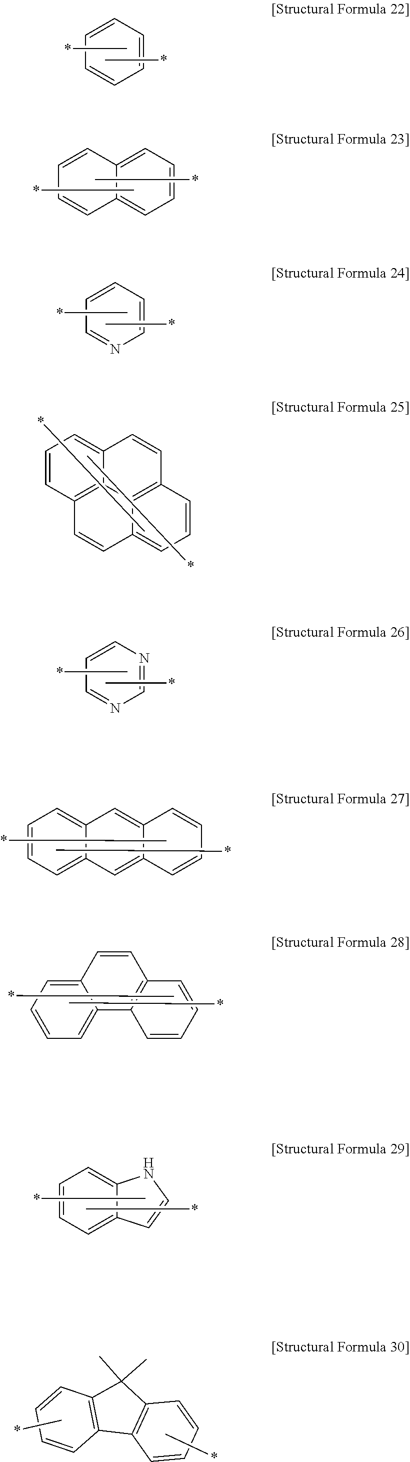
wherein each of unsubstituted carbon atoms of the aromatic ring moiety is bound with a hydrogen atom or a deuterium atom.

6. The organic light-emitting diode of claim 1, wherein M in Chemical Formula A or B is an oxygen atom (O) or a sulfur atom (S).

7. The organic light-emitting diode of claim 1, wherein Ar₁ to Ar₄ in Chemical Formula A or B are same or different and are each independently selected from the group among a substituted or unsubstituted alkyl of 1 to 30 carbon atoms, a substituted or unsubstituted aryl of 6 to 50 carbon atoms, a substituted or unsubstituted heteroaryl of 2 to 50 carbon atoms, a substituted or unsubstituted alkylsilyl of 1 to 30 carbon atoms, and a cyano.

8. The organic light-emitting diode of claim 1, wherein the amine compound is a monoamine compound satisfying the condition of m+n=1.

9. The organic light-emitting diode of claim 8, wherein m is 0 and n is 1 in Chemical Formula A.

10. The organic light-emitting diode of claim 1, wherein m and n are each 1.

11. The organic light-emitting diode of claim 1, wherein the amine compound is selected from among the compounds represented by the following <Chemical Formula 1> to <Chemical Formula 300>:

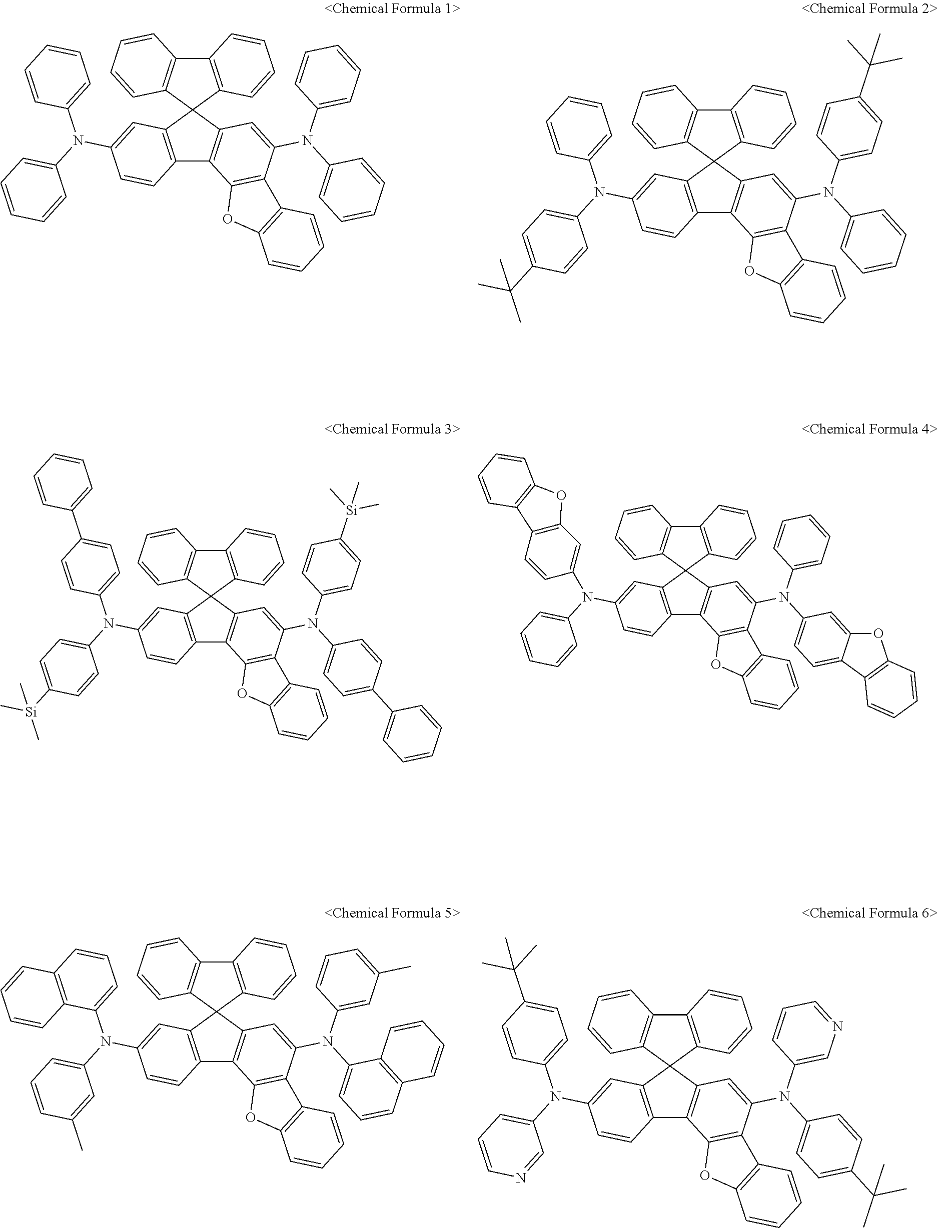

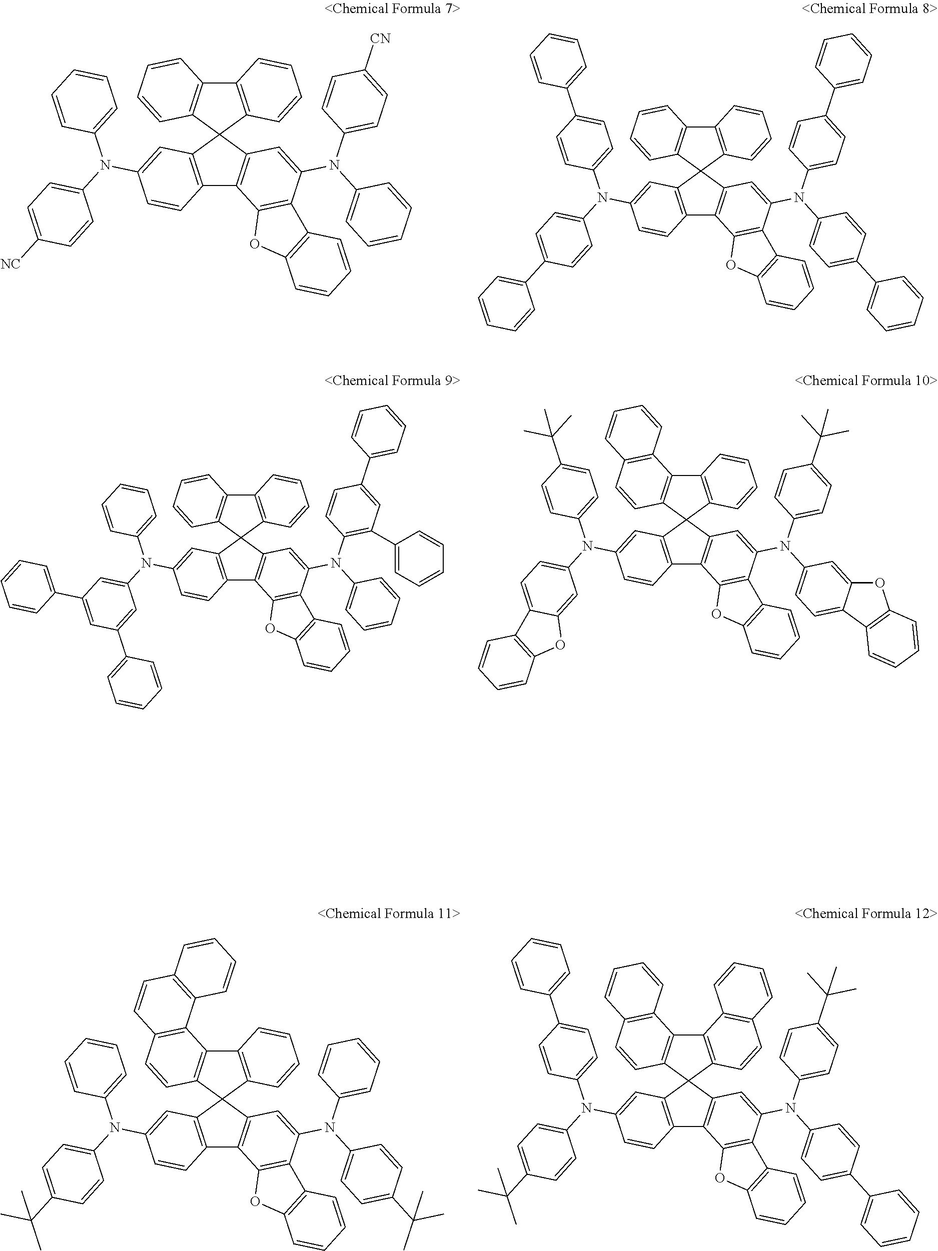

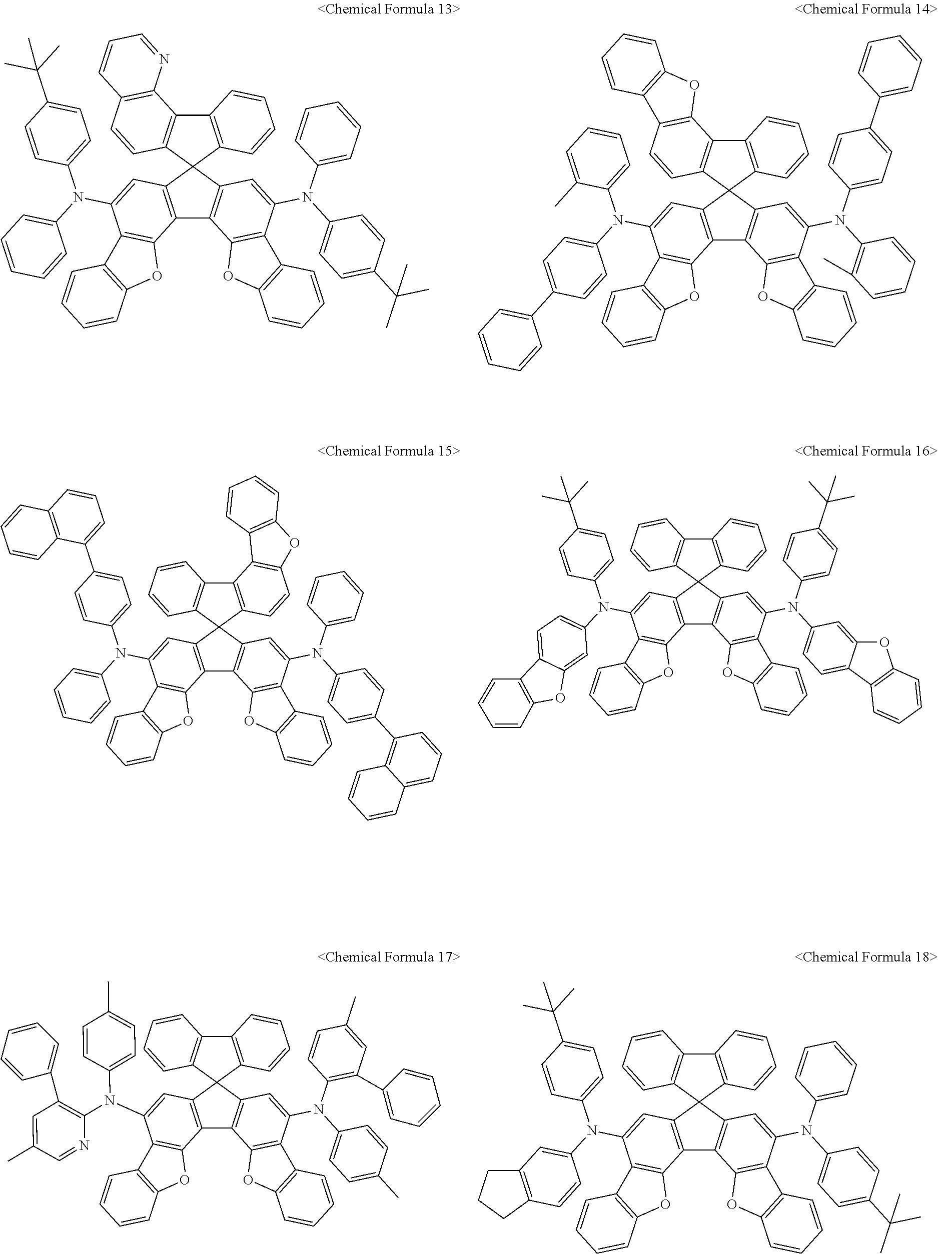

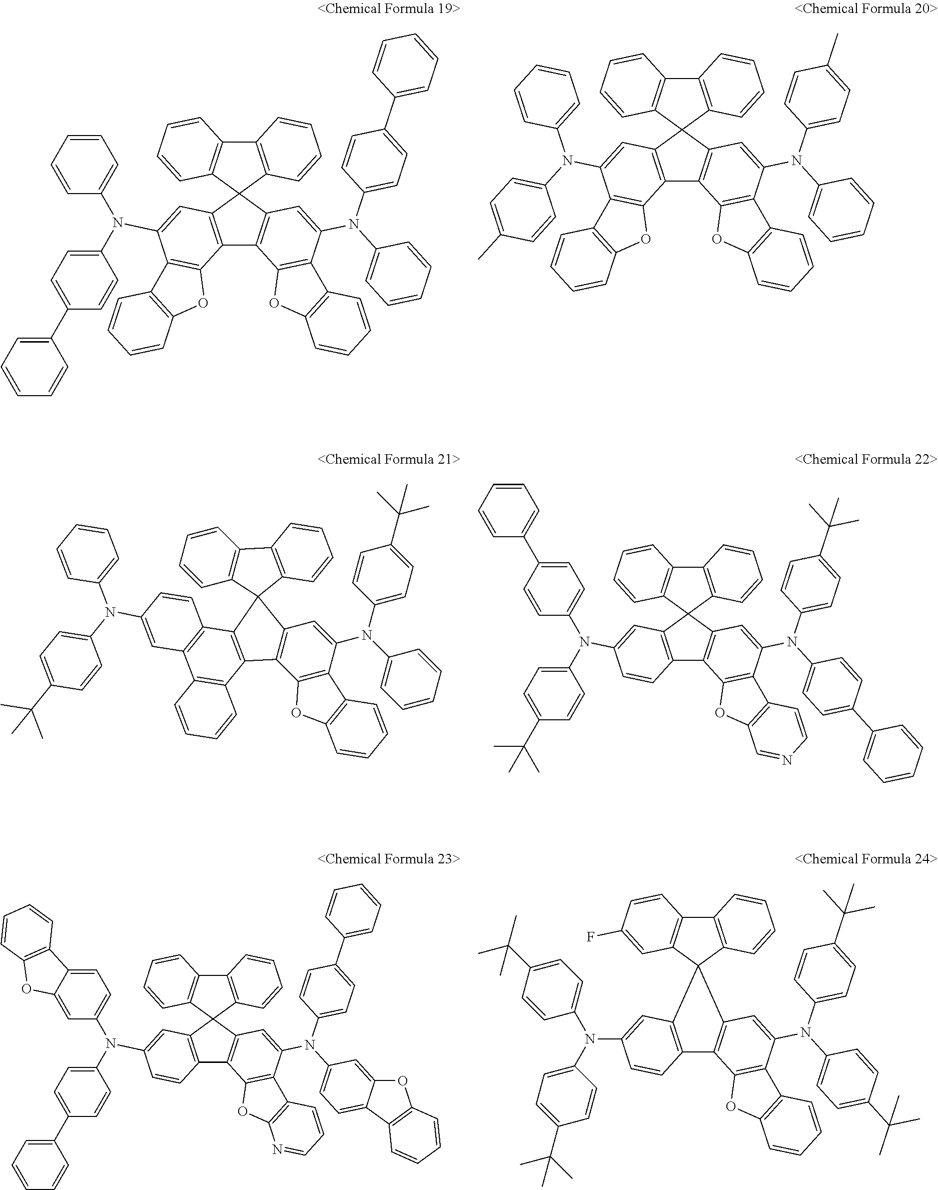

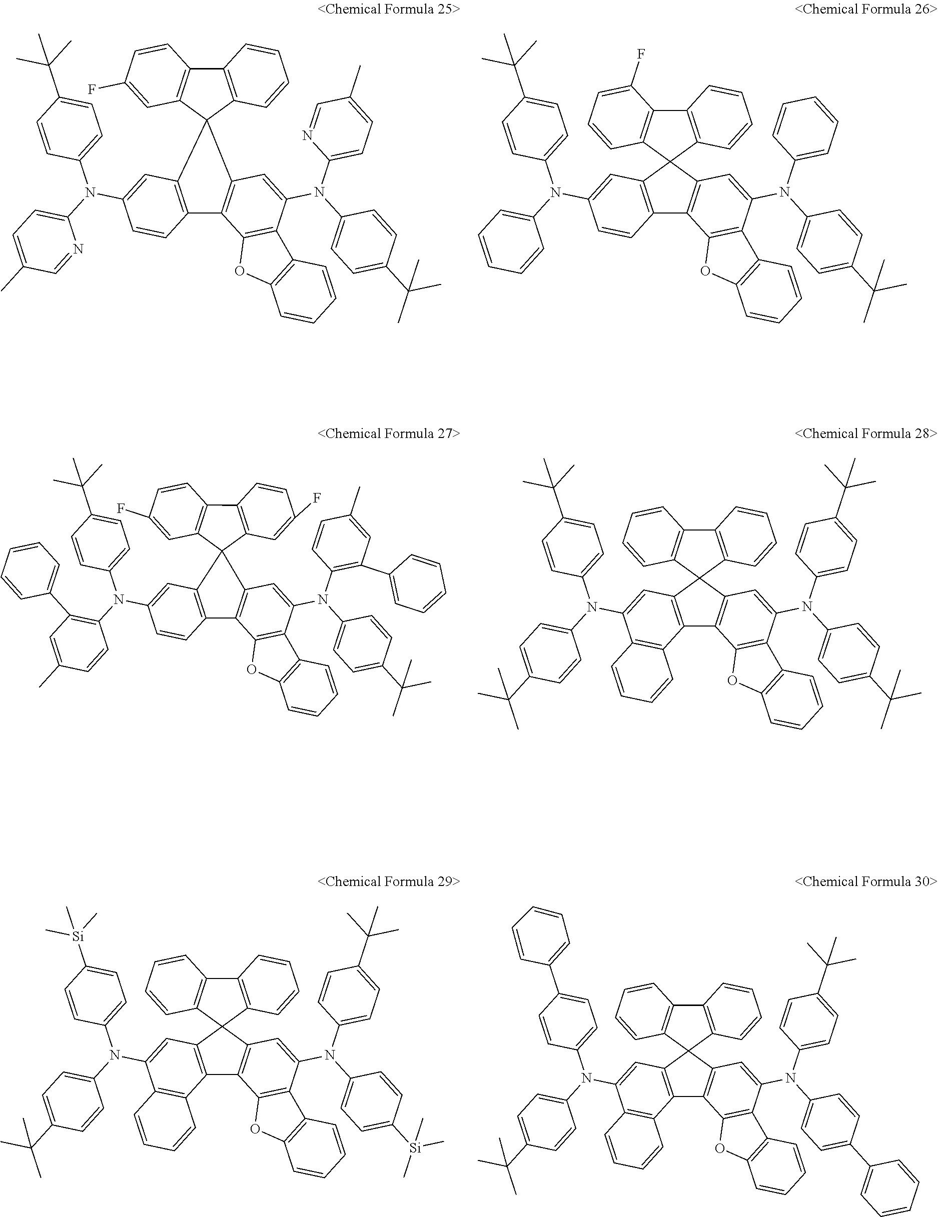

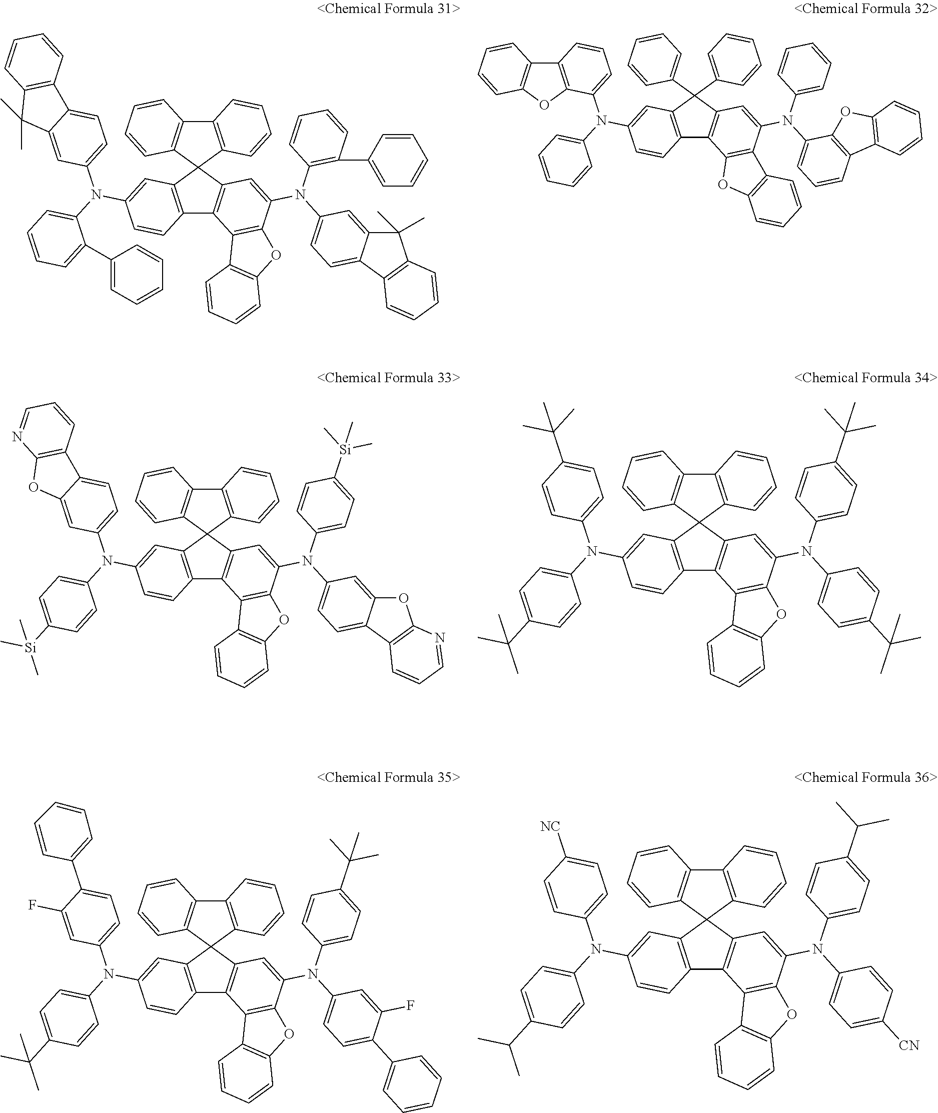

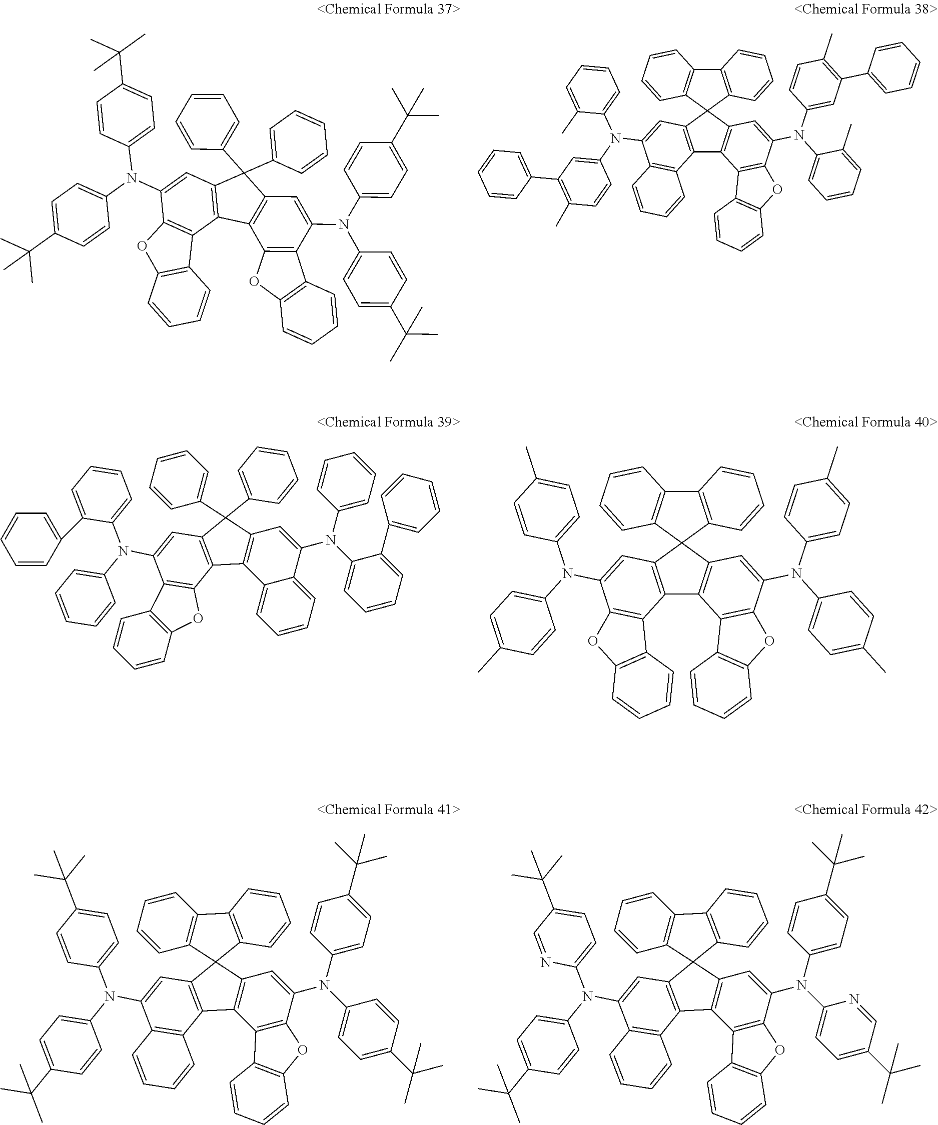

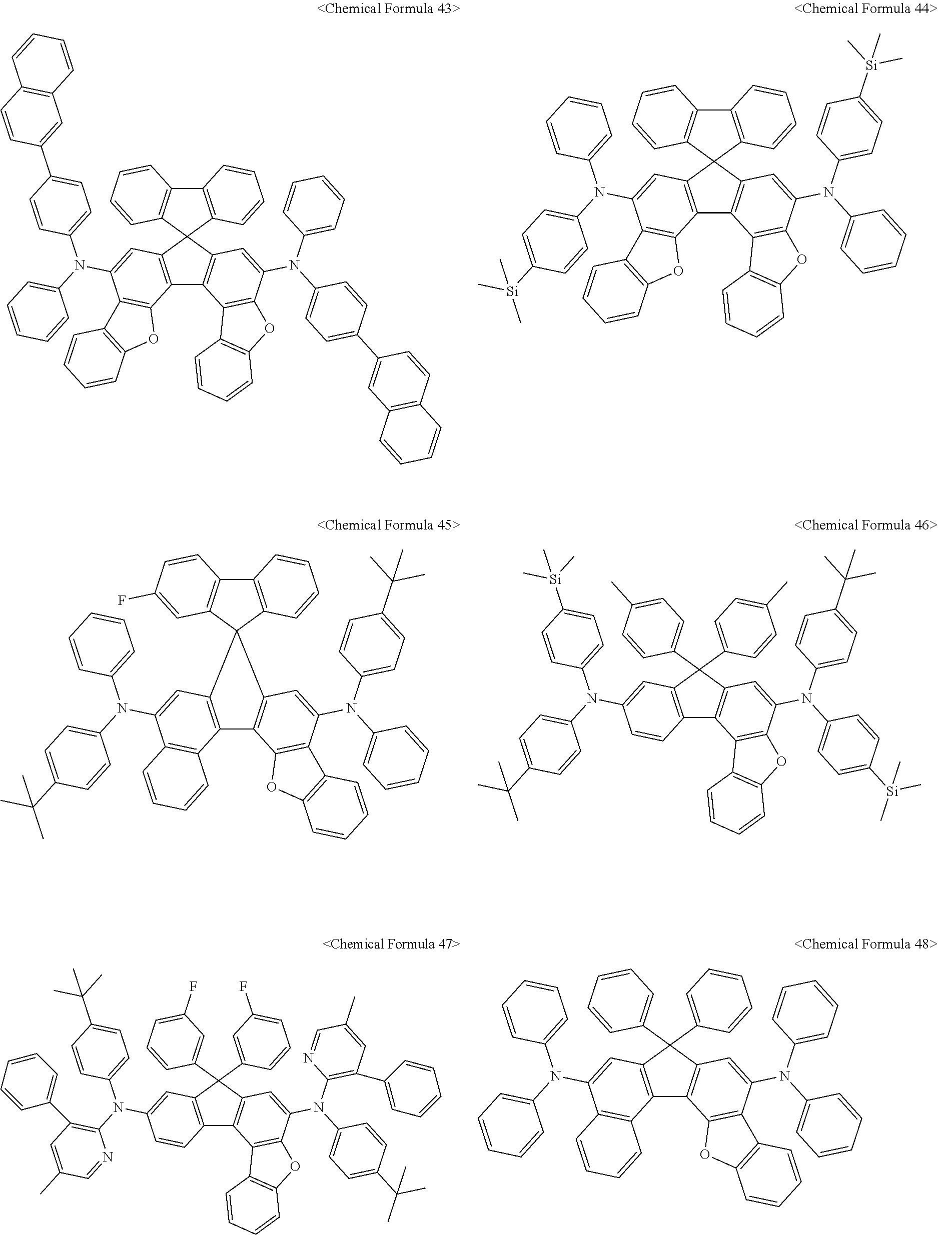

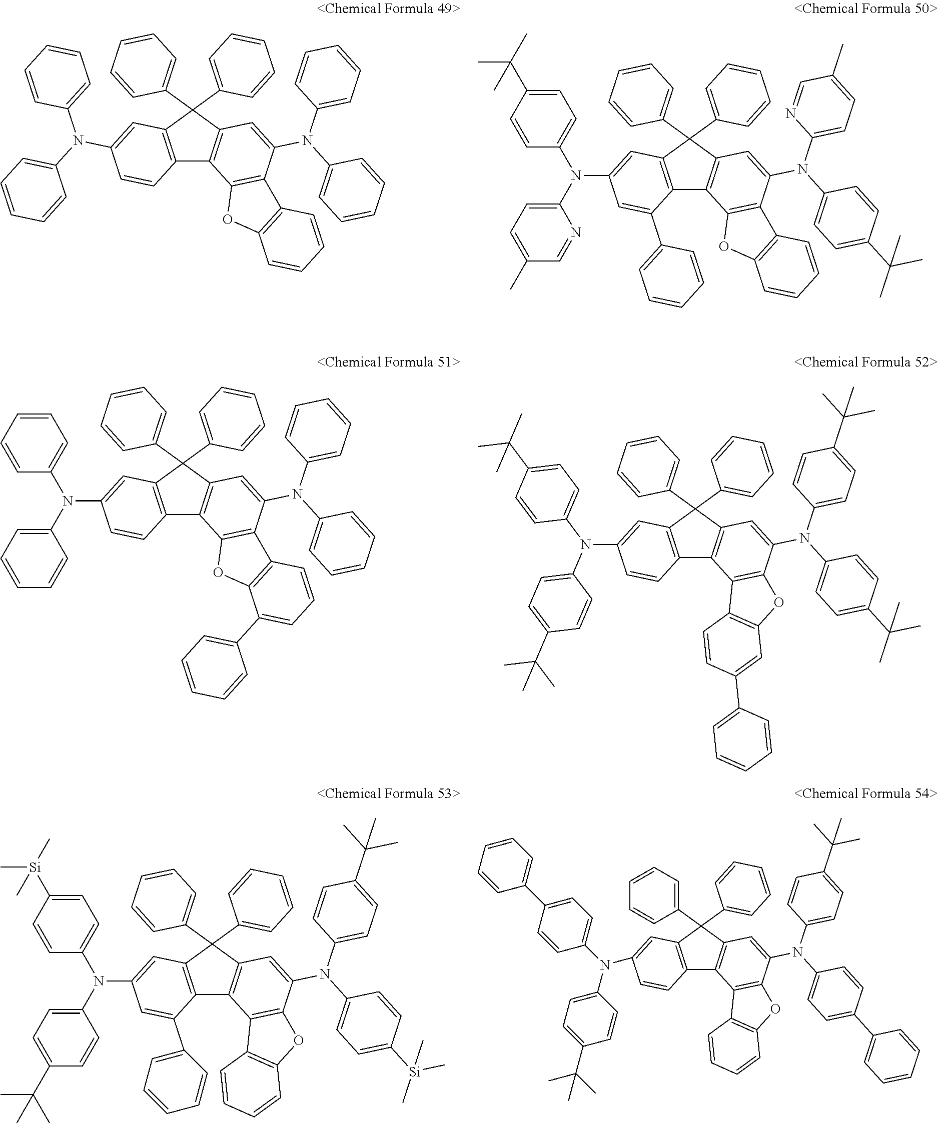

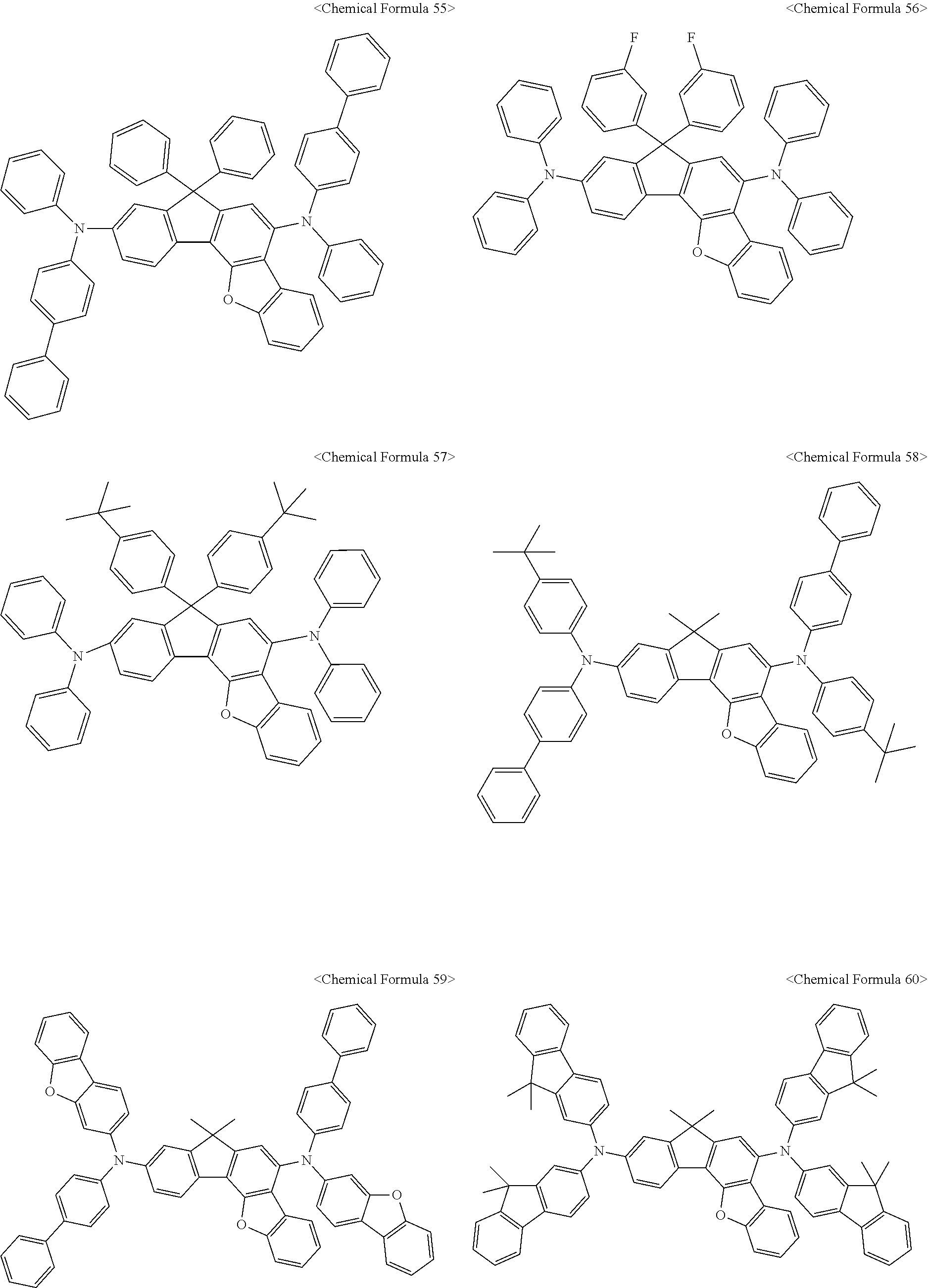

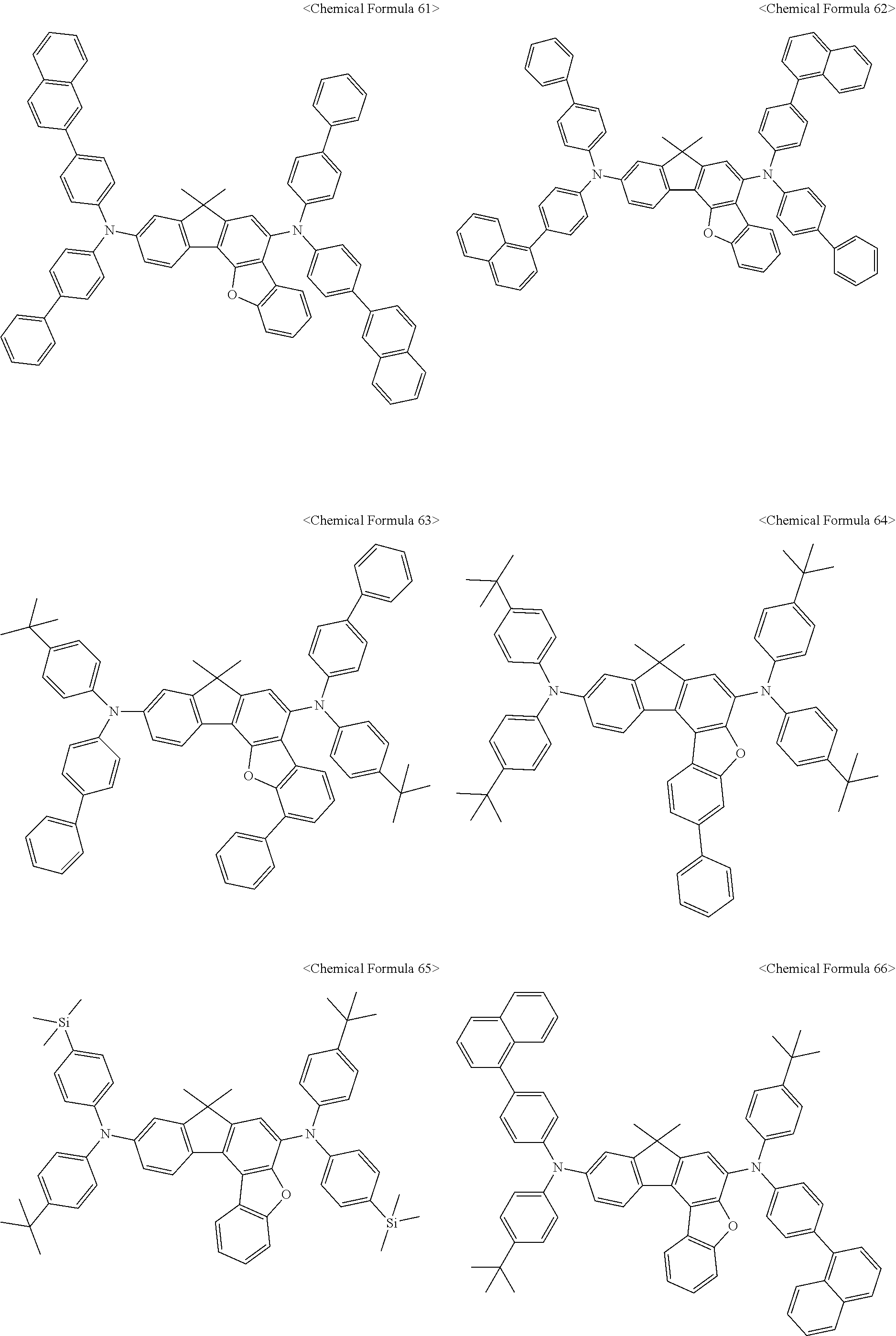

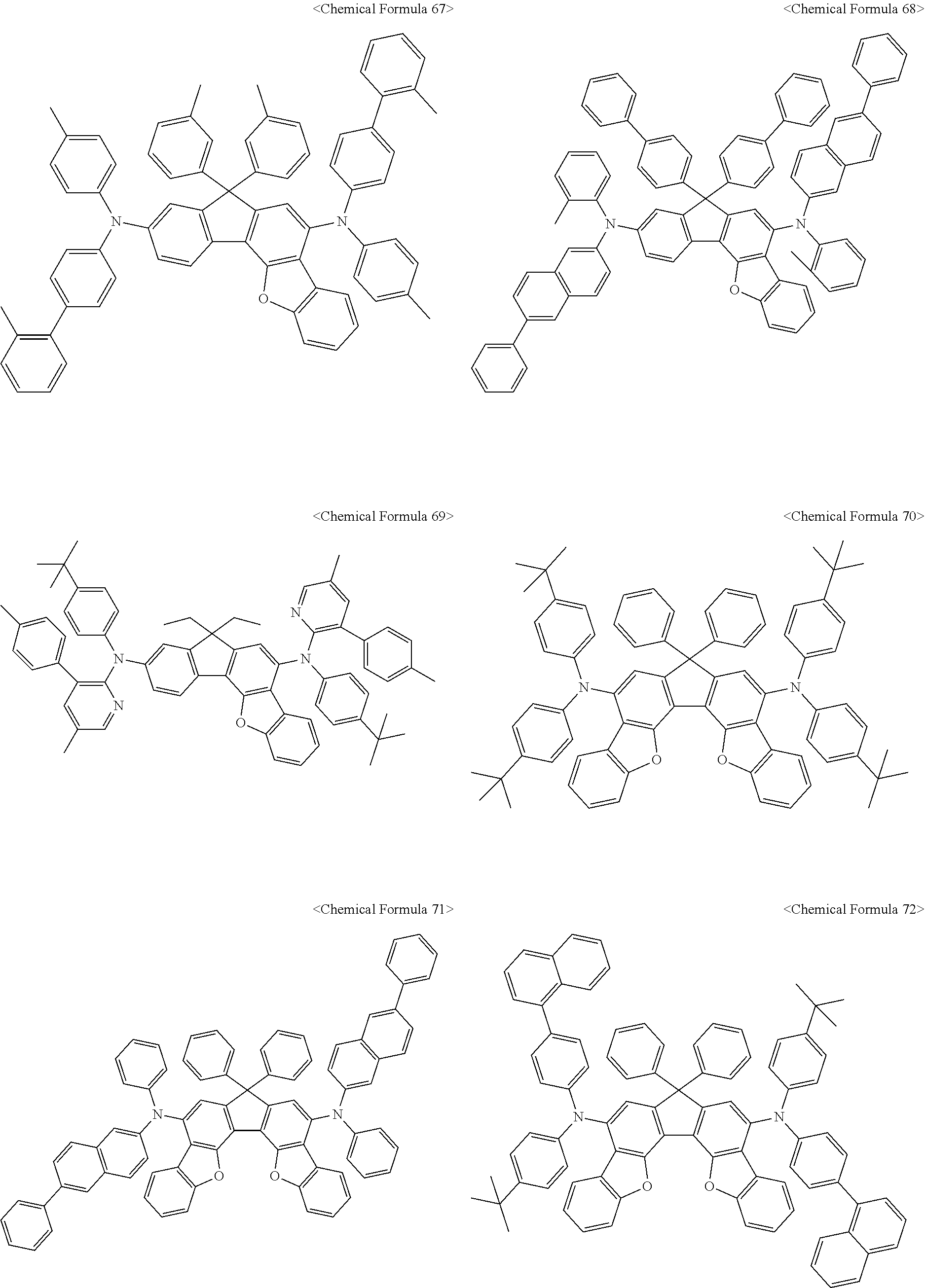

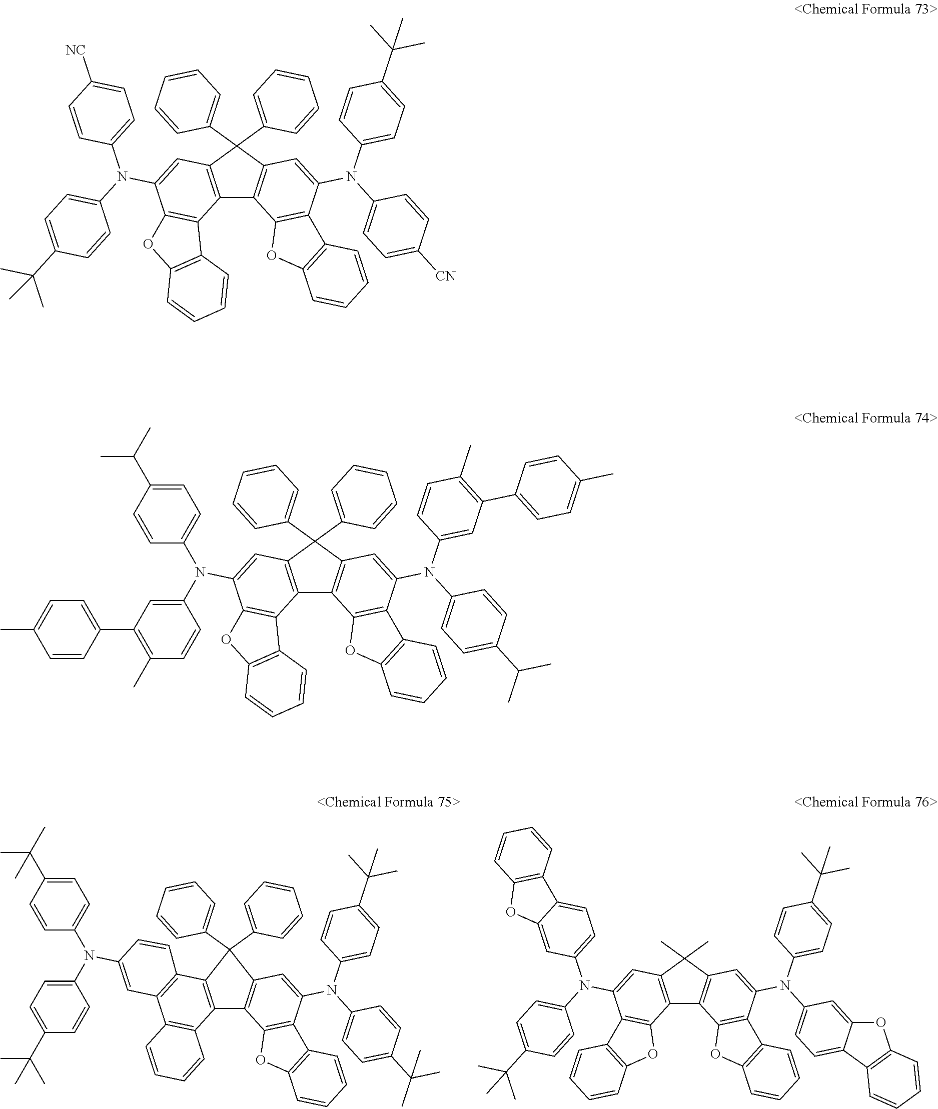

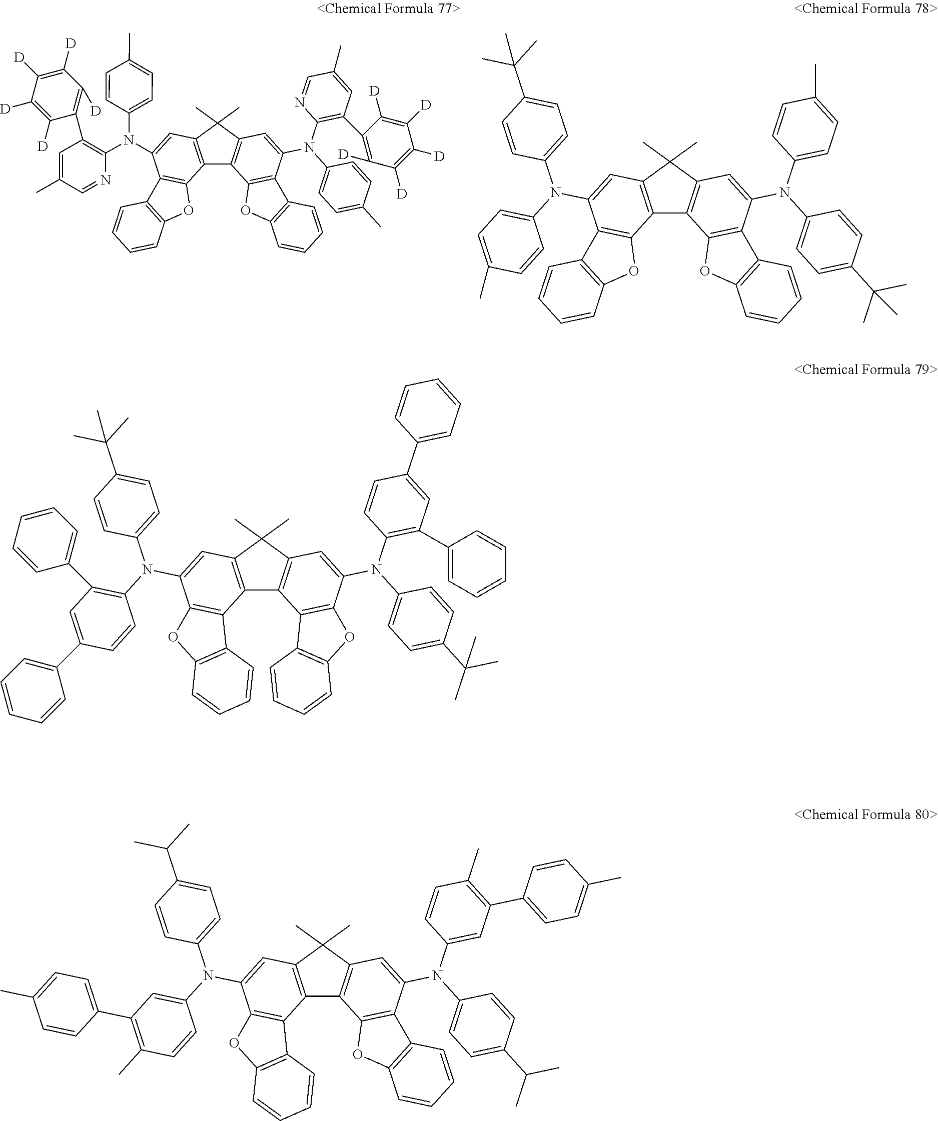

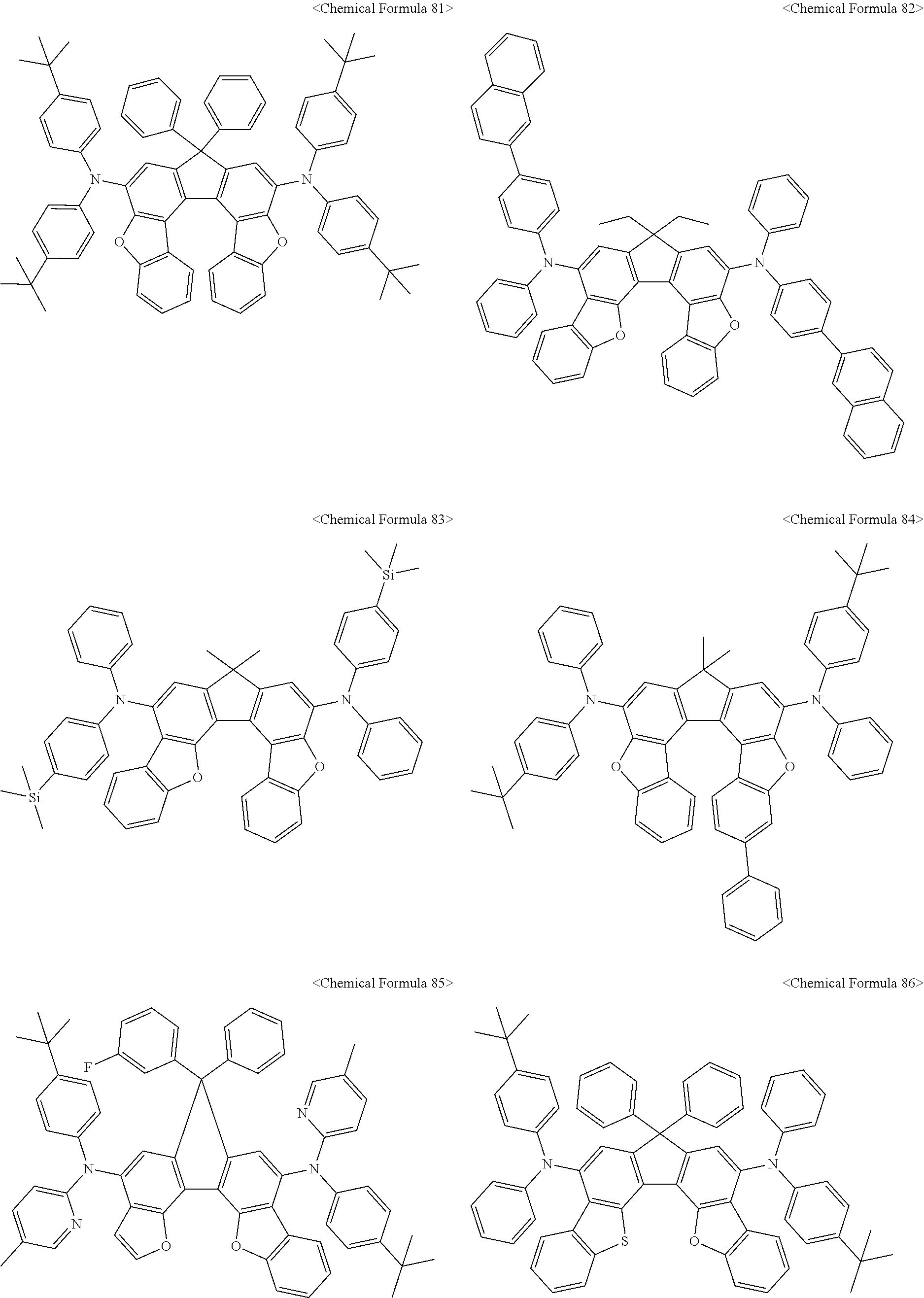

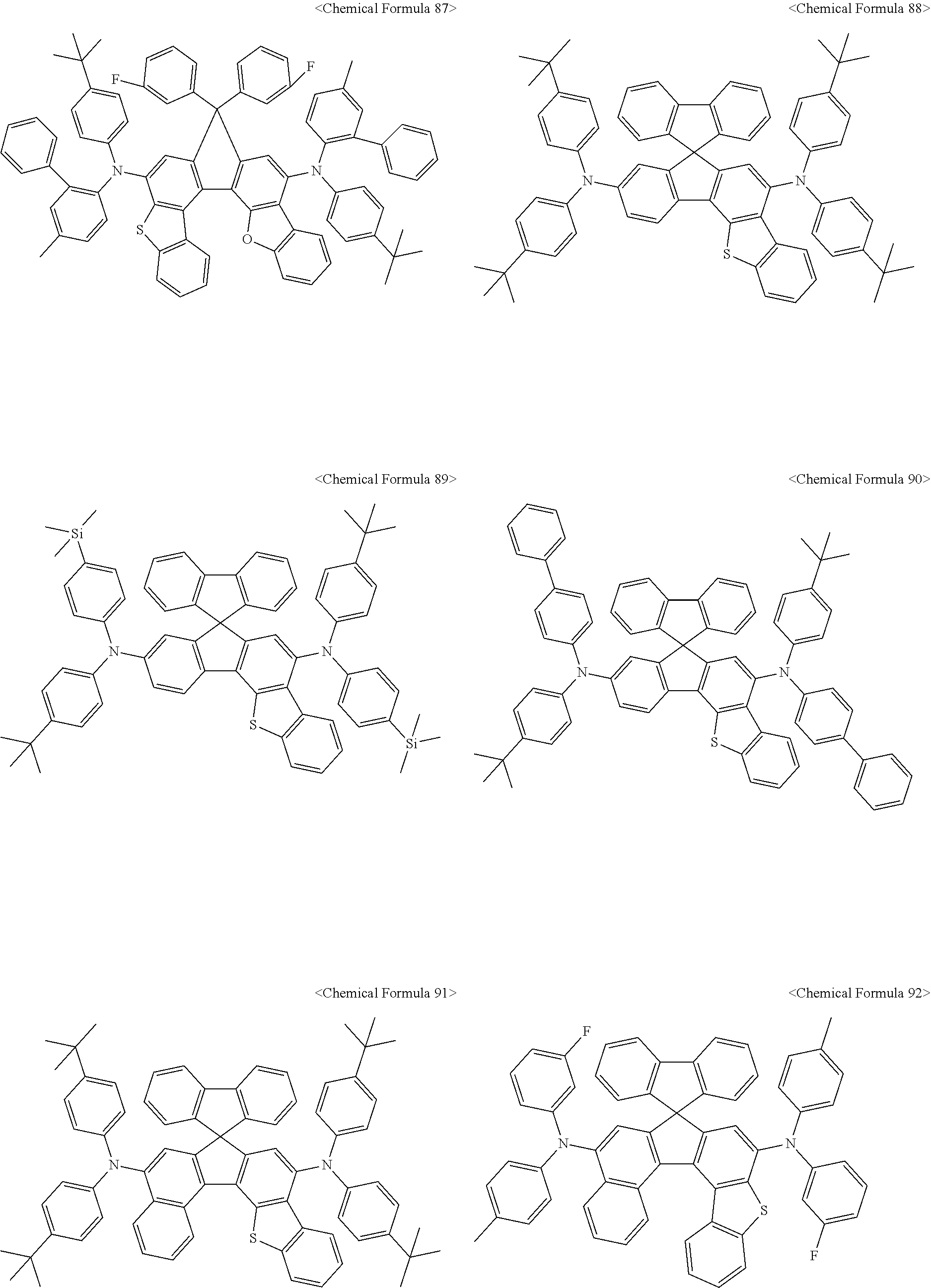

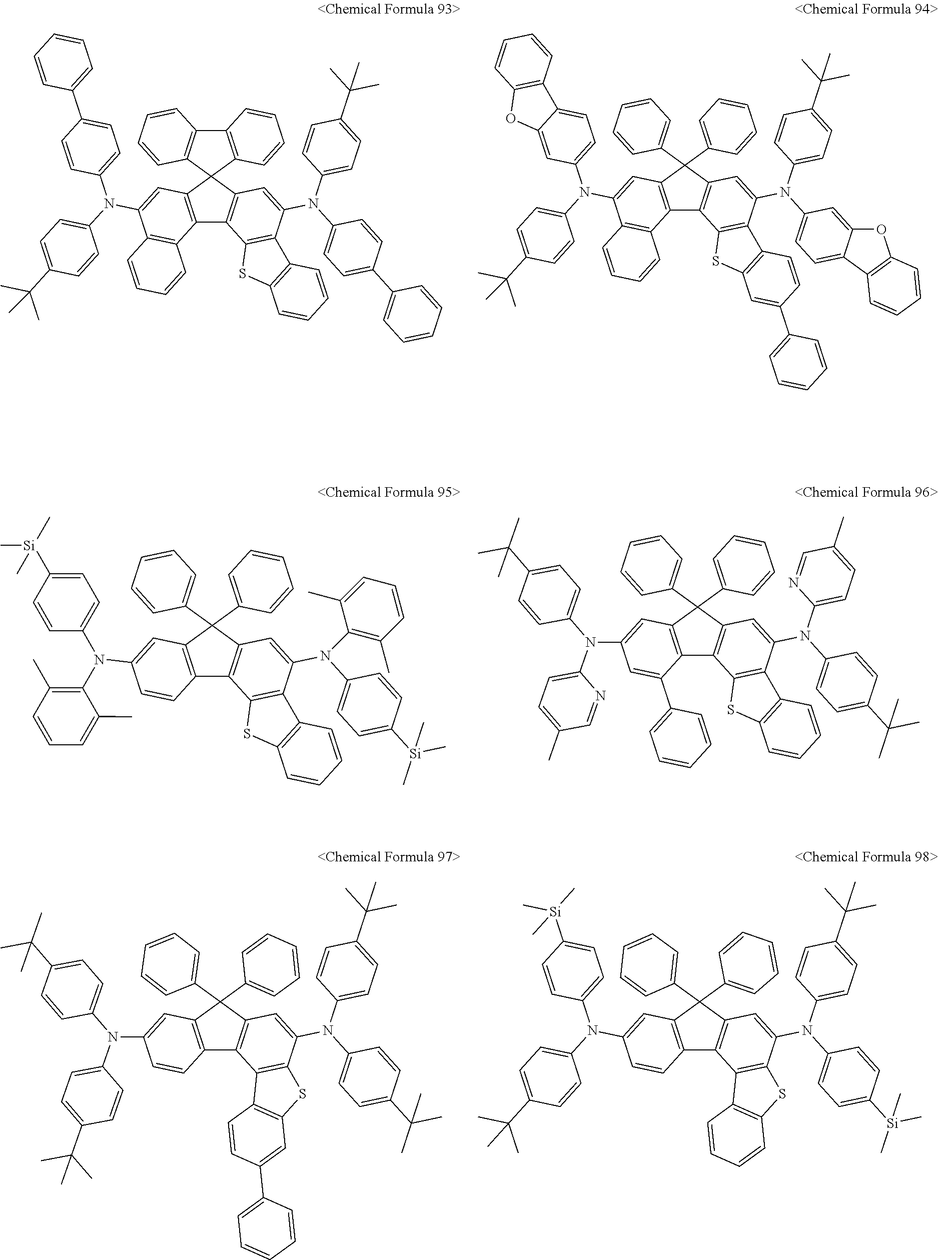

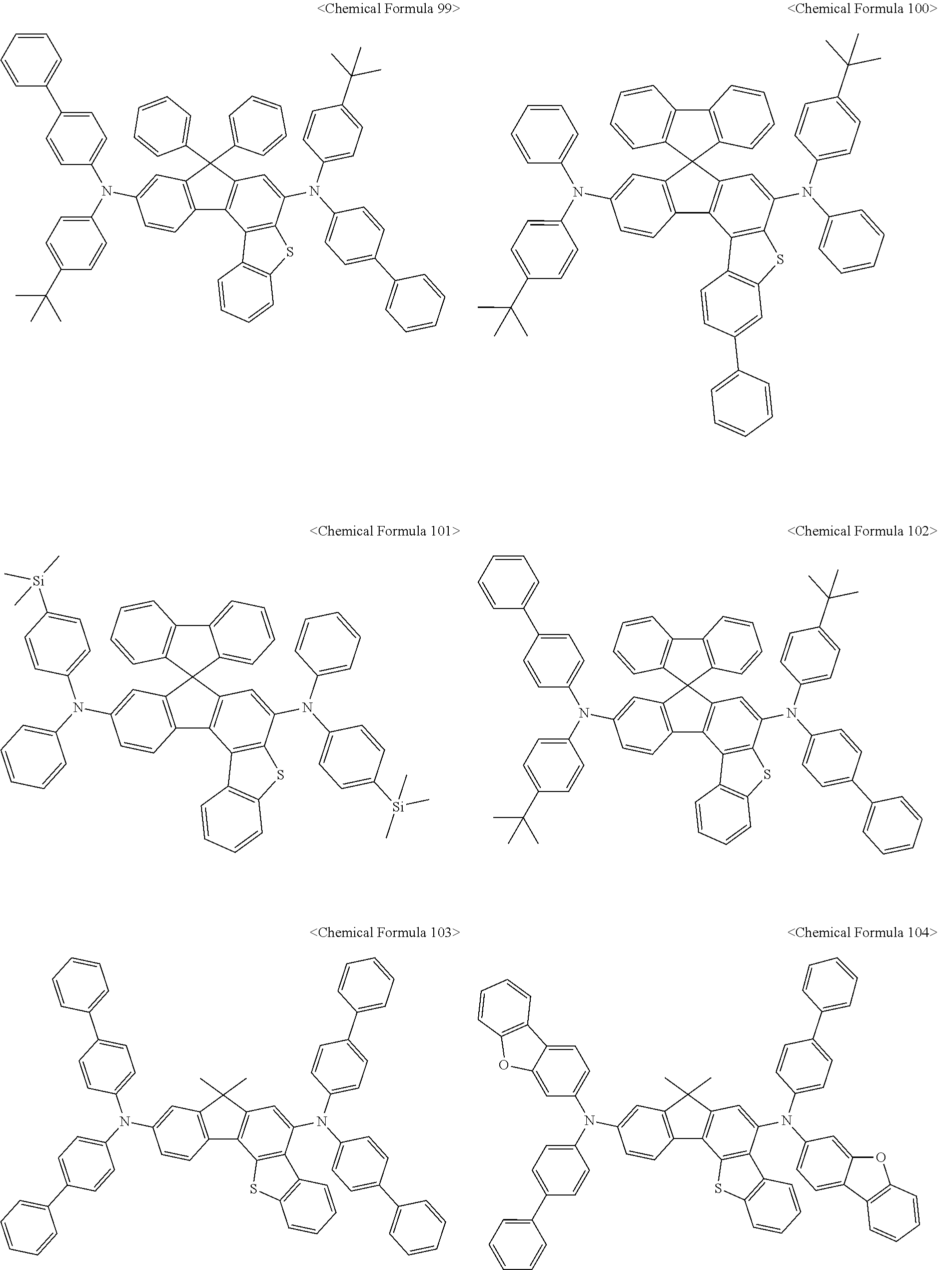

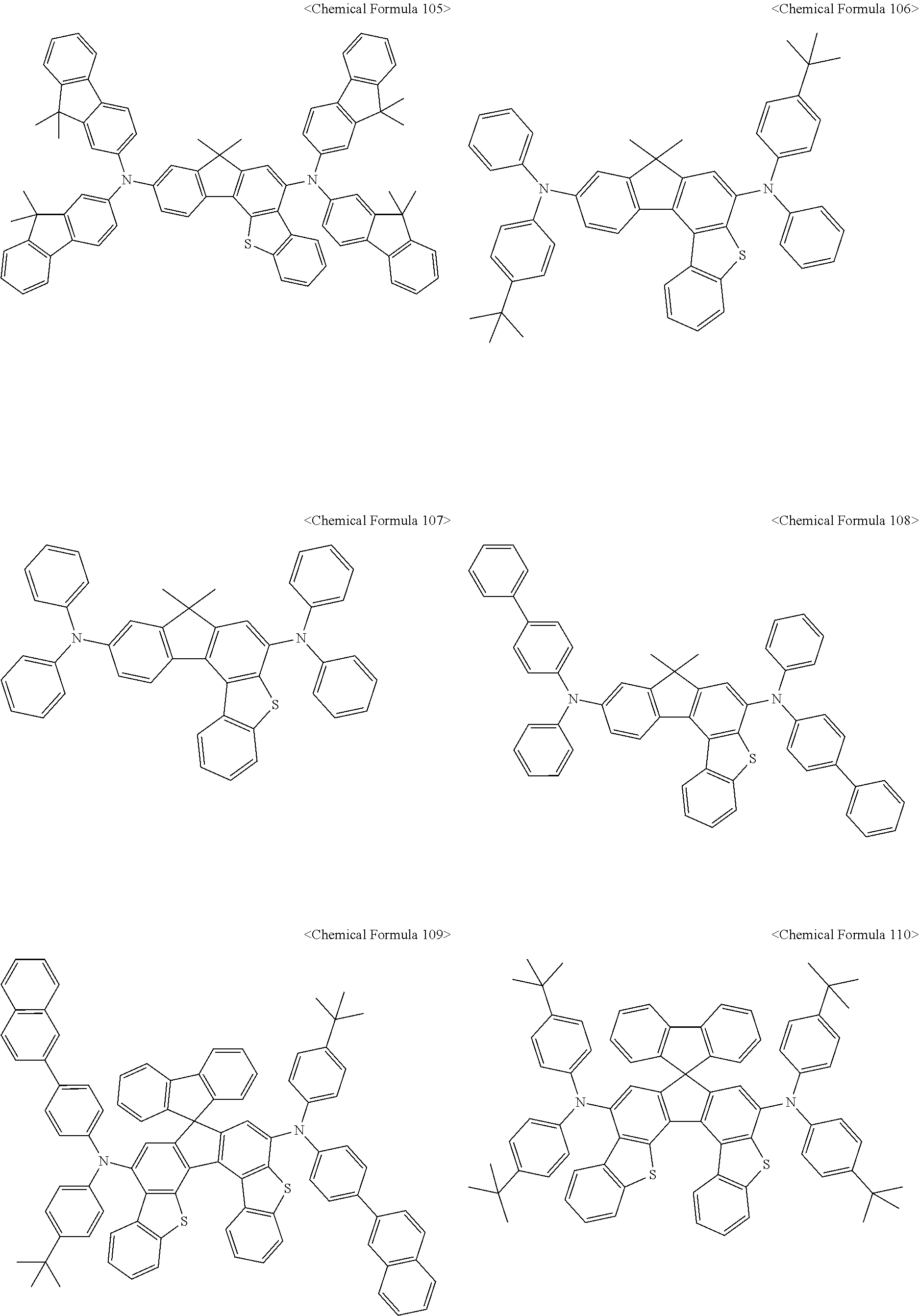

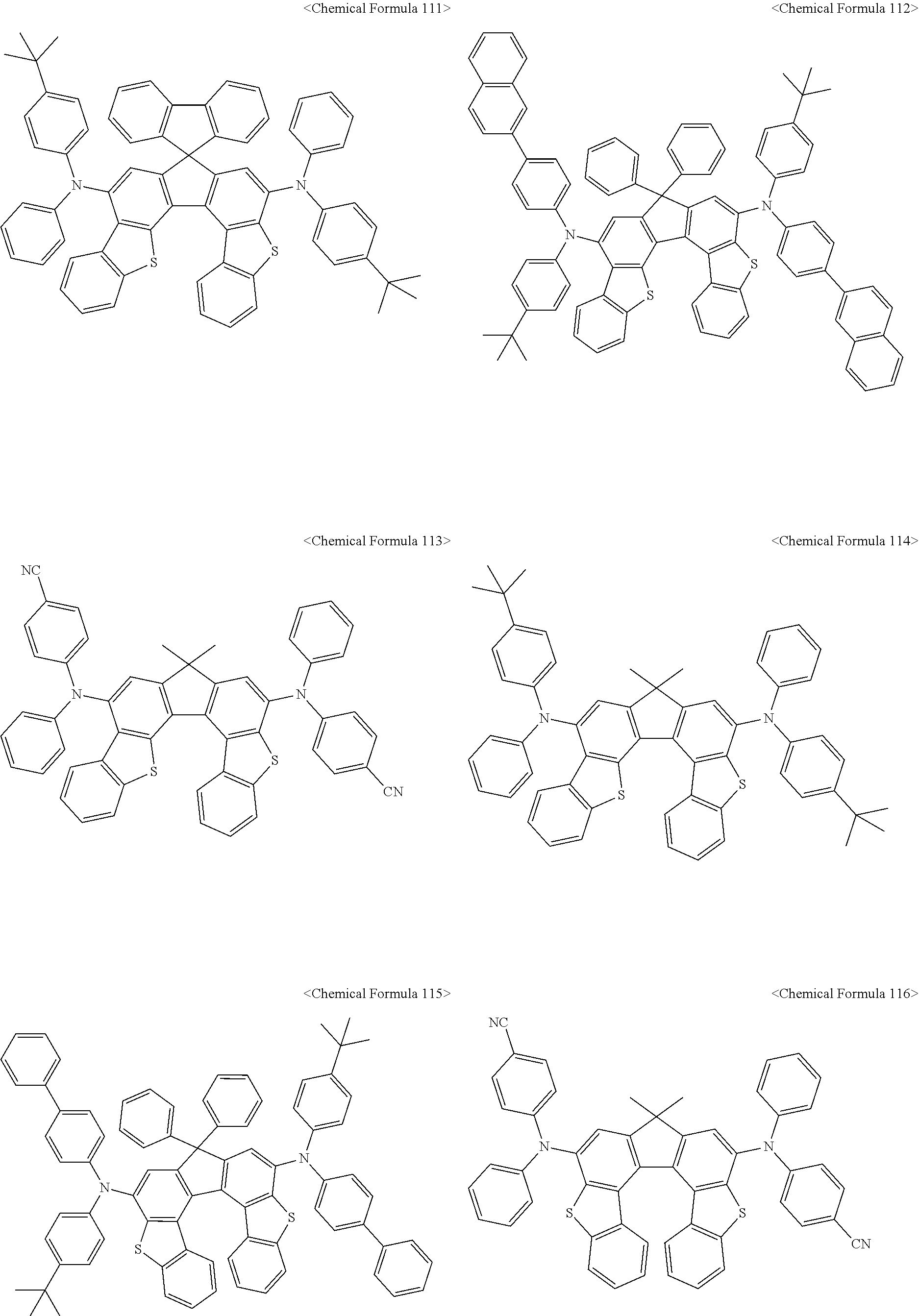

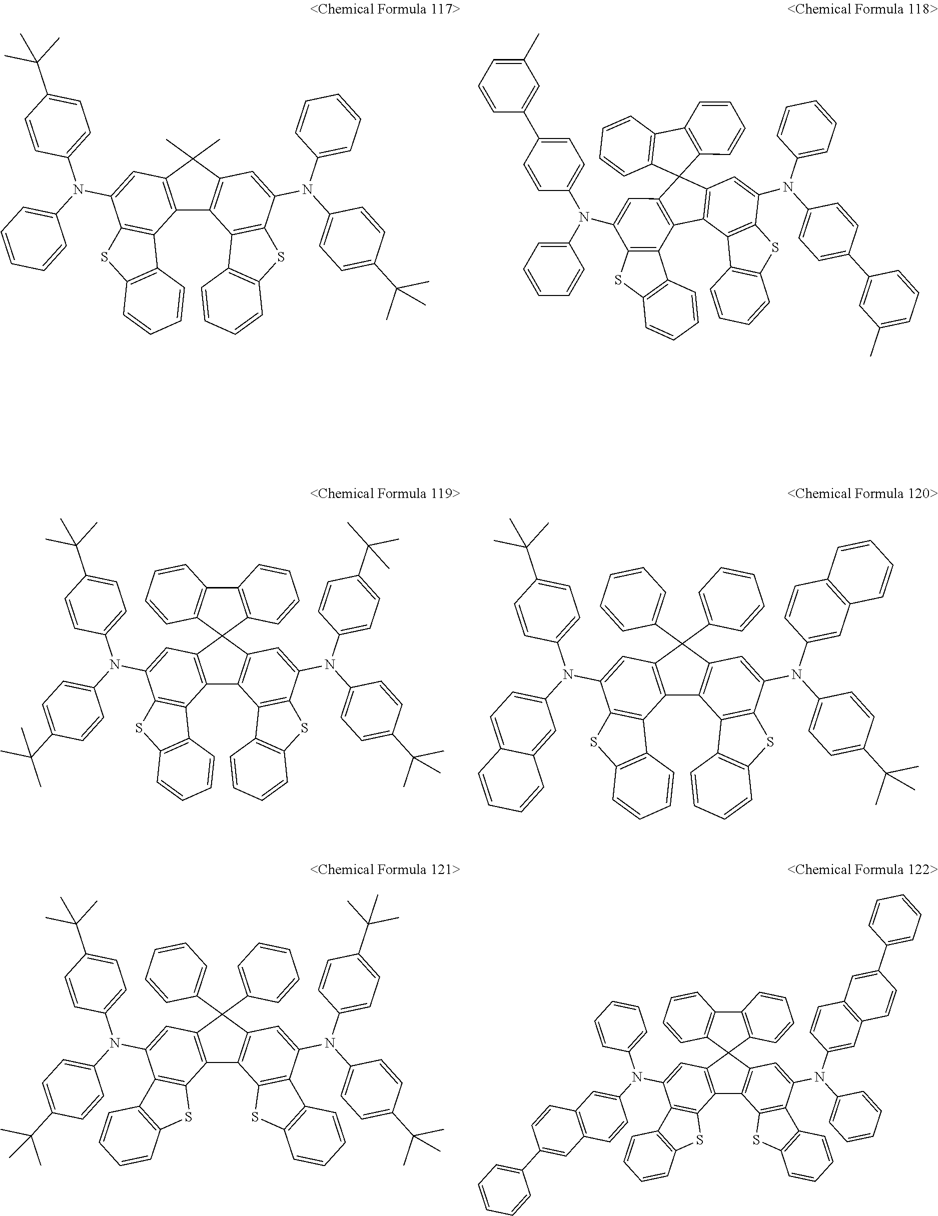

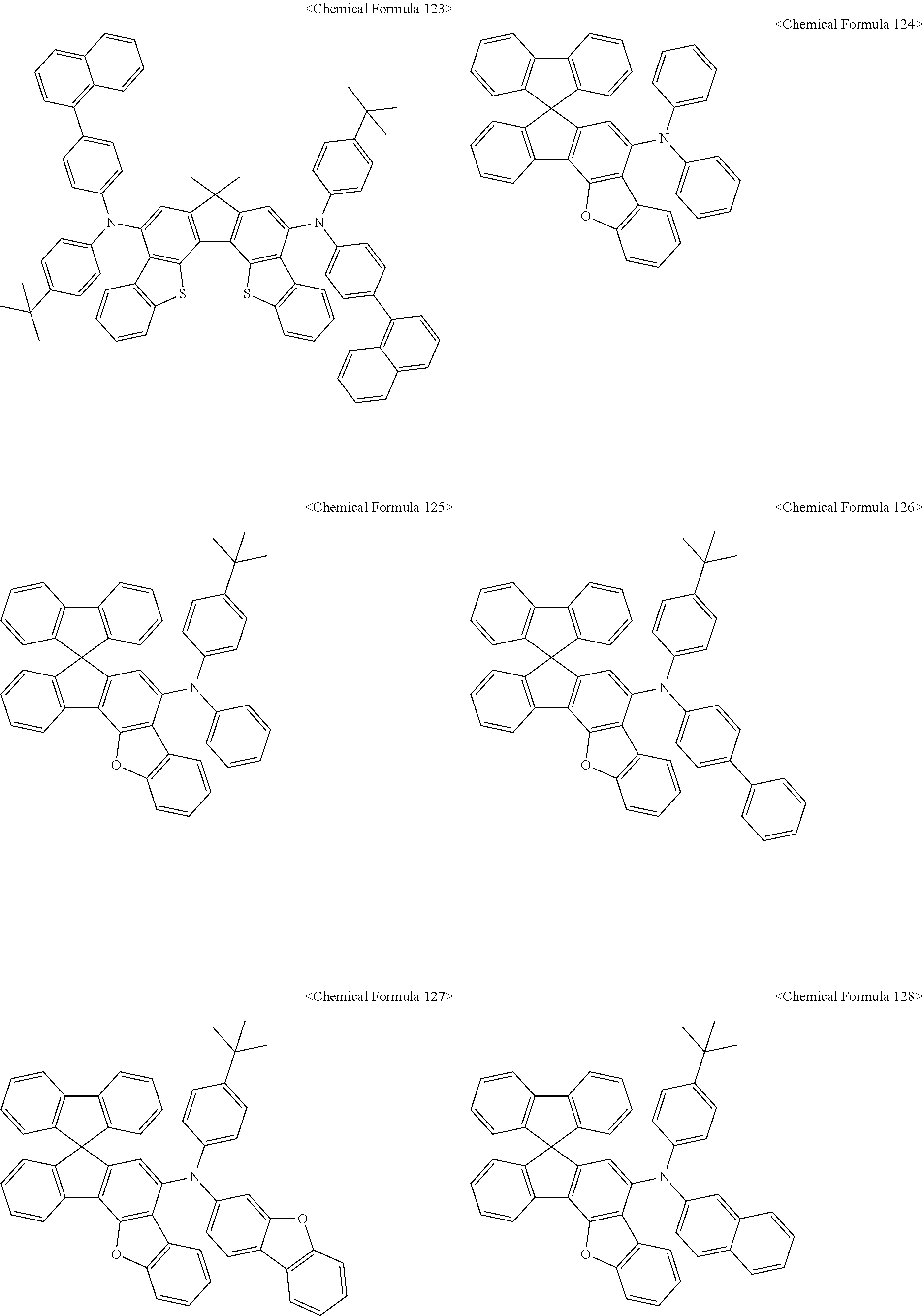

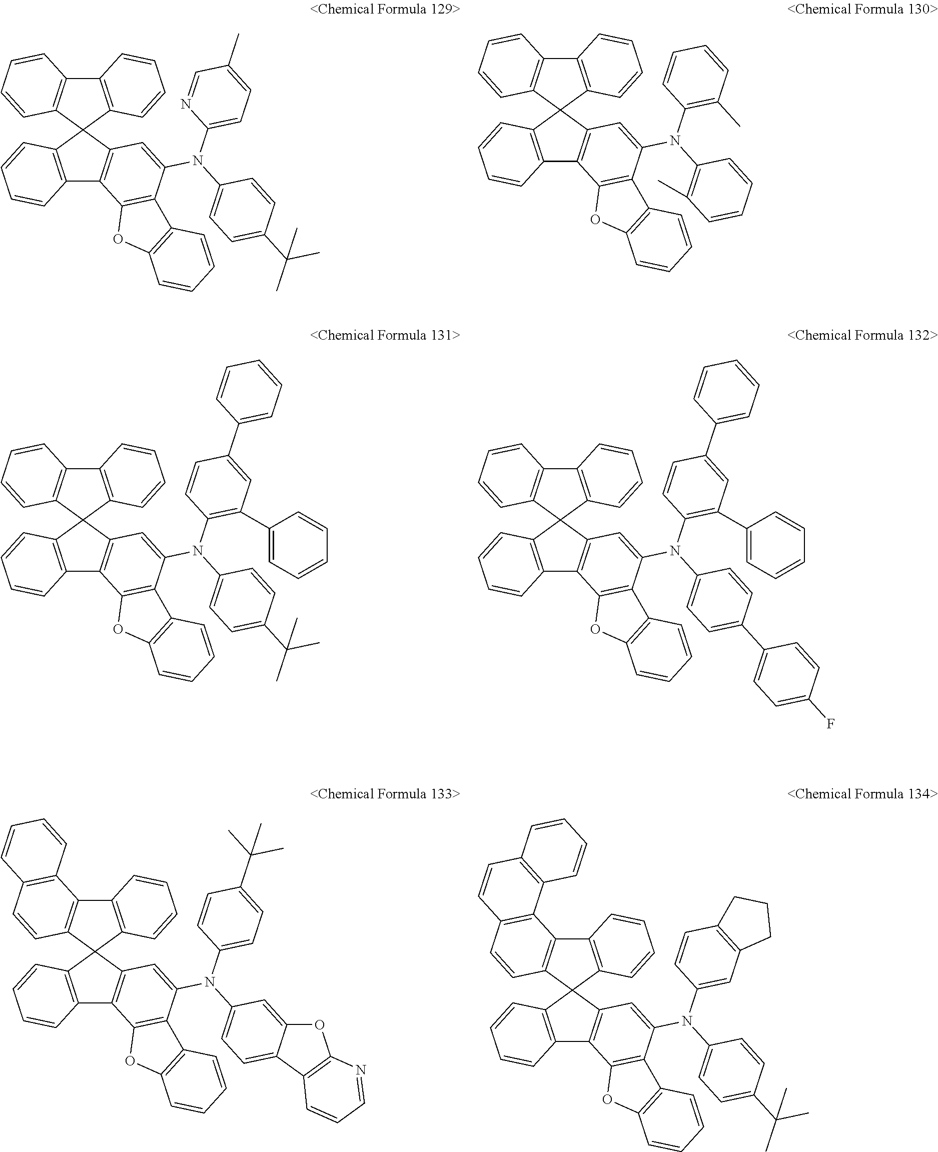

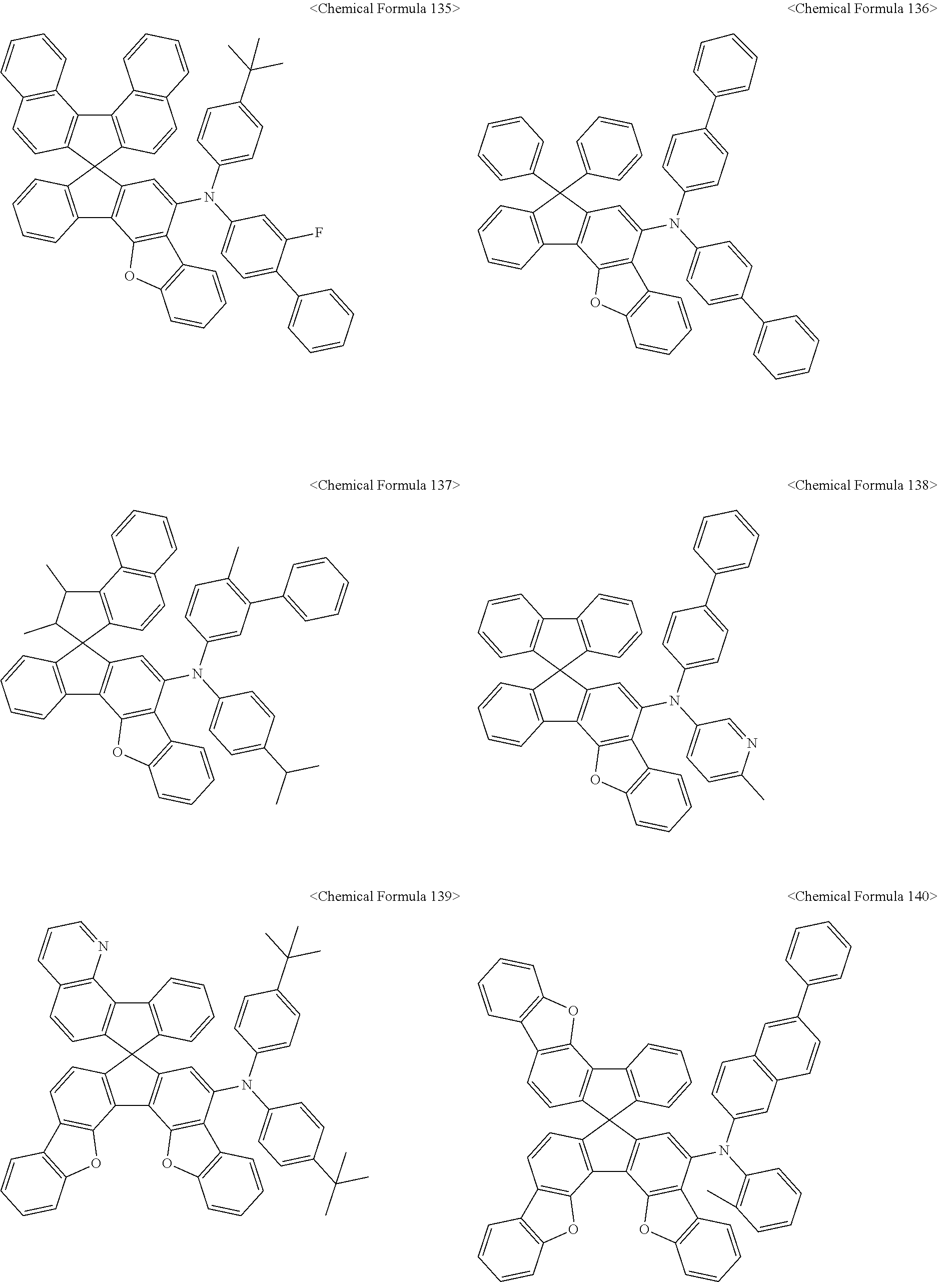

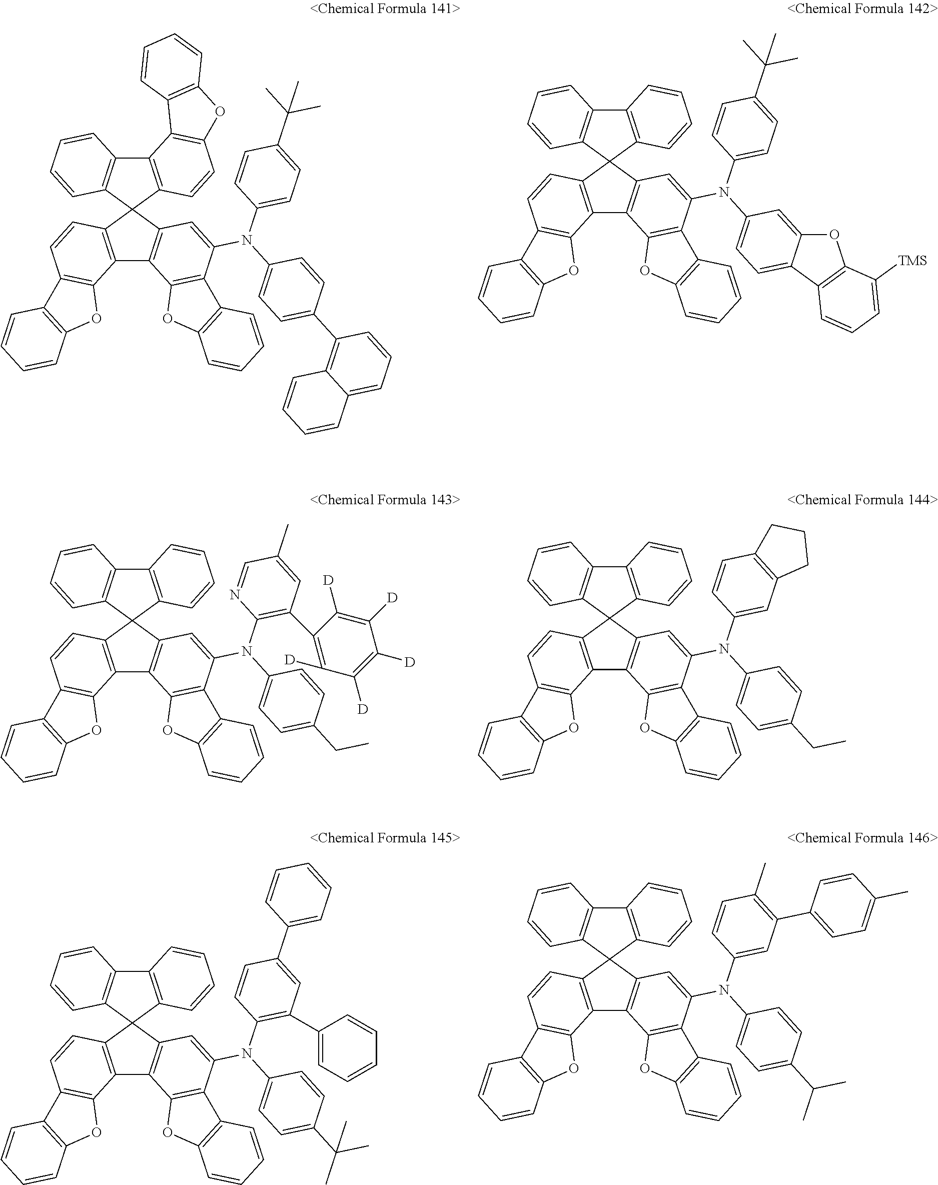

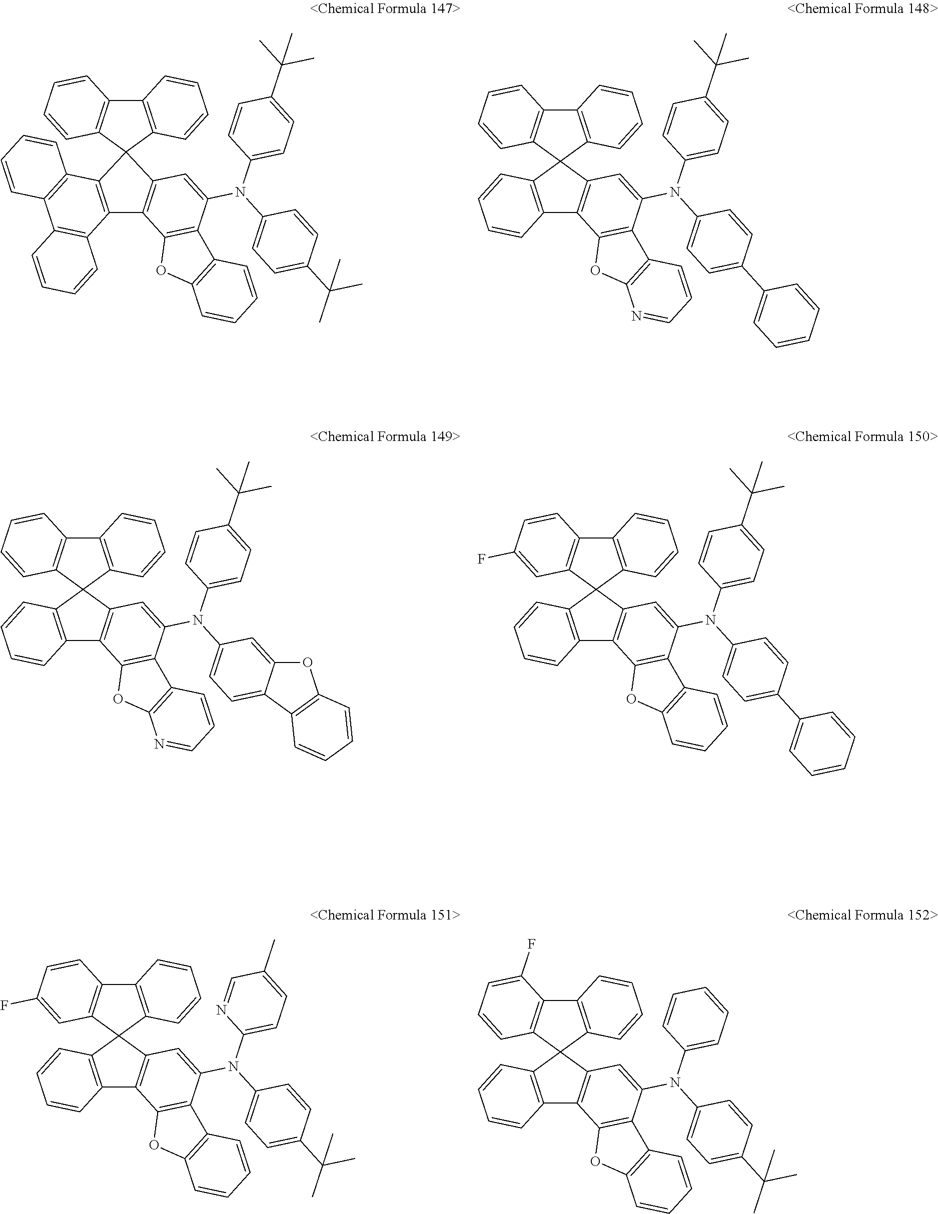

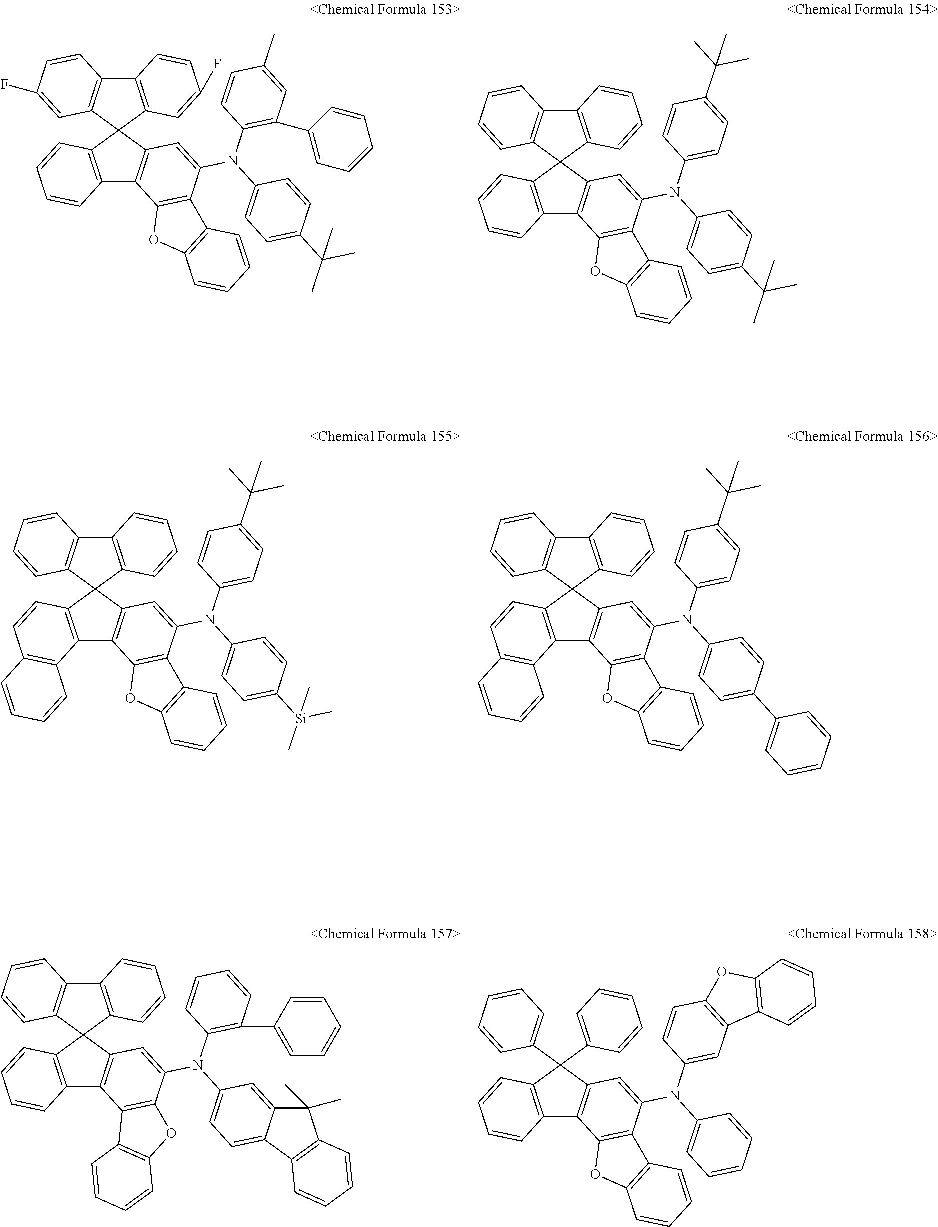

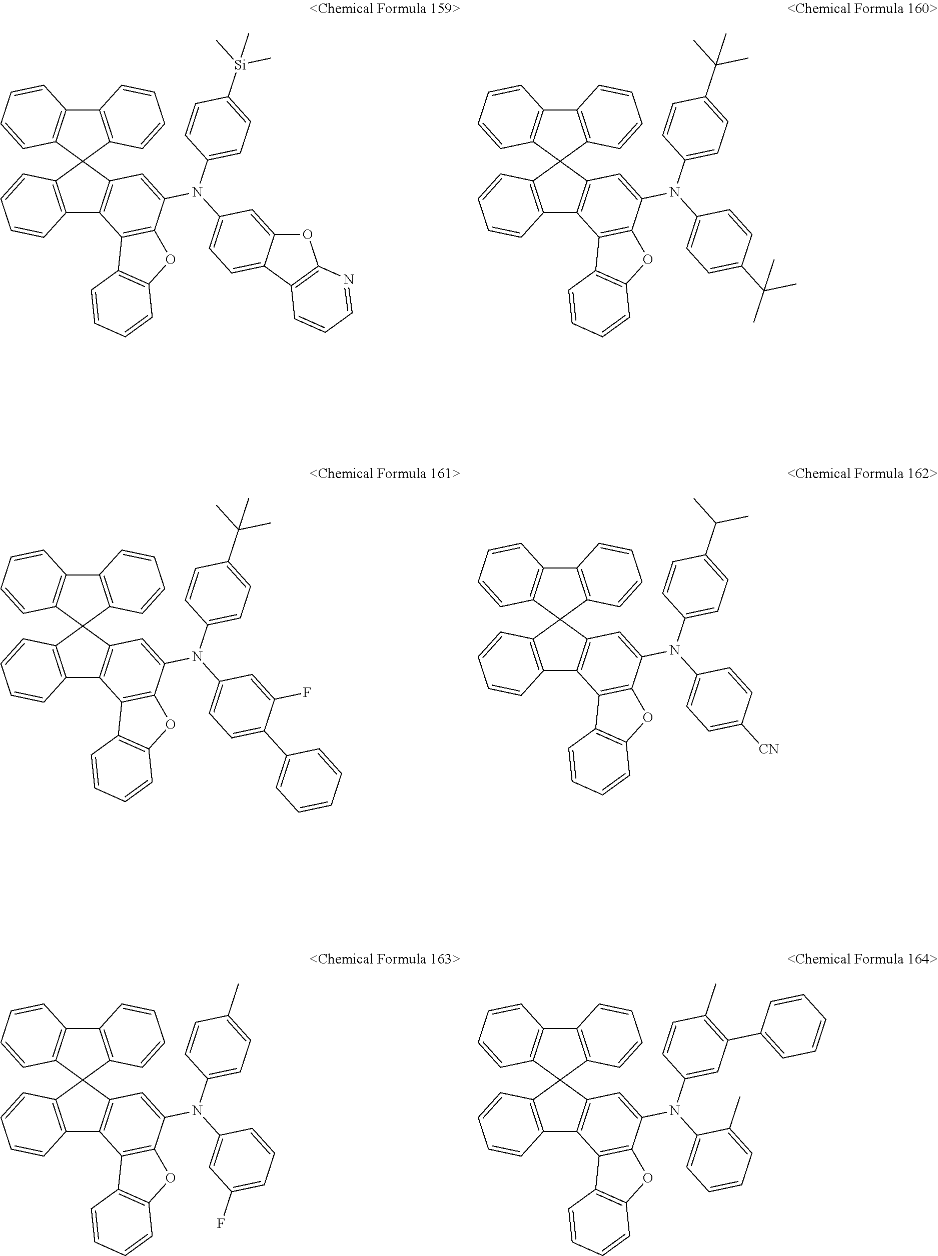

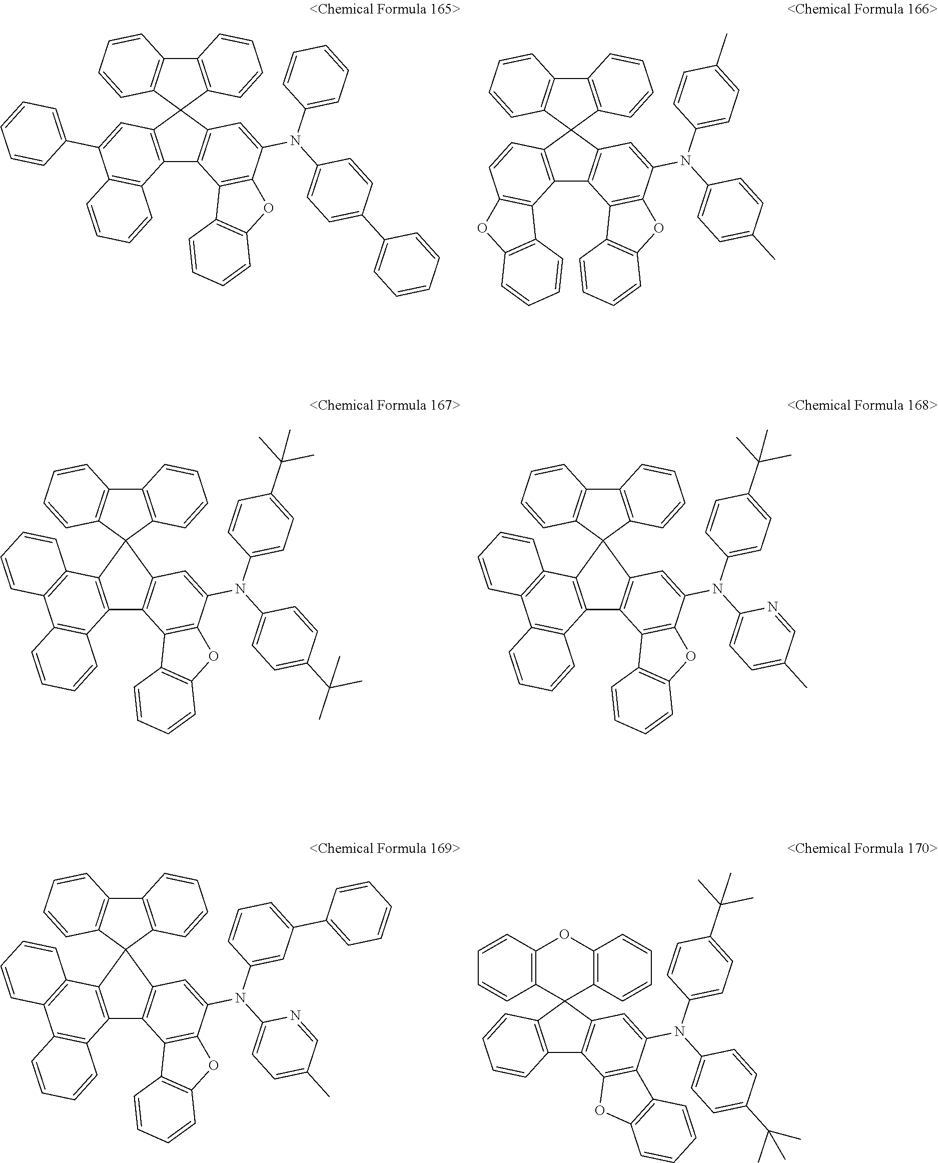

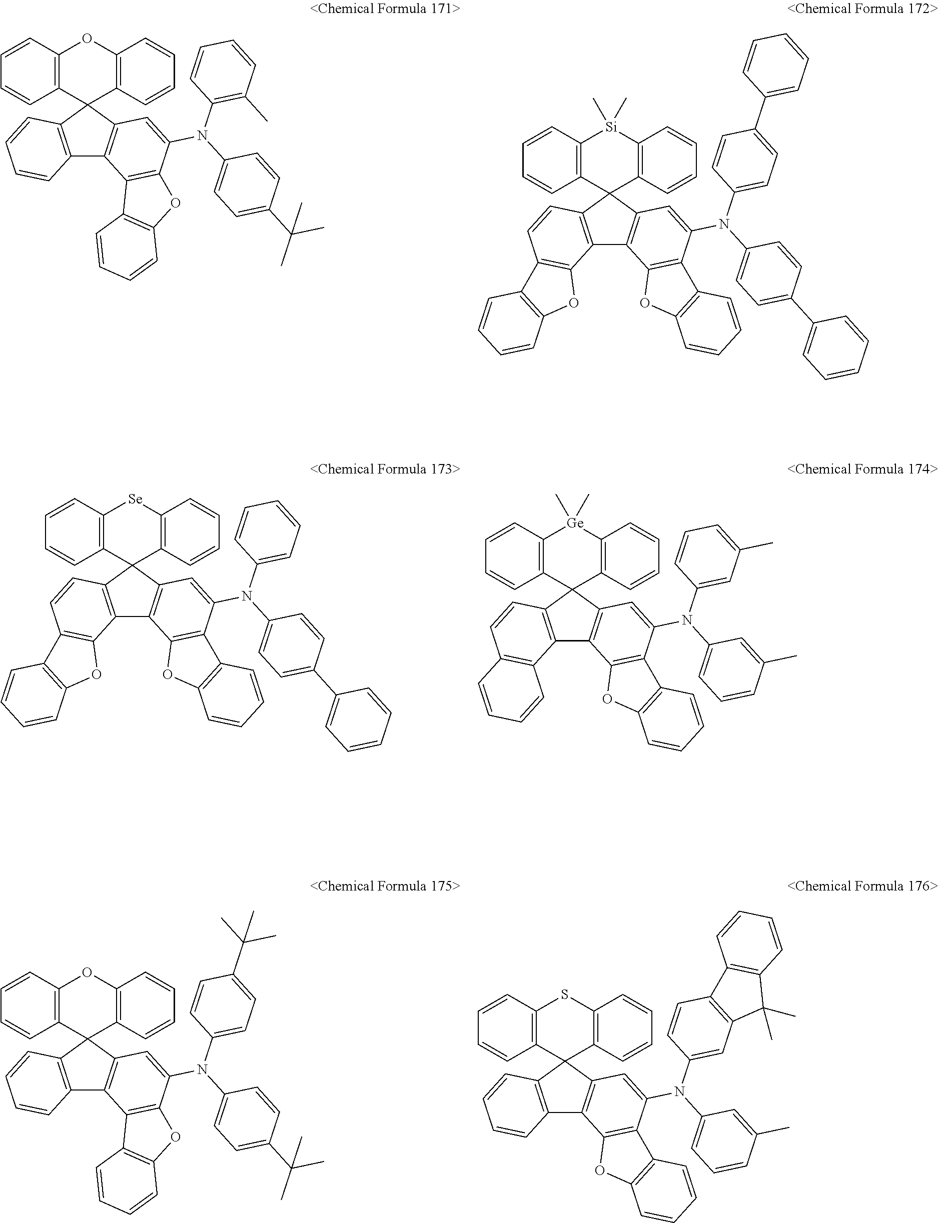

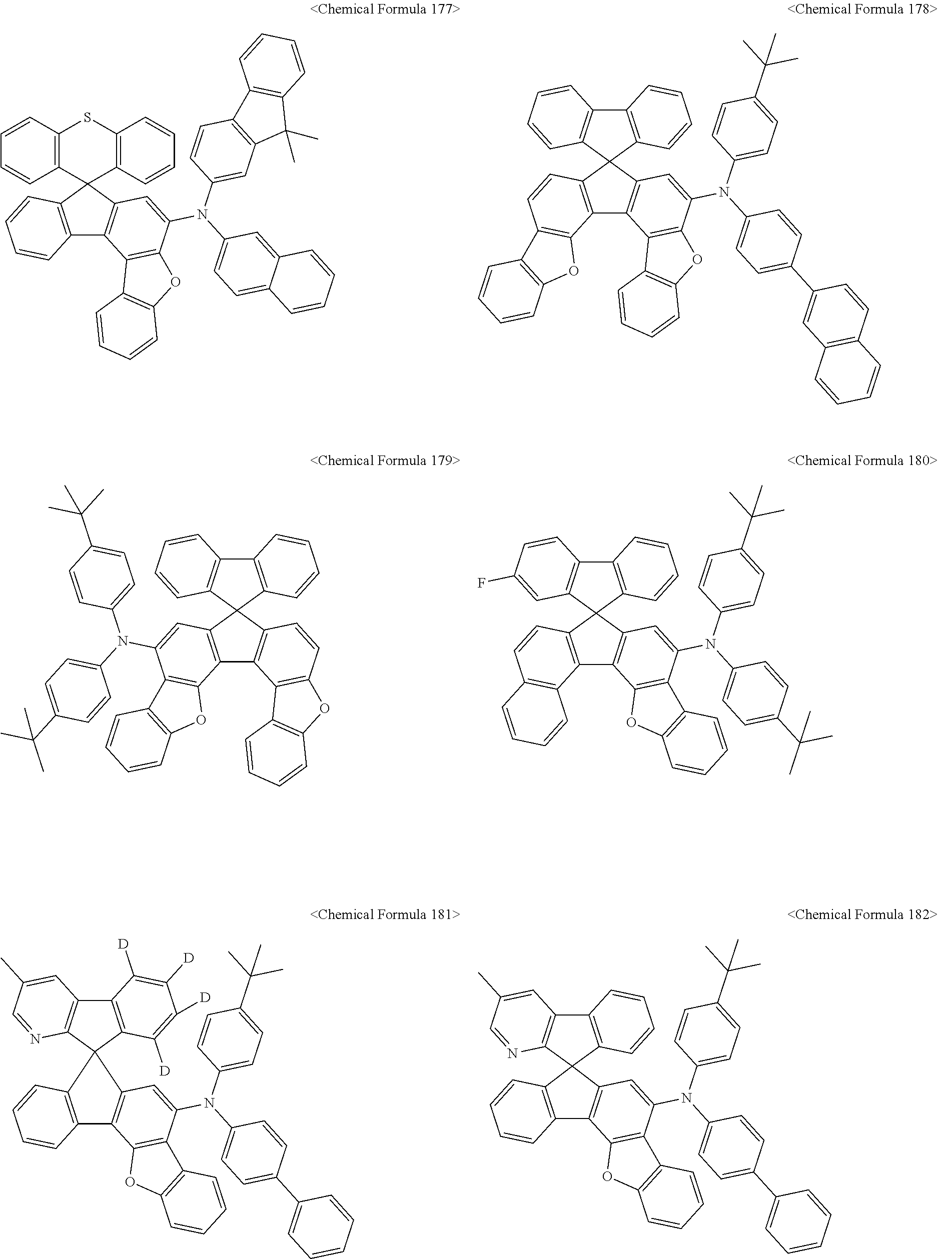

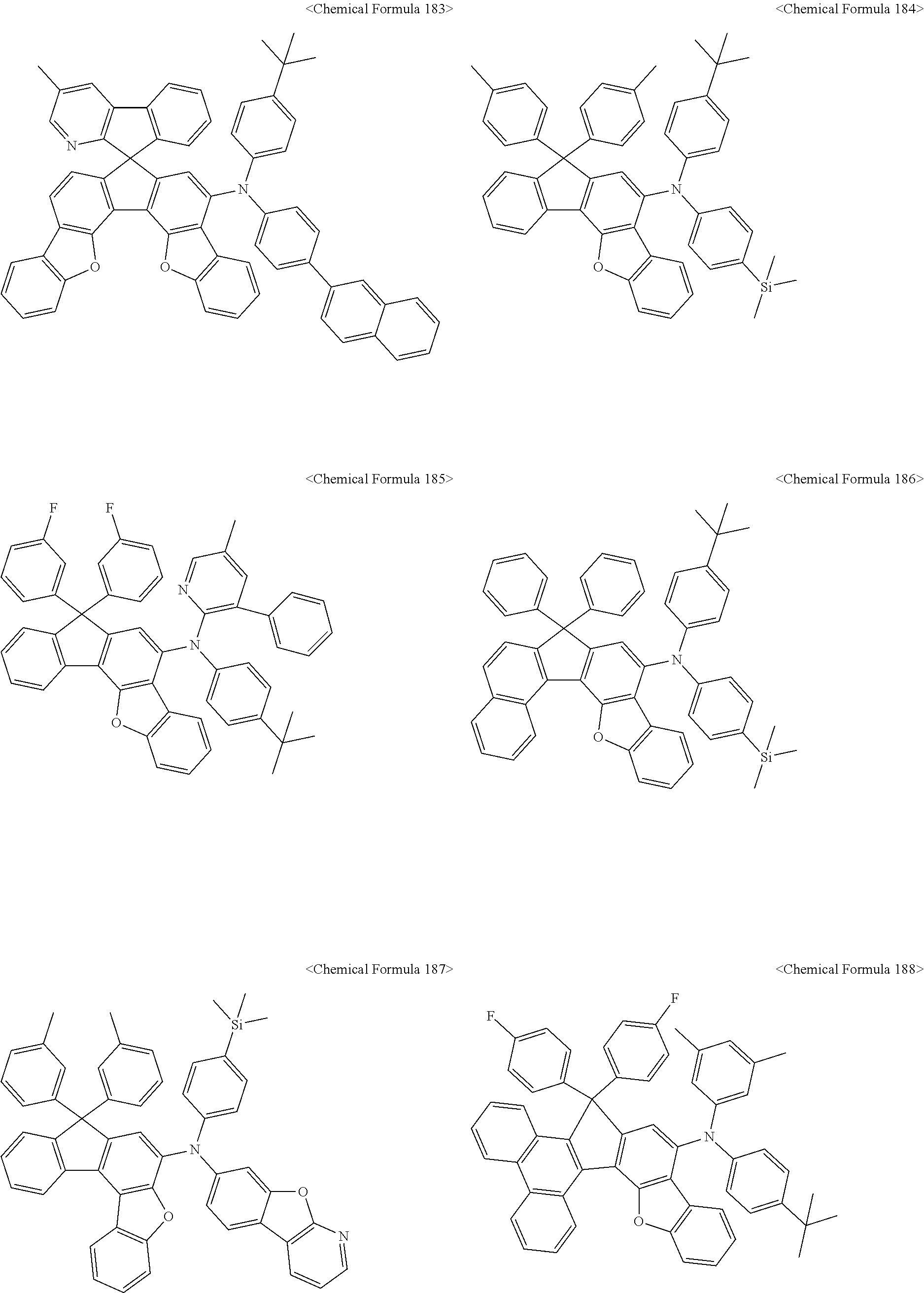

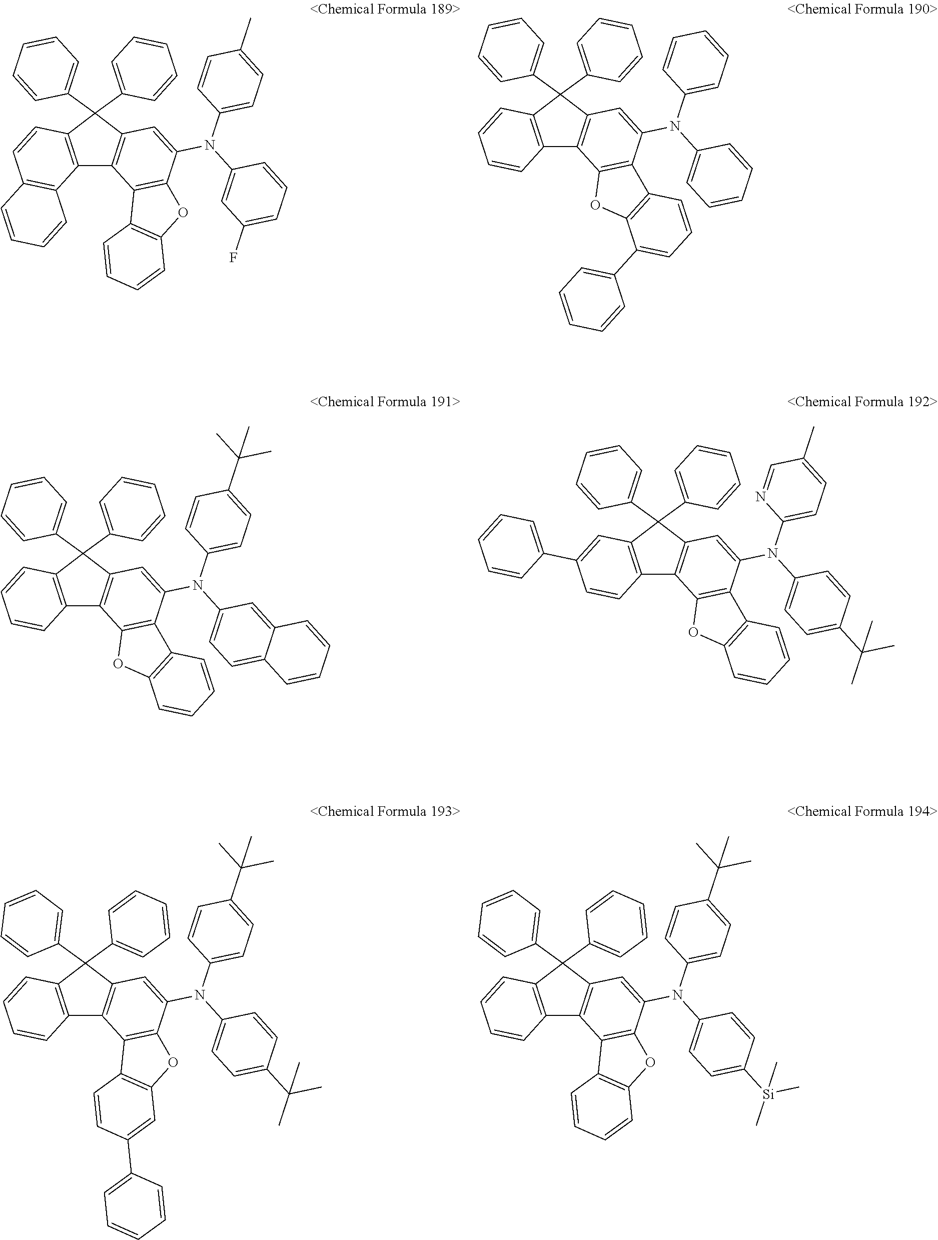

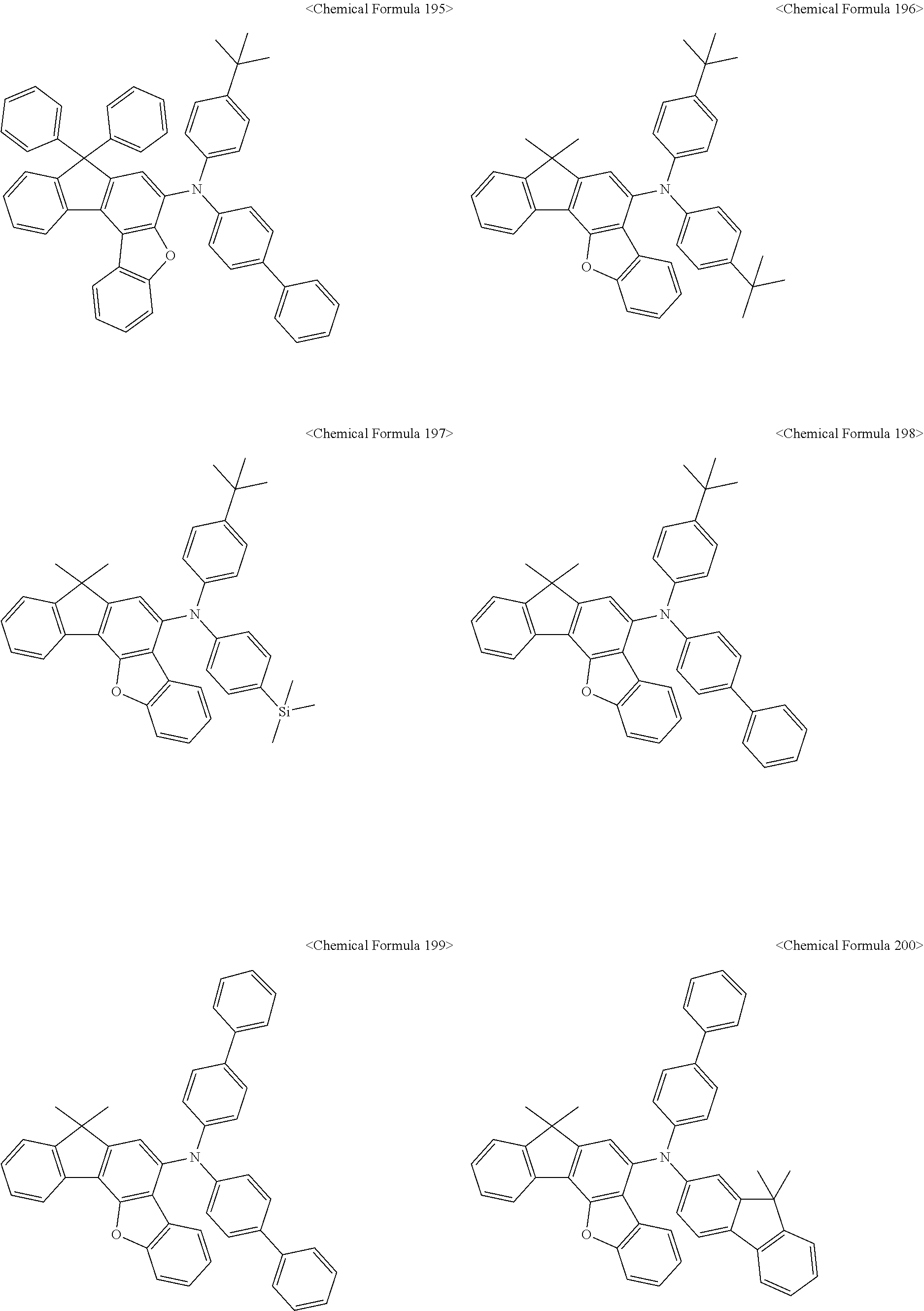

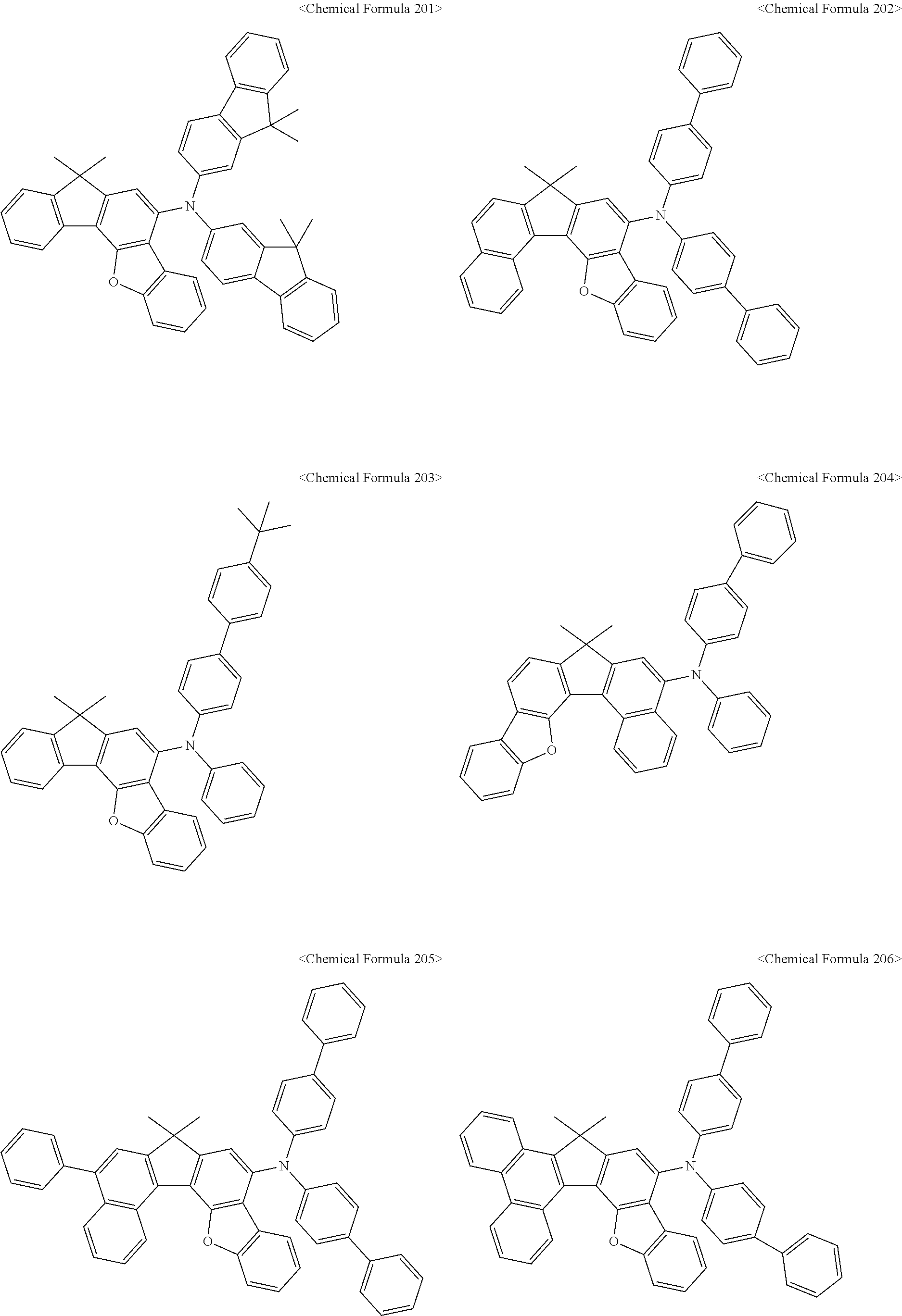

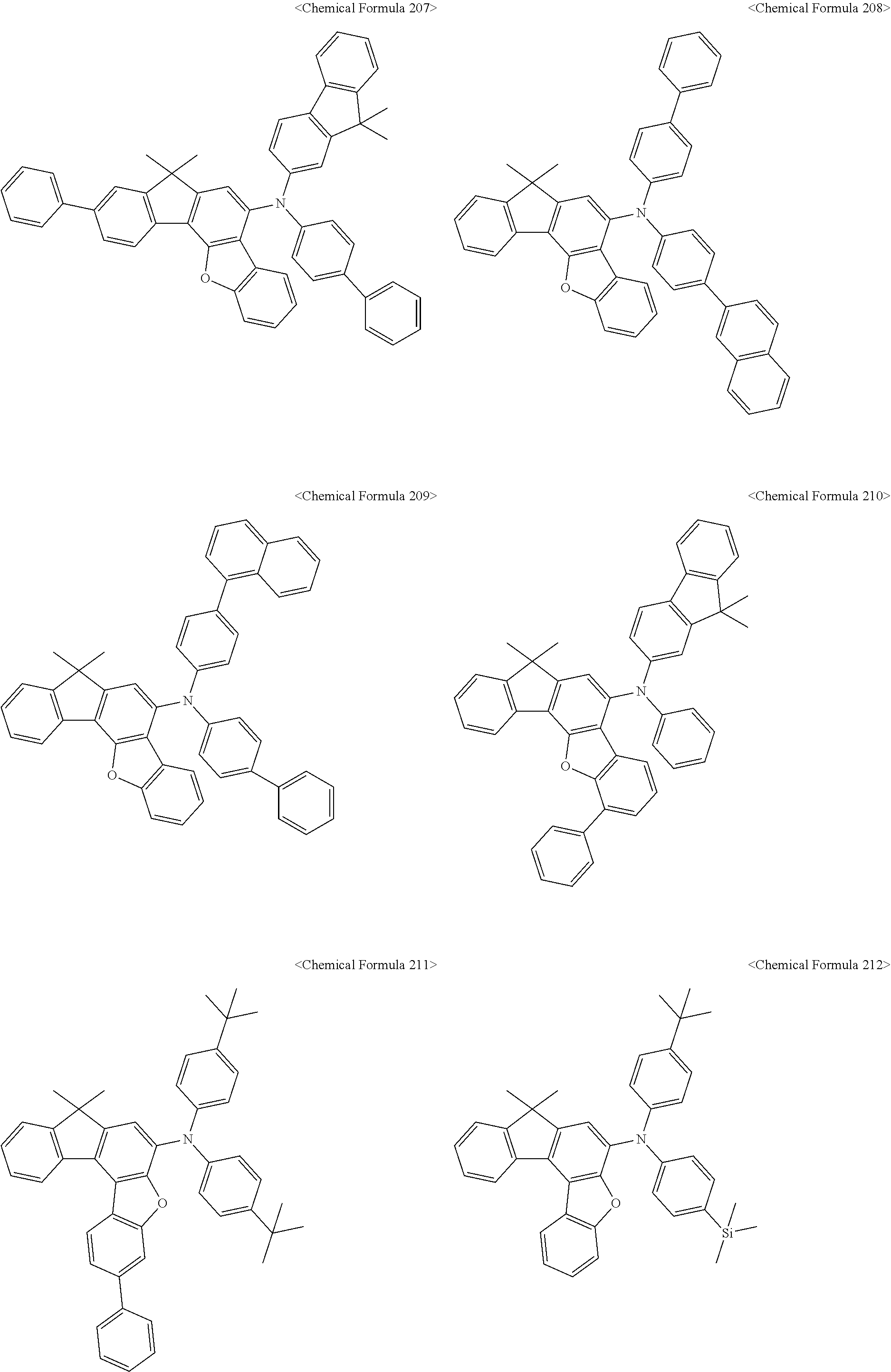

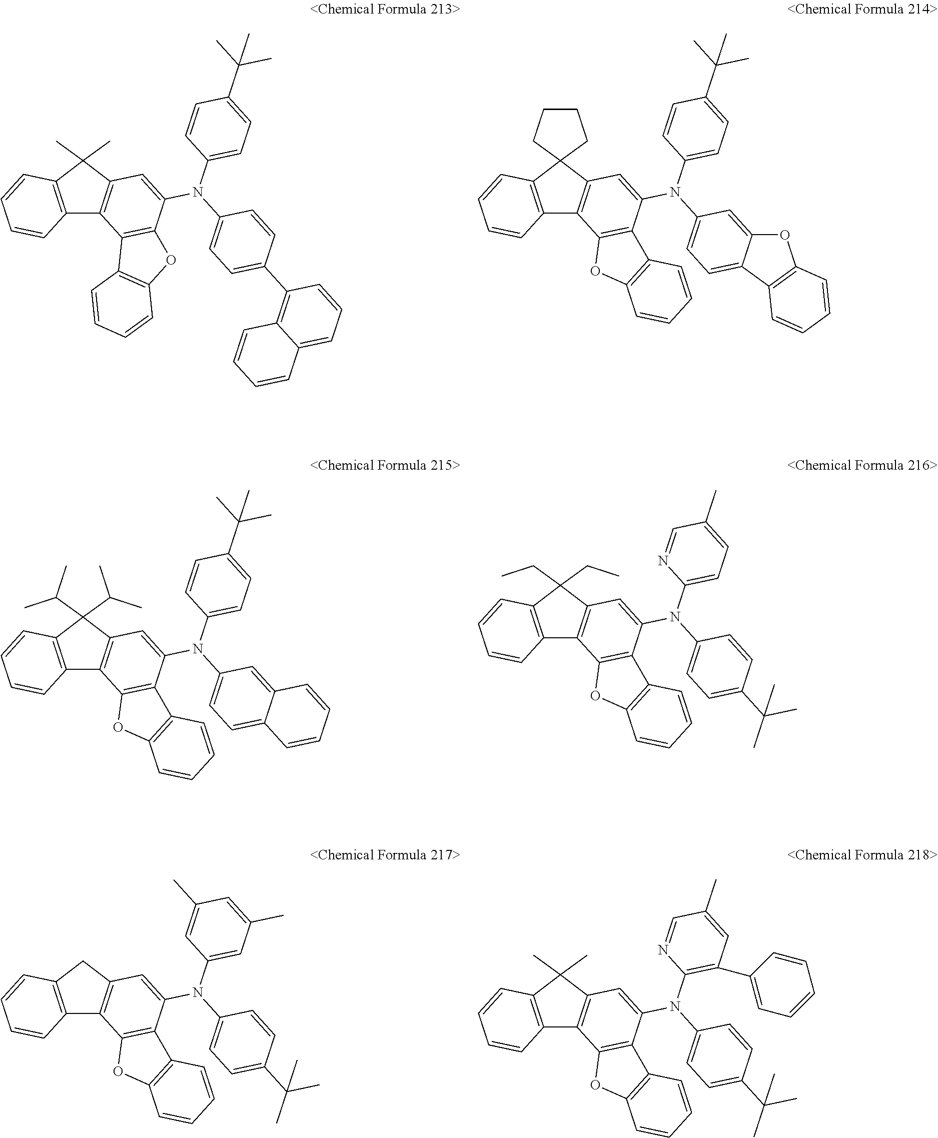 [SMILES: CC(C)(C)c1ccc(N(c2ccc(-c3cccc4ccccc34)cc2)c2cc3c(c4c2oc2ccccc24)-c2ccccc2C3(C)C)cc1 ; CC(C)(C)c1ccc(N(c2ccc3c(c2)oc2ccccc23)c2cc3c(c4oc5ccccc5c24)-c2ccccc2C32CCCC2)cc1 ; CC(C)C1(C(C)C)c2ccccc2-c2c1cc(N(c1ccc(C(C)(C)C)cc1)c1ccc3ccccc3c1)c1c2oc2ccccc21 ; CCC1(CC)c2ccccc2-c2c1cc(N(c1ccc(C(C)(C)C)cc1)c1ccc(C)cn1)c1c2oc2ccccc21 ; Cc1cc(C)cc(N(c2ccc(C(C)(C)C)cc2)c2cc3c(c4oc5ccccc5c24)-c2ccccc2C3)c1 ; Cc1cnc(N(c2ccc(C(C)(C)C)cc2)c2cc3c(c4oc5ccccc5c24)-c2ccccc2C3(C)C)c(-c2ccccc2)c1]

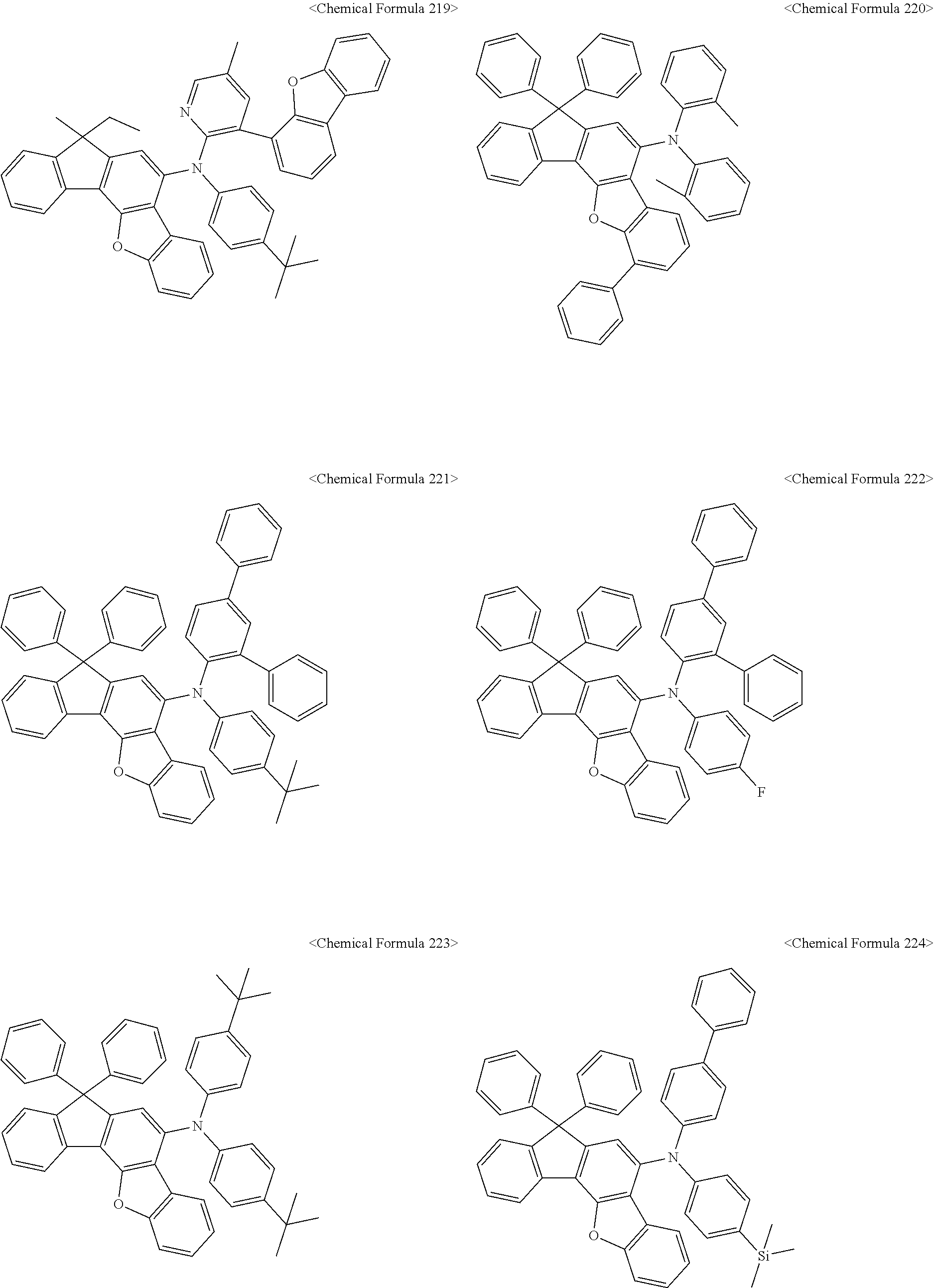

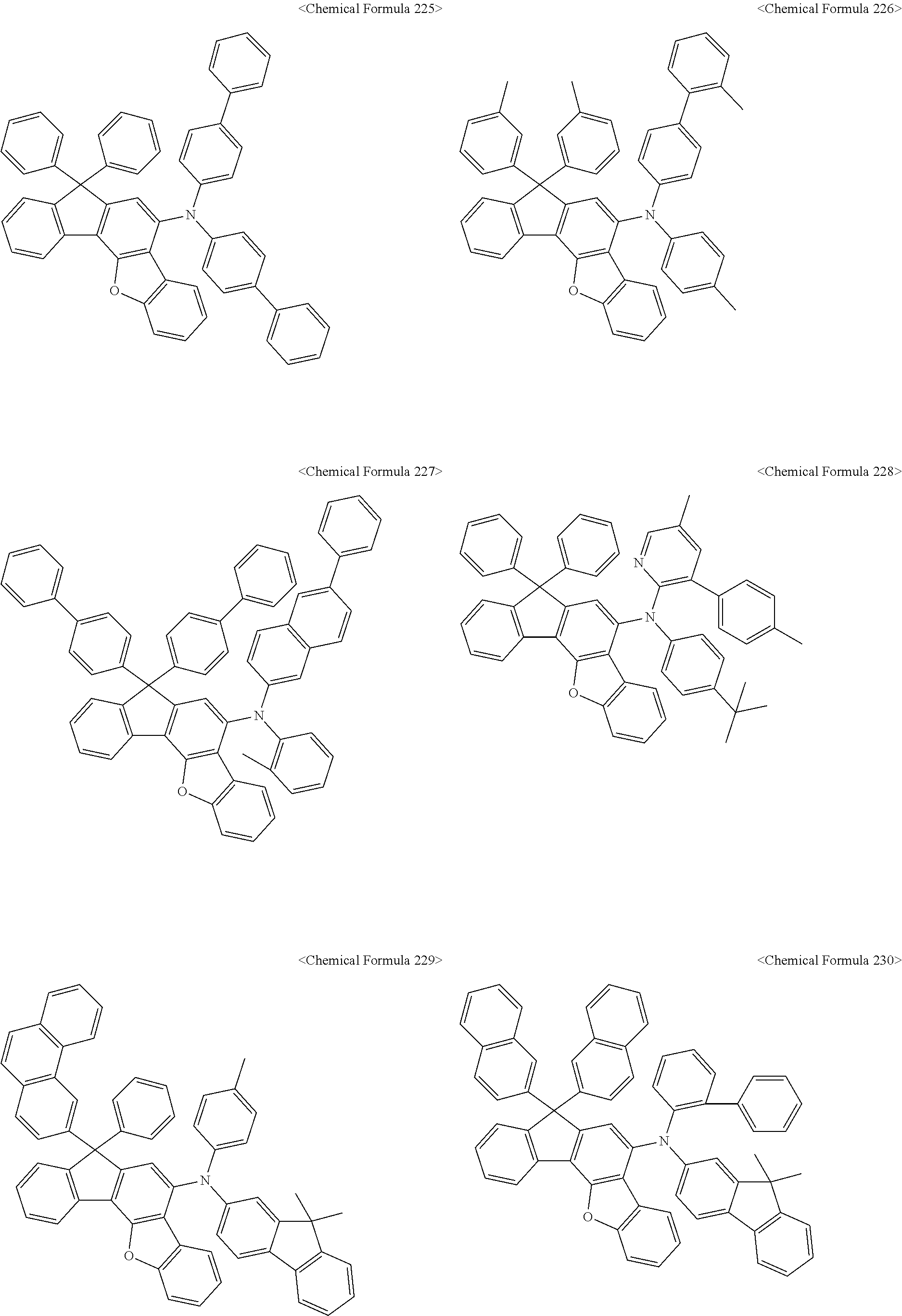

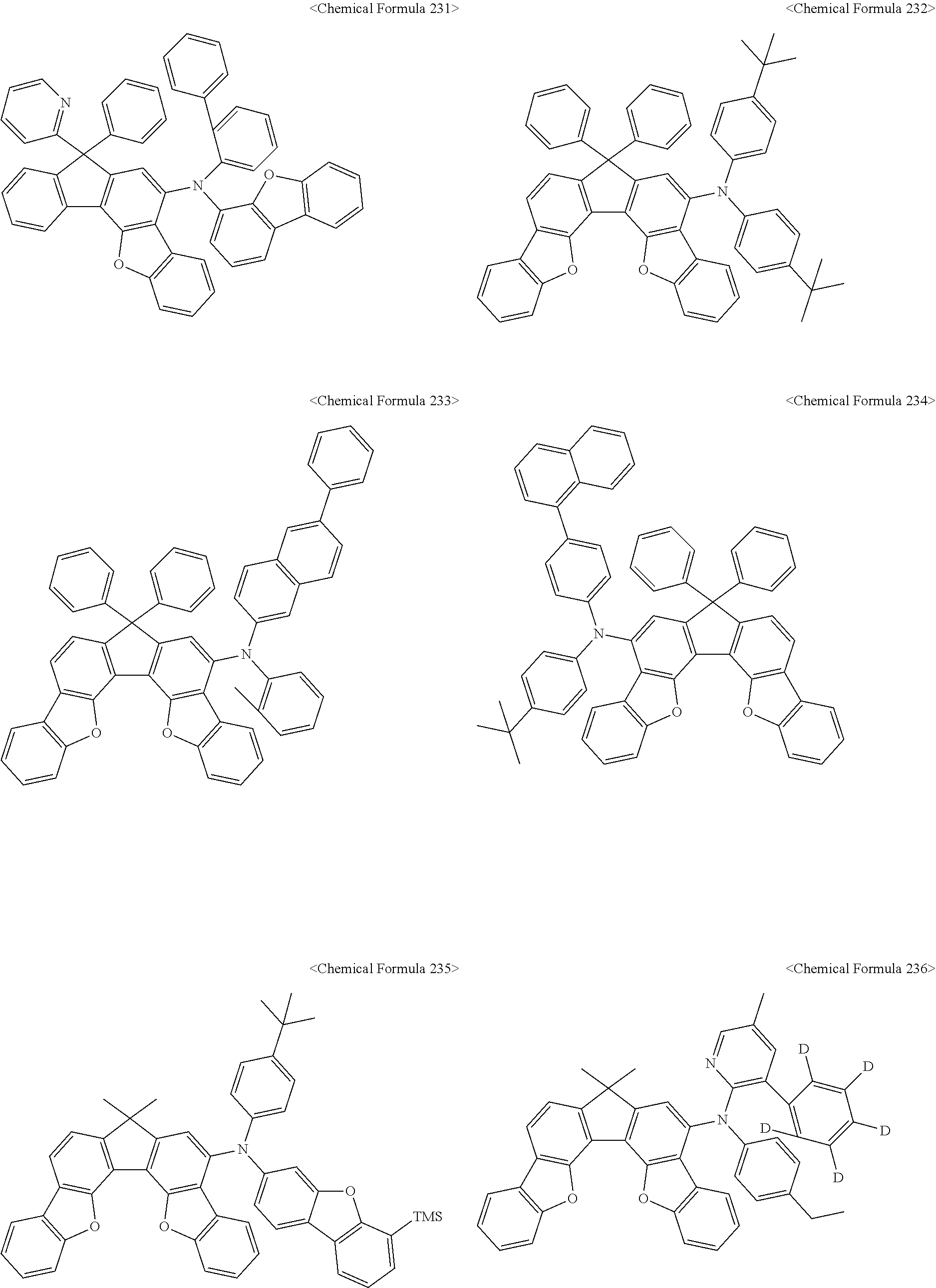

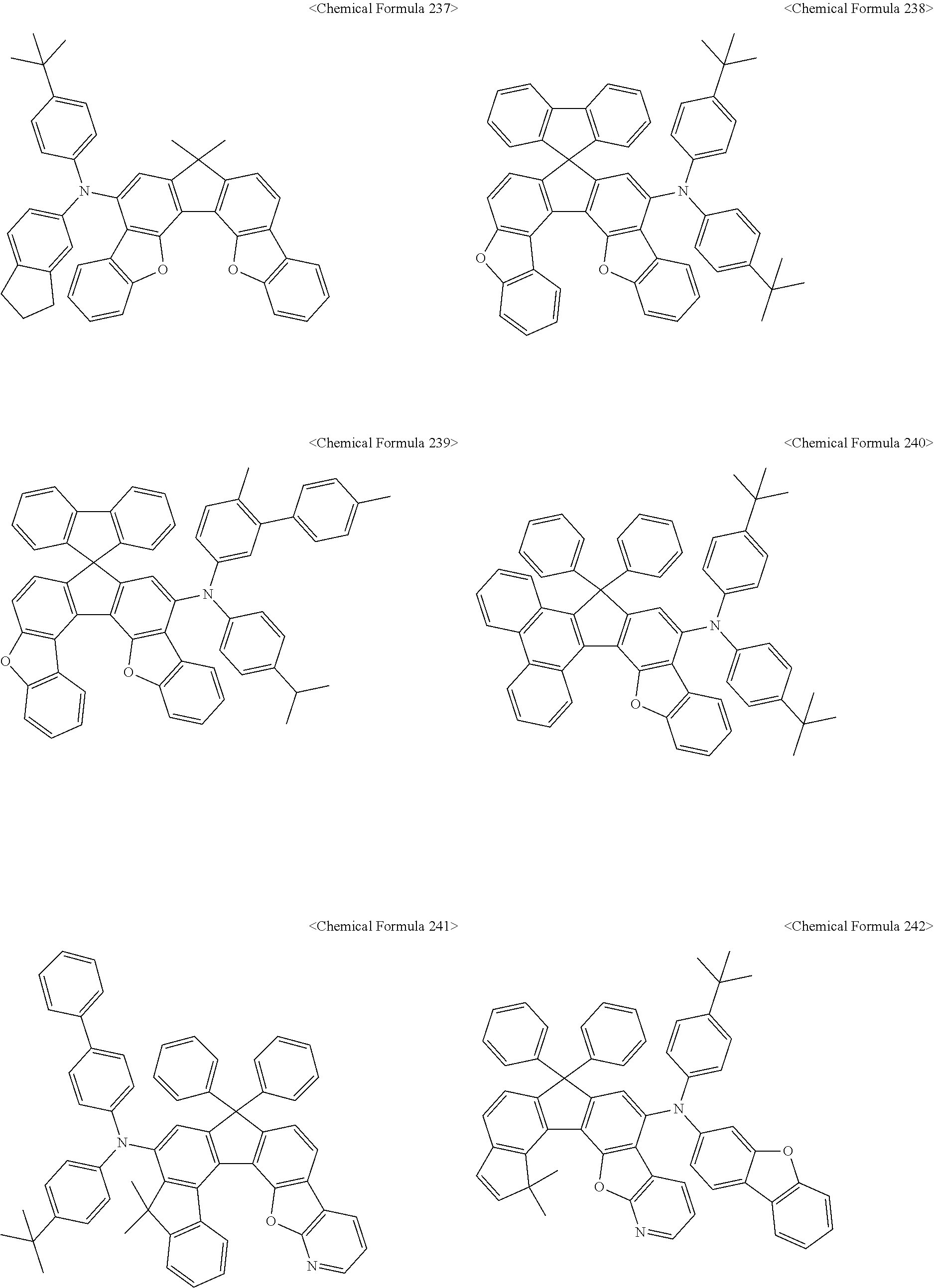

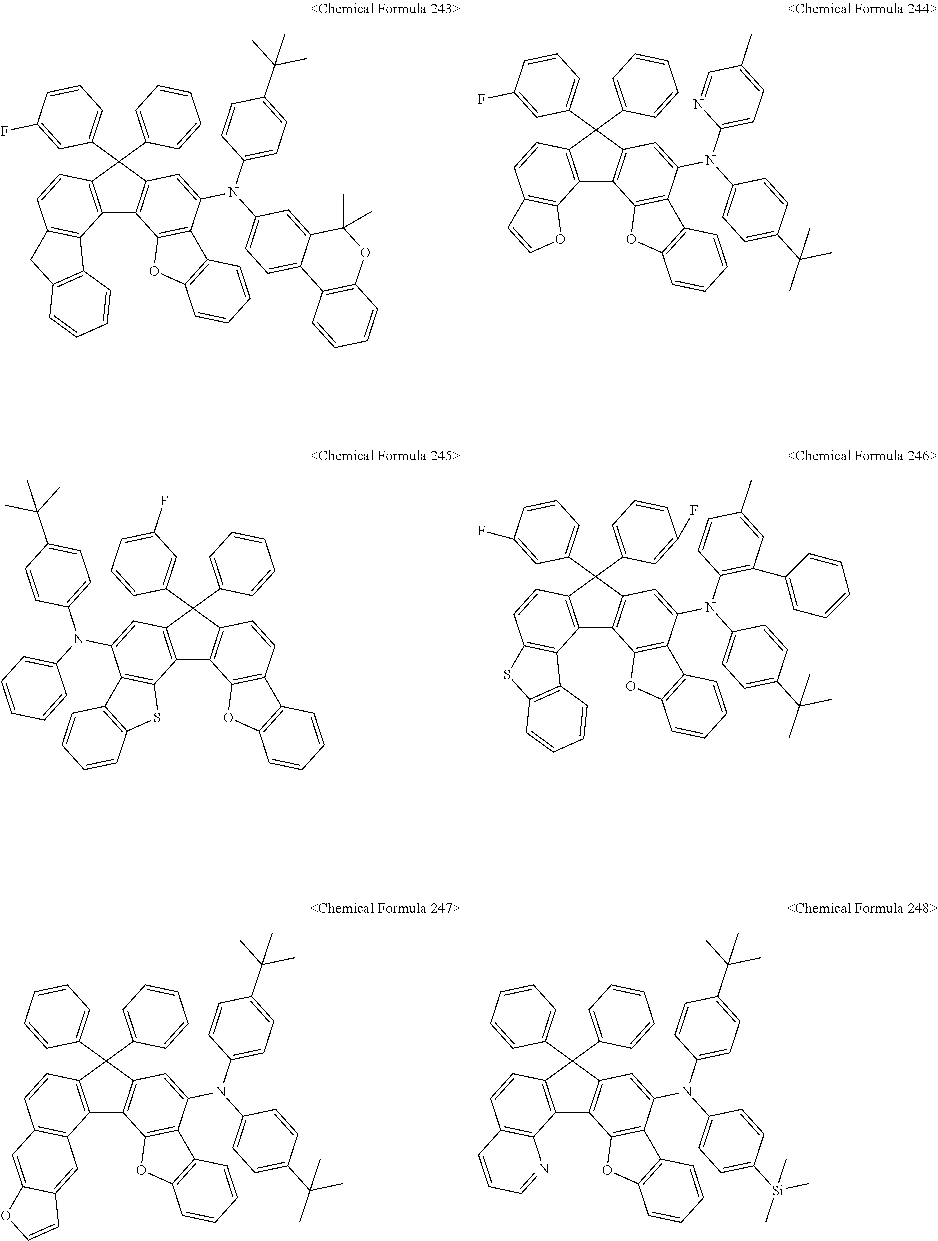

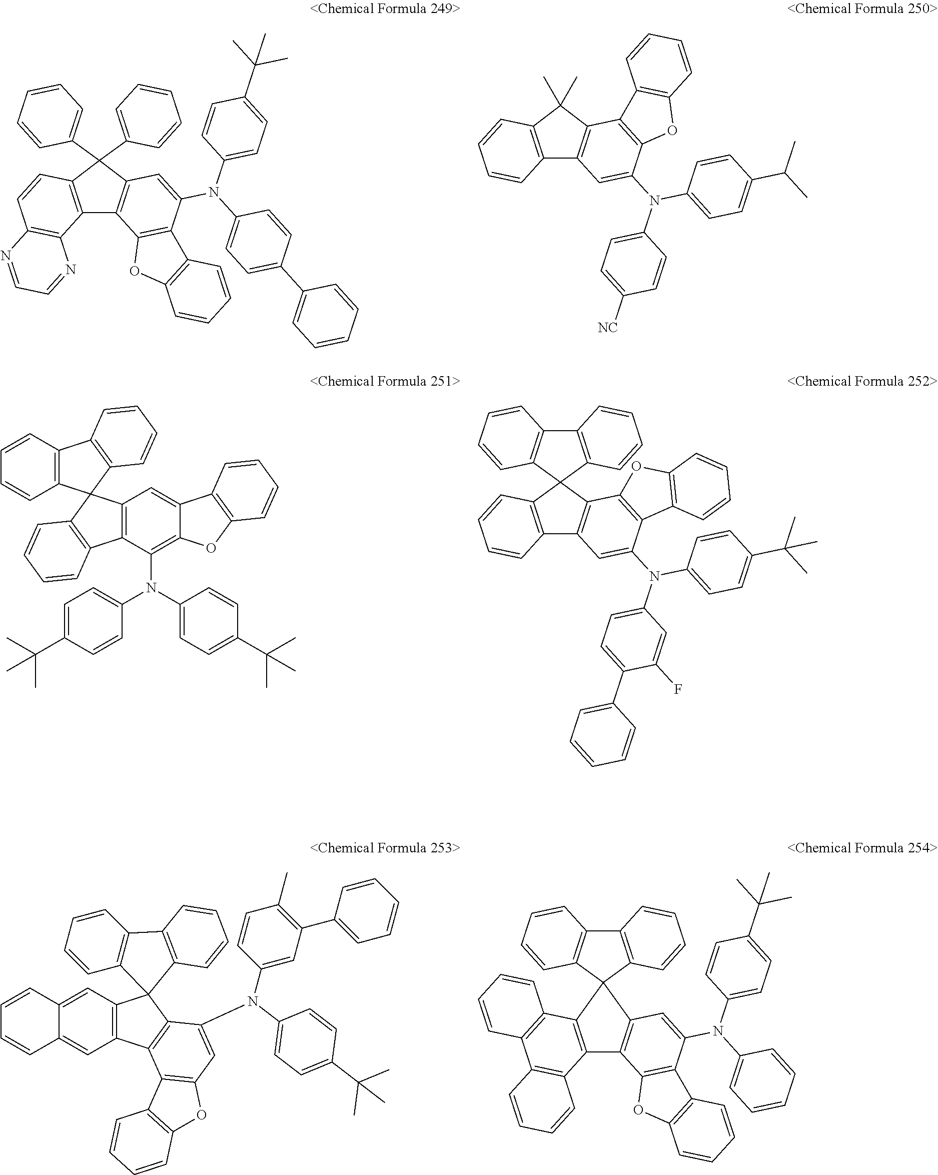

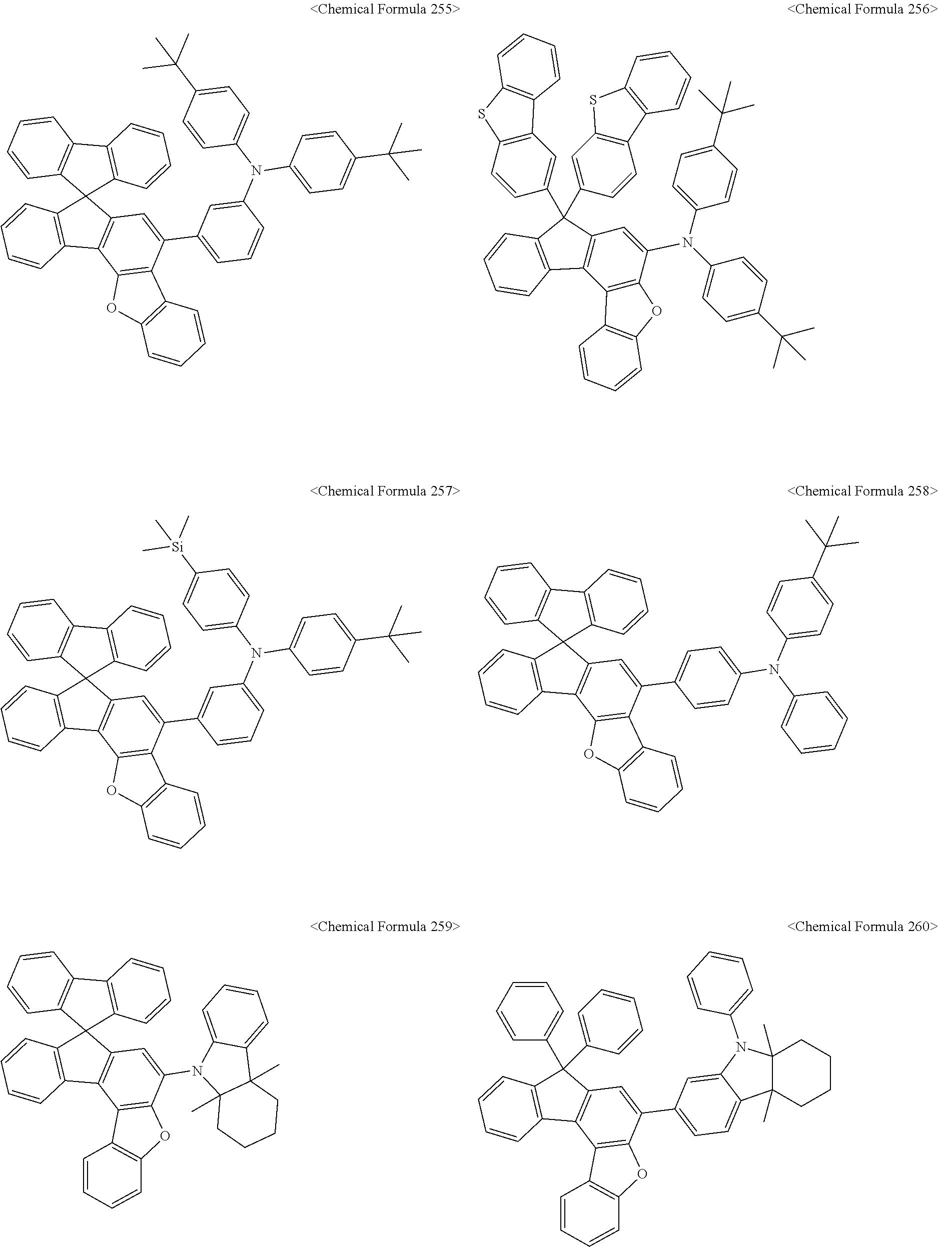

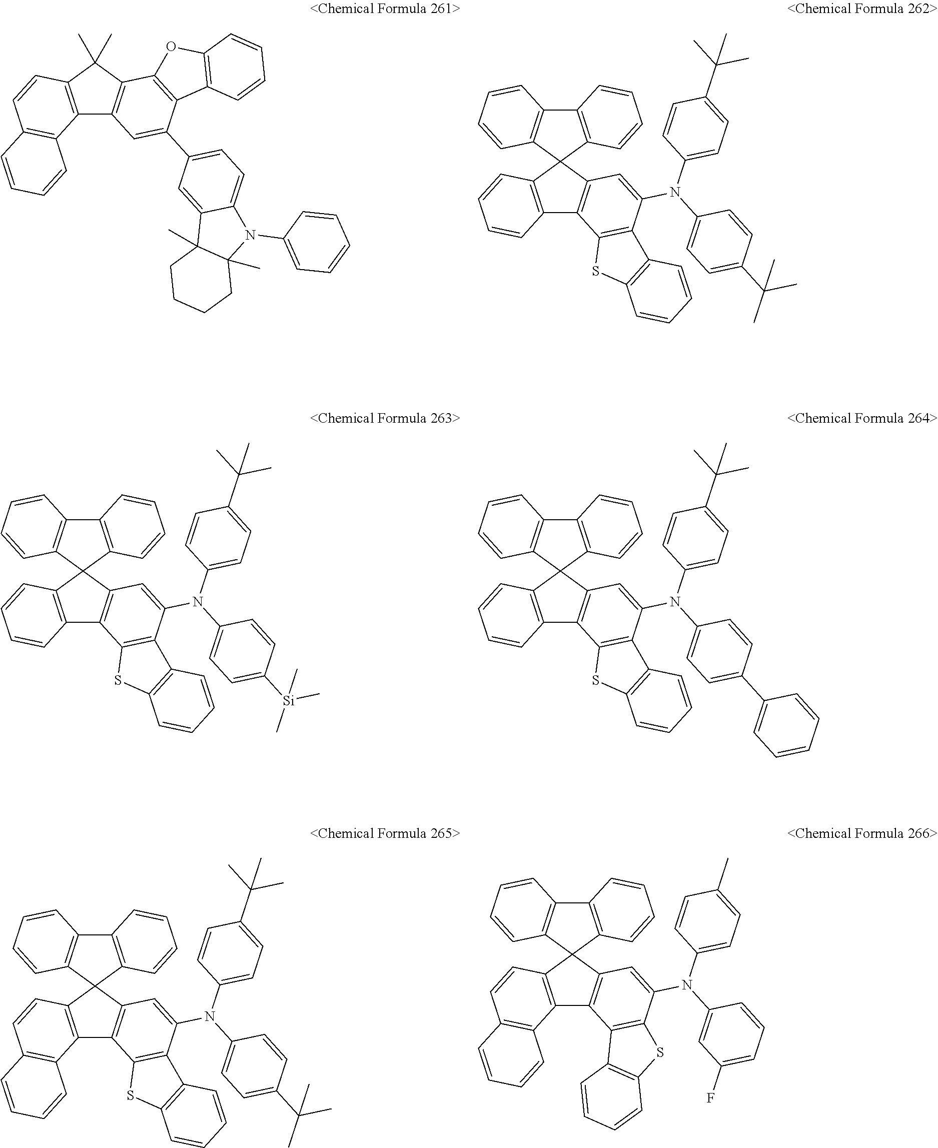

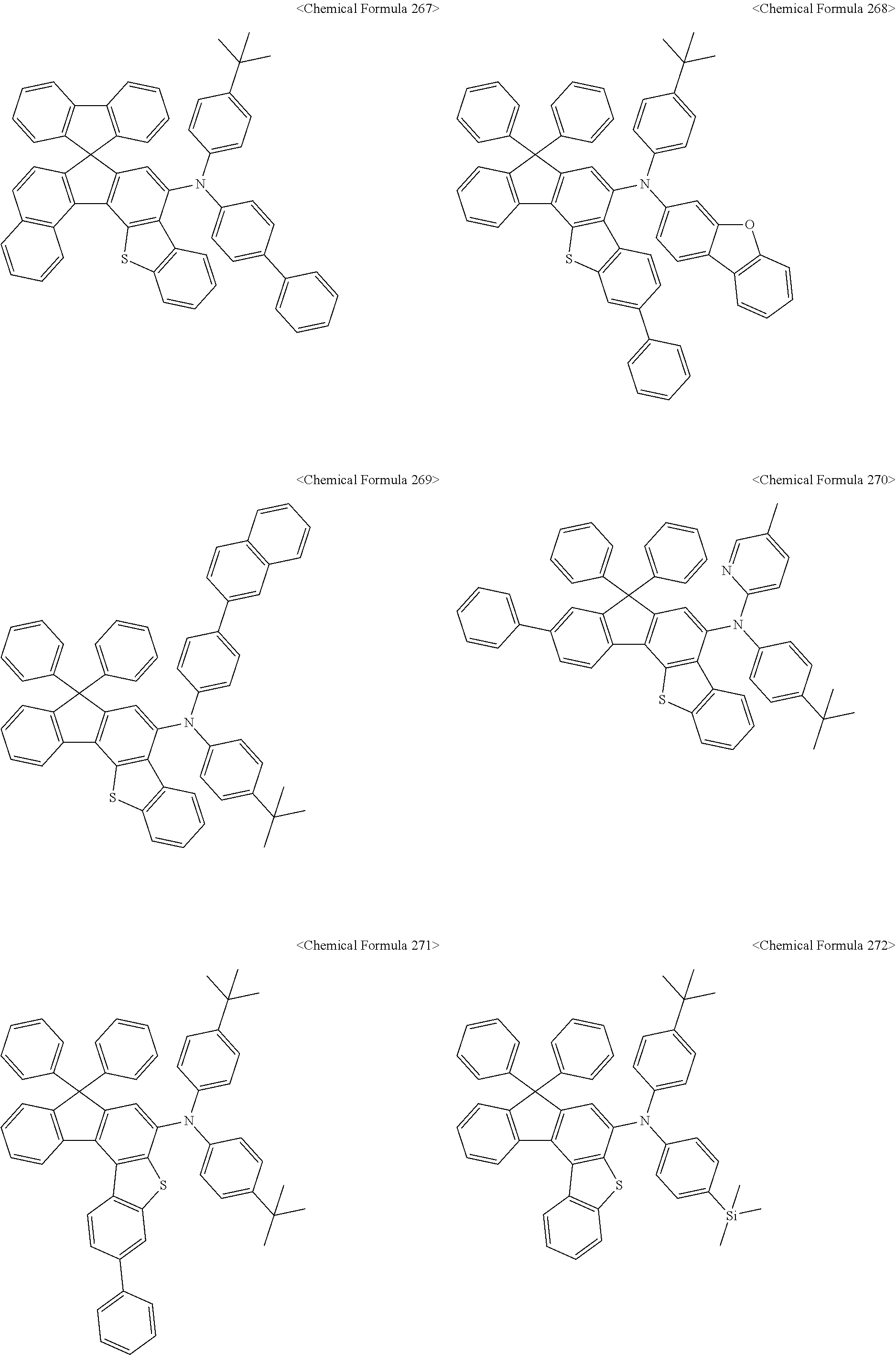

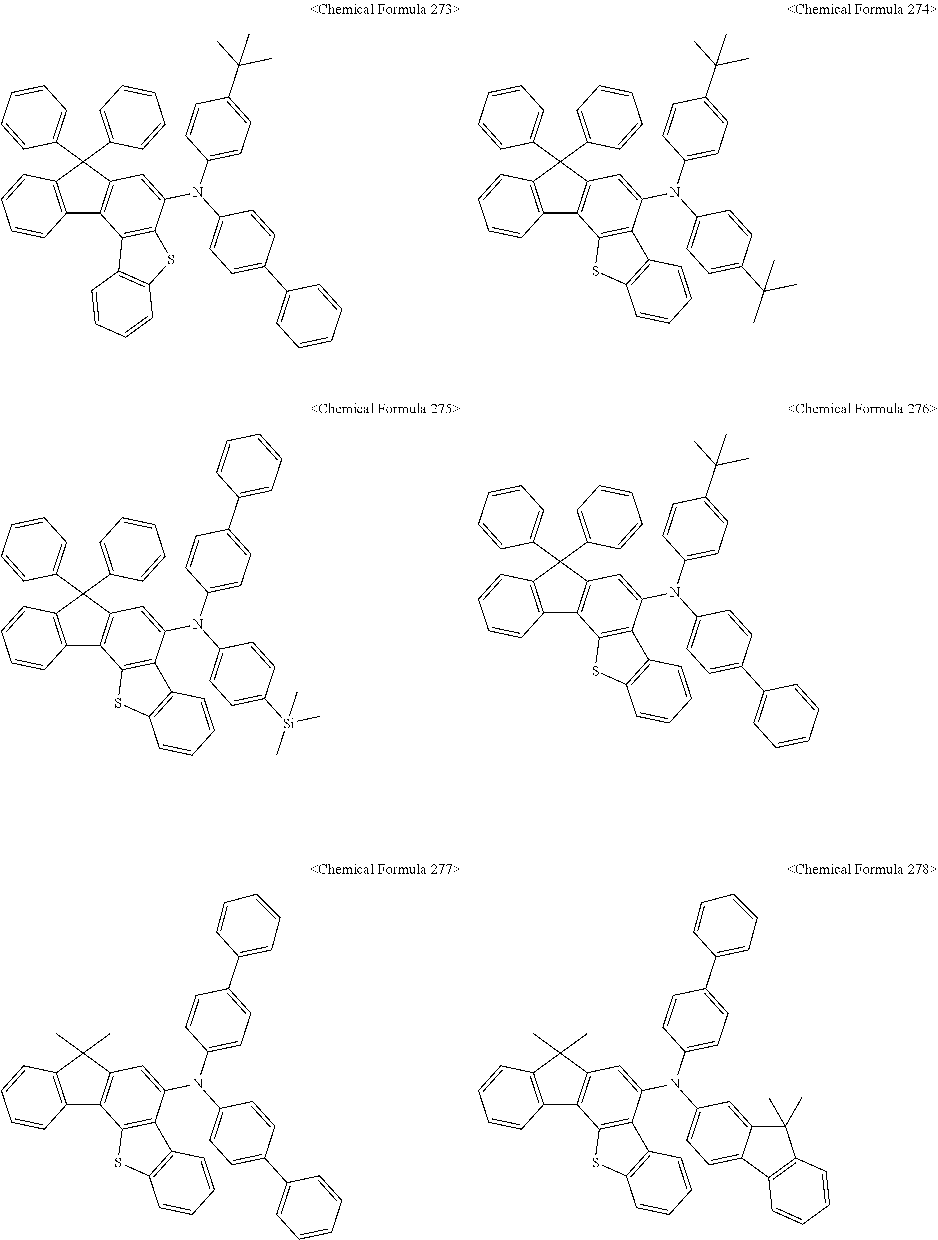

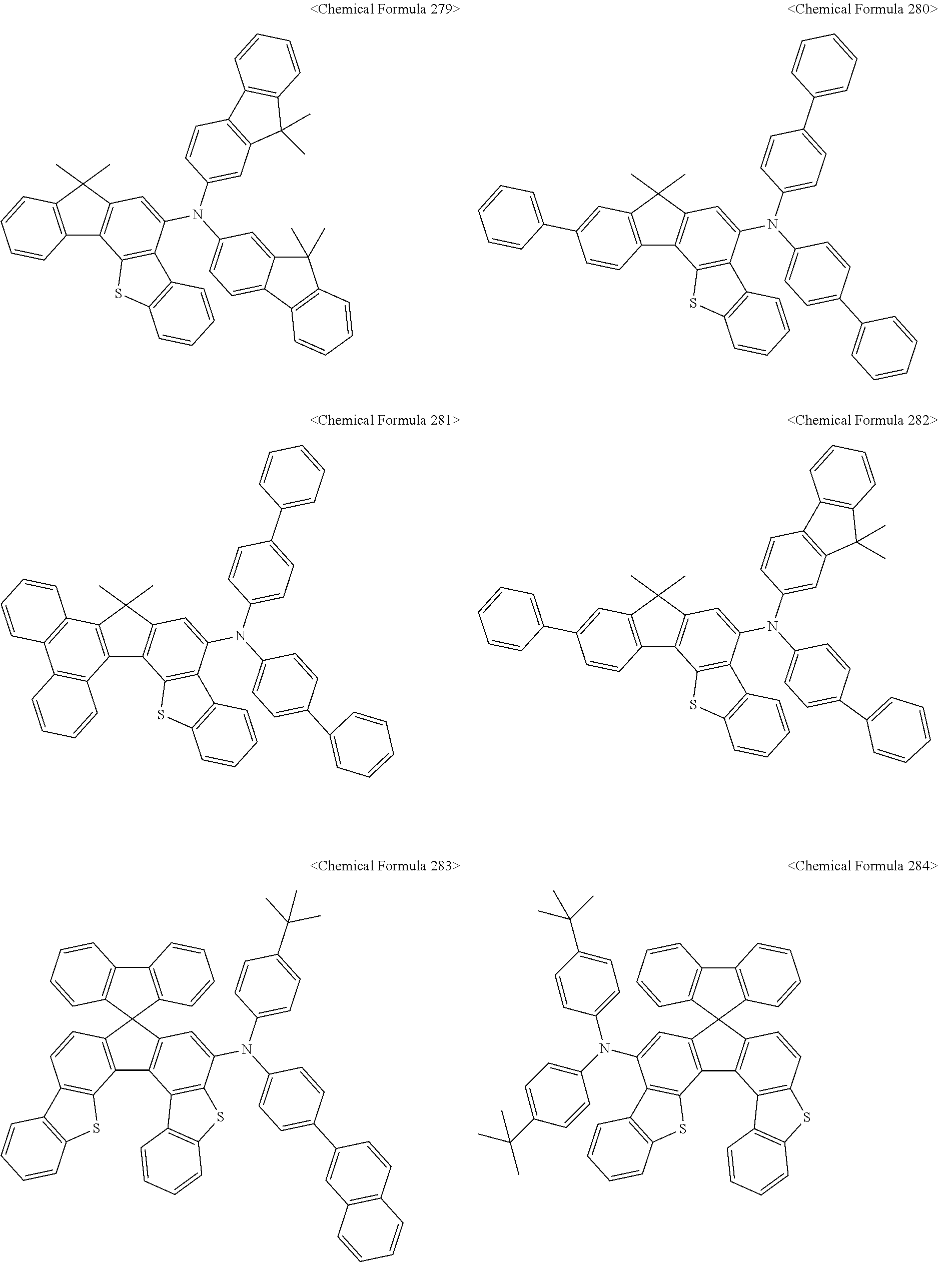

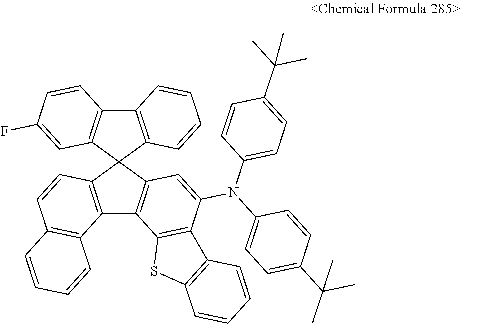 [SMILES: CC(C)(C)c1ccc(N(c2ccc(C(C)(C)C)cc2)c2cc3c(c4sc5ccccc5c24)-c2c(ccc4ccccc24)C32c3ccccc3-c3ccc(F)cc32)cc1]

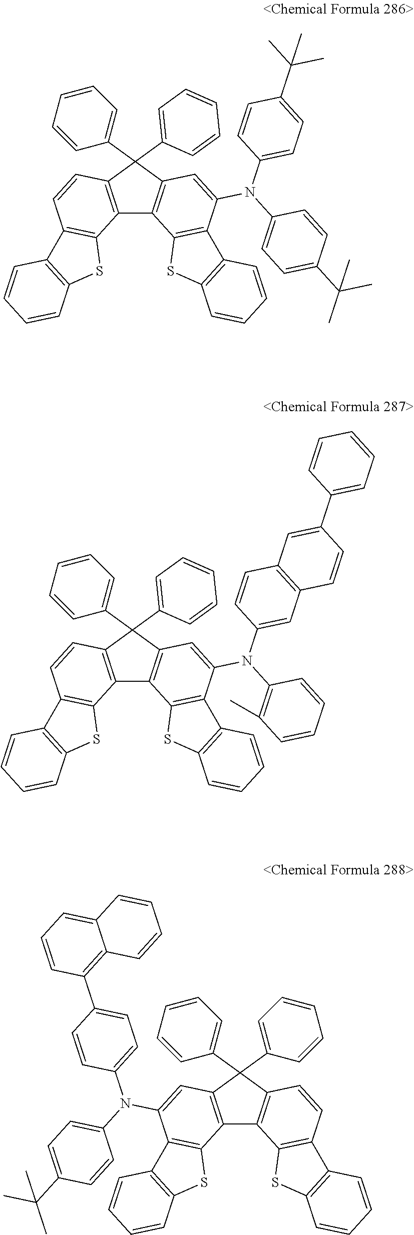

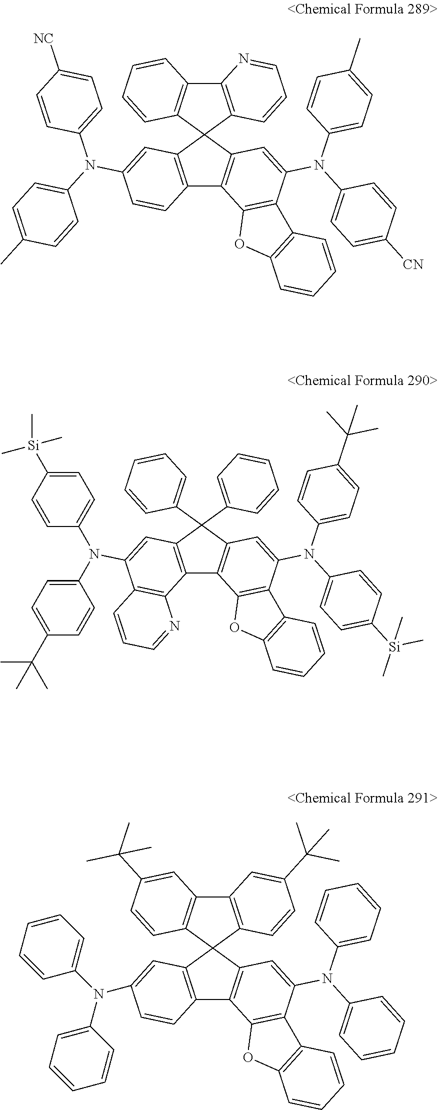 [SMILES: Cc1ccc(N(c2ccc(C#N)cc2)c2ccc3c(c2)C2(c4ccccc4-c4ncccc42)c2cc(N(c4ccc(C)cc4)c4ccc(C#N)cc4)c4c(oc5ccccc54)c2-3)cc1 ; CC(C)(C)c1ccc(N(c2ccc([Si](C)(C)C)cc2)c2cc3c(c4ncccc24)-c2c(cc(N(c4ccc(C(C)(C)C)cc4)c4ccc([Si](C)(C)C)cc4)c4c2oc2ccccc24)C3(c2ccccc2)c2ccccc2)cc1 ; CC(C)(C)c1ccc2c(c1)-c1cc(C(C)(C)C)ccc1C21c2cc(N(c3ccccc3)c3ccccc3)ccc2-c2c1cc(N(c1ccccc1)c1ccccc1)c1c2oc2ccccc21]

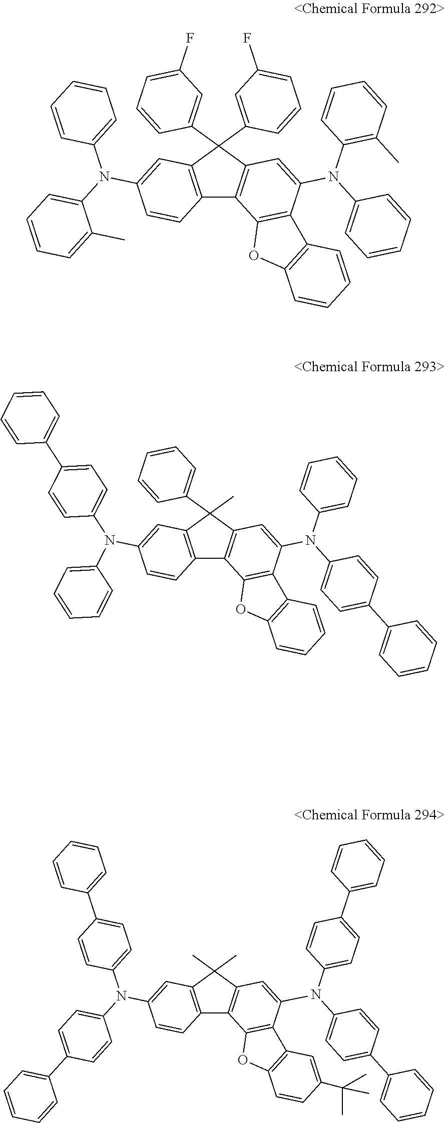 [SMILES: Cc1ccccc1N(c1ccccc1)c1ccc2c(c1)C(c1cccc(F)c1)(c1cccc(F)c1)c1cc(N(c3ccccc3)c3ccccc3C)c3c(oc4ccccc43)c1-2 ; CC1(c2ccccc2)c2cc(N(c3ccccc3)c3ccc(-c4ccccc4)cc3)ccc2-c2c1cc(N(c1ccccc1)c1ccc(-c3ccccc3)cc1)c1c2oc2ccccc21 ; CC(C)(C)c1ccc2oc3c4c(cc(N(c5ccc(-c6ccccc6)cc5)c5ccc(-c6ccccc6)cc5)c3c2c1)C(C)(C)c1cc(N(c2ccc(-c3ccccc3)cc2)c2ccc(-c3ccccc3)cc2)ccc1-4]

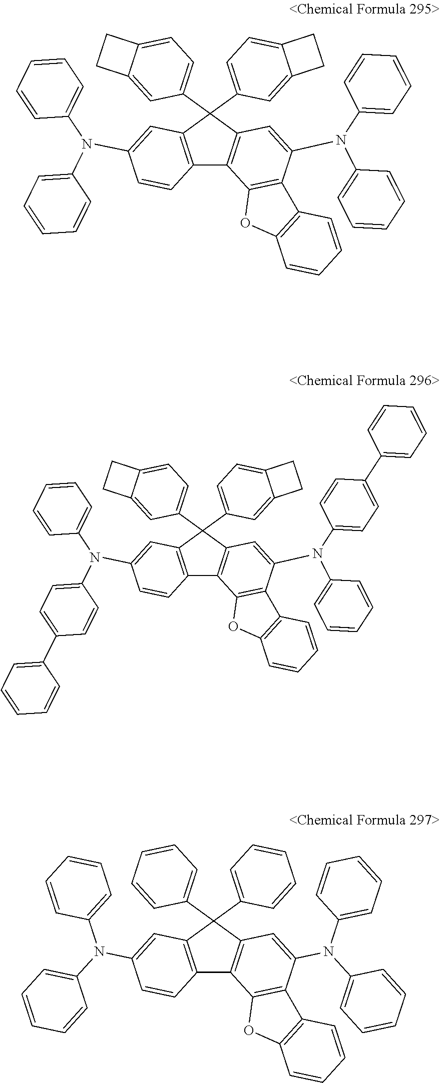 [SMILES: c1ccc(N(c2ccccc2)c2ccc3c(c2)C(c2ccc4c(c2)CC4)(c2ccc4c(c2)CC4)c2cc(N(c4ccccc4)c4ccccc4)c4c(oc5ccccc54)c2-3)cc1 ; c1ccc(-c2ccc(N(c3ccccc3)c3ccc4c(c3)C(c3ccc5c(c3)CC5)(c3ccc5c(c3)CC5)c3cc(N(c5ccccc5)c5ccc(-c6ccccc6)cc5)c5c(oc6ccccc65)c3-4)cc2)cc1 ; c1ccc(N(c2ccccc2)c2ccc3c(c2)C(c2ccccc2)(c2ccccc2)c2cc(N(c4ccccc4)c4ccccc4)c4c(oc5ccccc54)c2-3)cc1]

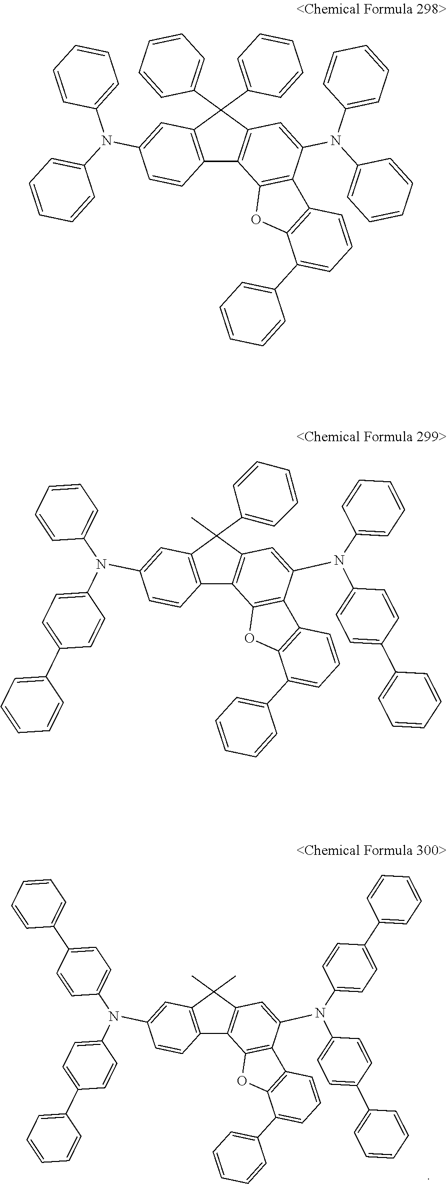 [SMILES: c1ccc(-c2cccc3c2oc2c4c(cc(N(c5ccccc5)c5ccccc5)c23)C(c2ccccc2)(c2ccccc2)c2cc(N(c3ccccc3)c3ccccc3)ccc2-4)cc1 ; CC1(c2ccccc2)c2cc(N(c3ccccc3)c3ccc(-c4ccccc4)cc3)ccc2-c2c1cc(N(c1ccccc1)c1ccc(-c3ccccc3)cc1)c1c2oc2c(-c3ccccc3)cccc21 ; CC1(C)c2cc(N(c3ccc(-c4ccccc4)cc3)c3ccc(-c4ccccc4)cc3)ccc2-c2c1cc(N(c1ccc(-c3ccccc3)cc1)c1ccc(-c3ccccc3)cc1)c1c2oc2c(-c3ccccc3)cccc21]

12. The organic light-emitting diode of claim 1, wherein the linker T₁ and T₂ are N—R₁₁ and N—R₁₄, respectively, R₁₁ and R₁₄ being each as defined in claim 1.

13. The organic light-emitting diode of claim 12, wherein the substituents R₁₁ and R₁₄ are same or different are each independently a substituted or unsubstituted aryl of 6 to 50 carbon atoms, or a substituted or unsubstituted heteroaryl of 2 to 50 carbon atoms.

14. The organic light-emitting diode of claim 1, wherein the linkers T₁ and T₂ in [Chemical Formula C] are same or different and are each independently represented by the following [Structural Formula A]: 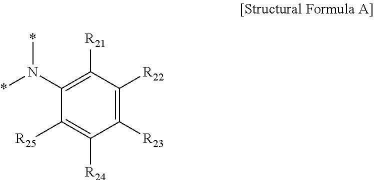
wherein,
“-*” denotes a bonding site at which the linker T₁ is connected to aromatic carbon atoms of Z₁ and Z₃ rings or the linker T₂ is connected to aromatic carbons of Z₂ and Z₃, and
R₂₁ to R₂₅, which are same or difference, are each independently a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen.

15. The organic light-emitting diode of claim 1, wherein at least one of the linkers T₁ and T₂ in Chemical Formula C is an oxygen atom.

16. The organic light-emitting diode of claim 15, wherein the linkers T₁ and T₂ in Chemical Formula C are each an oxygen atom.

17. The organic light-emitting diode of claim 1, wherein Z₁ to Z₃ rings in Chemical Formula C are same or different and are each a substituted or unsubstituted aromatic hydrocarbon ring of 6 to 50 carbon atoms.

18. The organic light-emitting diode of claim 17, wherein the aromatic hydrocarbon rings of Z₁ to Z₂ in Chemical Formula C are same or different and are each independently selected from [Structural Formula 40] to [Structural Formula 51]: 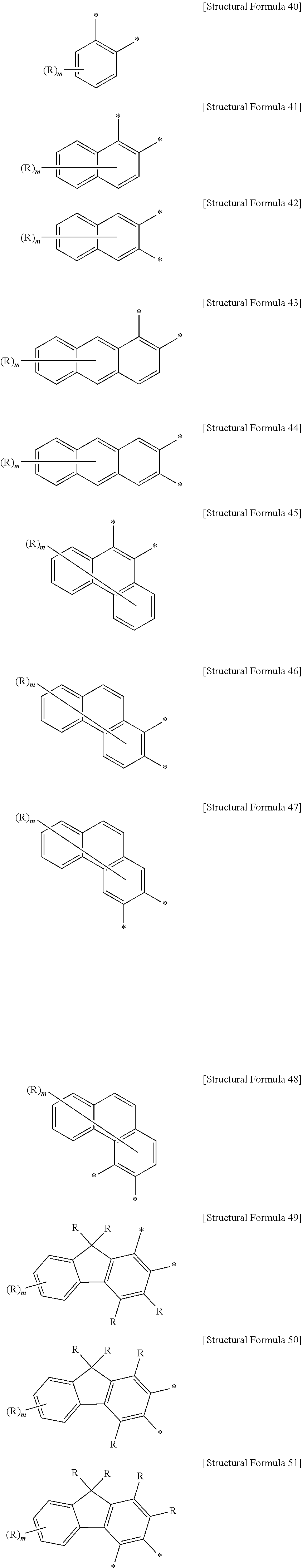
wherein,
“-*” denote a bonding site at which the corresponding carbon atoms within the aromatic ring of Z₁ are bonded to the linker T₁ and the boron atom (B) or the corresponding carbon atoms with the aromatic ring of Z₂ are bonded to the linker T₂ and the boron atom (B),
Rs, which are same or different, are selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen, and
m is an integer of 1 to 8 wherein when m is 2 or greater or when R is 2 or greater, the resulting R is same or different.

19. The organic light-emitting diode of claim 17, wherein the aromatic hydrocarbon ring of Z₃ is represented by the following [Structural Formula B]: 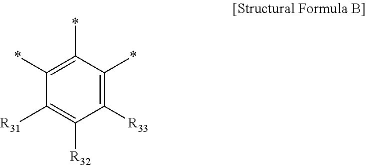
wherein,
“-*” denotes a bonding site at which the corresponding carbon atoms within the aromatic ring of Z₃ are respectively bonded to the linkers T₁ and T₂, and the boron atom (B),
R₃₁ to R₃₃ are same or different and are each independently selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted alkylamine of 1 to 30 carbon atoms, a substituted or unsubstituted arylamine of 5 to 30 carbon atoms, a substituted or unsubstituted alkylsilyl of 1 to 30 carbon atoms, a substituted or unsubstituted arylsilyl of 5 to 30 carbon atoms, a cyano, and a halogen, and
R₃₁ to R₃₃ are each linked to an adjacent substituent to form an additional mono- or polycyclic aliphatic or aromatic ring.

20. The organic light-emitting diode of claim 1, wherein the boron compound is selected from among the following <Compound 1> to <Compound 30>:

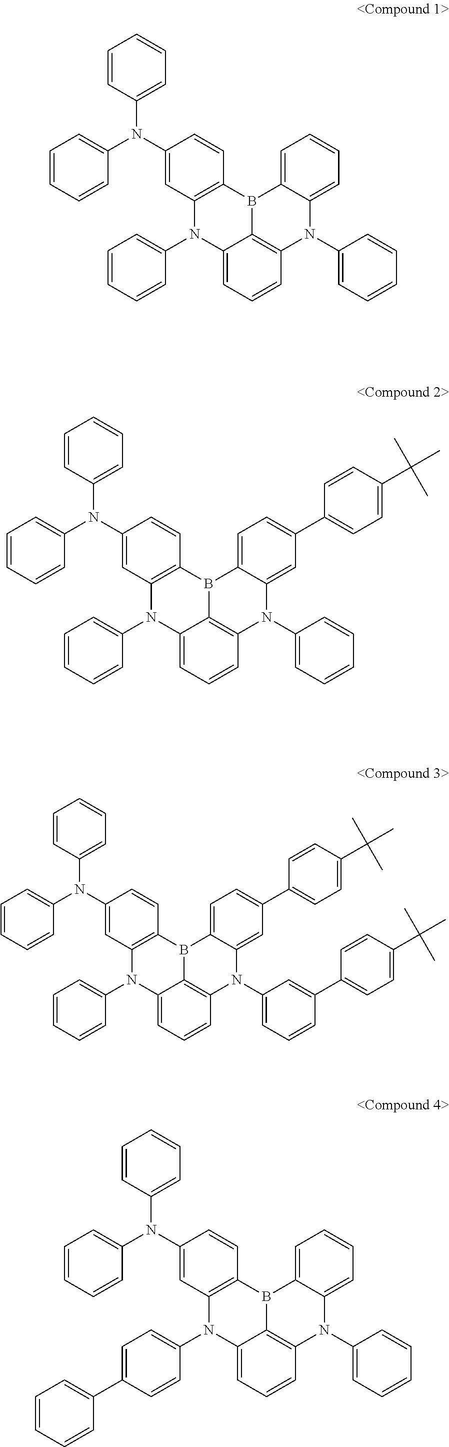 [SMILES: c1ccc(N(c2ccccc2)c2ccc3c(c2)N(c2ccccc2)c2cccc4c2B3c2ccccc2N4c2ccccc2)cc1 ; CC(C)(C)c1ccc(-c2ccc3c(c2)N(c2ccccc2)c2cccc4c2B3c2ccc(N(c3ccccc3)c3ccccc3)cc2N4c2ccccc2)cc1 ; CC(C)(C)c1ccc(-c2cccc(N3c4cc(-c5ccc(C(C)(C)C)cc5)ccc4B4c5ccc(N(c6ccccc6)c6ccccc6)cc5N(c5ccccc5)c5cccc3c54)c2)cc1 ; c1ccc(-c2ccc(N3c4cc(N(c5ccccc5)c5ccccc5)ccc4B4c5ccccc5N(c5ccccc5)c5cccc3c54)cc2)cc1]

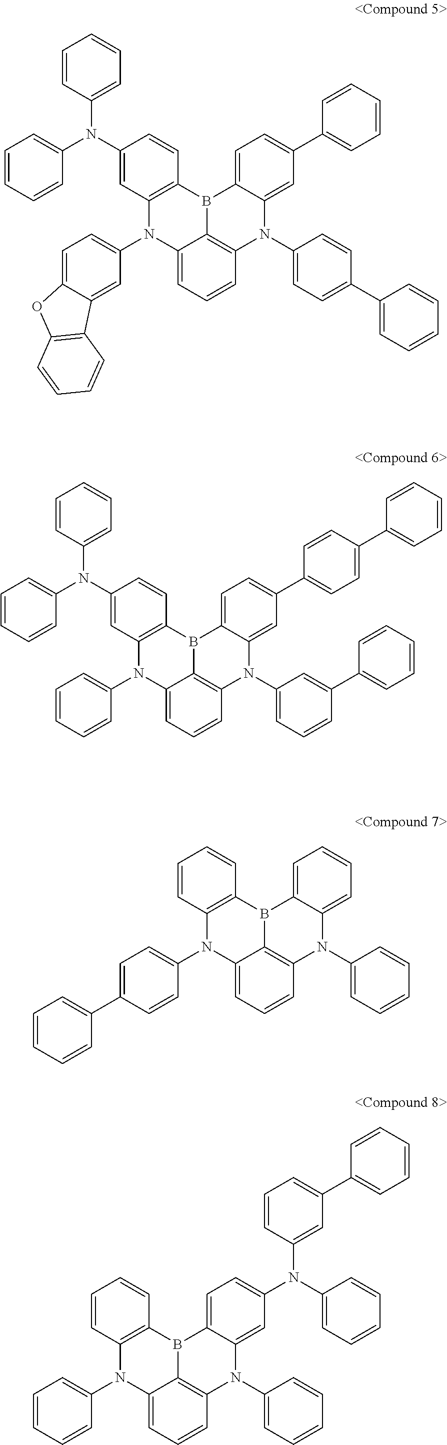 [SMILES: c1ccc(-c2ccc(N3c4cc(-c5ccccc5)ccc4B4c5ccc(N(c6ccccc6)c6ccccc6)cc5N(c5ccc6oc7ccccc7c6c5)c5cccc3c54)cc2)cc1 ; c1ccc(-c2ccc(-c3ccc4c(c3)N(c3cccc(-c5ccccc5)c3)c3cccc5c3B4c3ccc(N(c4ccccc4)c4ccccc4)cc3N5c3ccccc3)cc2)cc1 ; c1ccc(-c2ccc(N3c4ccccc4B4c5ccccc5N(c5ccccc5)c5cccc3c54)cc2)cc1 ; c1ccc(-c2cccc(N(c3ccccc3)c3ccc4c(c3)N(c3ccccc3)c3cccc5c3B4c3ccccc3N5c3ccccc3)c2)cc1]

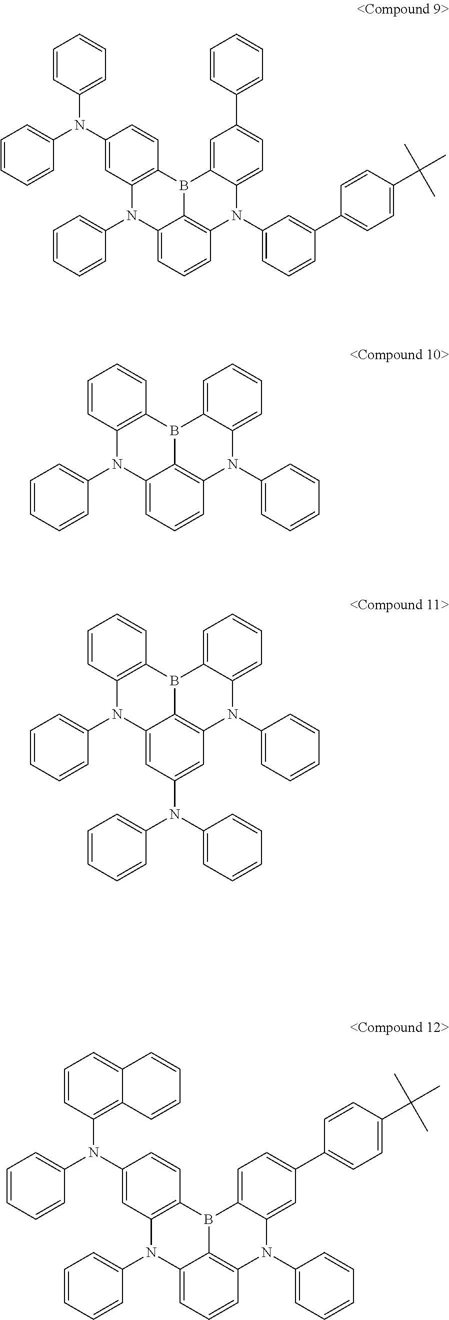 [SMILES: CC(C)(C)c1ccc(-c2cccc(N3c4ccc(-c5ccccc5)cc4B4c5ccc(N(c6ccccc6)c6ccccc6)cc5N(c5ccccc5)c5cccc3c54)c2)cc1 ; c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; CC(C)(C)c1ccc(-c2ccc3c(c2)N(c2ccccc2)c2cccc4c2B3c2ccc(N(c3ccccc3)c3cccc5ccccc35)cc2N4c2ccccc2)cc1]

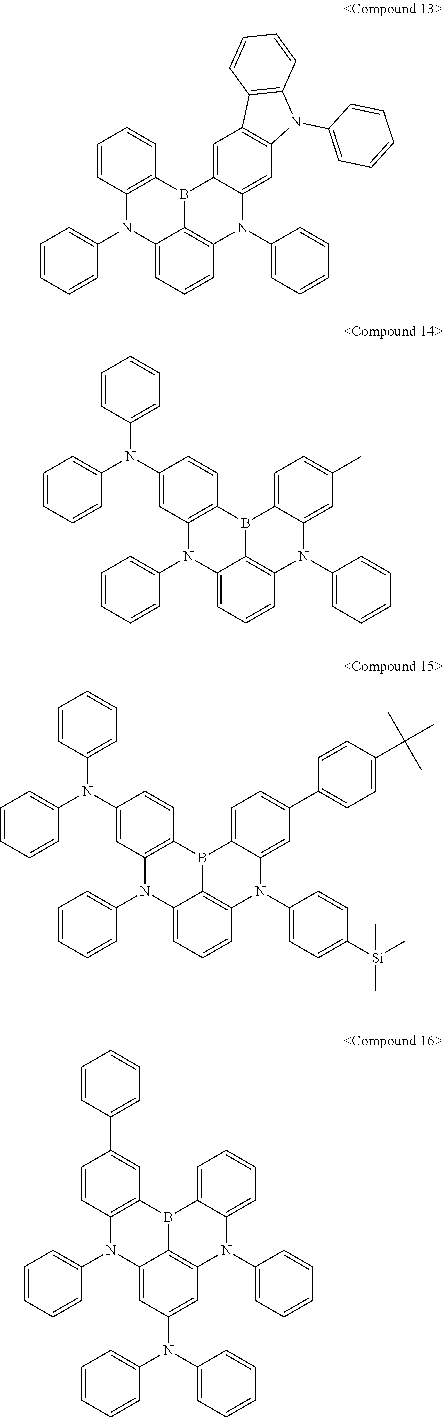 [SMILES: c1ccc(N2c3ccccc3B3c4cc5c6ccccc6n(-c6ccccc6)c5cc4N(c4ccccc4)c4cccc2c43)cc1 ; Cc1ccc2c(c1)N(c1ccccc1)c1cccc3c1B2c1ccc(N(c2ccccc2)c2ccccc2)cc1N3c1ccccc1 ; CC(C)(C)c1ccc(-c2ccc3c(c2)N(c2ccc([Si](C)(C)C)cc2)c2cccc4c2B3c2ccc(N(c3ccccc3)c3ccccc3)cc2N4c2ccccc2)cc1 ; c1ccc(-c2ccc3c(c2)B2c4ccccc4N(c4ccccc4)c4cc(N(c5ccccc5)c5ccccc5)cc(c42)N3c2ccccc2)cc1]

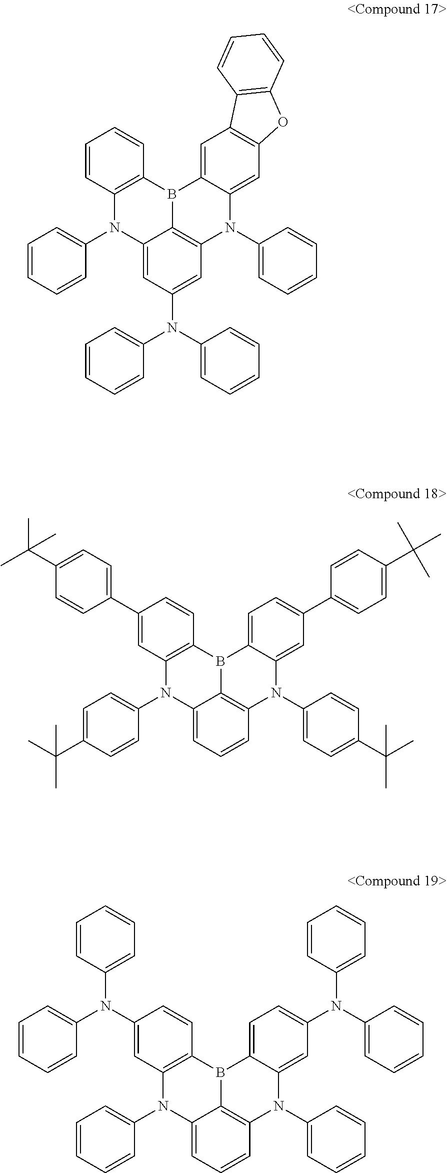 [SMILES: c1ccc(N(c2ccccc2)c2cc3c4c(c2)N(c2ccccc2)c2cc5oc6ccccc6c5cc2B4c2ccccc2N3c2ccccc2)cc1 ; CC(C)(C)c1ccc(-c2ccc3c(c2)N(c2ccc(C(C)(C)C)cc2)c2cccc4c2B3c2ccc(-c3ccc(C(C)(C)C)cc3)cc2N4c2ccc(C(C)(C)C)cc2)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1]

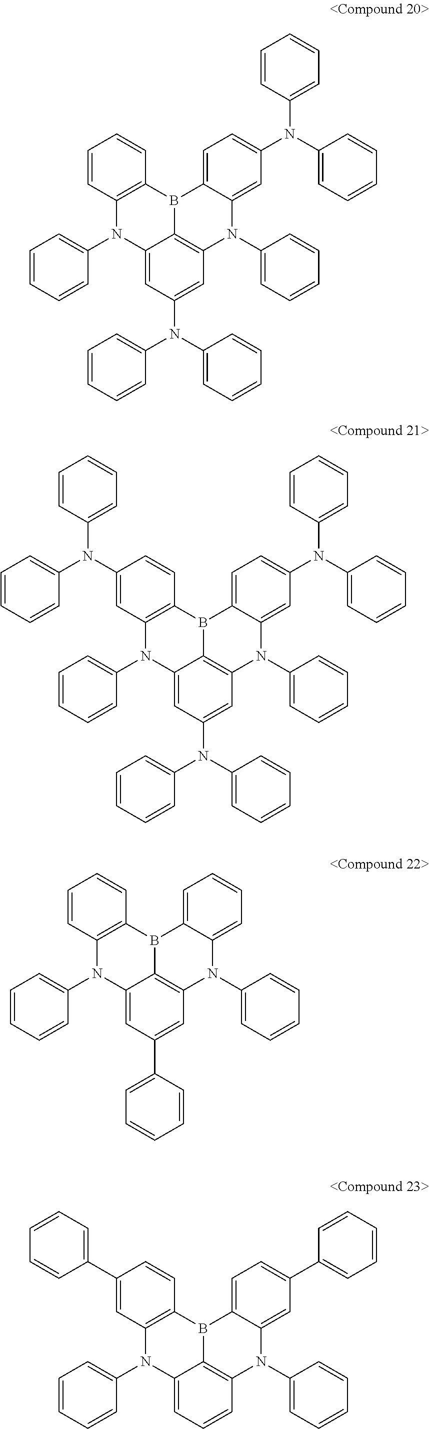 [SMILES: c1ccc(N(c2ccccc2)c2ccc3c(c2)N(c2ccccc2)c2cc(N(c4ccccc4)c4ccccc4)cc4c2B3c2ccccc2N4c2ccccc2)cc1 ; c1ccc(N(c2ccccc2)c2ccc3c(c2)N(c2ccccc2)c2cc(N(c4ccccc4)c4ccccc4)cc4c2B3c2ccc(N(c3ccccc3)c3ccccc3)cc2N4c2ccccc2)cc1 ; c1ccc(-c2cc3c4c(c2)N(c2ccccc2)c2ccccc2B4c2ccccc2N3c2ccccc2)cc1 ; c1ccc(-c2ccc3c(c2)N(c2ccccc2)c2cccc4c2B3c2ccc(-c3ccccc3)cc2N4c2ccccc2)cc1]

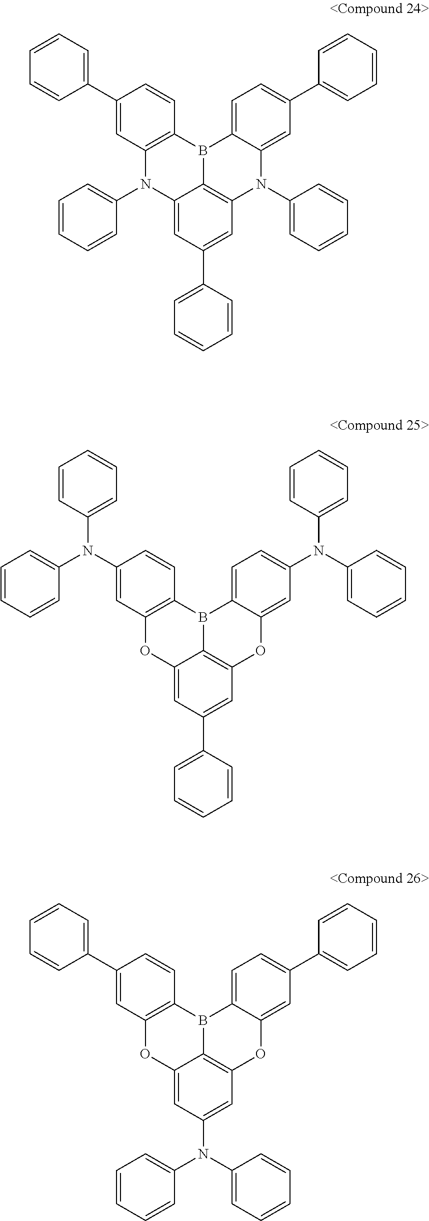 [SMILES: c1ccc(-c2ccc3c(c2)N(c2ccccc2)c2cc(-c4ccccc4)cc4c2B3c2ccc(-c3ccccc3)cc2N4c2ccccc2)cc1 ; c1ccc(-c2cc3c4c(c2)Oc2cc(N(c5ccccc5)c5ccccc5)ccc2B4c2ccc(N(c4ccccc4)c4ccccc4)cc2O3)cc1 ; c1ccc(-c2ccc3c(c2)Oc2cc(N(c4ccccc4)c4ccccc4)cc4c2B3c2ccc(-c3ccccc3)cc2O4)cc1]

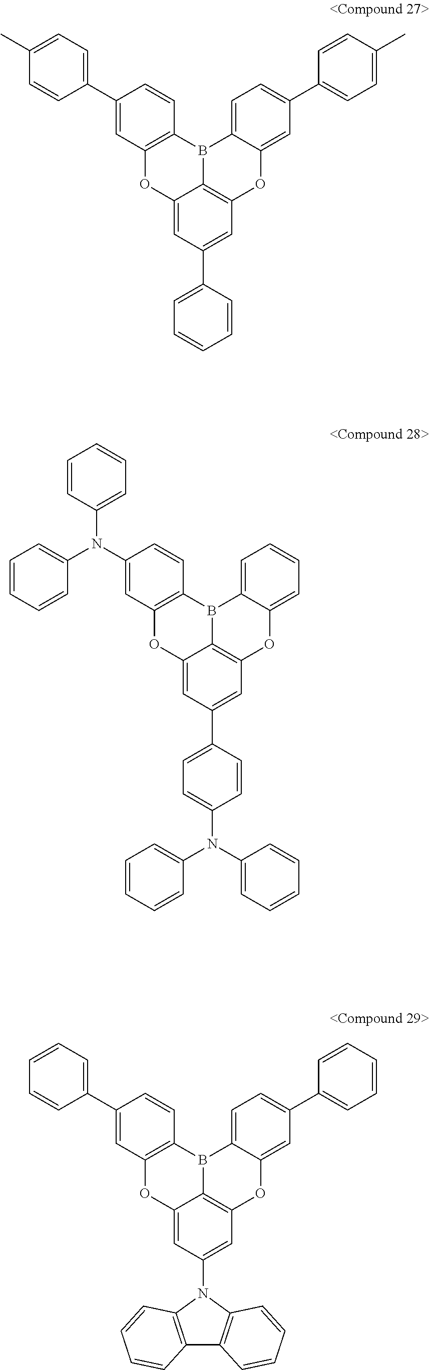

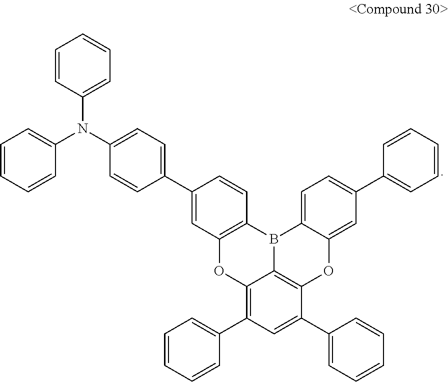 [SMILES: c1ccc(-c2ccc3c(c2)Oc2c(-c4ccccc4)cc(-c4ccccc4)c4c2B3c2ccc(-c3ccc(N(c5ccccc5)c5ccccc5)cc3)cc2O4)cc1]

21. The organic light-emitting diode of claim 1, further comprising at least one of a hole injection layer, a hole transport layer, a functional layer capable of both hole injection and hole transport, an electron transport layer, and an electron injection layer in addition to the light-emitting layer.

22. The organic light-emitting diode of claim 21, wherein the at least one selected from among the layers is formed using a deposition process or a solution process.

23. The organic light-emitting diode of claim 1, wherein the organic light-emitting diode is used for a device selected from among a flat display device, a flexible display device, a monochrome or grayscale flat illumination device, and a monochrome or grayscale flexible illumination device.
